(19) United States
(12) Patent Application Publication
(10) Pub. No.: US 2023/0203074 A1
(43) Pub. Date: Jun. 29, 2023

(54) ORGANOMETALLIC COMPOUND AND ORGANIC LIGHT-EMITTING DIODE INCLUDING THE SAME

(71) Applicants: LG DISPLAY CO., LTD., Seoul (KR); ROHM AND HAAS ELECTRONIC MATERIALS KOREA LTD., Cheonan-si (KR)

(72) Inventors: Hansol PARK, Goyang-si (KR); Yoojeong JEONG, Seoul (KR); Kusun CHOUNG, Seoul (KR); Kyoung-Jin PARK, Hwaseong-si (KR); Hyun KIM, Hwaseong-si (KR); Jin Ri HONG, Hwaseong-s (KR); Yeon Gun LEE, Hwaseong-si (KR)

(73) Assignees: LG DISPLAY CO., LTD., Seoul (KR); ROHM AND HAAS ELECTRONIC MATERIALS KOREA LTD., Cheonan-si (KR)

(21) Appl. No.: 18/084,532

(22) Filed: Dec. 19, 2022

(30) Foreign Application Priority Data
Dec. 27, 2021 (KR) 10-2021-0188300

(51) Int. Cl. C07F 15/00; H10K 85/30

(52) U.S. Cl. CPC C07F 15/0033; H10K 85/342; C07B 2200/05; H10K 2101/10

(57) ABSTRACT

Disclosed is a novel organometallic compound represented by following Chemical Formula 1. The organometallic compound acts as a dopant of a phosphorescent light-emitting layer of an organic light-emitting diode. Thus, an operation voltage of the diode is lowered, and luminous efficiency and a lifespan thereof are improved, and red-shift is suppressed:

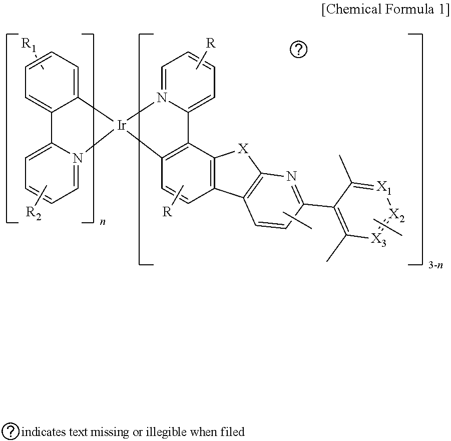

### CROSS-REFERENCE TO RELATED APPLICATION

This application claims priority from Korean Patent Application No. 10-2021-0188300 filed on Dec. 27, 2021 in the Korean Intellectual Property Office, and all the benefits accruing therefrom under 35 U.S.C. 119, the contents of which in its entirety are herein incorporated by reference.

### BACKGROUND

### Field

The present disclosure relates to an organometallic compound, and more particularly, to an organometallic compound having phosphorescent properties and an organic light-emitting diode including the same.

### Description of Related Art

As a display device is applied to various fields, interest with the display device is increasing. One of the display devices is an organic light-emitting display device including an organic light-emitting diode (OLED) which is rapidly developing.

In the organic light-emitting diode, when electric charges are injected into a light-emitting layer formed between a positive electrode and a negative electrode, an electron and a hole are recombined with each other in the light-emitting layer to form an exciton and thus energy of the exciton is converted to light. Thus, the organic light-emitting diode emits the light. Compared to conventional display devices, the organic light-emitting diode may operate at a low voltage, consume relatively little power, render excellent colors, and may be used in a variety of ways because a flexible substrate may be applied thereto. Further, a size of the organic light-emitting diode may be freely adjustable.

### SUMMARY

The organic light-emitting diode (OLED) has superior viewing angle and contrast ratio compared to a liquid crystal display (LCD), and is lightweight and is ultra-thin because the OLED does not require a backlight. The organic light-emitting diode includes a plurality of organic layers between a negative electrode (electron injection electrode; cathode) and a positive electrode (hole injection electrode; anode). The plurality of organic layers may include a hole injection layer, a hole transport layer, a hole transport auxiliary layer, an electron blocking layer, and a light-emitting layer, an electron transport layer, etc.

In this organic light-emitting diode structure, when a voltage is applied across the two electrodes, electrons and holes are injected from the negative and positive electrodes, respectively, into the light-emitting layer and thus excitons are generated in the light-emitting layer and then fall to a ground state to emit light.

Organic materials used in the organic light-emitting diode may be largely classified into light-emitting materials and charge-transporting materials. The light-emitting material is an important factor determining luminous efficiency of the organic light-emitting diode. The luminescent material has high quantum efficiency, excellent electron and hole mobility, and exists uniformly and stably in the light-emitting layer. The light-emitting materials may be classified into light-emitting materials emitting light of blue, red, and green colors based on colors of the light. A color-generating material may include a host and dopants to increase the color purity and luminous efficiency through energy transfer.

In recent years, there is a trend to use phosphorescent materials rather than fluorescent materials for the light-emitting layer. When the fluorescent material is used, singlets as about 25% of excitons generated in the light-emitting layer are used to emit light, while most of triplets as 75% of the excitons generated in the light-emitting layer are dissipated as heat. However, when the phosphorescent material is used, singlets and triplets are used to emit light.

Conventionally, an organometallic compound is used as the phosphorescent material used in the organic light-emitting diode. Research and development of the phosphorescent material to solve low efficiency and lifetime problems are continuously required.

Accordingly, a purpose of the present invention is to provide an organometallic compound capable of lowering operation voltage, and improving efficiency, and lifespan, and an organic light-emitting diode including an organic light-emitting layer containing the same.

Purposes of the present disclosure are not limited to the above-mentioned purpose. Other purposes and advantages of the present disclosure that are not mentioned may be understood based on following descriptions, and may be more clearly understood based on embodiments of the present disclosure. Further, it will be easily understood that the purposes and advantages of the present disclosure may be realized using means shown in the claims and combinations thereof.

In order to achieve the above purpose, one aspect of the present disclosure provides an organometallic compound having a novel structure represented by following Chemical Formula 1, an organic light-emitting diode in which a light-emitting layer contains the same as dopants thereof, and an organic light-emitting display device including the organic light-emitting diode:

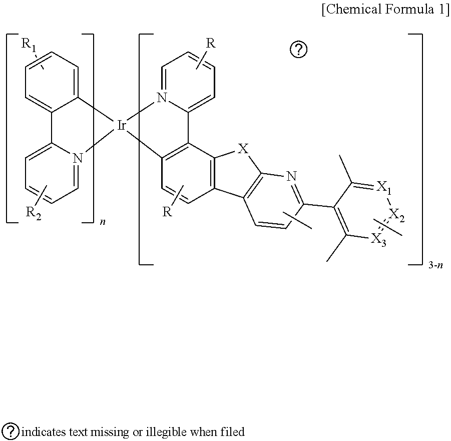

wherein in Chemical Formula 1,

X may represent one selected from a group consisting of O, S and Se;

each of X₁, X₂ and X₃ may independently represent N or CRₐ;

each of R₁, R₂ and R₃ may independently represent mono-substitution, di-substitution, tri-substitution, tetra-substitution or no-substitution;

each of R₅, R₆, R₇, and Rₐ may independently represent mono-substitution, di-substitution, tri-substitution, or no-substitution;

each of R₄ and R₈ may independently represent mono-substitution, di-substitution, or no-substitution;

each of R₁, R₂, R₃, R₄, R₇, R₈ and Rₐ may independently represent one selected from a group consisting of hydrogen, deuterium, halide, deuterated or undeuterated alkyl, cycloalkyl, heteroalkyl, arylalkyl, alkoxy, aryloxy, amino, silyl, alkenyl, cycloalkenyl, heteroalkenyl, alkynyl, aryl, heteroaryl, acyl, carbonyl, carboxylic acid, ester, nitrile, isonitrile, sulfanyl, sulfinyl, sulfonyl, phosphino, and combinations thereof,

each of R₅ and R₆ may independently represent one selected from a group consisting of halide, deuterated or undeuterated alkyl, cycloalkyl, heteroalkyl, arylalkyl, alkoxy, aryloxy, amino, silyl, alkenyl, cycloalkenyl, heteroalkenyl, alkynyl, aryl, heteroaryl, acyl, carbonyl, carboxylic acid, ester, nitrile, isonitrile, sulfanyl, sulfinyl, sulfonyl, phosphino, and combinations thereof, and

n may be 0, 1 or 2.

Another aspect of the present disclosure provides an organic light-emitting device comprising: a first electrode; a second electrode facing the first electrode; and an organic layer disposed between the first electrode and the second electrode, wherein the organic layer includes a light-emitting layer, wherein the light-emitting layer contains a dopant material, wherein the dopant material includes the organometallic compound as defined above.

Still another aspect of the present disclosure provides an organic light-emitting device comprising: a first electrode and a second electrode facing each other; and a first light-emitting stack and a second light-emitting stack positioned between the first electrode and the second electrode, wherein each of the first light-emitting stack and the second light-emitting stack includes at least one light-emitting layer, wherein at least one of the light-emitting layers is a green phosphorescent light-emitting layer, wherein the green phosphorescent light-emitting layer contains a dopant material, wherein the dopant material includes the organometallic compound as defined above.

Still another aspect of the present disclosure provides an organic light-emitting device comprising: a first electrode and a second electrode facing each other; and a first light-emitting stack, a second light-emitting stack, and a third light-emitting stack positioned between the first electrode and the second electrode, wherein each of the first light-emitting stack, the second light-emitting stack and the third light-emitting stack includes at least one light-emitting layer, wherein at least one of the light-emitting layers is a green phosphorescent light-emitting layer, wherein the green phosphorescent light-emitting layer contains a dopant material, wherein the dopant material includes the organometallic compound as defined above.

Still yet another aspect of the present disclosure provides an organic light-emitting display device comprising: a substrate; a driving element positioned on the substrate; and an organic light-emitting element disposed on the substrate and connected to the driving element, wherein the organic light-emitting element includes the organic light-emitting device according as defined above.

The organometallic compound according to the present disclosure may be used as the dopant of the phosphorescent light-emitting layer of the organic light-emitting diode, such that the operation voltage of the organic light-emitting diode may be lowered, and the efficiency and lifespan characteristics of the organic light-emitting diode may be improved and at the same time, red-shift may be suppressed.

Effects of the present disclosure are not limited to the above-mentioned effects, and other effects as not mentioned will be clearly understood by those skilled in the art from following descriptions.

### BRIEF DESCRIPTION OF DRAWINGS

FIG. 1 is a cross-sectional view schematically showing an organic light-emitting diode in which a light-emitting layer contains an organometallic compound according to an illustrative embodiment of the present disclosure.

FIG. 2 is a cross-sectional view schematically illustrating an organic light-emitting diode having a tandem structure having two light-emitting stacks and containing an organometallic compound represented by Chemical Formula 1 according to an illustrative embodiment of the present disclosure.

FIG. 3 is a cross-sectional view schematically illustrating an organic light-emitting diode having a tandem structure having three light-emitting stacks and containing an organometallic compound represented by Chemical Formula 1 according to an illustrative embodiment of the present disclosure.

FIG. 4 is a cross-sectional view schematically illustrating an organic light-emitting display device including an organic light-emitting diode according to an illustrative embodiment of the present disclosure.

### DETAILED DESCRIPTIONS

Advantages and features of the present disclosure, and a method of achieving the advantages and features will become apparent with reference to embodiments described later in detail together with the accompanying drawings. However, the present disclosure is not limited to the embodiments as disclosed below, but may be implemented in various different forms. Thus, these embodiments are set forth only to make the present disclosure complete, and to completely inform the scope of the present disclosure to those of ordinary skill in the technical field to which the present disclosure belongs, and the present disclosure is only defined by the scope of the claims.

A shape, a size, a ratio, an angle, a number, etc. disclosed in the drawings for describing the embodiments of the present disclosure are illustrative, and the present disclosure is not limited thereto. The same reference numerals refer to the same elements herein. Further, descriptions and details of well-known steps and elements are omitted for simplicity of the description. Furthermore, in the following detailed description of the present disclosure, numerous specific details are set forth in order to provide a thorough understanding of the present disclosure. However, it will be understood that the present disclosure may be practiced without these specific details. In other instances, well-known methods, procedures, components, and circuits have not been described in detail so as not to unnecessarily obscure aspects of the present disclosure.

The terminology used herein is directed to the purpose of describing particular embodiments only and is not intended to be limiting of the present disclosure. As used herein, the singular constitutes “a” and “an” are intended to include the plural constitutes as well, unless the context clearly indicates otherwise. It will be further understood that the terms “comprise”, “including”, “include”, and “including” when used in this specification, specify the presence of the stated features, integers, operations, elements, and/or components, but do not preclude the presence or addition of one or more other features, integers, operations, elements, components, and/or portions thereof. As used herein, the term “and/or” includes any and all combinations of one or more of the associated listed items. Expression such as “at least one of” when preceding a list of elements may modify the entire list of elements and may not modify the individual elements of the list. In interpretation of numerical values, an error or tolerance therein may occur even when there is no explicit description thereof.

In addition, it will also be understood that when a first element or layer is referred to as being present “on” a second element or layer, the first element may be disposed directly on the second element or may be disposed indirectly on the second element with a third element or layer being disposed between the first and second elements or layers. It will be understood that when an element or layer is referred to as being “connected to”, or “coupled to” another element or layer, it may be directly on, connected to, or coupled to the other element or layer, or one or more intervening elements or layers may be present. In addition, it will also be understood that when an element or layer is referred to as being “between” two elements or layers, it may be the only element or layer between the two elements or layers, or one or more intervening elements or layers may also be present.

Further, as used herein, when a layer, film, region, plate, or the like is disposed “on” or “on a top” of another layer, film, region, plate, or the like, the former may directly contact the latter or still another layer, film, region, plate, or the like may be disposed between the former and the latter. As used herein, when a layer, film, region, plate, or the like is directly disposed “on” or “on a top” of another layer, film, region, plate, or the like, the former directly contacts the latter and still another layer, film, region, plate, or the like is not disposed between the former and the latter. Further, as used herein, when a layer, film, region, plate, or the like is disposed “below” or “under” another layer, film, region, plate, or the like, the former may directly contact the latter or still another layer, film, region, plate, or the like may be disposed between the former and the latter. As used herein, when a layer, film, region, plate, or the like is directly disposed “below” or “under” another layer, film, region, plate, or the like, the former directly contacts the latter and still another layer, film, region, plate, or the like is not disposed between the former and the latter.

In descriptions of temporal relationships, for example, temporal precedent relationships between two events such as “after”, “subsequent to”, “before”, etc., another event may occur therebetween unless “directly after”, “directly subsequent” or “directly before” is not indicated.

It will be understood that, although the terms “first”, “second”, “third”, and so on may be used herein to describe various elements, components, regions, layers and/or sections, these elements, components, regions, layers and/or sections should not be limited by these terms. These terms are used to distinguish one element, component, region, layer or section from another element, component, region, layer or section. Thus, a first element, component, region, layer or section described below could be termed a second element, component, region, layer or section, without departing from the spirit and scope of the present disclosure.

The features of the various embodiments of the present disclosure may be partially or entirely combined with each other, and may be technically associated with each other or operate with each other. The embodiments may be implemented independently of each other and may be implemented together in an association relationship.

In interpreting a numerical value, the value is interpreted as including an error range unless there is no separate explicit description thereof.

It will be understood that when an element or layer is referred to as being “connected to”, or “coupled to” another element or layer, it may be directly on, connected to, or coupled to the other element or layer, or one or more intervening elements or layers may be present. In addition, it will also be understood that when an element or layer is referred to as being “between” two elements or layers, it may be the only element or layer between the two elements or layers, or one or more intervening elements or layers may also be present.

The features of the various embodiments of the present disclosure may be partially or entirely combined with each other, and may be technically associated with each other or operate with each other. The embodiments may be implemented independently of each other and may be implemented together in an association relationship.

Unless otherwise defined, all terms including technical and scientific terms used herein have the same meaning as commonly understood by one of ordinary skill in the art to which this inventive concept belongs. It will be further understood that terms, such as those defined in commonly used dictionaries, should be interpreted as having a meaning that is consistent with their meaning in the context of the relevant art and will not be interpreted in an idealized or overly formal sense unless expressly so defined herein.

Hereinafter, a structure and a preparation example of an organometallic compound according to the present disclosure and an organic light-emitting diode including the same will be described.

Conventionally, an organometallic compound has been used as a dopant in a phosphorescent light-emitting layer of an organic light-emitting diode. For example,

Conventionally, an organometallic compound has been used as a dopant of a phosphorescent light-emitting layer. For example, a structure such as 2-phenylpyridine, 2-phenylquinoline, or 2-pyridine benzofuropyridine is known as a main ligand structure of the organometallic compound. However, the conventional light-emitting dopant has a limit in improving efficiency and lifespan of the organic light-emitting diode. Thus, it is necessary to develop a novel light-emitting dopant material. Accordingly, applicants of the present disclosure have derived a light-emitting dopant material that can further improve the efficiency and lifespan of the organic light-emitting diode.

Based on intensive research, the applicants of the present disclosure have identified that when an organometallic compound represented by a following Chemical Formula 1 is used as a phosphorescent light-emitting dopant material, the above purpose of the present disclosure has been achieved, and thus have completed the present disclosure:

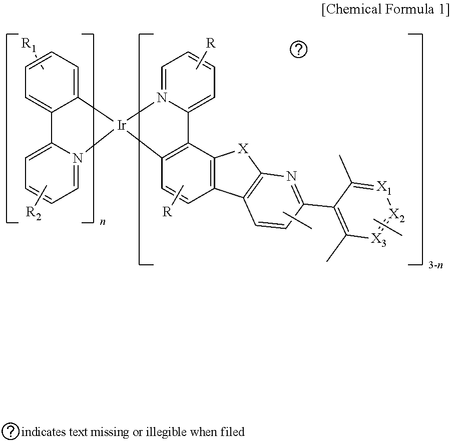

wherein in Chemical Formula 1,

X may represent one selected from a group consisting of O, S and Se;

each of X₁, X₂ and X₃ may independently represent N or CRₐ;

each of R₁, R₂ and R₃ may independently represent mono-substitution, di-substitution, tri-substitution, tetra-substitution or no-substitution;

each of R₅, R₆, R₇, and Rₐ may independently represent mono-substitution, di-substitution, tri-substitution, or no-substitution;

each of R₄ and R₈ may independently represent mono-substitution, di-substitution, or no-substitution;

each of R₁, R₂, R₃, R₄, R₇, R₈ and Rₐ may independently represent one selected from a group consisting of hydrogen, deuterium, halide, deuterated or undeuterated alkyl, cycloalkyl, heteroalkyl, arylalkyl, alkoxy, aryloxy, amino, silyl, alkenyl, cycloalkenyl, heteroalkenyl, alkynyl, aryl, heteroaryl, acyl, carbonyl, carboxylic acid, ester, nitrile, isonitrile, sulfanyl, sulfinyl, sulfonyl, phosphino, and combinations thereof,

each of R₅ and R₆ may independently represent one selected from a group consisting of halide, deuterated or undeuterated alkyl, cycloalkyl, heteroalkyl, arylalkyl, alkoxy, aryloxy, amino, silyl, alkenyl, cycloalkenyl, heteroalkenyl, alkynyl, aryl, heteroaryl, acyl, carbonyl, carboxylic acid, ester, nitrile, isonitrile, sulfanyl, sulfinyl, sulfonyl, phosphino, and combinations thereof, and

n may be 0, 1 or 2.

In particular, as may be identified in a main ligand structure of Chemical Formula 1, a ratio of lengths of a major axis and a minor axis of a ring to which carbon (C) is connected among two rings connected to Ir (iridium) as a central coordination metal is increased, thereby increase performance including light-emitting efficiency of an organic light-emitting diode using the organometallic compound of Chemical Formula 1 as a phosphorescent light-emitting dopant thereof. The ratio of lengths of the major axis and the minor axis means a ratio of the lengths of the major axis and the minor axis perpendicular thereto of an optimized target substance via calculation of B3LYP/LANL2DZ (6-31g,d) in a Gaussian16 program. In this regard, the length of the major axis means a length of the longest portion of a substance having the central coordination metal Ir as an axis.

According to an embodiment of the present disclosure, in Chemical Formula 1, each of R₅ and R₆ may independently represent one selected from a group consisting of a C1-C6 straight-chain alkyl group mono-substituted with deuterium or a halogen element; a branched alkyl group mono-substituted with deuterium or a halogen element; and a cycloalkyl group mono-substituted with deuterium or a halogen element.

For example, when X in Chemical Formula 1 according to the present disclosure is O (oxygen), an organometallic compound in which a bulky 6-membered aromatic ring structure having a substituent (except for hydrogen) binds to a benzofuropyridine group is derived. Thus, when the organometallic compound represented by Chemical Formula 1 is used as a dopant material of the phosphorescent light-emitting layer of the organic light-emitting diode, the light-emitting efficiency and lifespan of the organic light-emitting diode may be improved, and the operation voltage thereof may be lowered. This result was experimentally identified. Thus, the present disclosure has been completed.

Specifically, i) the organometallic compound structure of Chemical Formula 1 according to the present disclosure has the ratio of lengths of the major axis and the minor axis larger than that of a conventional compound in which the aromatic ring structure does not bind to the benzofuropyridine group. Thus, the luminous efficiency of the organic light-emitting diode using the organometallic compound of Chemical Formula 1 according to the present disclosure may be improved. At the same time, ii) stability of the main ligand structure may be increased, the lifespan of the organic light-emitting diode using the organometallic compound of Chemical Formula 1 according to the present disclosure may be increased. At the same time, iii) red-shift of the organic light-emitting diode using the organometallic compound of Chemical Formula 1 according to the present disclosure may be suppressed.

More specifically, controlling the ratio of lengths of the major axis and the minor axis of the organometallic compound to improve the efficiency and lifetime of the organic light-emitting diode using the organometallic compound such as the iridium complex as a phosphorescent light-emitting dopant may cause a wavelength of light emitting therefrom to be somewhat larger than a target wavelength. However, it may be identified from a following Table 1 that when the organometallic compound of Chemical Formula 1 according to the present disclosure is used as a dopant material of the phosphorescent light-emitting layer of the organic light-emitting diode, the wavelength may be maintained as the target wavelength (e.g., 520 nm to 540 nm for a green phosphorescent light-emitting layer). Thus, the efficiency and lifespan of the organic light-emitting diode may be improved and at the same time, the red-shift may be suppressed. This has important technical significance.

As will be described in more detail later in the specific Examples of the present disclosure and the performance evaluation of the organic light-emitting diode, the ratio of lengths of the major axis and the minor axis of each of ‘Ref 1’, ‘Ref 3’ as organometallic compounds according to Comparative Examples of the present disclosure, and ‘Target Comp.’ complying with the definition of Chemical Formula 1 of the present disclosure were measured, and ‘Ref 1’, ‘Ref 3’ and ‘Target Comp.’ were used as the dopants of the light-emitting layer of the organic light-emitting diode. Further, in order to accurately compare the ratios of lengths of the major axis and the minor axis thereof with each other, the compounds had the same auxiliary ligand.

A manufacturing method of the organic light-emitting diode was the same as described in <Present Example 1>, except that ‘Ref 1’, ‘Ref 3’ and ‘Target Comp.’ as the dopant material were used instead of Compound 1. EQE and LT95 of each of organic light-emitting diodes were measured in the same manner as those described in a following <Evaluation of performance of organic light-emitting diode>. Results are shown in Table 1 below. The ratio of lengths of the major axis and the minor axis means a ratio of the lengths of the major axis and the minor axis perpendicular thereto of an optimized target substance via calculation of B3LYP/LANL2DZ (6-31g,d) in a Gaussian16 program. In addition, the emission wavelength of the organic light-emitting diode using each of ‘Ref 3’ and ‘Target Comp.’ was as follows: the emission wavelength when ‘Ref 3’ was used was increased by 10 to 15 nm compared to that when ‘Target Comp.’ was used. Thus, it was identified that efficiency and characteristics when using Ref 3 were inferior to those when using Target Comp.

TABLE 1

| | Ratio of length of | | |
|---|---|---|---|
| | major and minor | | |
| Dopant | axes | EQE | LT95 |
| Ref 1 | 1.28 | 100% | 100% |
| Ref 3 | 1.61 | 110% | 127% |
| Target Comp. | 1.61 | 127% | 151% |

Structures of Ref 1, Ref 3, and Target Comp. in the Table 1 are as follows:

### Ref 1

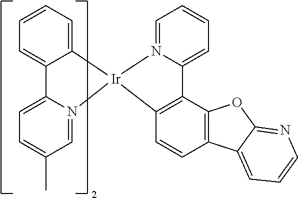

### Ref 3

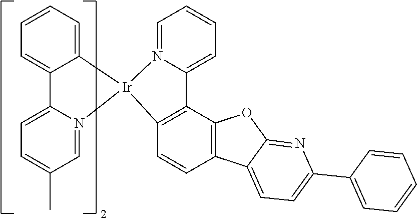

### Target Comp.:

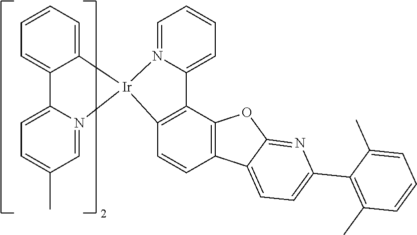

The organometallic compound according to an embodiment of the present disclosure may include not only the main ligand as described above binding to the central coordination metal (iridium) but also a bidentate ligand as an auxiliary ligand binding to the central coordination metal (iridium). As shown in Chemical Formula 1, the auxiliary ligand may have a 2-phenylpyridine structure, wherein each of R₁ and R₂ may independently represent mono-substitution, di-substitution, tri-substitution, tetra-substitution or no-substitution.

The organometallic compound according to an implementation of the present disclosure may have a heteroleptic or homoleptic structure. For example, the organometallic compound according to an embodiment of the present disclosure may have a heteroleptic structure in which in Chemical Formula 1, n is 1; or a heteroleptic structure where in Chemical Formula 1, n is 2; or a homoreptic structure where in Chemical Formula 1, n is 0.

A specific example of the compound represented by Chemical Formula 1 according to the present disclosure may include one selected from a group consisting of following compounds 1 to 564. However, the specific example of the compound represented by Chemical Formula 1 according to the present disclosure is not limited thereto as long as the compound meets the above definition of Chemical Formula 1 as the Target Comp. meets:

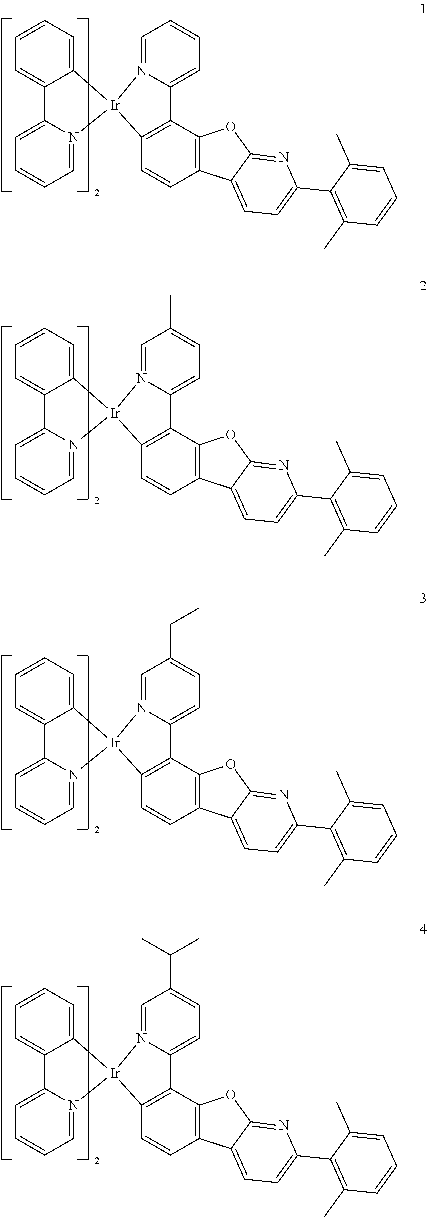

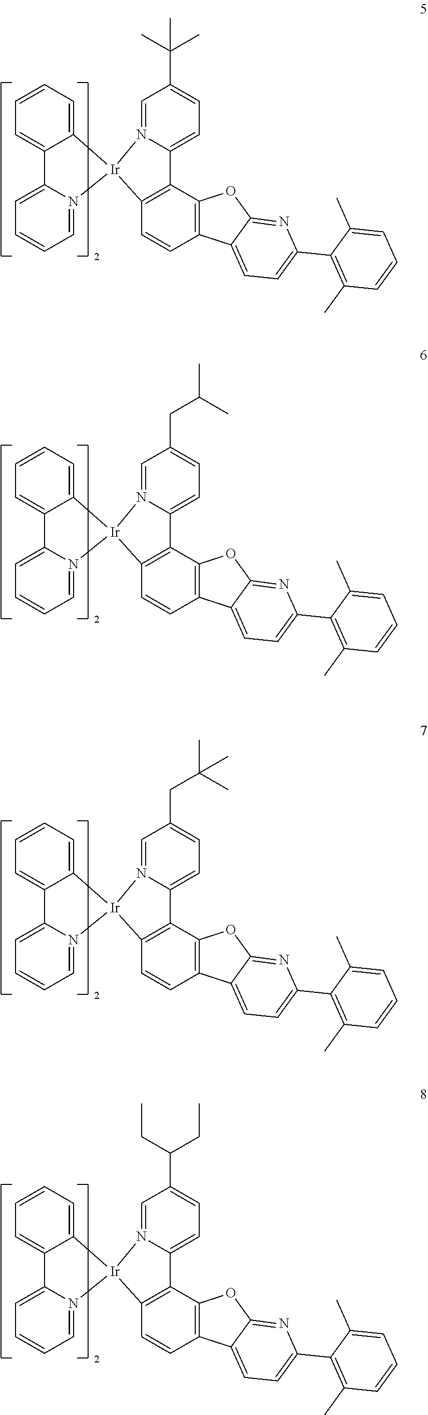

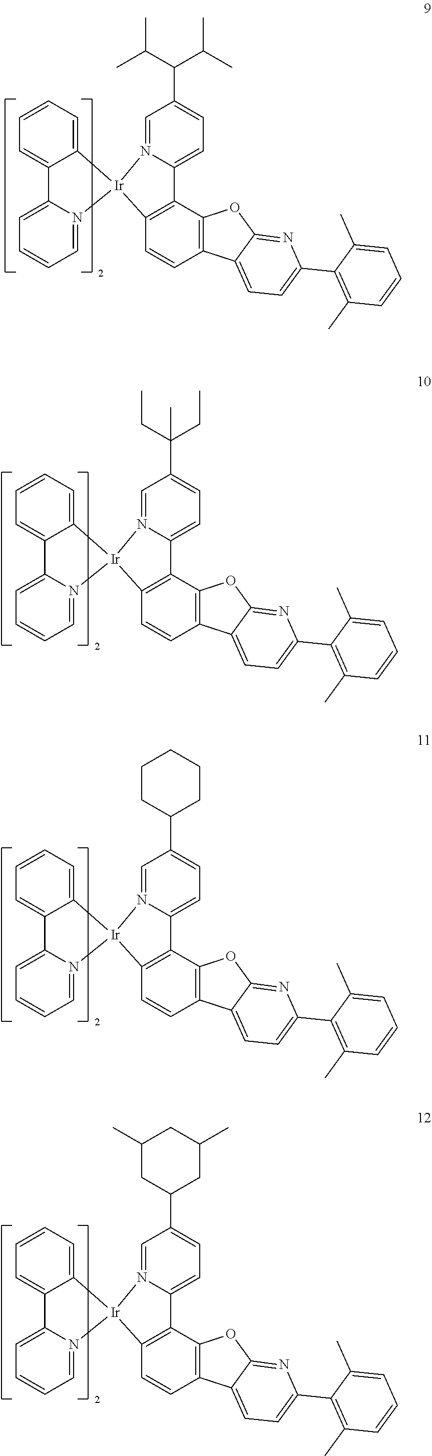

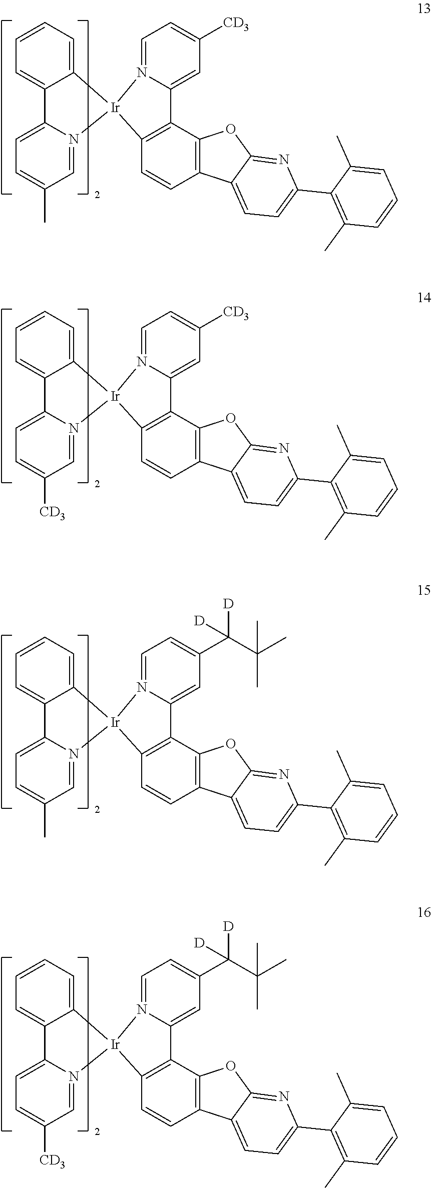

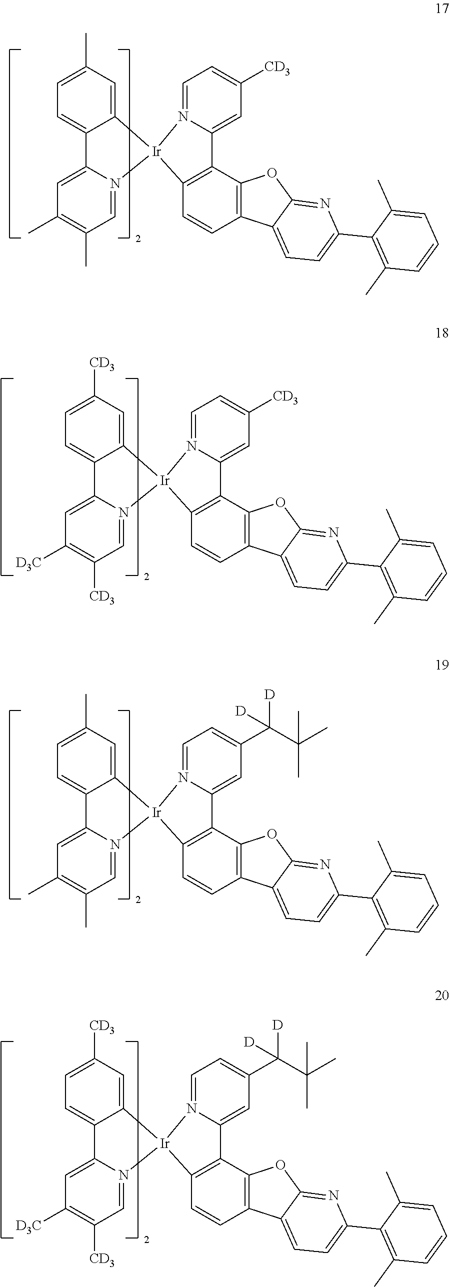

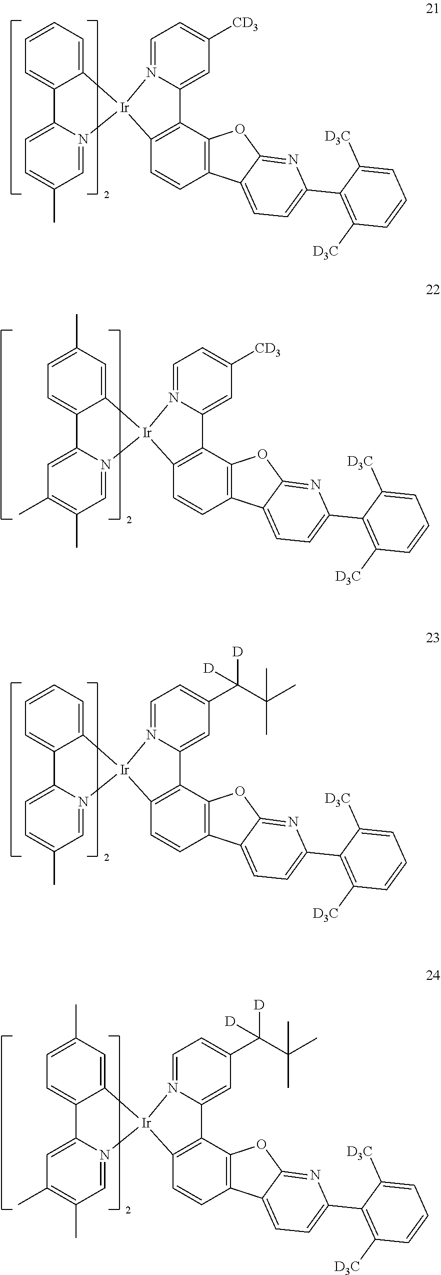

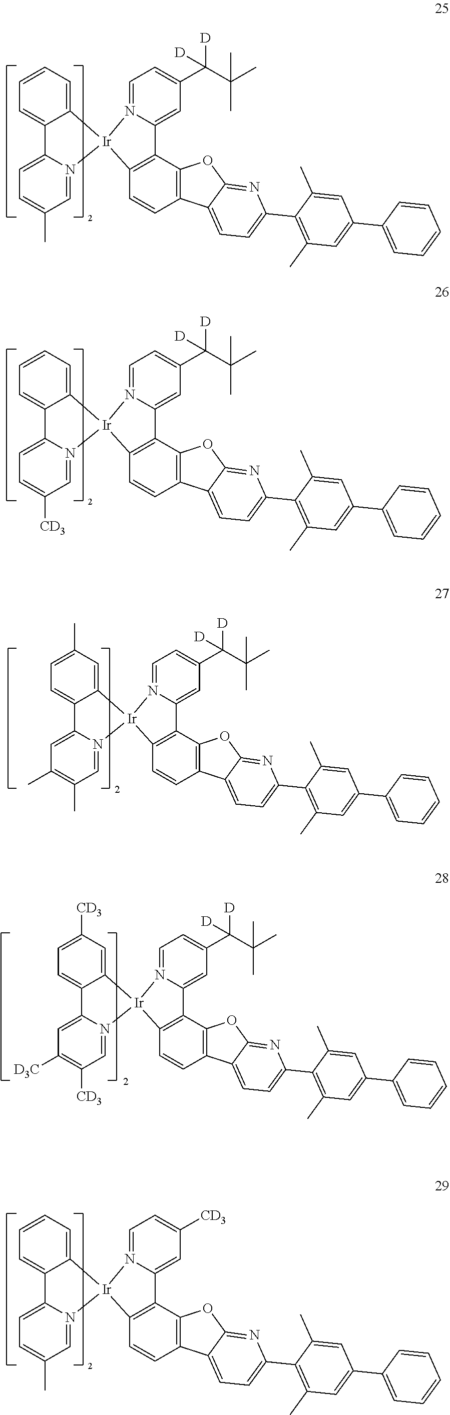

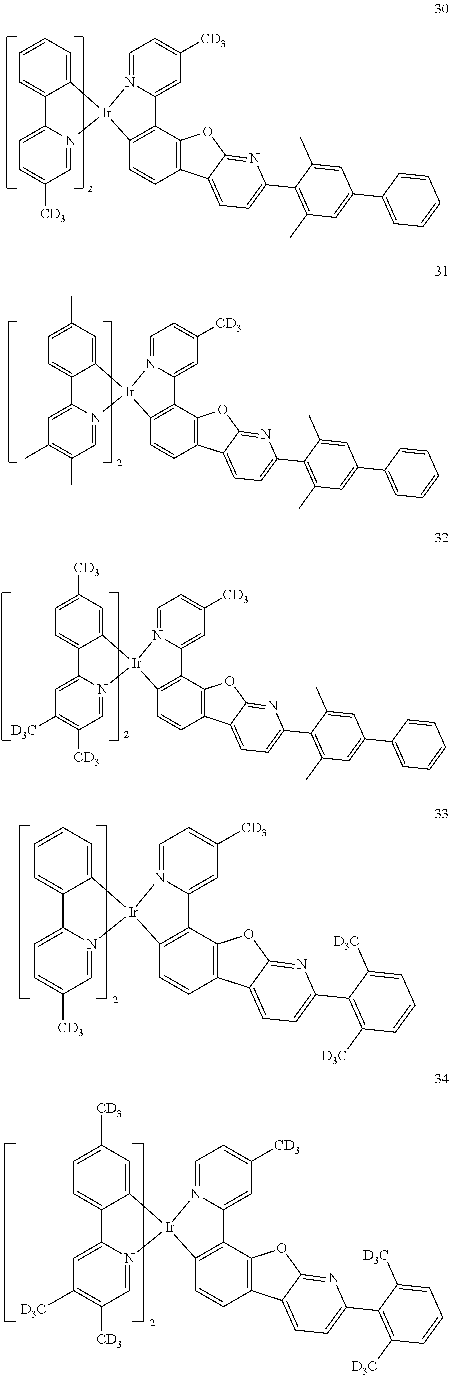

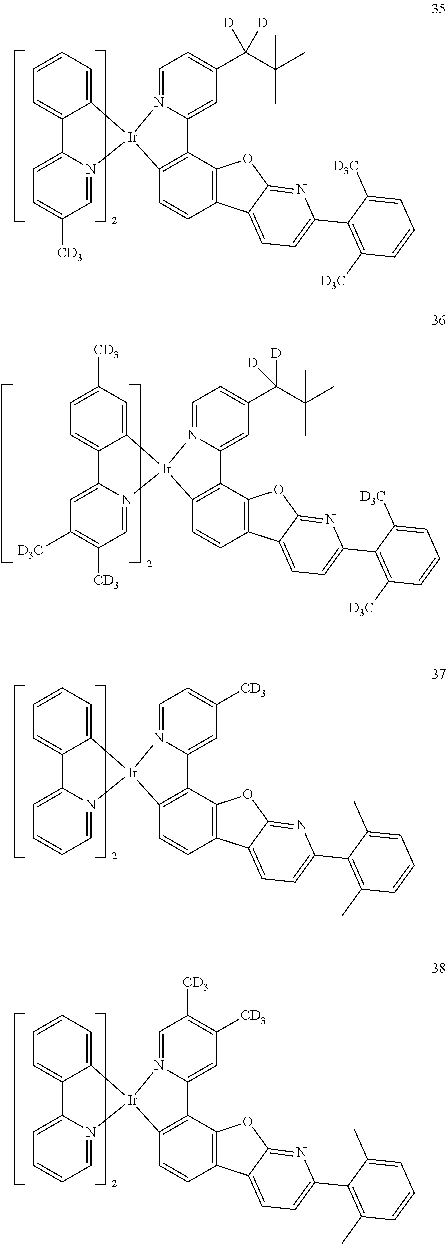

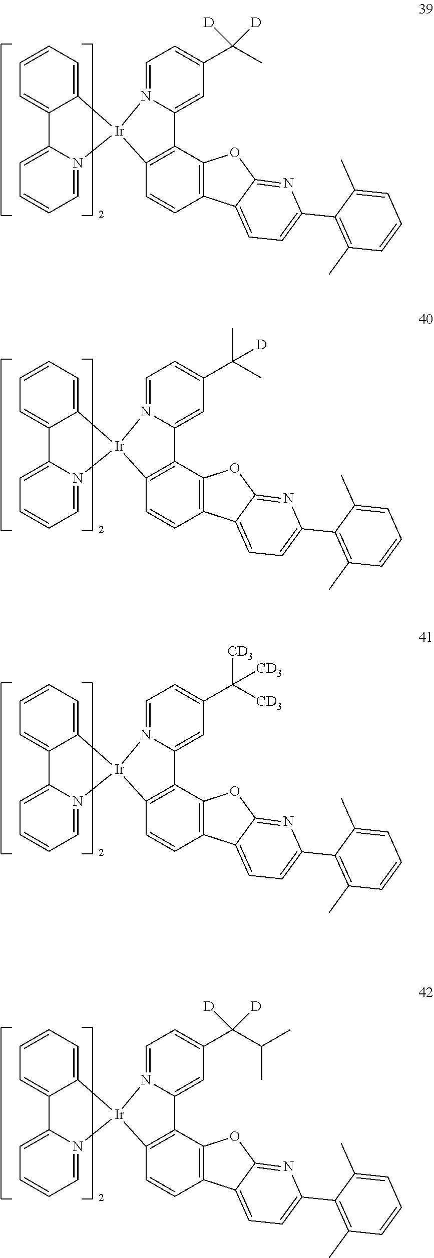

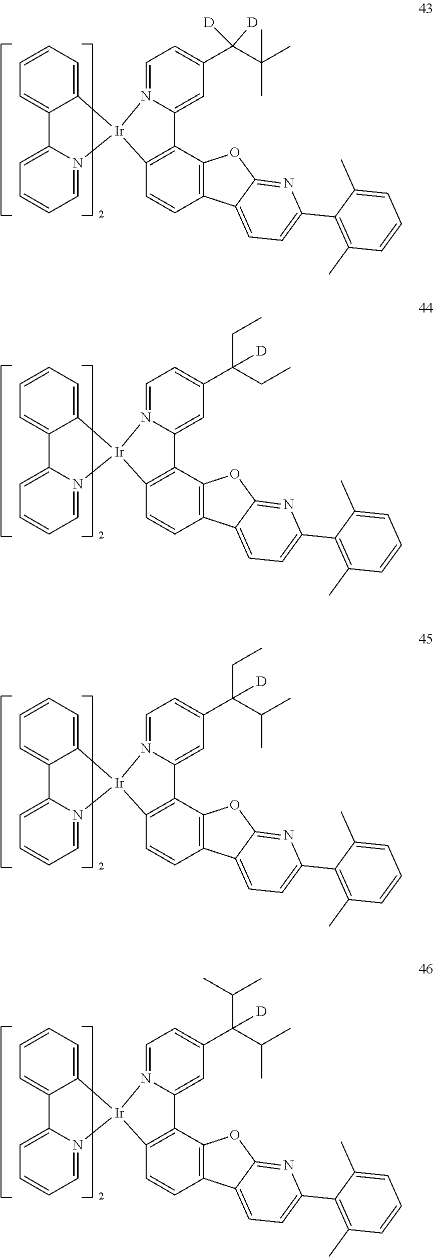

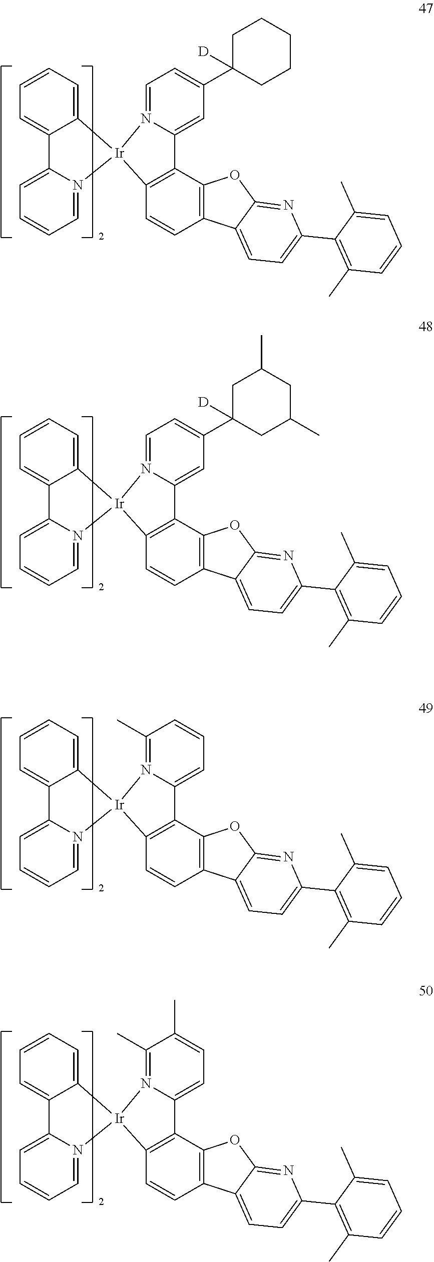

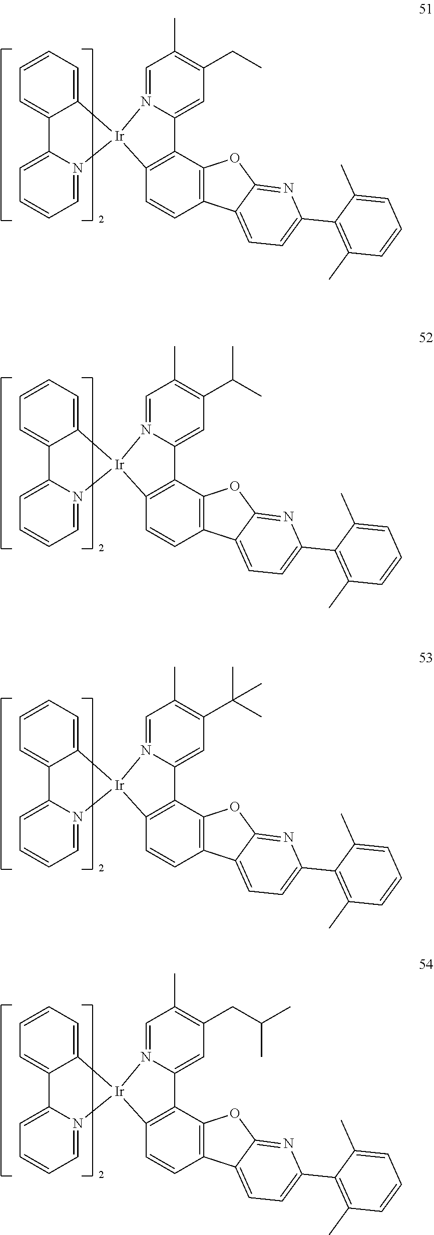

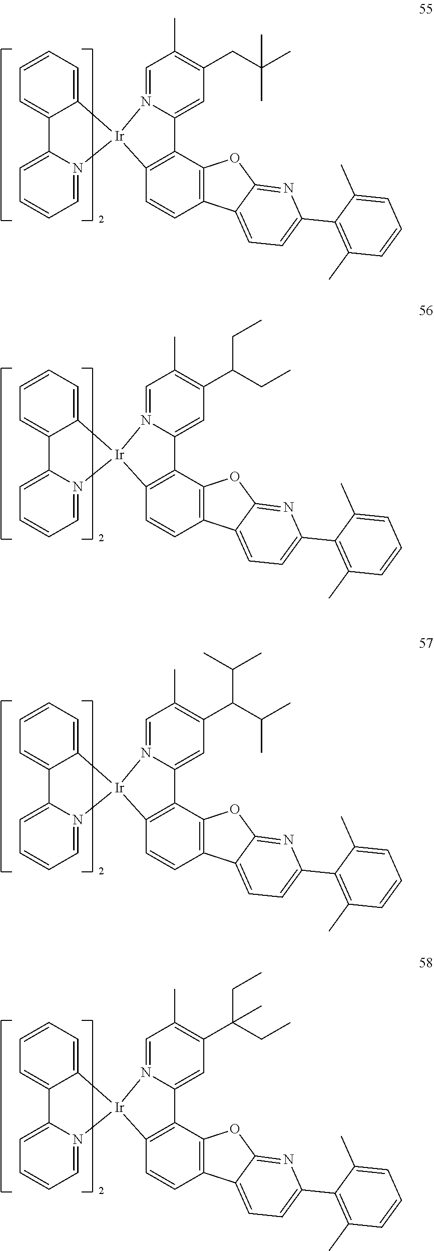

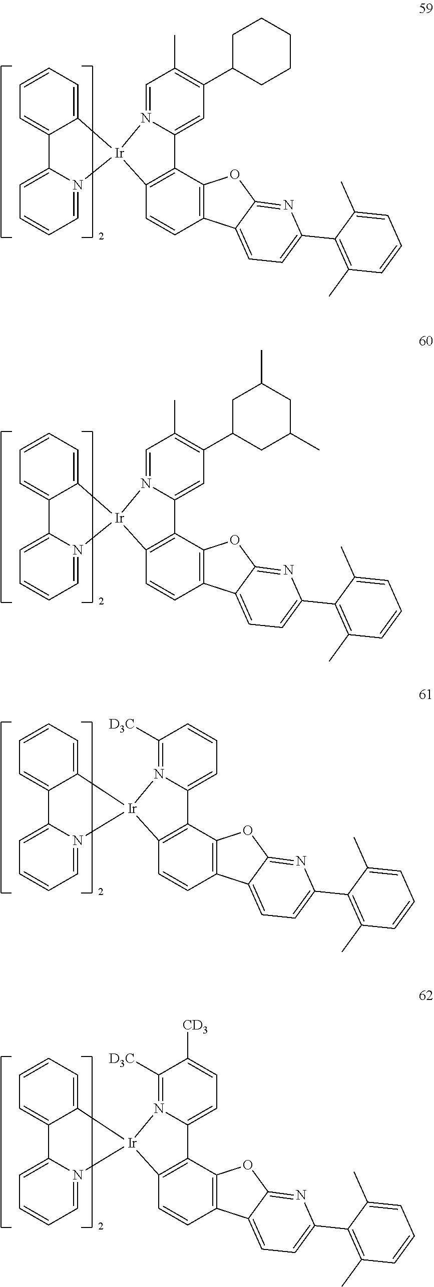

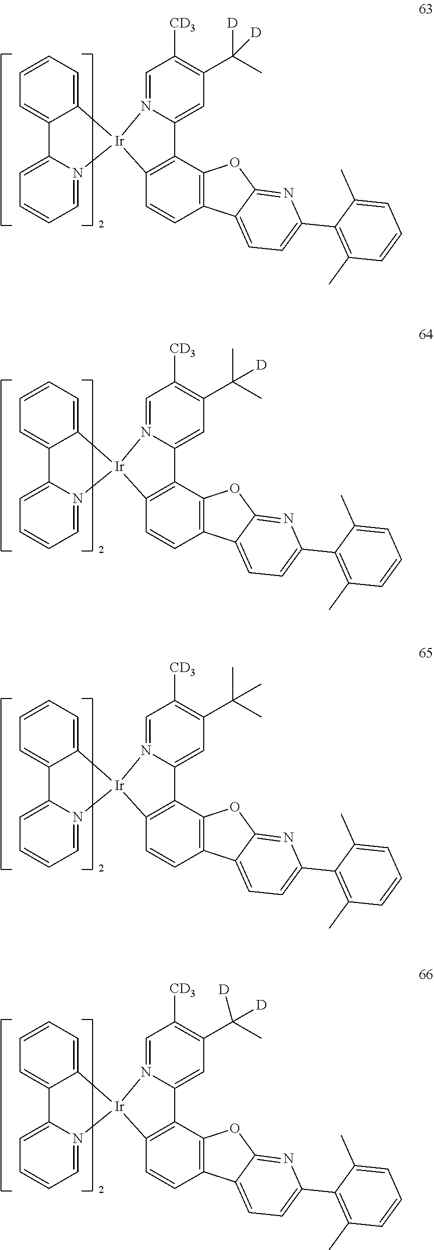

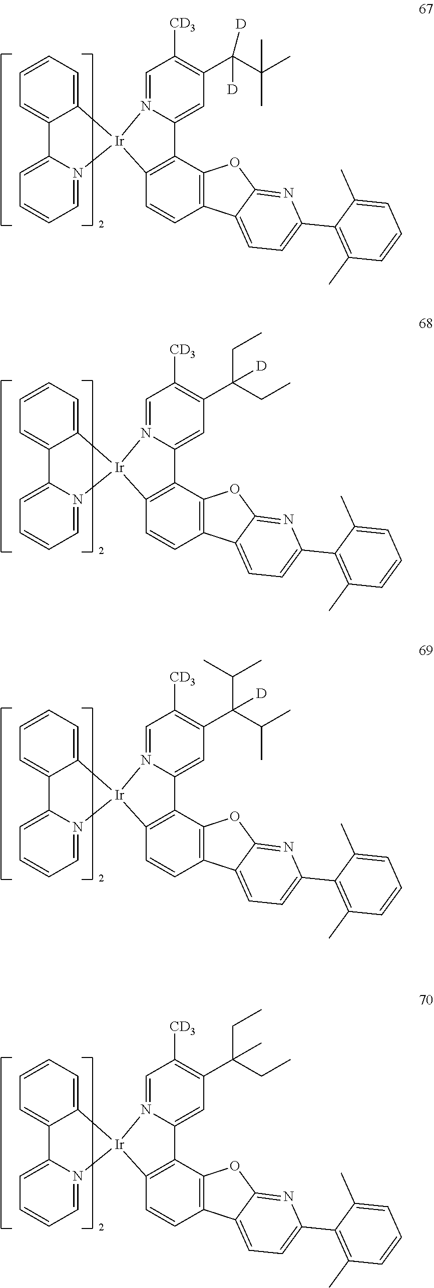

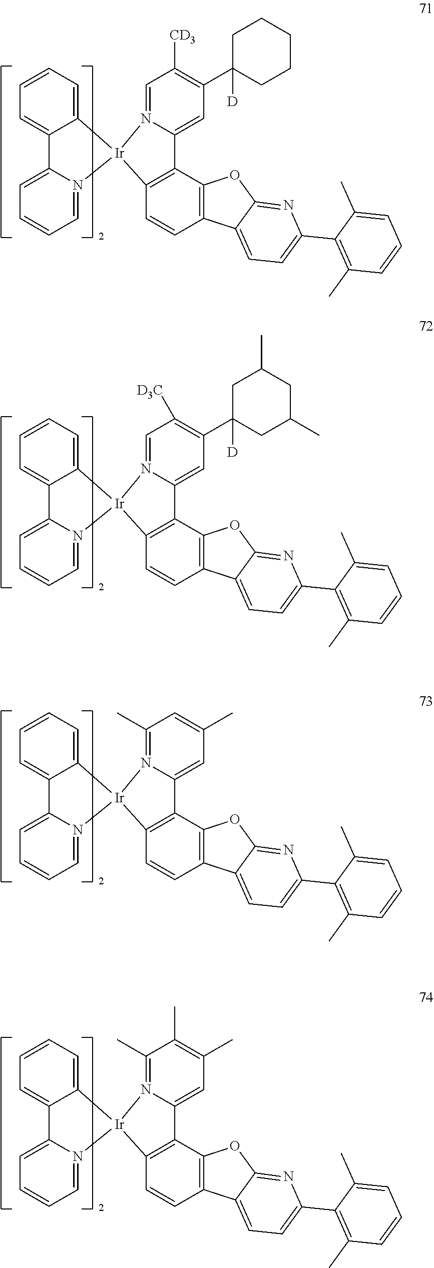

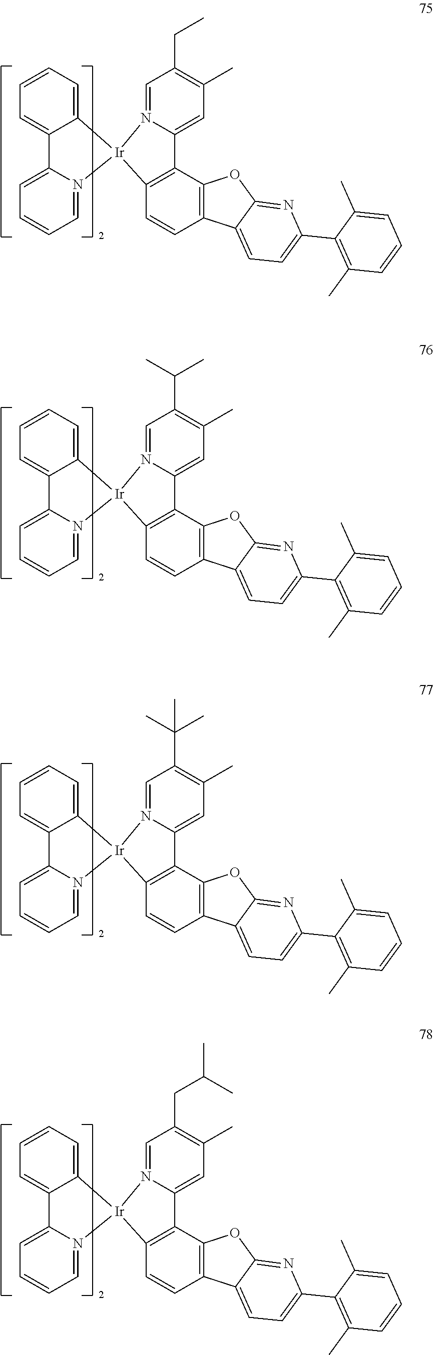

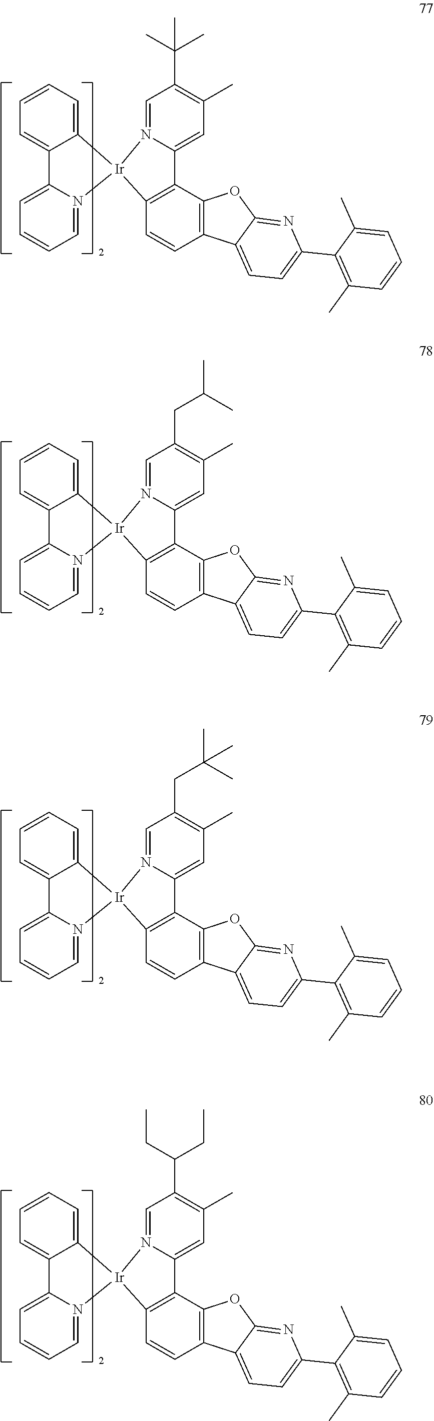

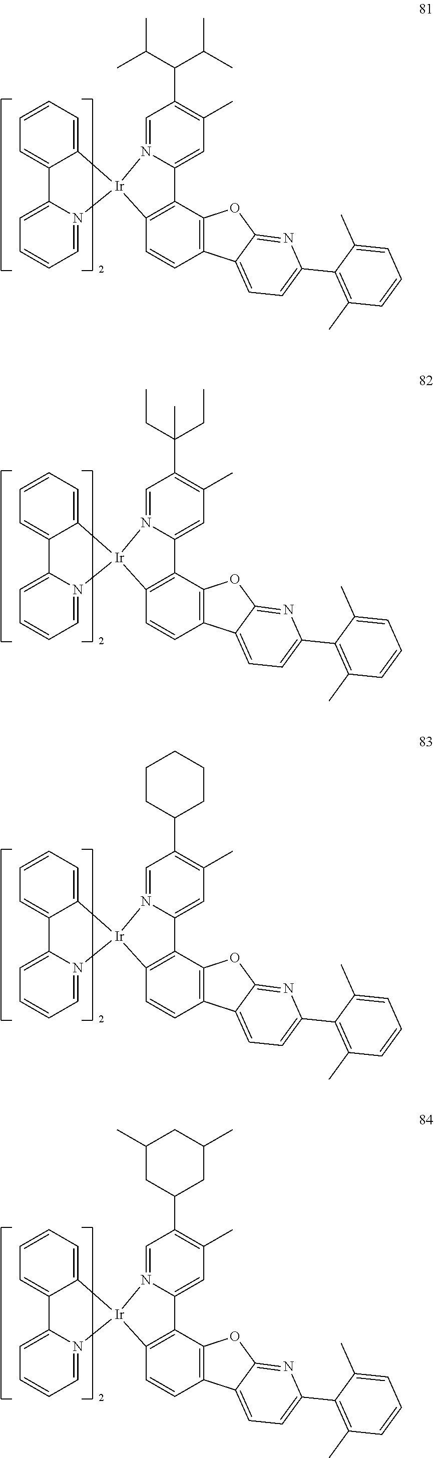

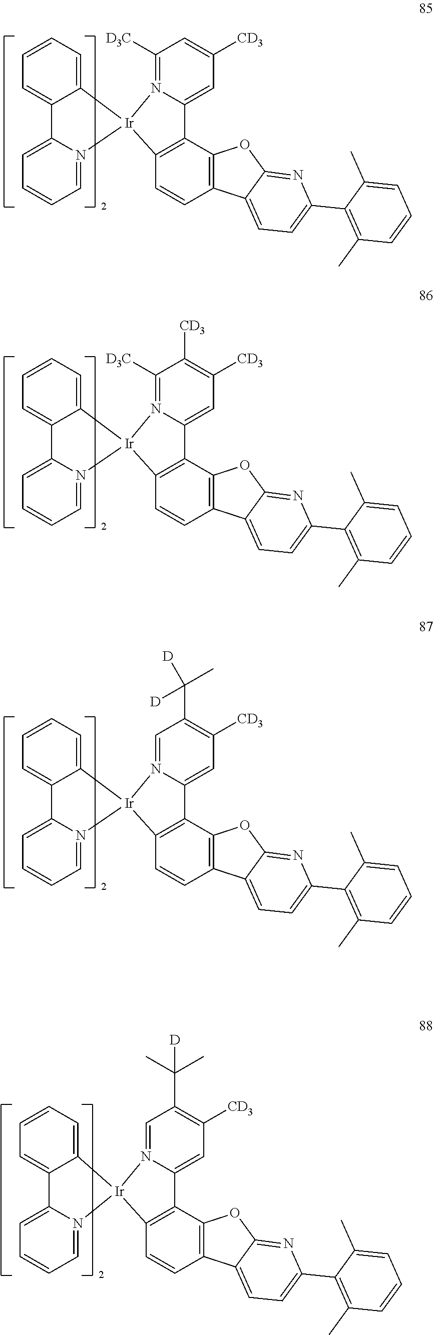

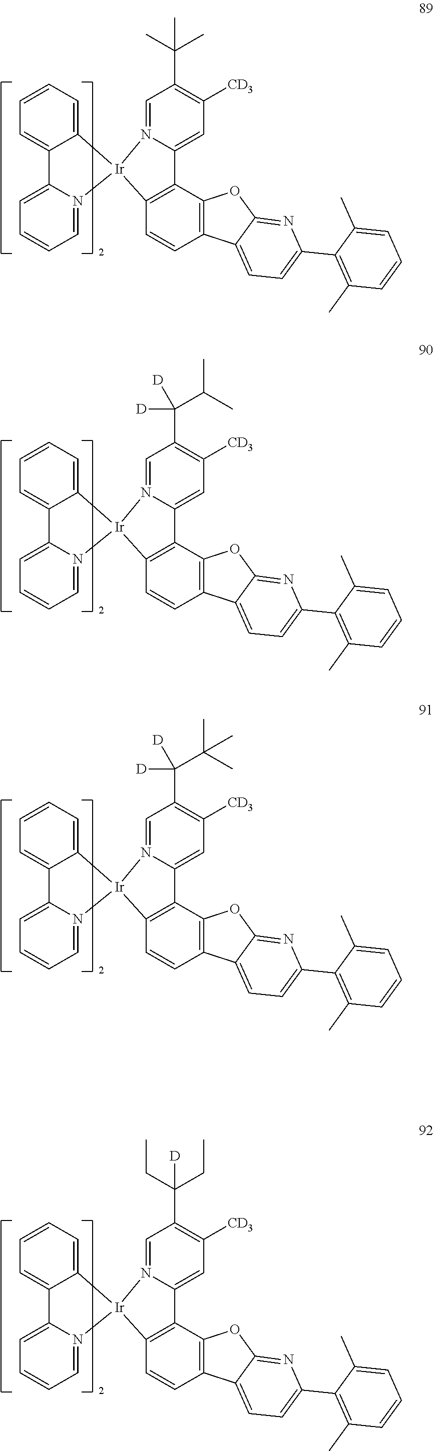

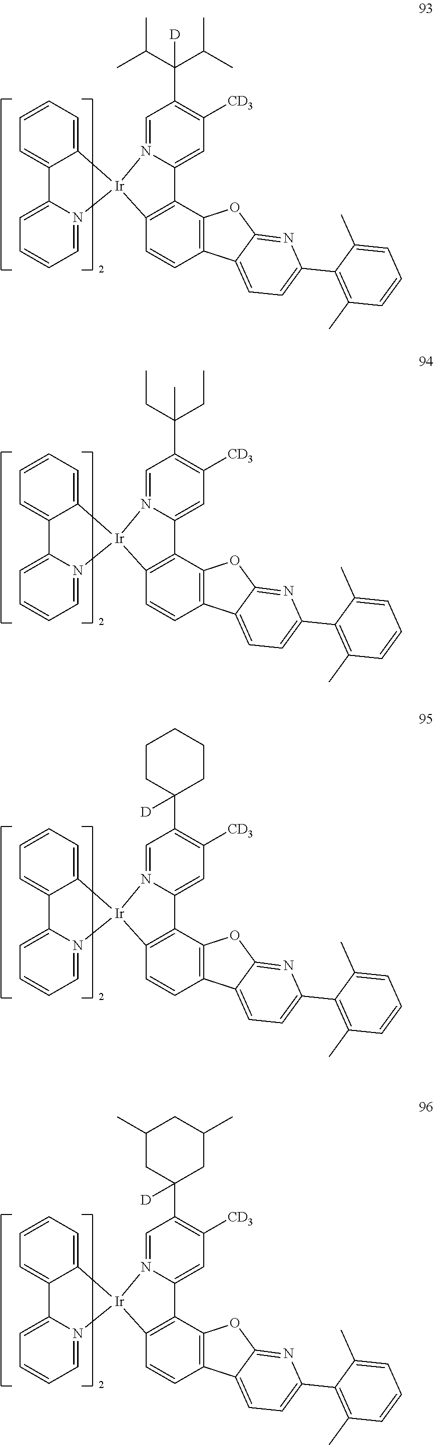

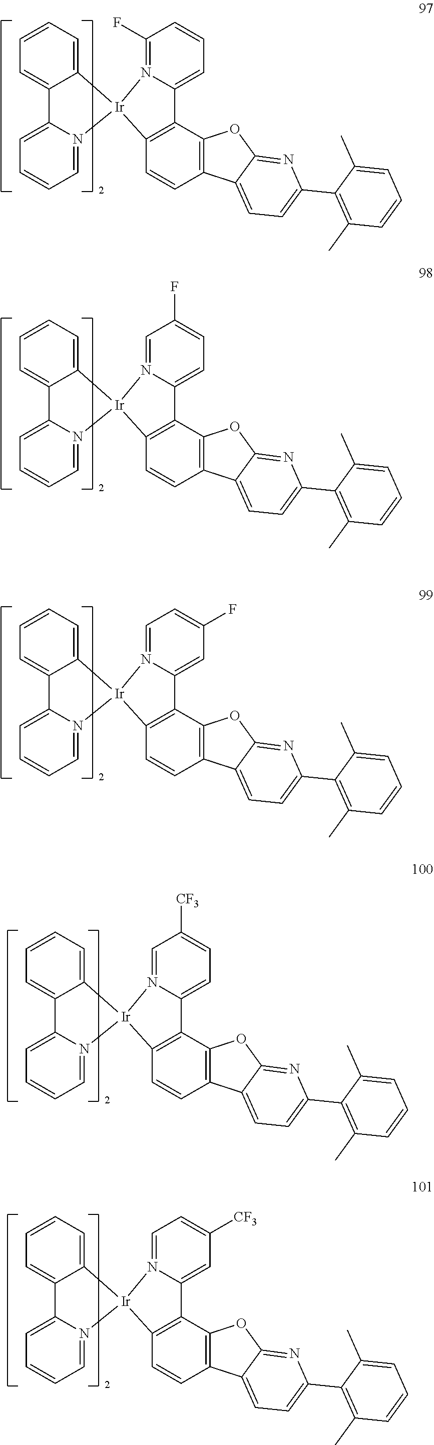

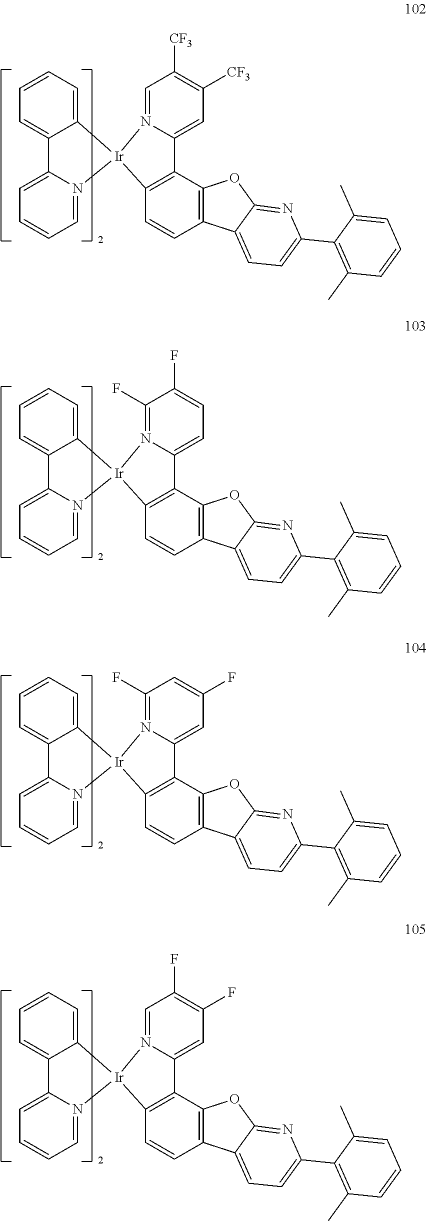

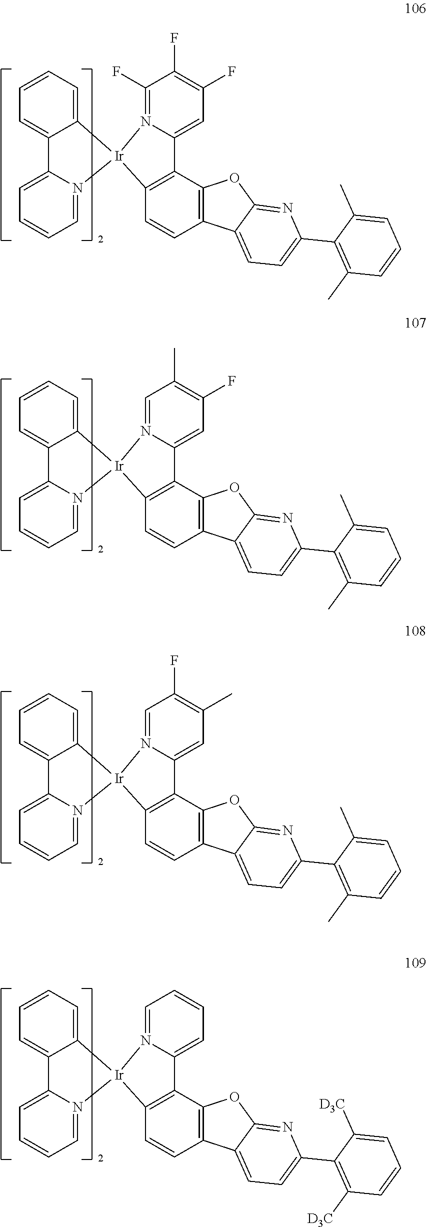

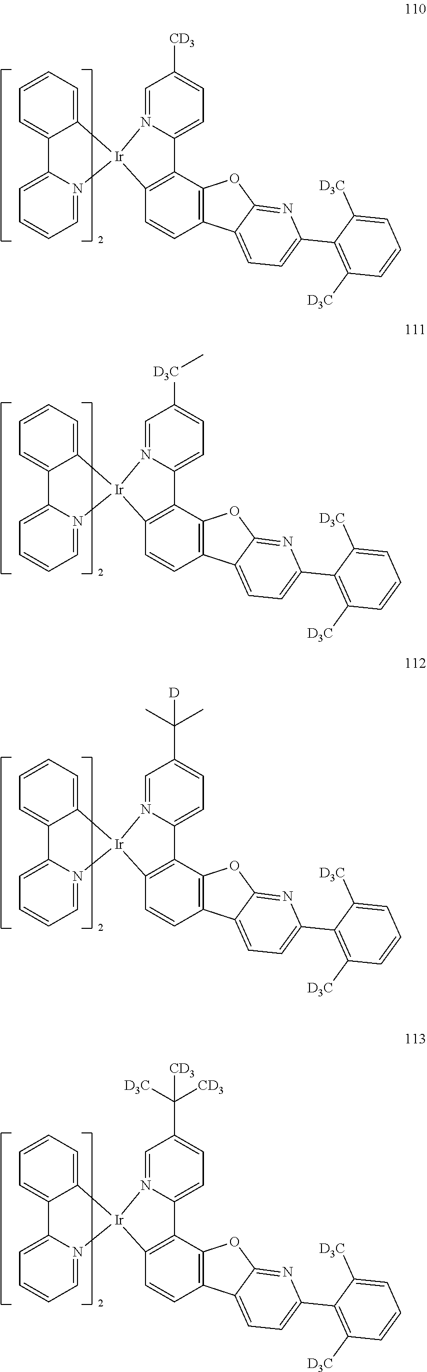

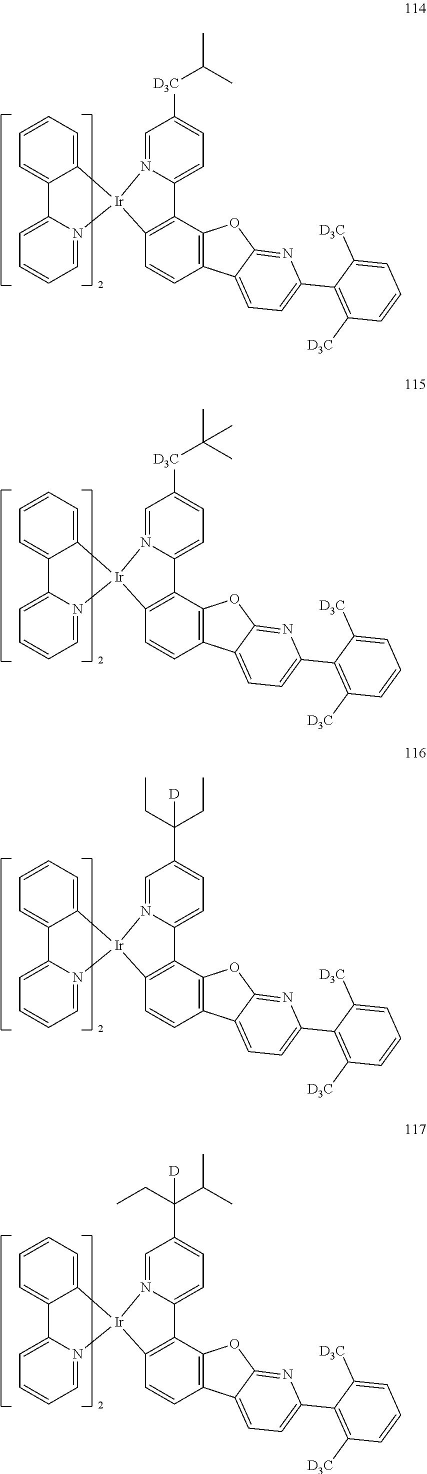

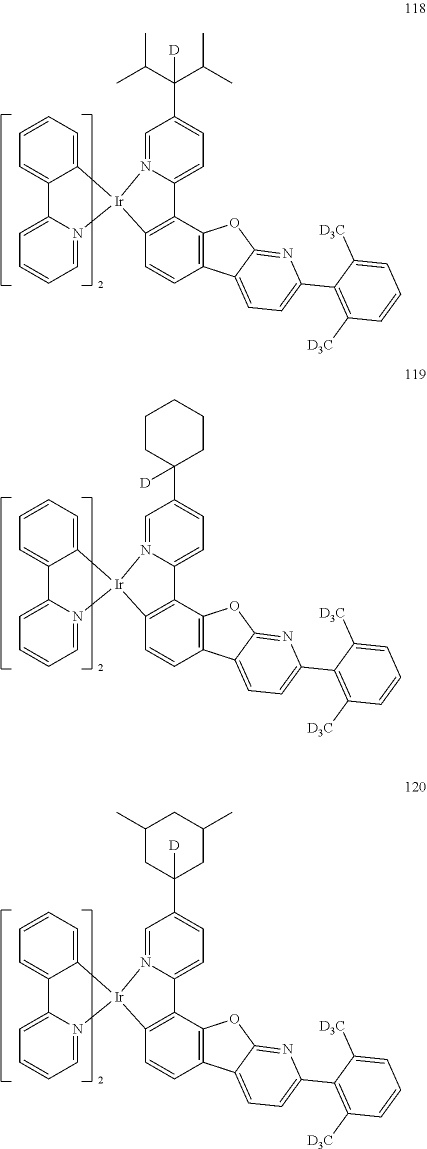

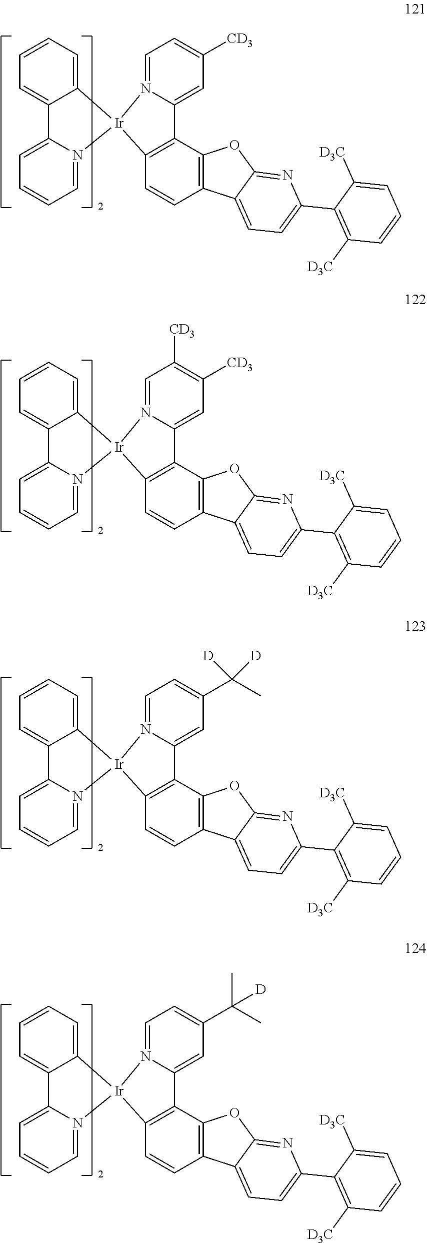

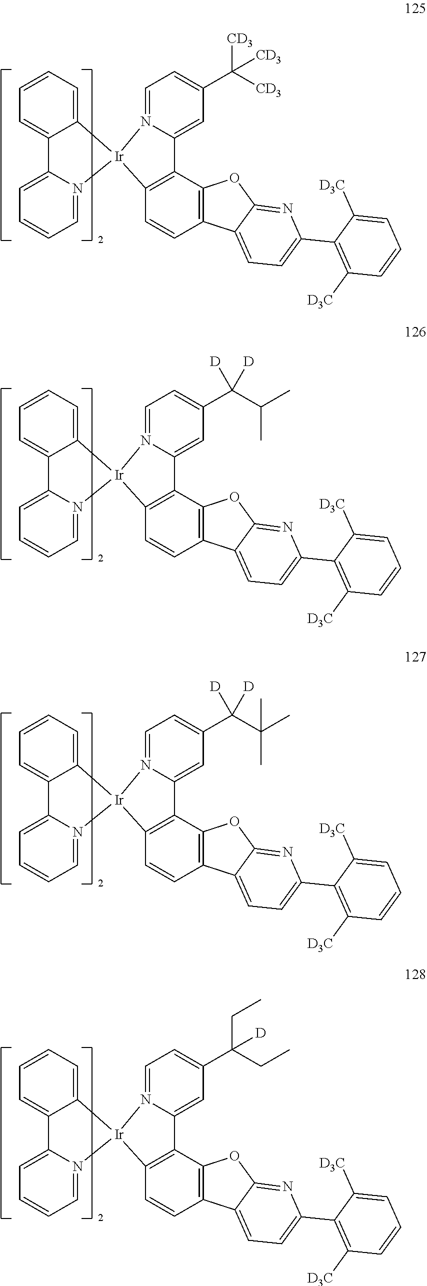

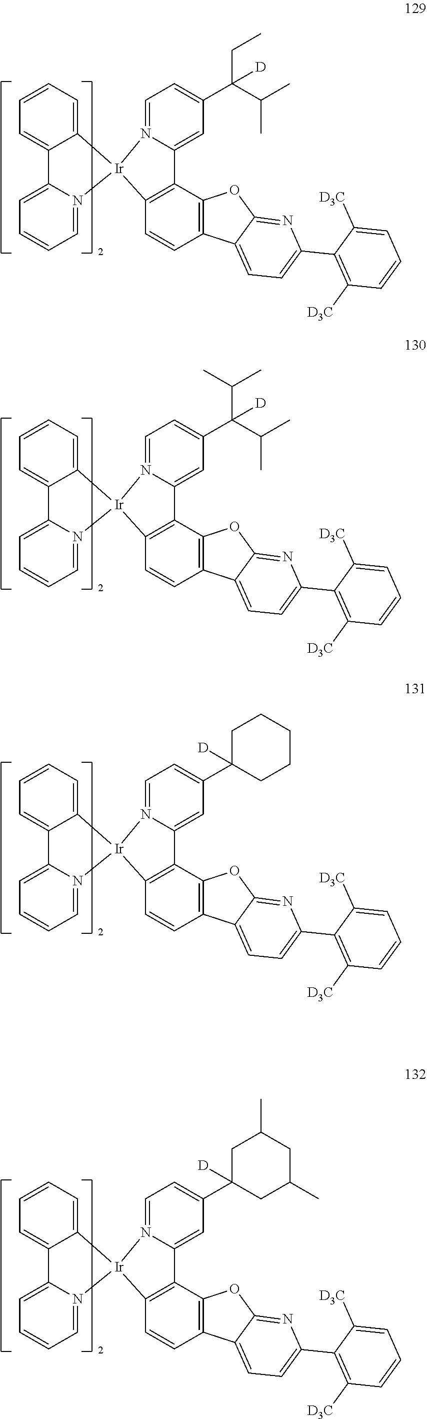

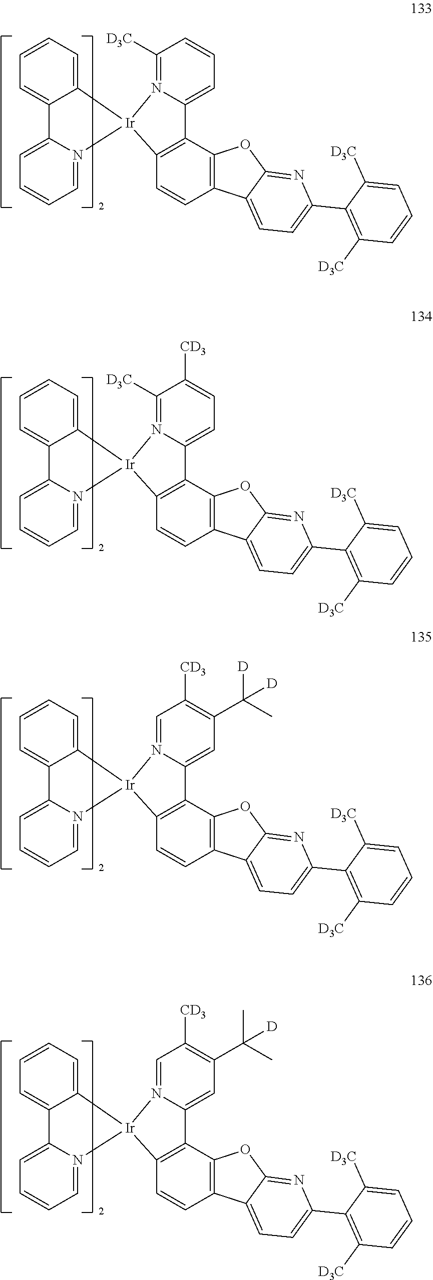

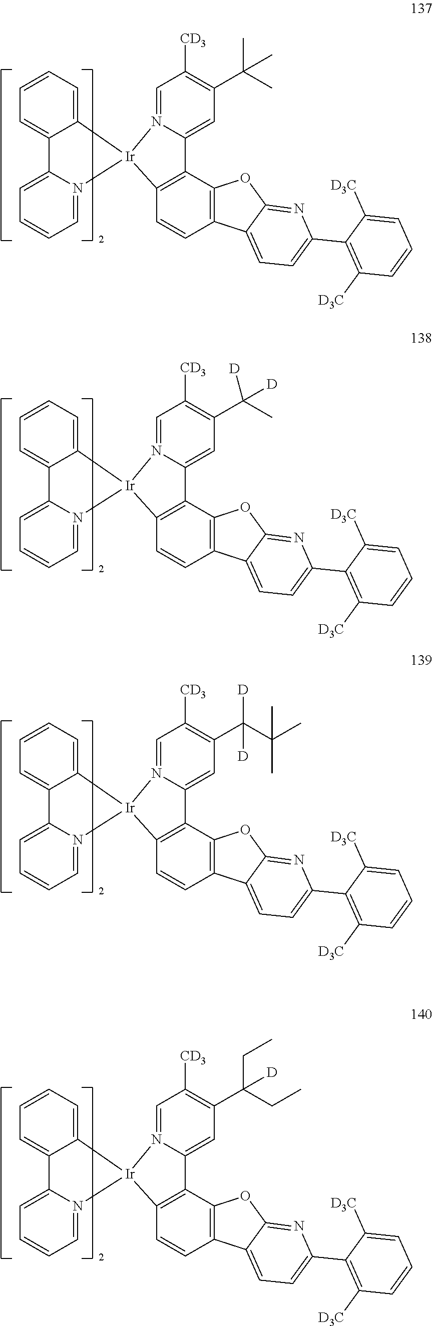

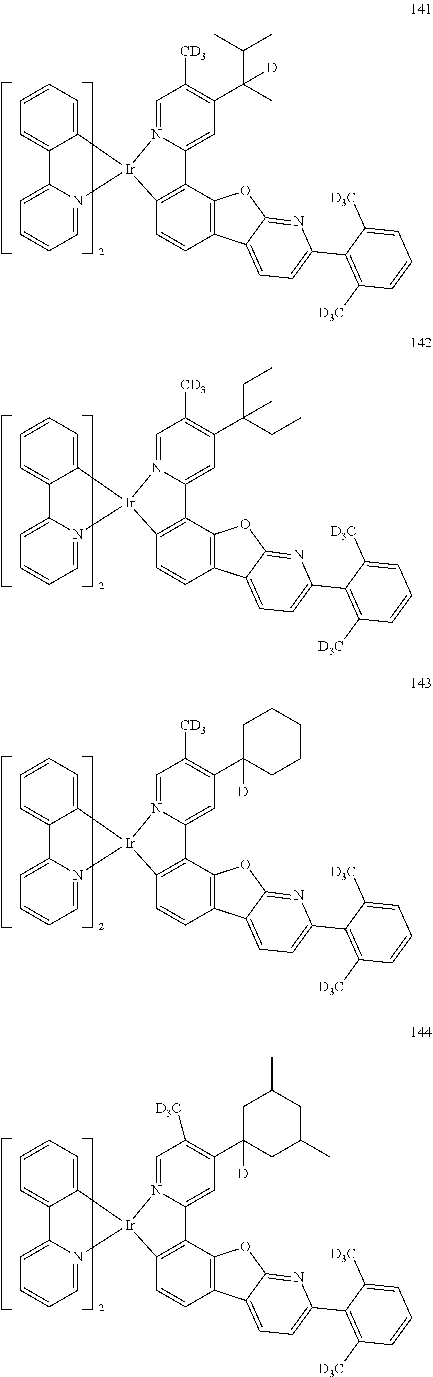

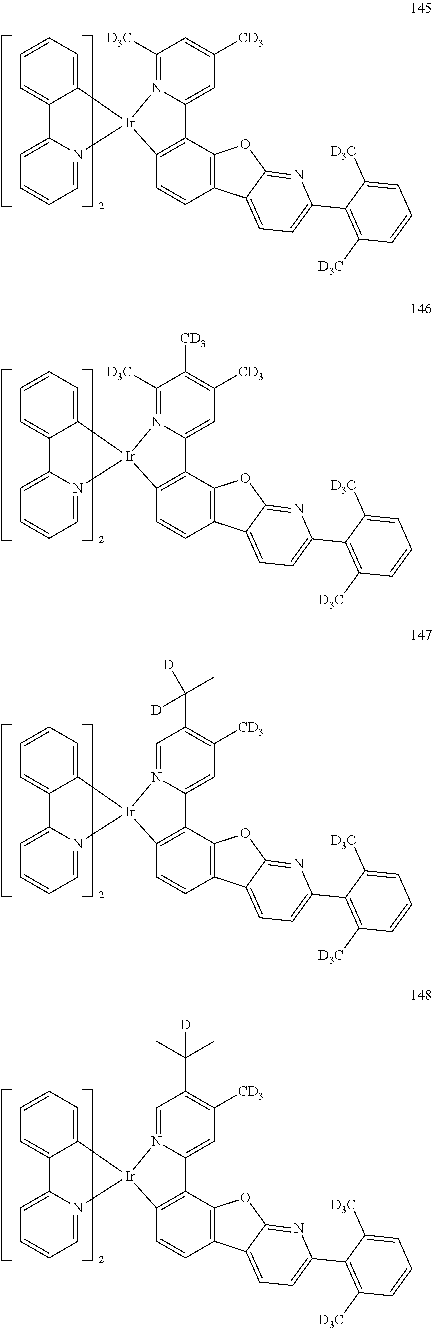

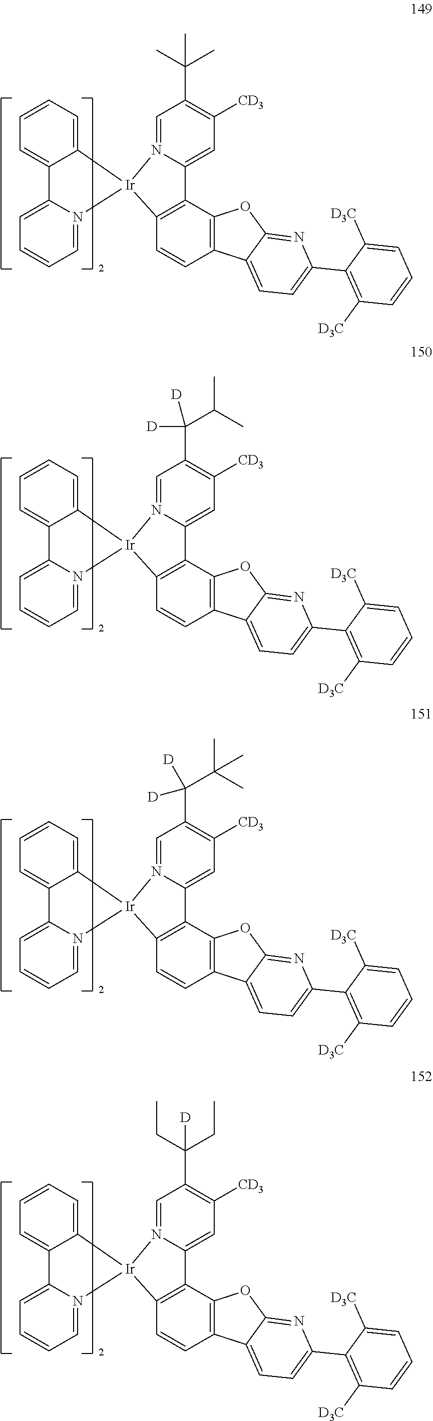

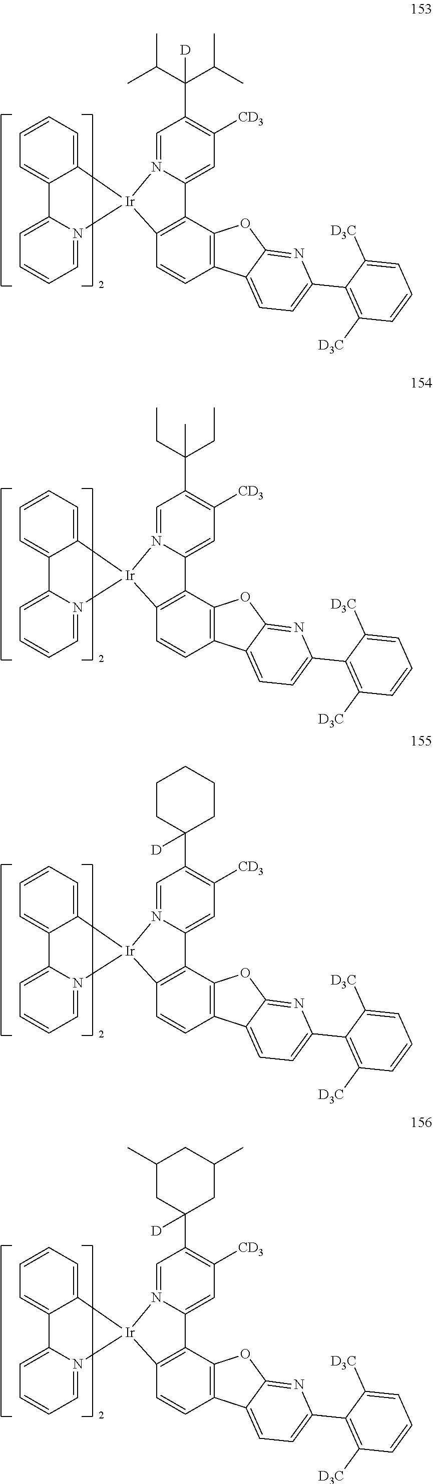

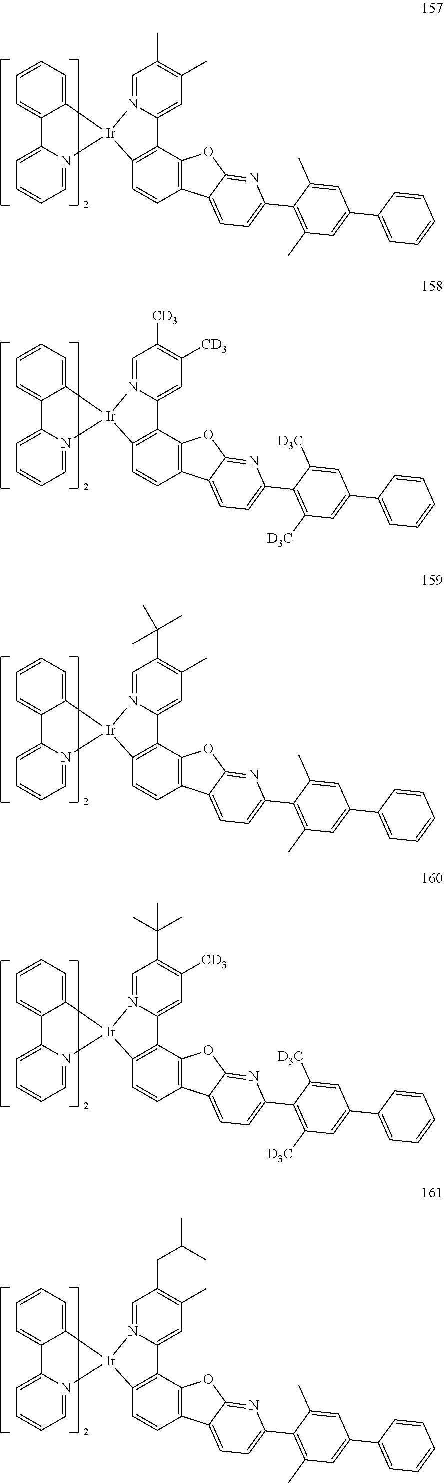

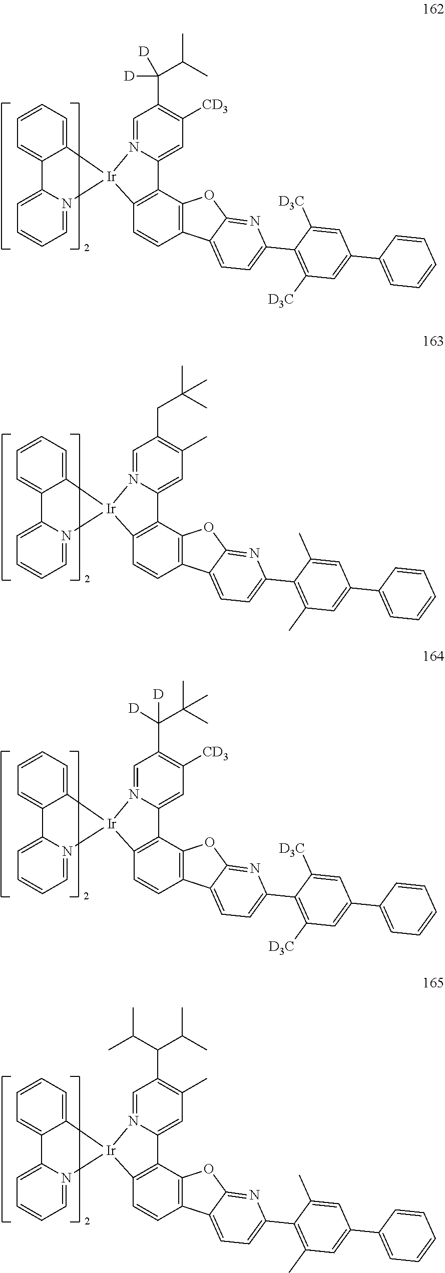

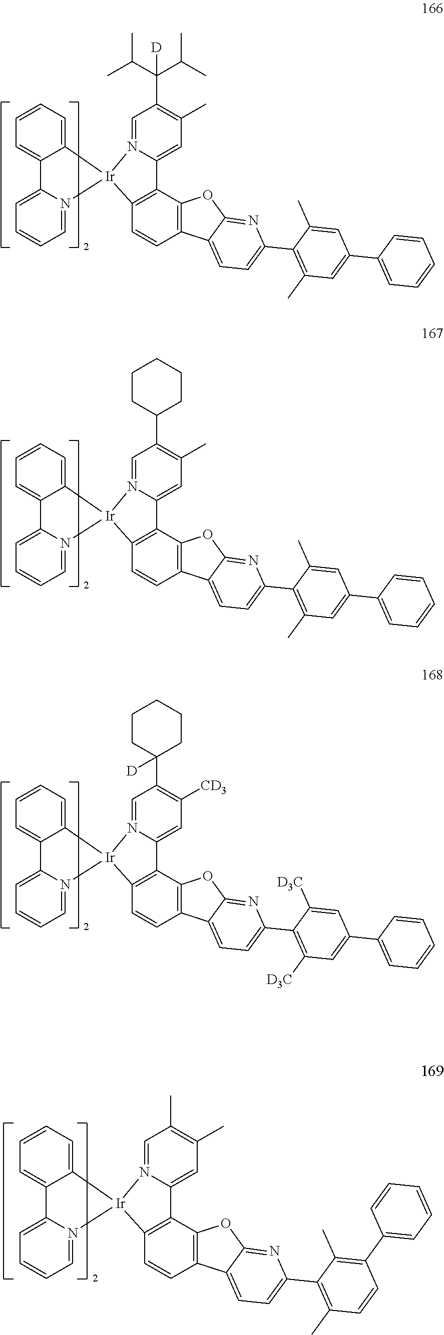

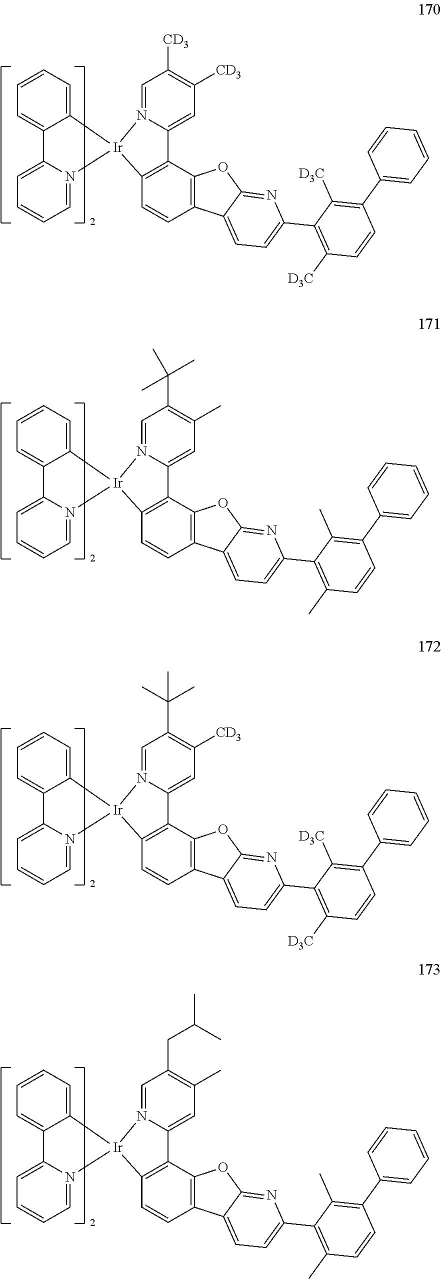

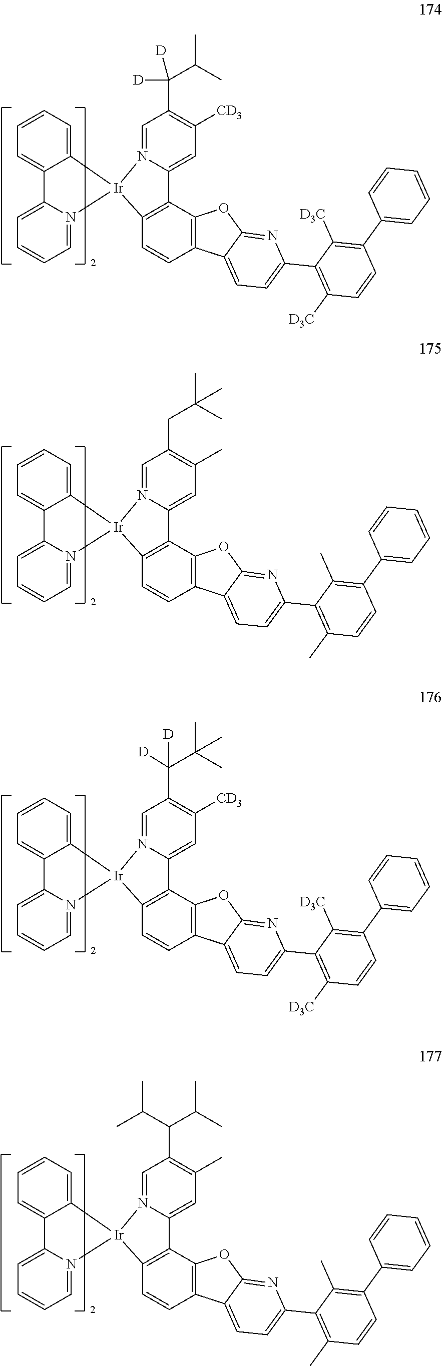

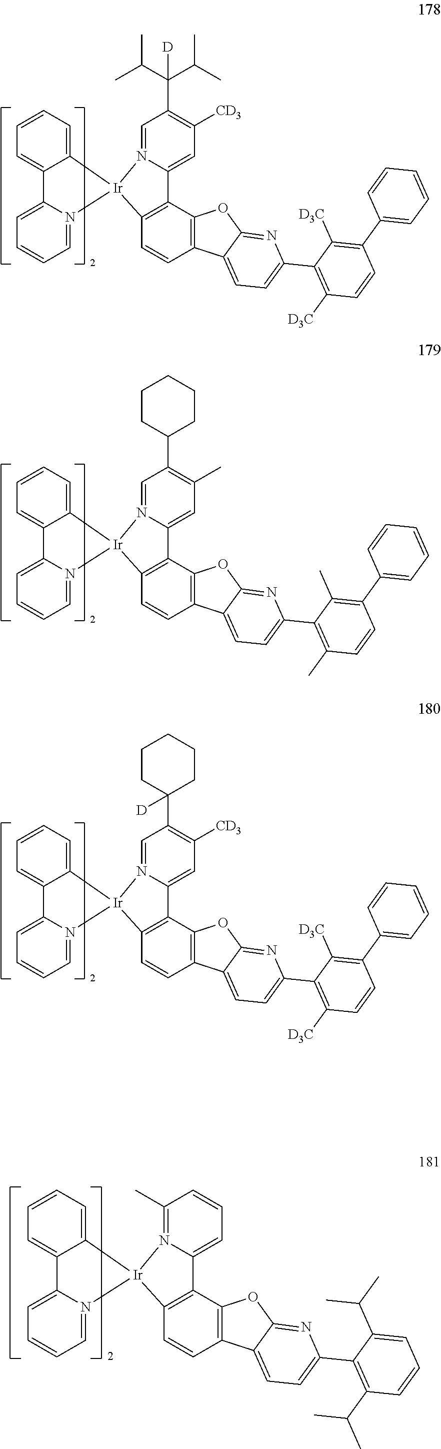

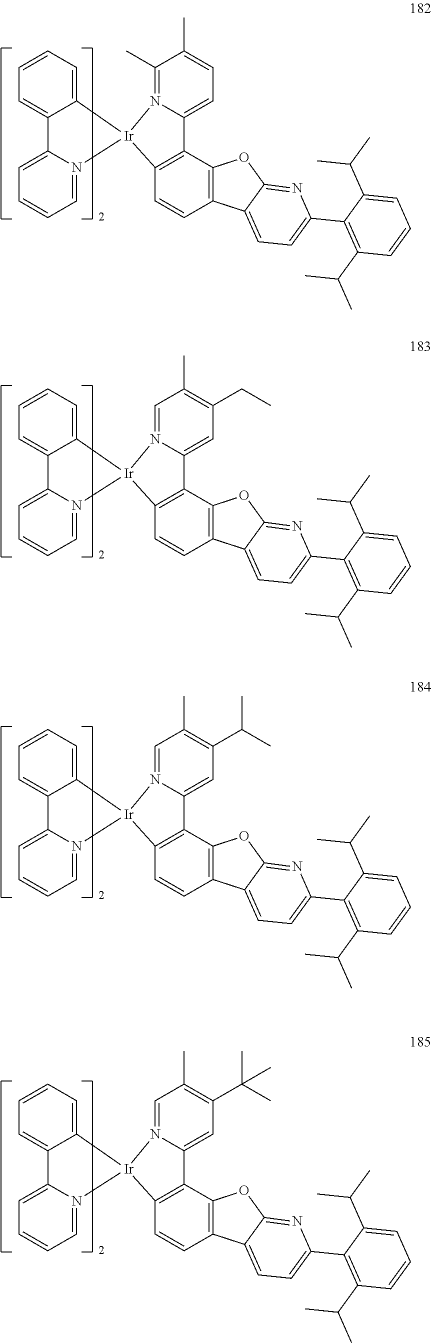

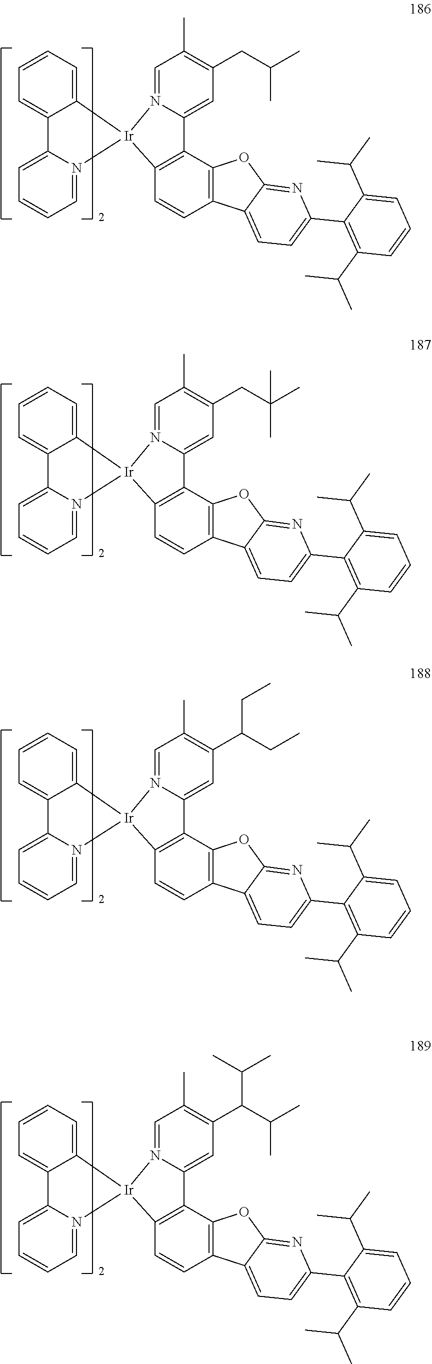

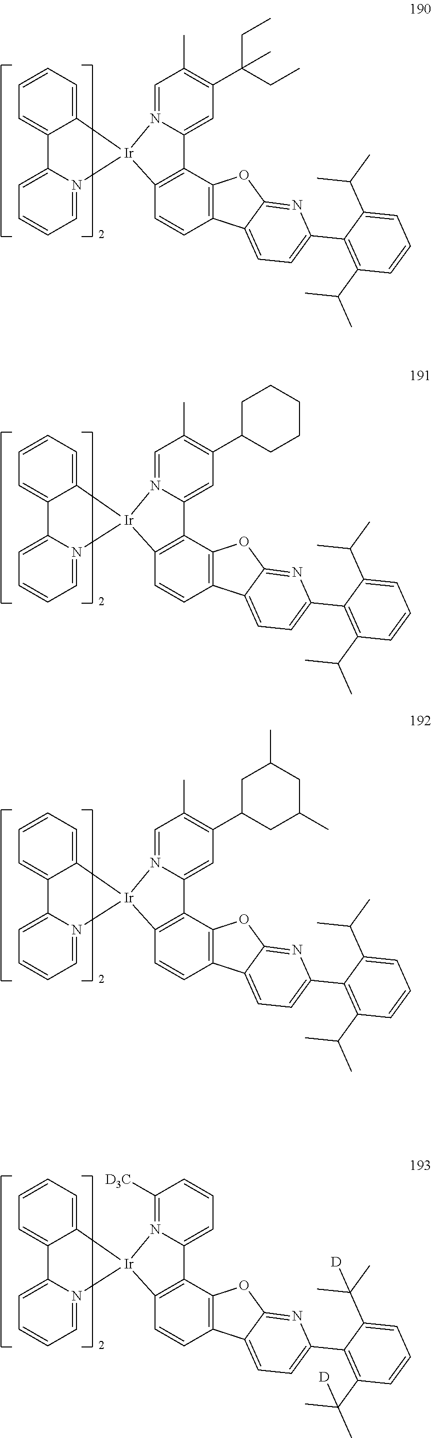

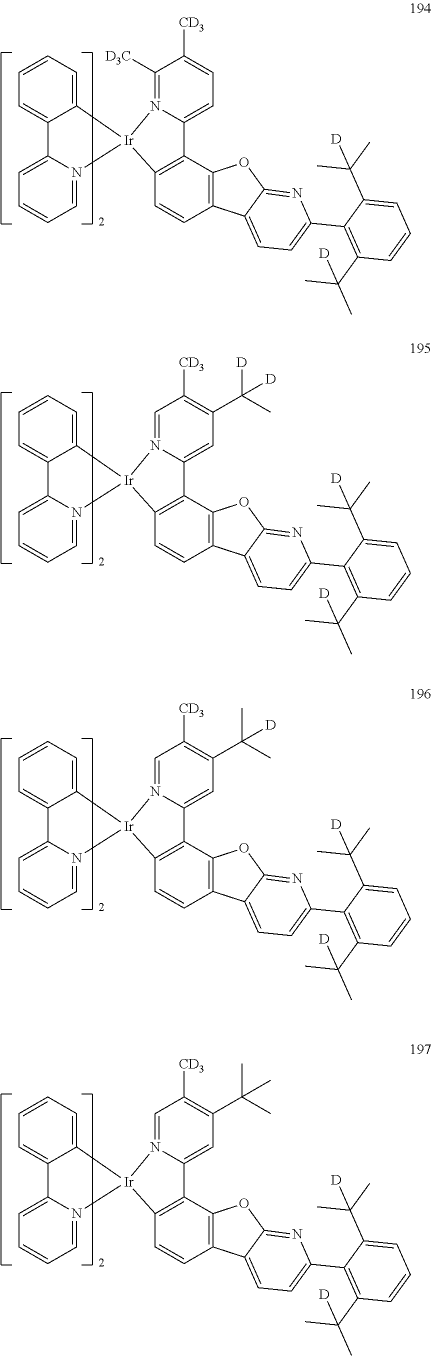

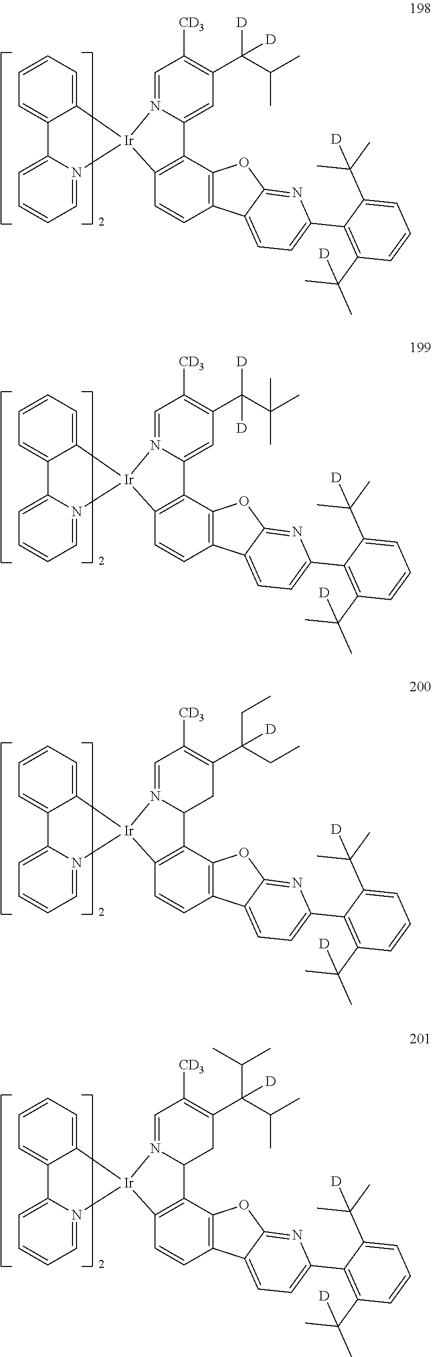

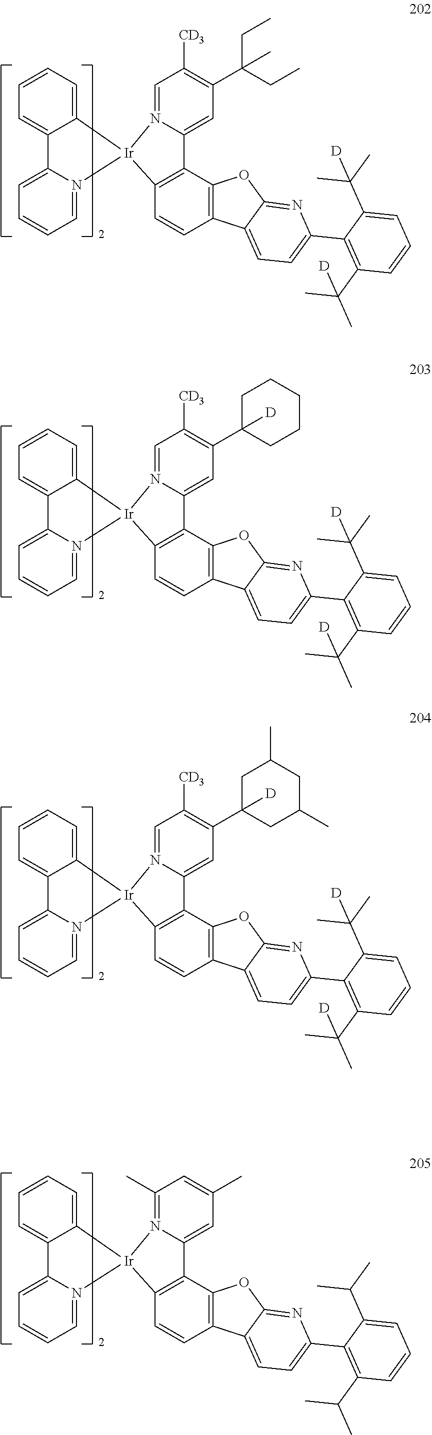

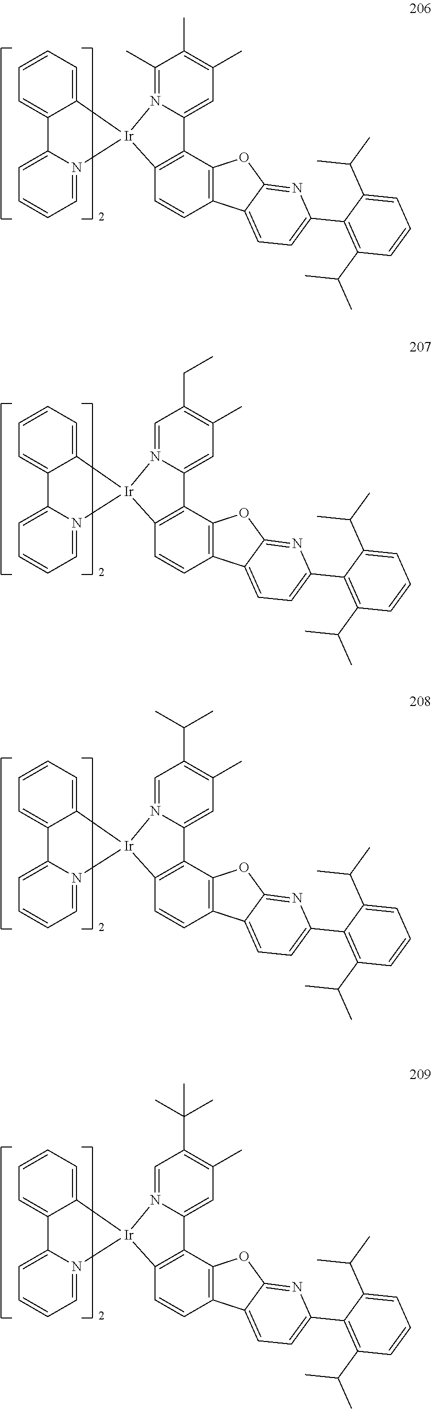

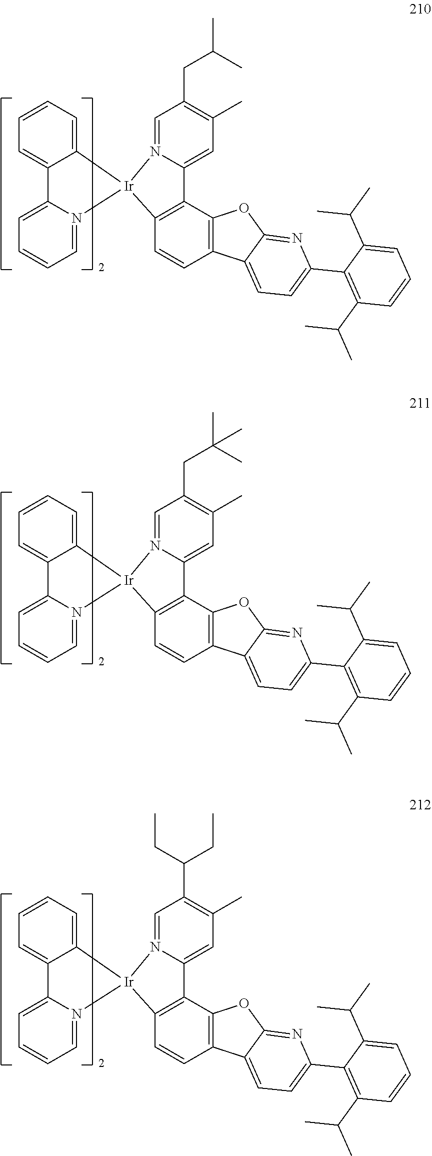

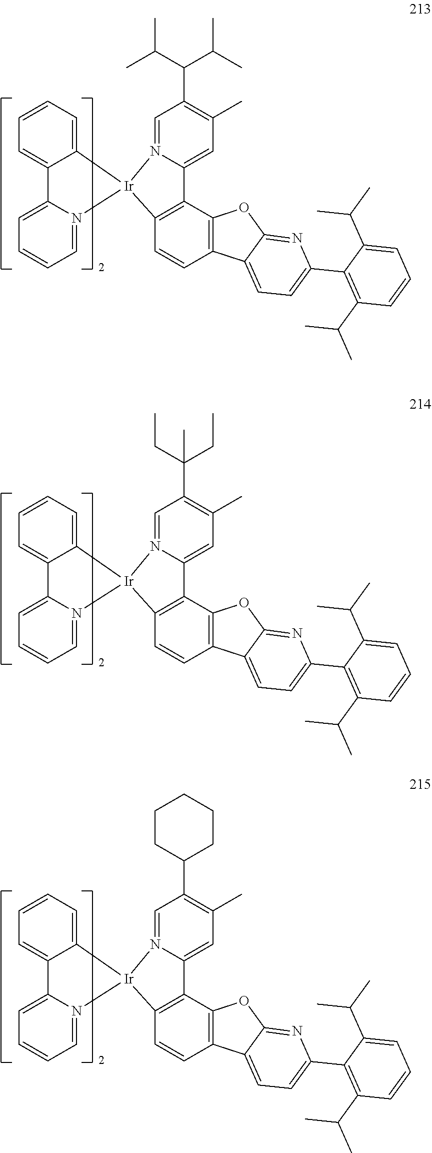

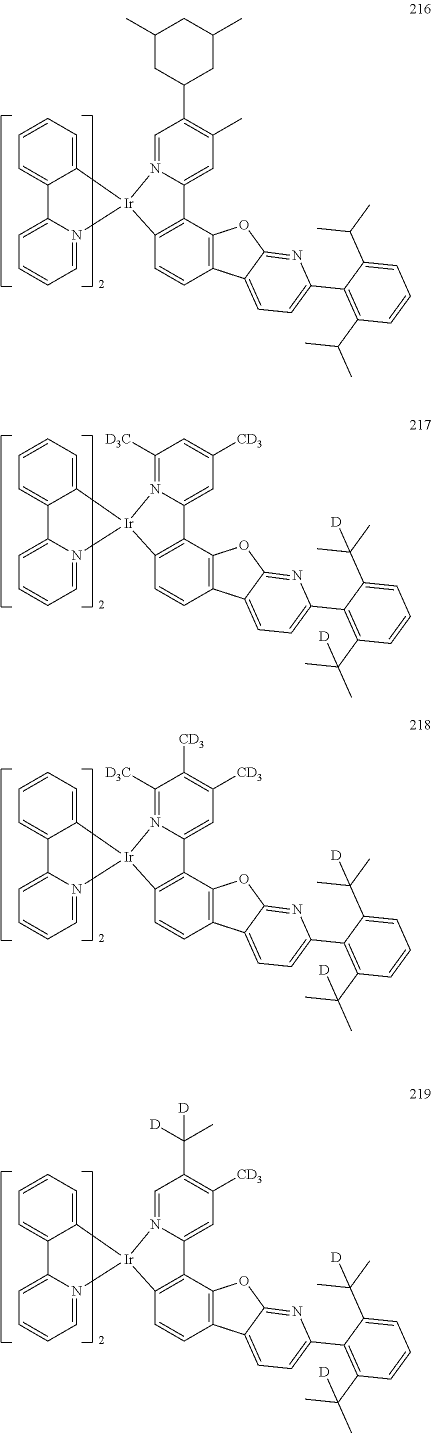

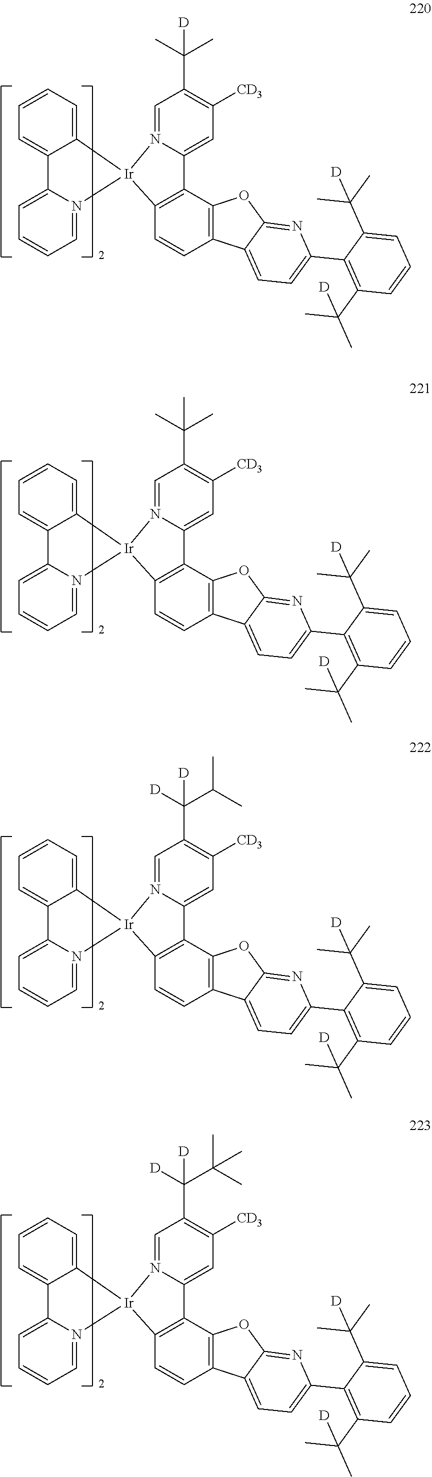

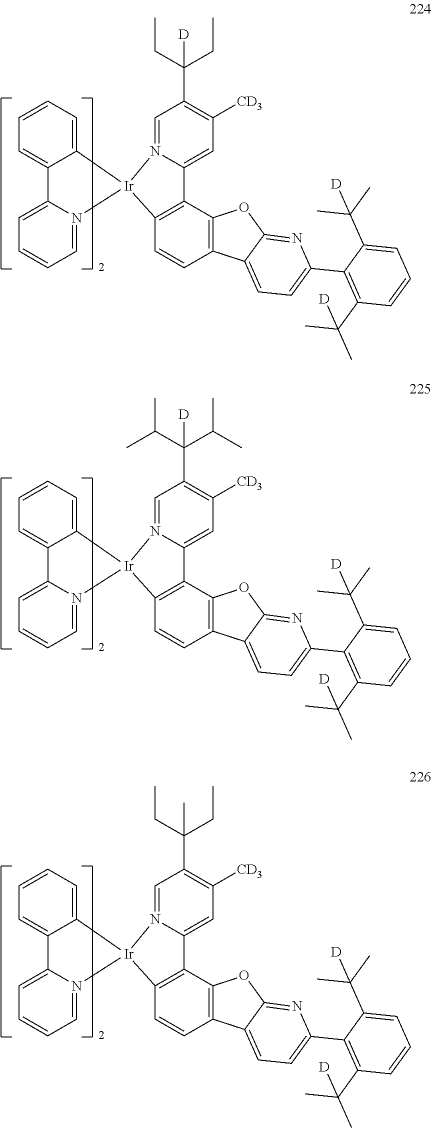

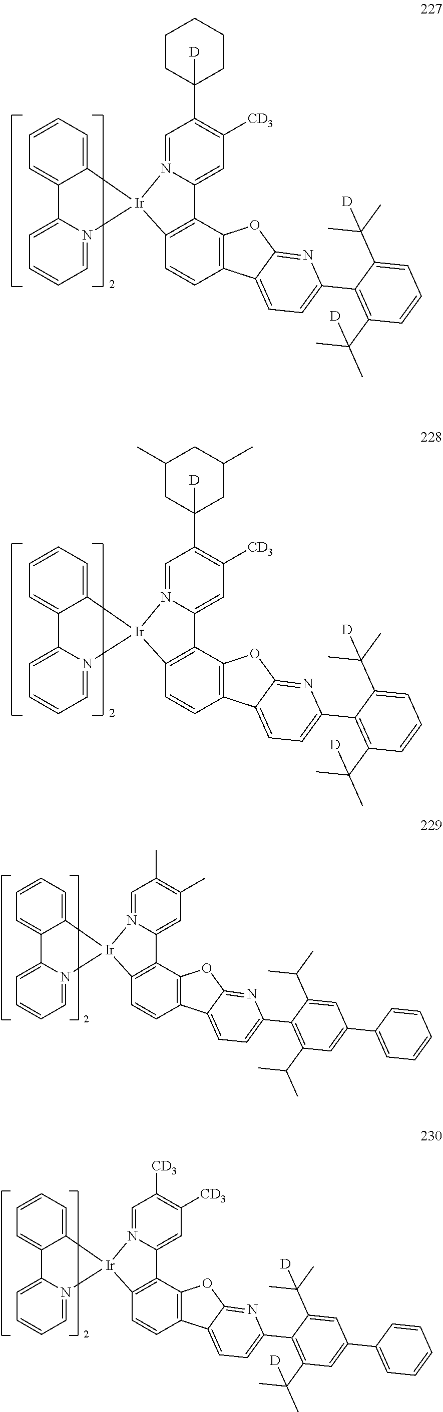

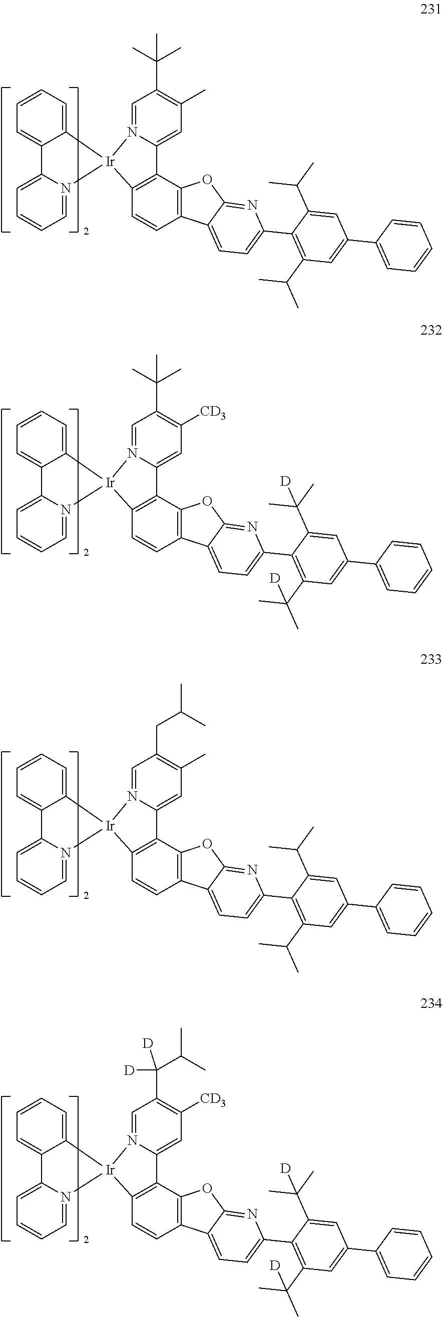

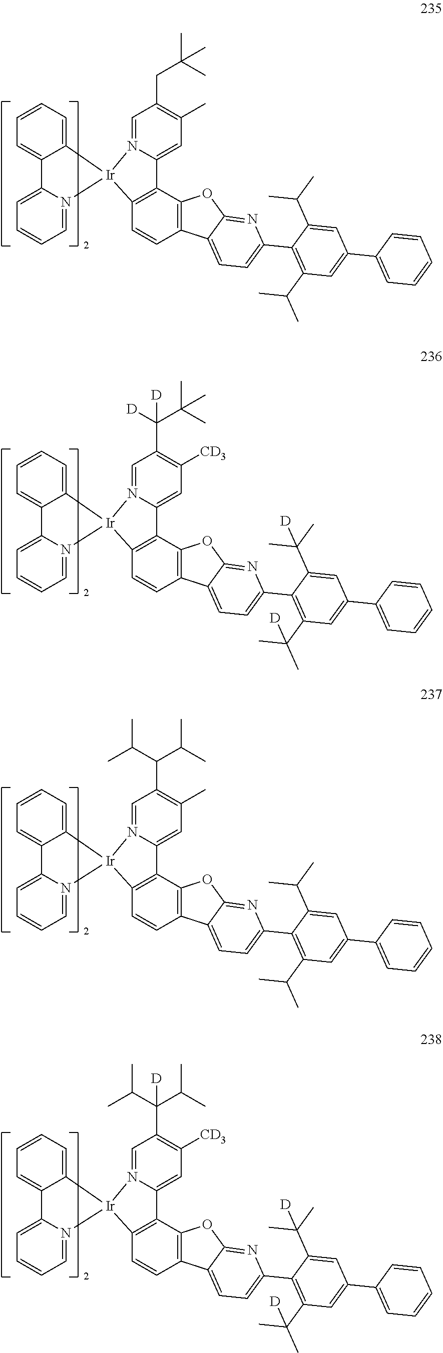

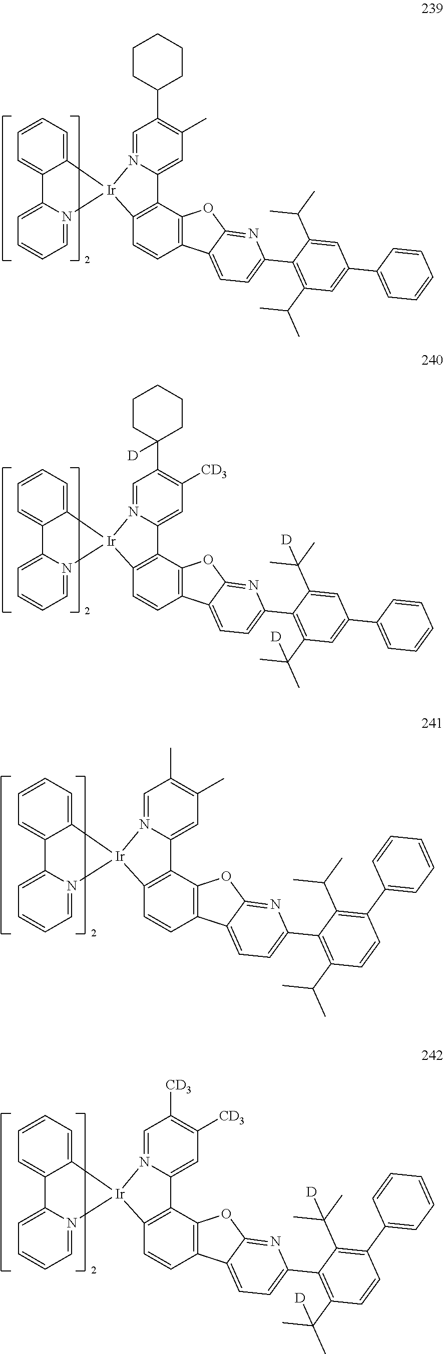

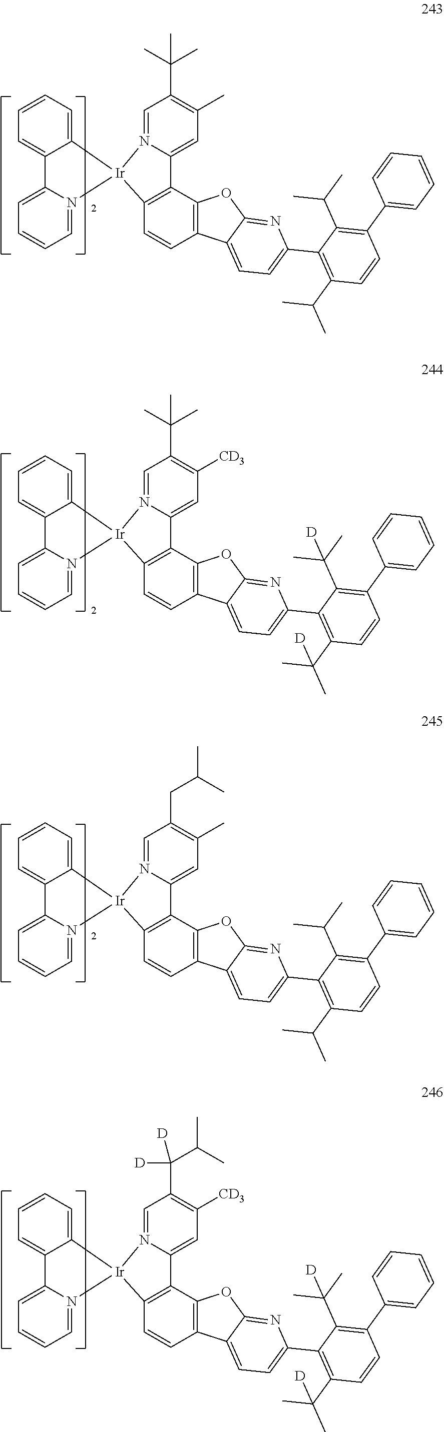

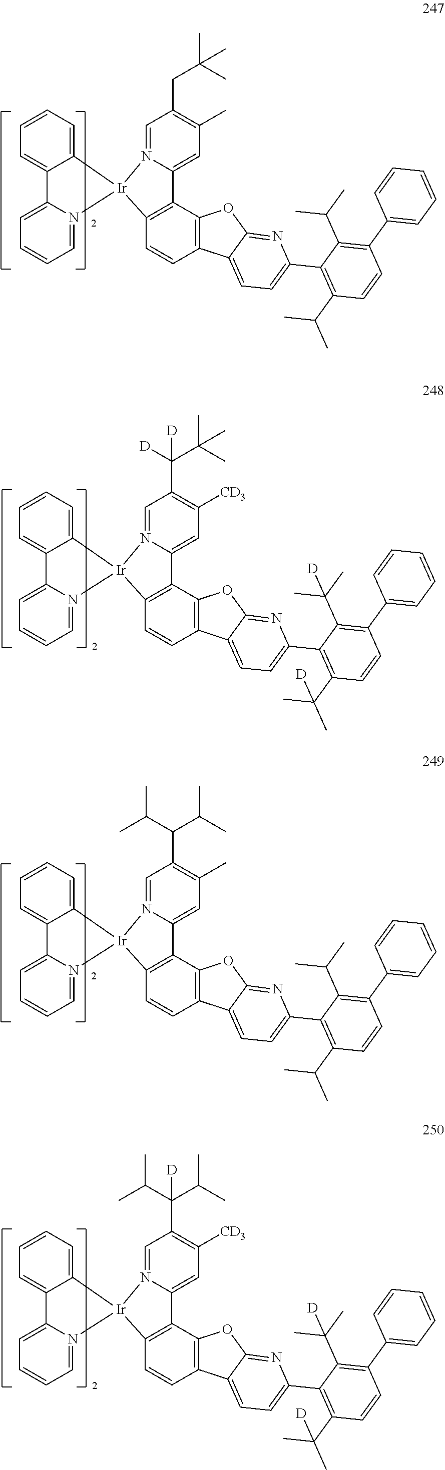

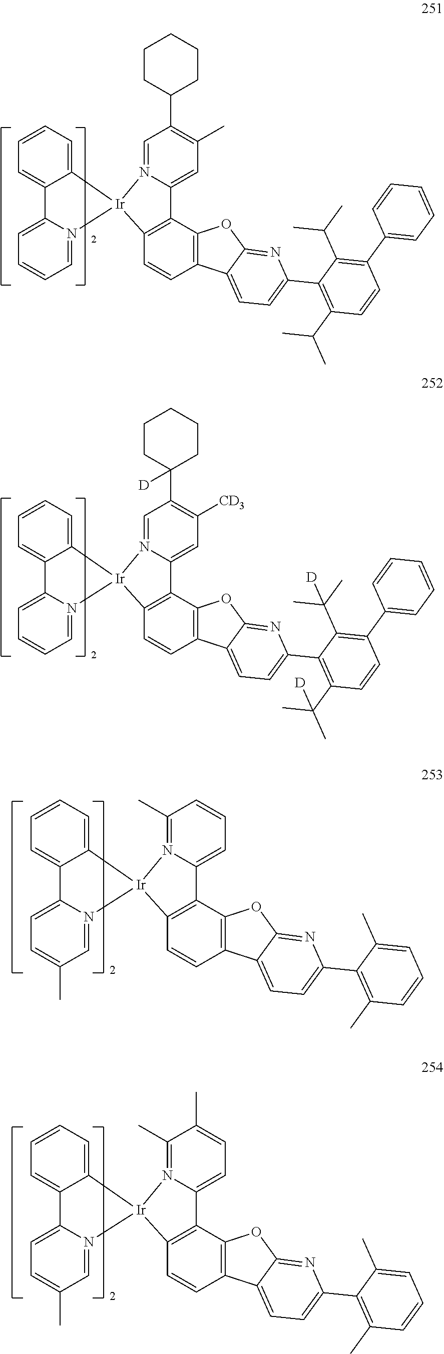

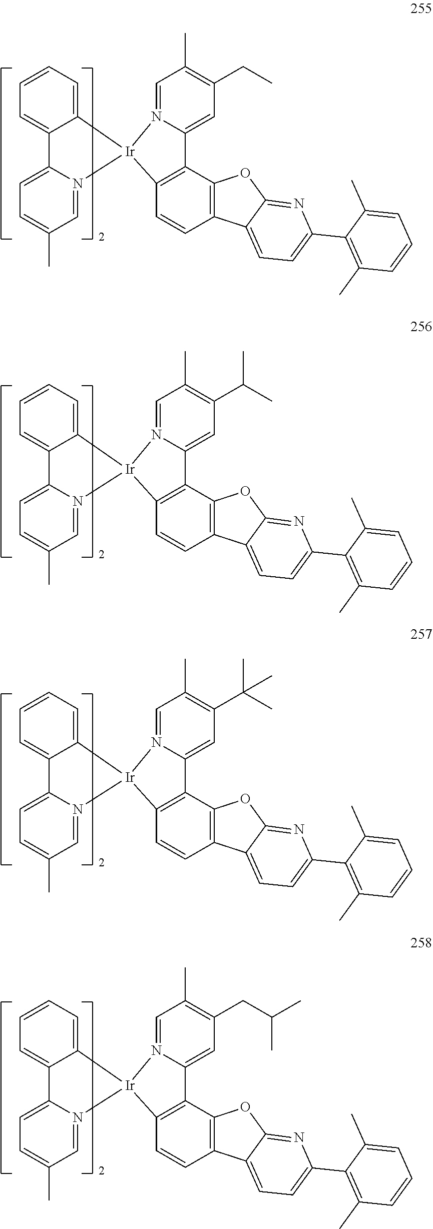

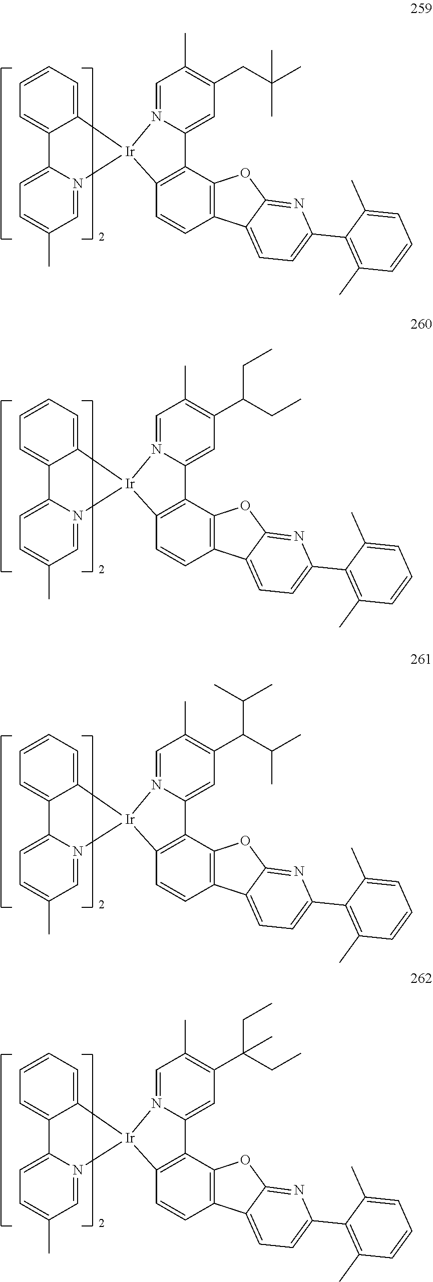

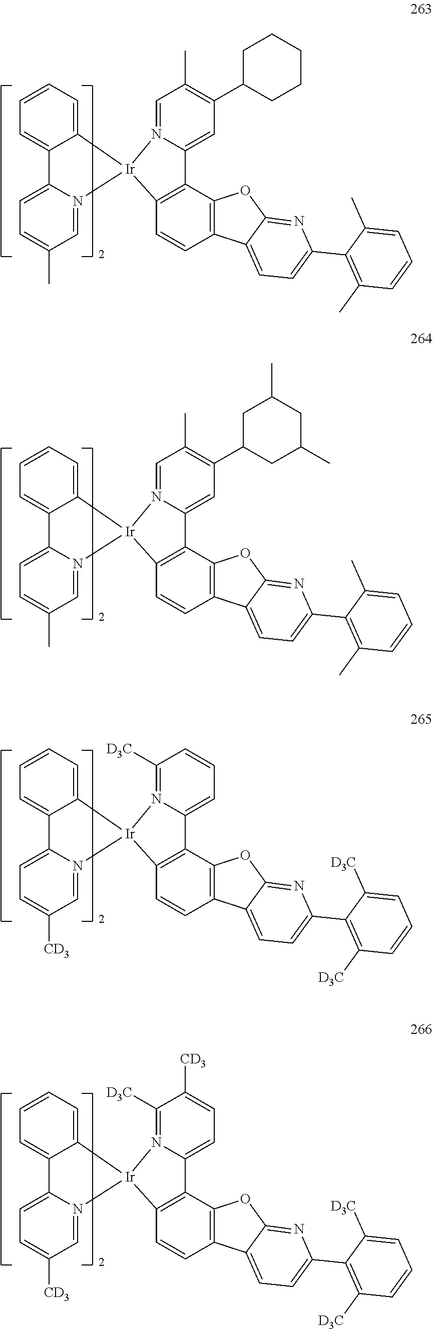

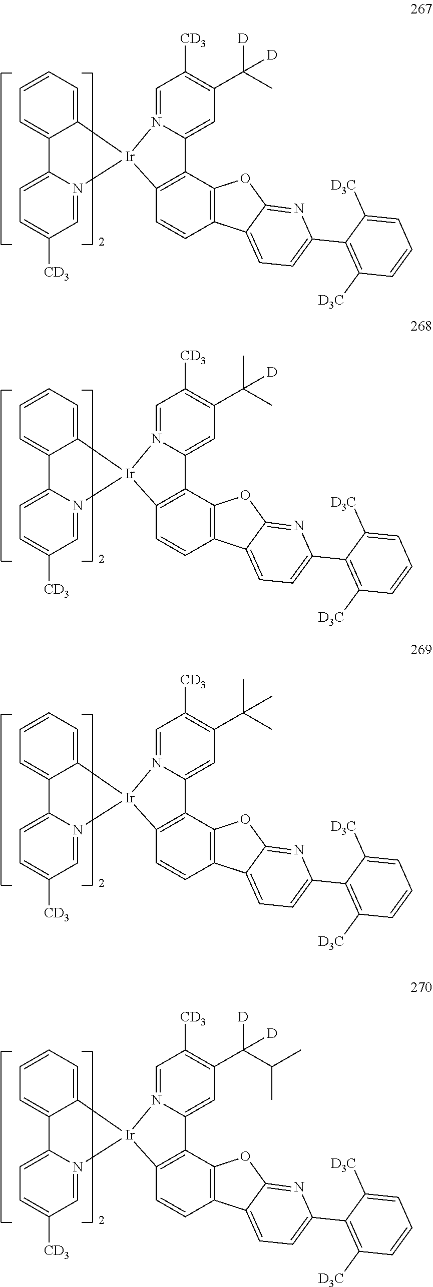

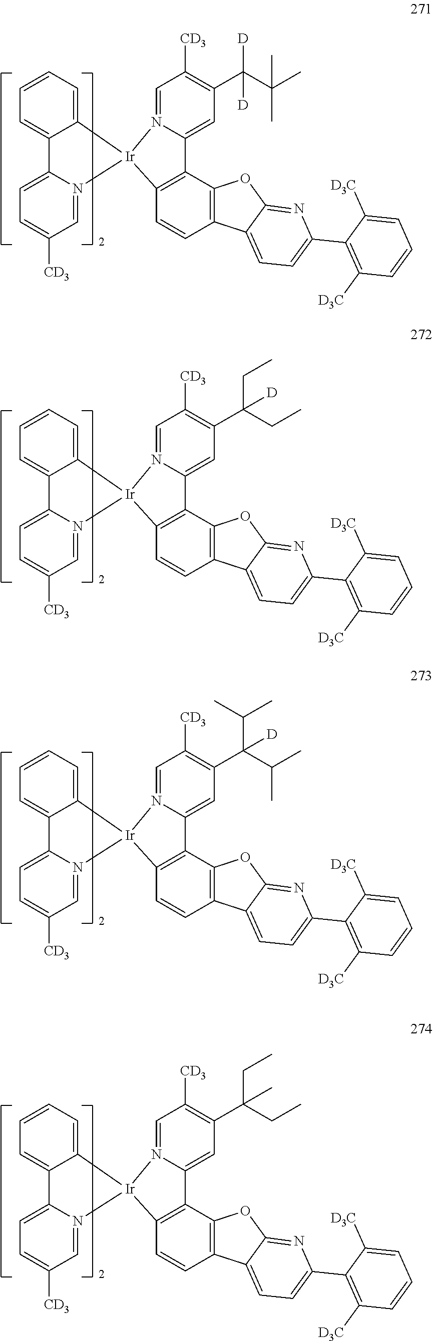

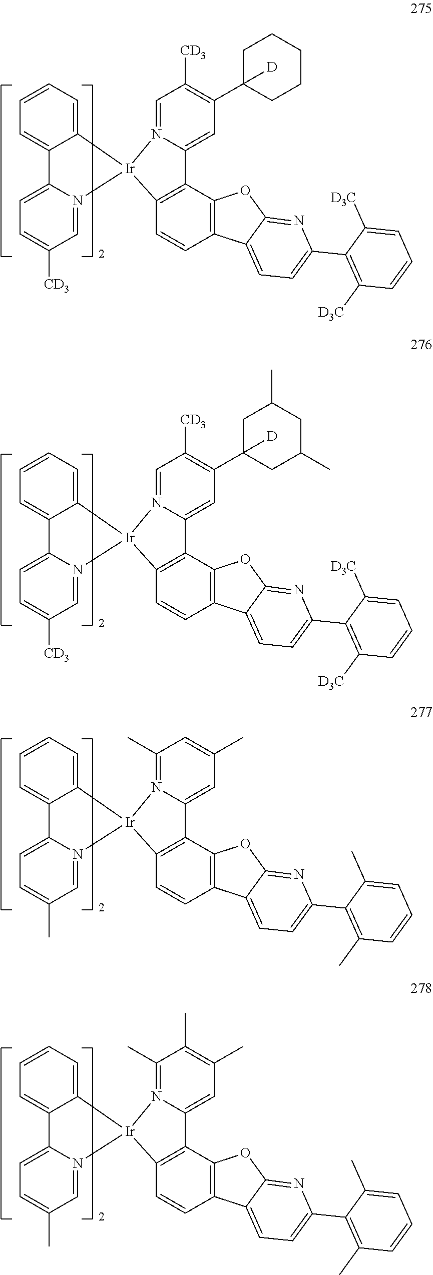

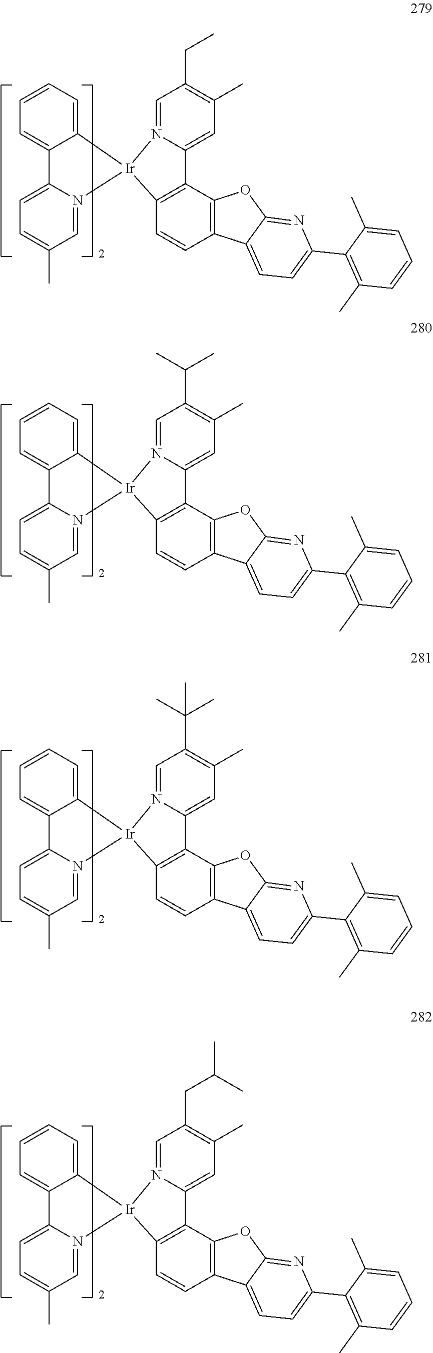

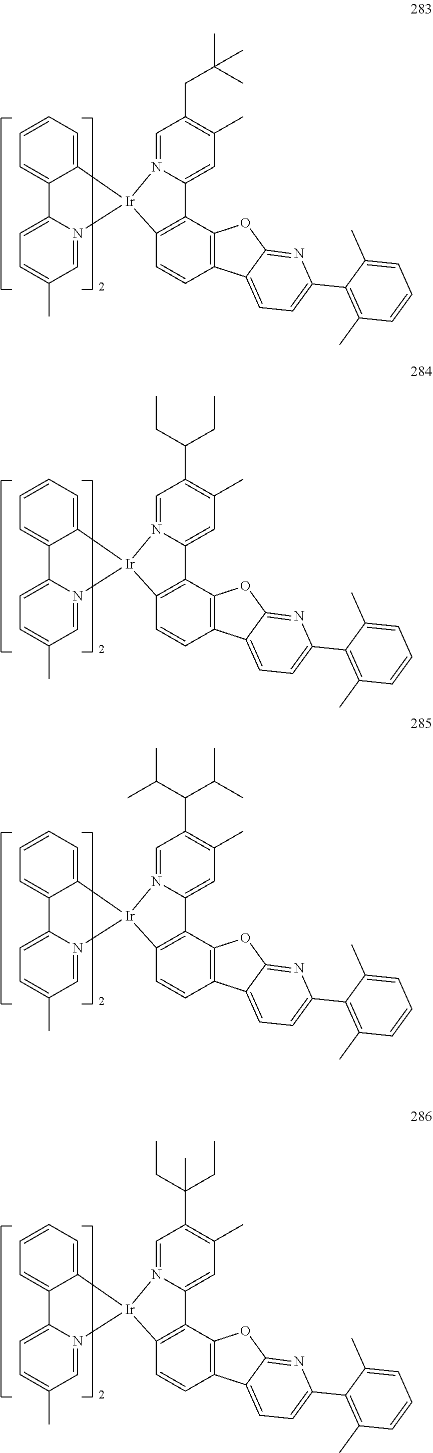

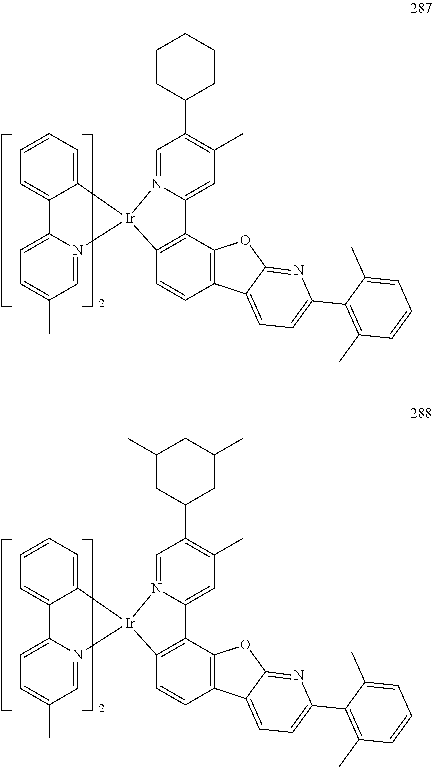

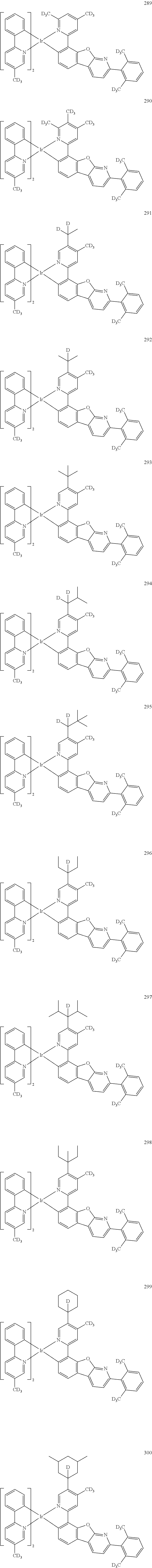

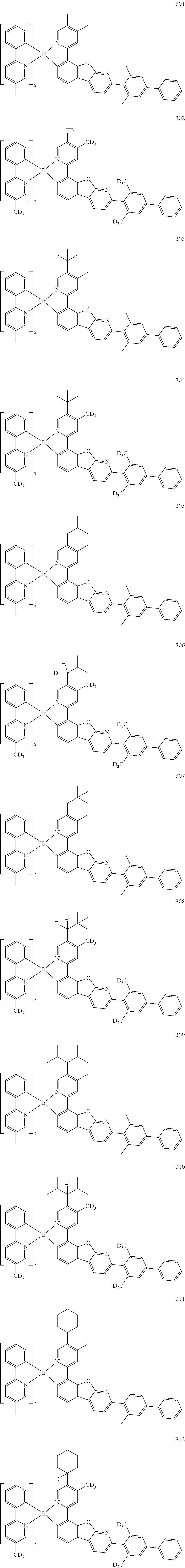

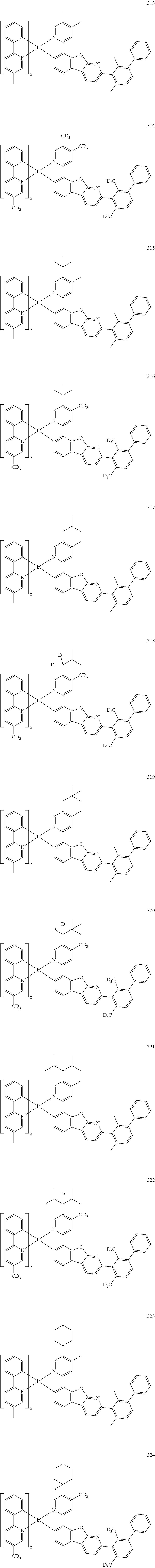

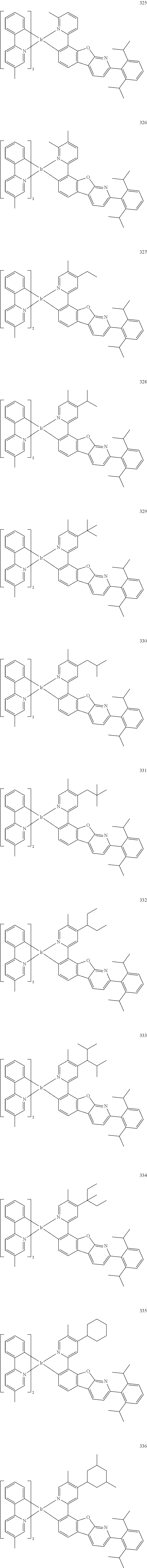

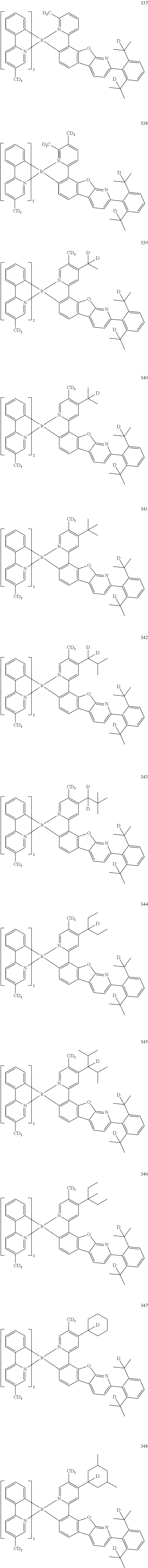

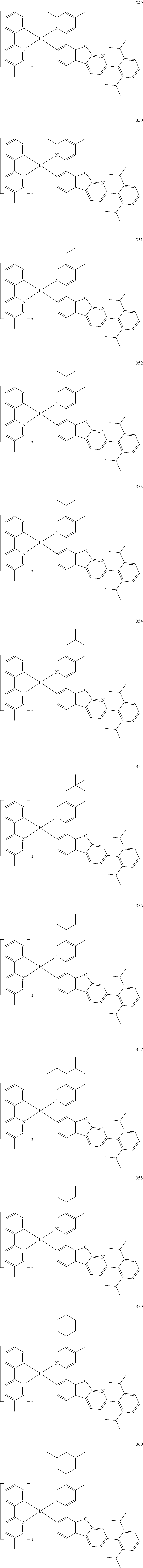

[chemical structure]

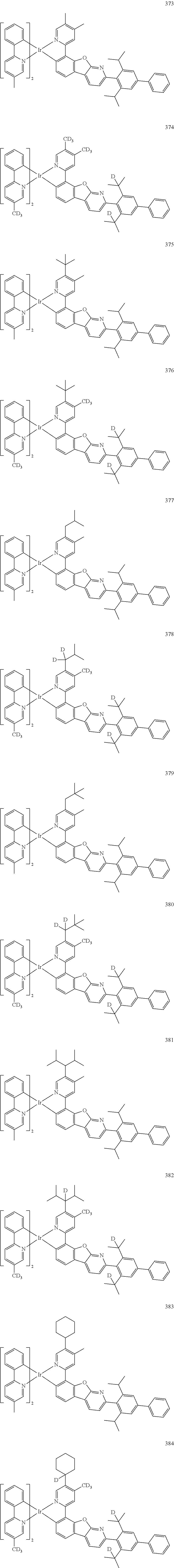

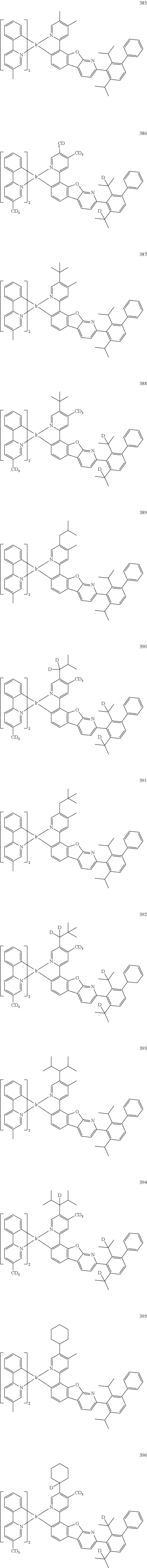

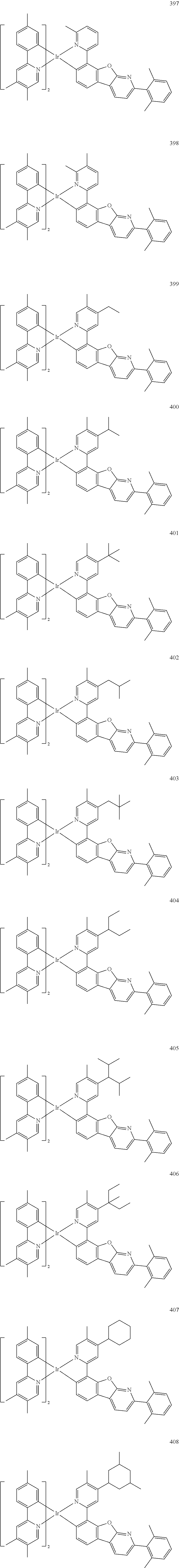

[chemical structure]

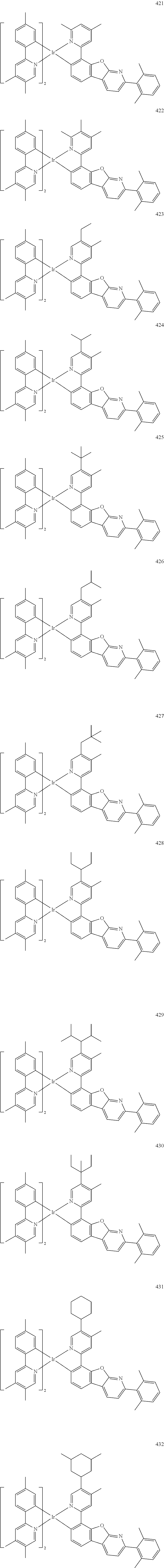

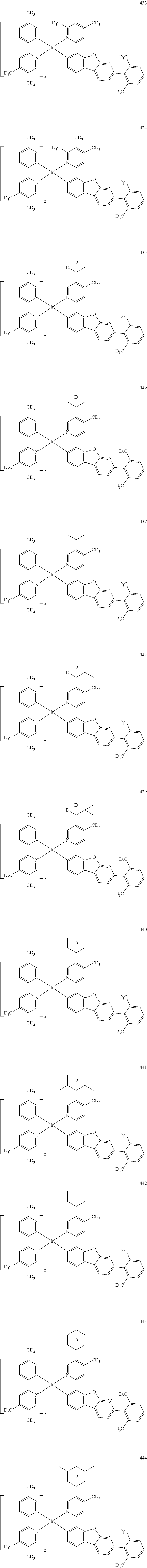

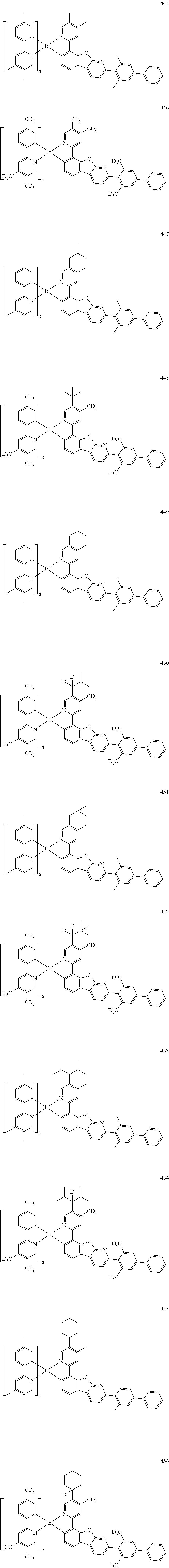

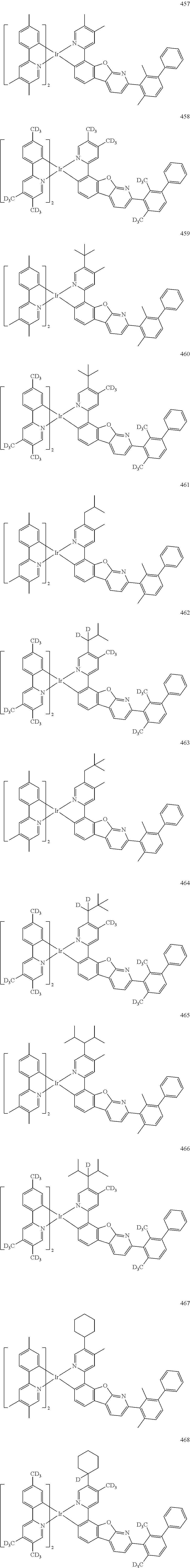

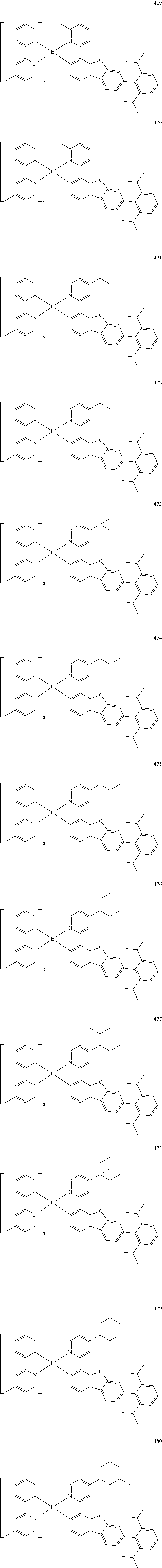

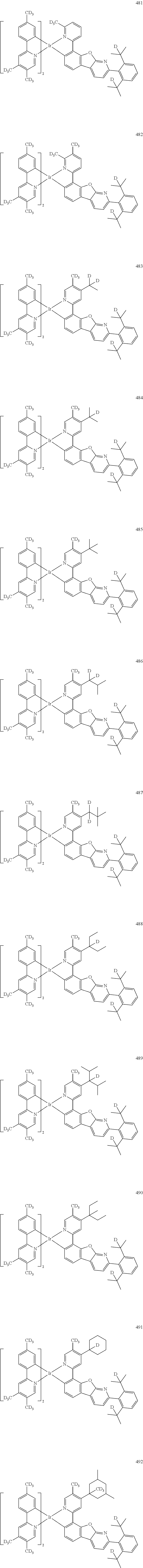

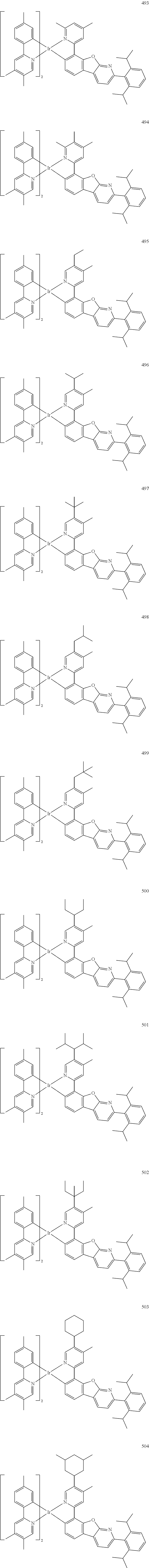

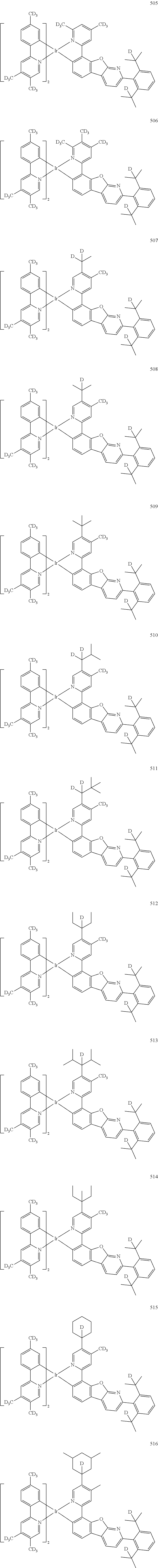

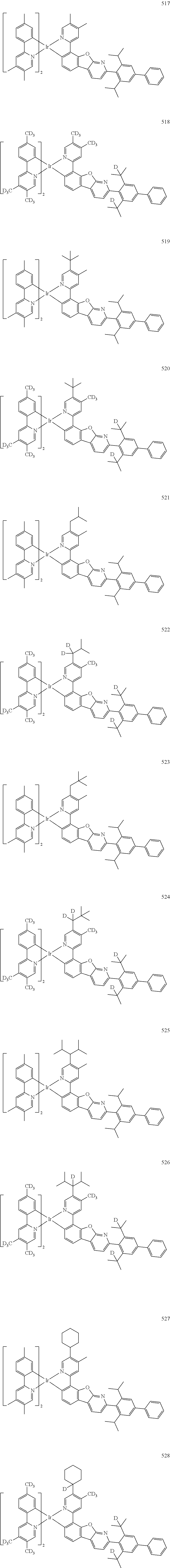

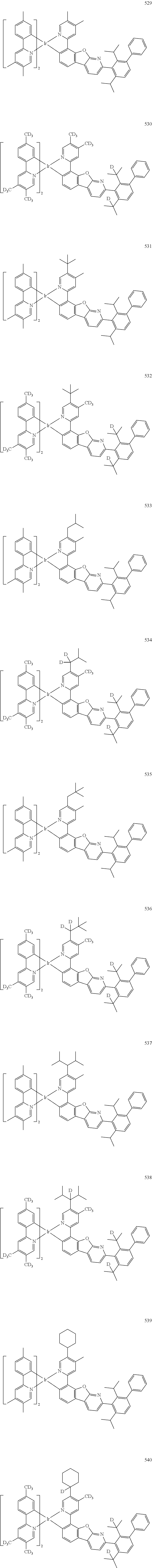

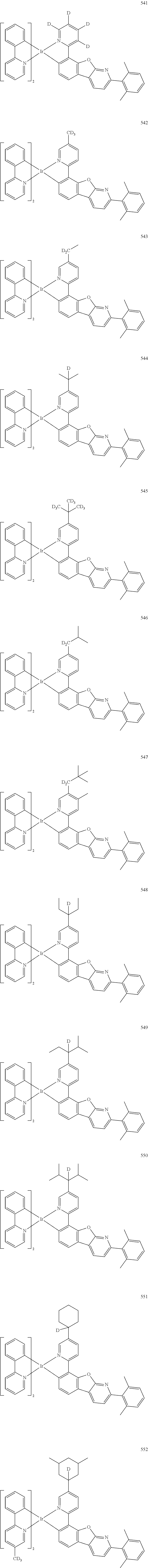

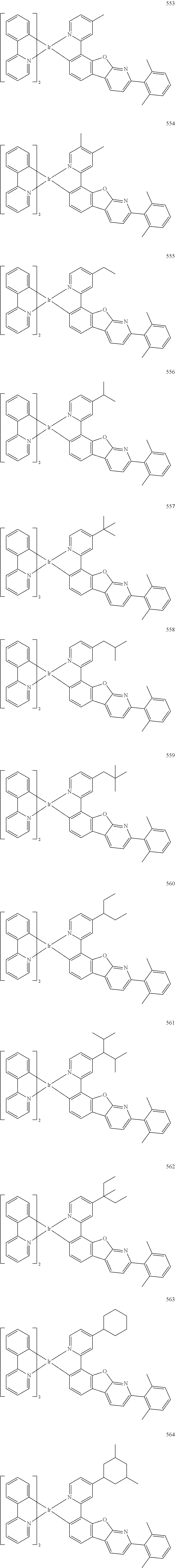

According to one implementation of the present disclosure, the organometallic compound represented by the Chemical Formula I of the present disclosure may be used as a red phosphorescent material or a green phosphorescent material, preferably, as the green phosphorescent material

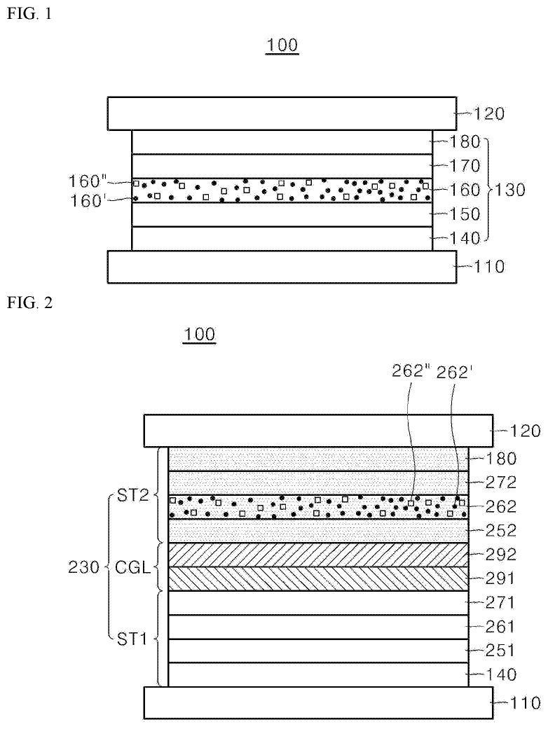

Referring to FIG. 1 according to one implementation of the present disclosure, an organic light-emitting diode 100 may be provided which includes a first electrode 110; a second electrode 120 facing the first electrode 110; and an organic layer 130 disposed between the first electrode 110 and the second electrode 120. The organic layer 130 may include a light-emitting layer 160, and the light-emitting layer 160 may include a host material 160′ and dopants 160″. The dopants 160″ may be made of the organometallic compound represented by the Chemical Formula I. In addition, in the organic light-emitting diode 100, the organic layer 130 disposed between the first electrode 110 and the second electrode 120 may be formed by sequentially stacking a hole injection layer 140 (HIL), a hole transport layer 150, (HTL), a light emission layer 160 (EML), an electron transport layer 170 (ETL) and an electron injection layer 180 (EIL) on the first electrode 110. The second electrode 120 may be formed on the electron injection layer 180, and a protective layer (not shown) may be formed thereon.

Further, although not shown in FIG. 1, a hole transport auxiliary layer may be further added between the hole transport layer 150 and the light-emitting layer 160. The hole transport auxiliary layer may contain a compound having good hole transport properties, and may reduce a difference between HOMO energy levels of the hole transport layer 150 and the light-emitting layer 160 so as to adjust the hole injection properties. Thus, accumulation of holes at an interface between the hole transport auxiliary layer and the light-emitting layer 160 may be reduced, thereby reducing a quenching phenomenon in which excitons disappear at the interface due to polarons. Accordingly, deterioration of the element may be reduced and the element may be stabilized, thereby improving efficiency and lifespan thereof.

The first electrode 110 may act as a positive electrode, and may be made of ITO, IZO, tin-oxide, or zinc-oxide as a conductive material having a relatively large work function value. However, the present disclosure is not limited thereto.

The second electrode 120 may act as a negative electrode, and may include Al, Mg, Ca, or Ag as a conductive material having a relatively small work function value, or an alloy or combination thereof. However, the present disclosure is not limited thereto.

The hole injection layer 140 may be positioned between the first electrode 110 and the hole transport layer 150. The hole injection layer 140 may have a function of improving interface characteristics between the first electrode 110 and the hole transport layer 150, and may be selected from a material having appropriate conductivity. The hole injection layer 140 may include one or more compounds selected from a group consisting of MTDATA, CuPc, TCTA, HATCN, TDAPB, PEDOT/PSS, and N1,N1′-([1,1′-biphenyl]-4,4′-diyl)bis(N1,N4,N4)-triphenylbenzene-1,4-diamine). Preferably, the hole injection layer 140 may include N1,N1′-([1,1′-biphenyl]-4,4′-diyl)bis(N1,N4,N4-triphenylbenzene-1,4-diamine). However, the present disclosure is limited thereto.

The hole transport layer 150 may be positioned adjacent to the light-emitting layer and between the first electrode 110 and the light-emitting layer 160. A material of the hole transport layer 150 may include a compound selected from a group consisting of TPD, NPB, CBP, N-(biphenyl-4-yl)-9,9-dimethyl-N-(4-(9-phenyl-9H-carbazol-3-yl)phenyl)-9H-fluoren-2-amine, N-(biphenyl-4-yl)-N-(4-(9-phenyl-9H-carbazol-3-yl)phenyl)biphenyl)-4-amine, etc. Preferably, the material of the hole transport layer 150 may include NPB. However, the present disclosure is not limited thereto.

According to the present disclosure, the light-emitting layer 160 may be formed by doping a host material 160′ with the organometallic compound represented by the Chemical Formula I as a dopant 160″ in order to improve luminous efficiency of the diode 100. The dopant 160″ may be used as a green or red light emitting material, and preferably as a green phosphorescent material.

A doping concentration of the dopant 160″ according to the present disclosure may be adjusted to be within a range of 1 to 30% by weight based on a total weight of the host material 160′. However, the disclosure is not limited thereto. For example, the doping concentration may be in a range of 2 to 20 wt %, for example, 3 to 15 wt %, for example, 5 to 10 wt %, for example, 3 to 8 wt %, for example, 2 to 7 wt %, for example, 5 to 7 wt %, or for example, 5 to 6 wt %.

The light-emitting layer 160 according to the present disclosure contains the host material 160′ which is known in the art and may achieve an effect of the present disclosure while the layer 160 contains the organometallic compound represented by the Chemical Formula I as the dopant 160″. For example, in accordance with the present disclosure, the host material 160′ may include a compound containing a carbazole group, and may preferably include one host material selected from a group consisting of CBP (carbazole biphenyl), mCP (1,3-bis(carbazol-9-yl), and the like. However, the disclosure is not limited thereto.

Further, the electron transport layer 170 and the electron injection layer 180 may be sequentially stacked between the light-emitting layer 160 and the second electrode 120. A material of the electron transport layer 170 has high electron mobility such that electrons may be stably supplied to the light-emitting layer under smooth electron transport.

For example, the material of the electron transport layer 170 may be known in the art and include, for example, a compound selected from a group consisting of Alq3 (tris(8-hydroxyquinolino)aluminum), Liq (8-hydroxyquinolinolatolithium), PBD (2-(4-biphenylyl)-5-(4-tert-butylphenyl)-1,3,4oxadiazole), TAZ (3-(4-biphenyl)4-phenyl-5-tert-butylphenyl-1,2,4-triazole), spiro-PBD, BAlq (bis(2-methyl-8-quinolinolate)-4-(phenylphenolato)aluminium), SAlq, TPBi (2,2′,2-(1,3,5-benzinetriyl)-tris(1-phenyl-1-H-benzimidazole), oxadiazole, triazole, phenanthroline, benzoxazole, benzthiazole, and 2-(4-(9,10-di(naphthalen-2-yl)anthracen-2-yl)phenyl)-1-phenyl-1H-benzo[d]imidazole. Preferably, the material of the electron transport layer 170 may include 2-(4-(9,10-di(naphthalen-2-yl)anthracen-2-yl)phenyl)-1-phenyl-1H-benzo[d]imidazole. However, the present disclosure is not limited thereto.

The electron injection layer 180 serves to facilitate electron injection, and a material of the electron injection layer may be known in the art and include, for example, a compound selected from a group consisting of Alq3 (tris(8-hydroxyquinolino)aluminum), PBD, TAZ, spiro-PBD, BAlq, SAlq, etc. However, the present disclosure is not limited thereto. Alternatively, the electron injection layer 180 may be made of a metal compound. The metal compound may include, for example, one or more selected from a group consisting of Liq, LiF, NaF, KF, RbF, CsF, FrF, BeF₂, MgF₂, CaF₂, SrF₂, BaF₂ and RaF₂. However, the present disclosure is not limited thereto.

The organic light-emitting diode according to the present disclosure may be embodied as a white light-emitting diode having a tandem structure. The tandem organic light-emitting diode according to an illustrative embodiment of the present disclosure may be formed in a structure in which adjacent ones of two or more light-emitting stacks are connected to each other via a charge generation layer (CGL). The organic light-emitting diode may include at least two light-emitting stacks disposed on a substrate, wherein each of the at least two light-emitting stacks includes first and second electrodes facing each other, and the light-emitting layer disposed between the first and second electrodes to emit light in a specific wavelength band. The plurality of light-emitting stacks may emit light of the same color or different colors. In addition, one or more light-emitting layers may be included in one light-emitting stack, and the plurality of light-emitting layers may emit light of the same color or different colors.

In this case, the light-emitting layer included in at least one of the plurality of light-emitting stacks may contain the organometallic compound represented by the Chemical Formula I according to the present disclosure as the dopants. Adjacent ones of the plurality of light-emitting stacks in the tandem structure may be connected to each other via the charge generation layer CGL including an N-type charge generation layer and a P-type charge generation layer.

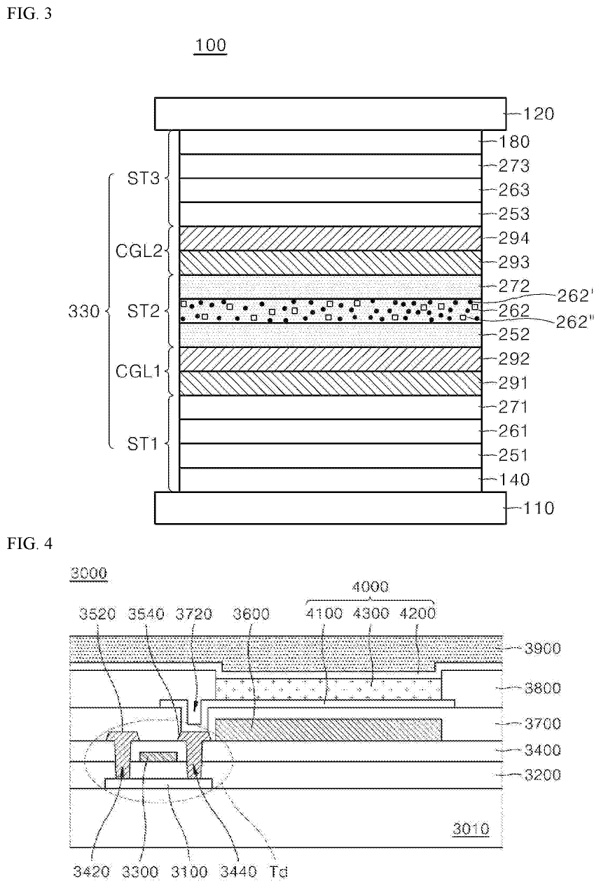

FIG. 2 and FIG. 3 are cross-sectional views schematically showing an organic light-emitting diode in a tandem structure having two light-emitting stacks and an organic light-emitting diode in a tandem structure having three light-emitting stacks, respectively, according to some implementations of the present disclosure.

As shown in FIG. 2, an organic light-emitting diode 100 according to the present disclosure include a first electrode 110 and a second electrode 120 facing each other, and an organic layer 230 positioned between the first electrode 110 and the second electrode 120. The organic layer 230 may be positioned between the first electrode 110 and the second electrode 120 and may include a first light-emitting stack ST1 including a first light-emitting layer 261, a second light-emitting stack ST2 positioned between the first light-emitting stack ST1 and the second electrode 120 and including a second light-emitting layer 262, and the charge generation layer CGL positioned between the first and second light-emitting stacks ST1 and ST2. The charge generation layer CGL may include an N-type charge generation layer 291 and a P-type charge generation layer 292. At least one of the first light-emitting layer 261 and the second light-emitting layer 262 may contain the organometallic compound represented by the Chemical Formula I according to the present disclosure as the dopants. For example, as shown in FIG. 2, the second light-emitting layer 262 of the second light-emitting stack ST2 may contain a host material 262′, and dopants 262″ made of the organometallic compound represented by the Chemical Formula I doped therein. Although not shown in FIG. 2, each of the first and second light-emitting stacks ST1 and ST2 may further include, in addition to each of the first light-emitting layer 261 and the second light-emitting layer 262, an additional light-emitting layer.

As shown in FIG. 3, the organic light-emitting diode 100 according to the present disclosure include the first electrode 110 and the second electrode 120 facing each other, and an organic layer 330 positioned between the first electrode 110 and the second electrode 120. The organic layer 330 may be positioned between the first electrode 110 and the second electrode 120 and may include the first light-emitting stack ST1 including the first light-emitting layer 261, the second light-emitting stack ST2 including the second light-emitting layer 262, a third light-emitting stack ST3 including a third light-emitting layer 263, a first charge generation layer CGL1 positioned between the first and second light-emitting stacks ST1 and ST2, and a second charge generation layer CGL2 positioned between the second and third light-emitting stacks ST2 and ST3. The first charge generation layer CGL1 may include a N-type charge generation layers 291 and a P-type charge generation layer 292. The second charge generation layer CGL2 may include a N-type charge generation layers 293 and a P-type charge generation layer 294. At least one of the first light-emitting layer 261, the second light-emitting layer 262, and the third light-emitting layer 263 may contain the organometallic compound represented by the Chemical Formula I according to the present disclosure as the dopants. For example, as shown in FIG. 3, the second light-emitting layer 262 of the second light-emitting stack ST2 may contain the host material 262′, and the dopants 262″ made of the organometallic compound represented by the Chemical Formula I doped therein. Although not shown in FIG. 3, each of the first, second and third light-emitting stacks ST1, ST2 and ST3 may further include an additional light-emitting layer, in addition to each of the first light-emitting layer 261, the second light-emitting layer 262 and the third light-emitting layer 263.

Furthermore, an organic light-emitting diode according to an embodiment of the present disclosure may include a tandem structure in which four or more light-emitting stacks and three or more charge generating layers are disposed between the first electrode and the second electrode.

The organic light-emitting diode according to the present disclosure may be used as a light-emitting element of each of an organic light-emitting display device and a lighting device. In one implementation, FIG. 4 is a cross-sectional view schematically illustrating an organic light-emitting display device including the organic light-emitting diode according to some embodiments of the present disclosure as a light-emitting element thereof.

As shown in FIG. 4, an organic light-emitting display device 3000 includes a substrate 3010, an organic light-emitting diode 4000, and an encapsulation film 3900 covering the organic light-emitting diode 4000. A driving thin-film transistor Td as a driving element, and the organic light-emitting diode 4000 connected to the driving thin-film transistor Td are positioned on the substrate 3010.

Although not shown explicitly in FIG. 4, a gate line and a data line that intersect each other to define a pixel area, a power line extending parallel to and spaced from one of the gate line and the data line, a switching thin film transistor connected to the gate line and the data line, and a storage capacitor connected to one electrode of the thin film transistor and the power line are further formed on the substrate 3010.

The driving thin-film transistor Td is connected to the switching thin film transistor, and includes a semiconductor layer 3100, a gate electrode 3300, a source electrode 3520, and a drain electrode 3540.

The semiconductor layer 3100 may be formed on the substrate 3010 and may be made of an oxide semiconductor material or polycrystalline silicon. When the semiconductor layer 3100 is made of an oxide semiconductor material, a light-shielding pattern (not shown) may be formed under the semiconductor layer 3100. The light-shielding pattern prevents light from being incident into the semiconductor layer 3100 to prevent the semiconductor layer 3100 from being deteriorated due to the light. Alternatively, the semiconductor layer 3100 may be made of polycrystalline silicon. In this case, both edges of the semiconductor layer 3100 may be doped with impurities.

The gate insulating layer 3200 made of an insulating material is formed over an entirety of a surface of the substrate 3010 and on the semiconductor layer 3100. The gate insulating layer 3200 may be made of an inorganic insulating material such as silicon oxide or silicon nitride.

The gate electrode 3300 made of a conductive material such as a metal is formed on the gate insulating layer 3200 and corresponds to a center of the semiconductor layer 3100. The gate electrode 3300 is connected to the switching thin film transistor.

The interlayer insulating layer 3400 made of an insulating material is formed over the entirety of the surface of the substrate 3010 and on the gate electrode 3300. The interlayer insulating layer 3400 may be made of an inorganic insulating material such as silicon oxide or silicon nitride, or an organic insulating material such as benzocyclobutene or photo-acryl.

The interlayer insulating layer 3400 has first and second semiconductor layer contact holes 3420 and 3440 defined therein respectively exposing both opposing sides of the semiconductor layer 3100. The first and second semiconductor layer contact holes 3420 and 3440 are respectively positioned on both opposing sides of the gate electrode 3300 and are spaced apart from the gate electrode 3300.

The source electrode 3520 and the drain electrode 3540 made of a conductive material such as metal are formed on the interlayer insulating layer 3400. The source electrode 3520 and the drain electrode 3540 are positioned around the gate electrode 3300, and are spaced apart from each other, and respectively contact both opposing sides of the semiconductor layer 3100 via the first and second semiconductor layer contact holes 3420 and 3440, respectively. The source electrode 3520 is connected to a power line (not shown).

The semiconductor layer 3100, the gate electrode 3300, the source electrode 3520, and the drain electrode 3540 constitute the driving thin-film transistor Td. The driving thin-film transistor Td has a coplanar structure in which the gate electrode 3300, the source electrode 3520, and the drain electrode 3540 are positioned on top of the semiconductor layer 3100.

Alternatively, the driving thin-film transistor Td may have an inverted staggered structure in which the gate electrode is disposed under the semiconductor layer while the source electrode and the drain electrode are disposed above the semiconductor layer. In this case, the semiconductor layer may be made of amorphous silicon. In one example, the switching thin-film transistor (not shown) may have substantially the same structure as that of the driving thin-film transistor (Td).

In one example, the organic light-emitting display device 3000 may include a color filter 3600 absorbing the light generated from the electroluminescent element (light-emitting diode) 4000. For example, the color filter 3600 may absorb red (R), green (G), blue (B), and white (W) light. In this case, red, green, and blue color filter patterns that absorb light may be formed separately in different pixel areas. Each of these color filter patterns may be disposed to overlap each organic layer 4300 of the organic light-emitting diode 4000 to emit light of a wavelength band corresponding to each color filter. Adopting the color filter 3600 may allow the organic light-emitting display device 3000 to realize full-color.

For example, when the organic light-emitting display device 3000 is of a bottom emission type, the color filter 3600 absorbing light may be positioned on a portion of the interlayer insulating layer 3400 corresponding to the organic light-emitting diode 4000. In an optional embodiment, when the organic light-emitting display device 3000 is of a top emission type, the color filter may be positioned on top of the organic light-emitting diode 4000, that is, on top of a second electrode 4200. For example, the color filter 3600 may be formed to have a thickness of 2 to 5 μm.

In one example, a protective layer 3700 having a drain contact hole 3720 defined therein exposing the drain electrode 3540 of the driving thin-film transistor Td is formed to cover the driving thin-film transistor Td.

On the protective layer 3700, each first electrode 4100 connected to the drain electrode 3540 of the driving thin-film transistor Td via the drain contact hole 3720 is formed individually in each pixel area.

The first electrode 4100 may act as a positive electrode (anode), and may be made of a conductive material having a relatively large work function value. For example, the first electrode 4100 may be made of a transparent conductive material such as ITO, IZO or ZnO.

In one example, when the organic light-emitting display device 3000 is of a top-emission type, a reflective electrode or a reflective layer may be further formed under the first electrode 4100. For example, the reflective electrode or the reflective layer may be made of one of aluminum (Al), silver (Ag), nickel (Ni), and an aluminum-palladium-copper (APC) alloy.

A bank layer 3800 covering an edge of the first electrode 4100 is formed on the protective layer 3700. The bank layer 3800 exposes a center of the first electrode 4100 corresponding to the pixel area.

An organic layer 4300 is formed on the first electrode 4100. Optionally, the organic light-emitting diode 4000 may have a tandem structure. Regarding the tandem structure, reference may be made to FIG. 2 to FIG. 4 which show some embodiments of the present disclosure, and the above descriptions thereof.

The second electrode 4200 is formed on the substrate 3010 on which the organic layer 4300 has been formed. The second electrode 4200 is disposed over the entirety of the surface of the display area and is made of a conductive material having a relatively small work function value and may be used as a negative electrode (a cathode). For example, the second electrode 4200 may be made of one of aluminum (Al), magnesium (Mg), and an aluminum-magnesium alloy (Al—Mg).

The first electrode 4100, the organic layer 4300, and the second electrode 4200 constitute the organic light-emitting diode 4000.

An encapsulation film 3900 is formed on the second electrode 4200 to prevent external moisture from penetrating into the organic light-emitting diode 4000. Although not shown explicitly in FIG. 4, the encapsulation film 3900 may have a triple-layer structure in which a first inorganic layer, an organic layer, and an inorganic layer are sequentially stacked. However, the present disclosure is not limited thereto.

Hereinafter, Preparation Example and Present Example of the present disclosure will be described. However, following Present Example is only one example of the present disclosure. The present disclosure is not limited thereto.

### Preparation Example—Preparation of Ligand

(1) Preparation of Ligand A

Step 1) Preparation of Ligand A-3

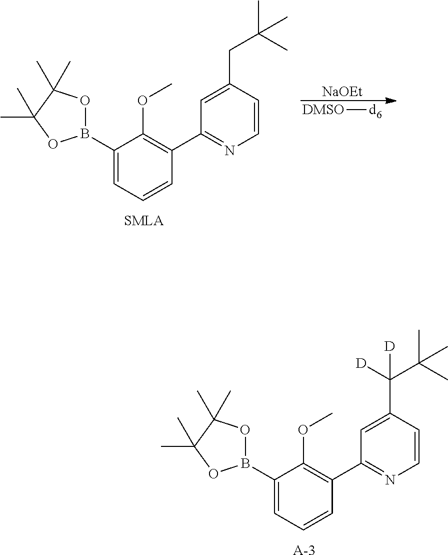

A solution in which SM_A (9.50 g, 25 mmol) and sodium ethoxide (3.39 g, 50 mmol) were dissolved in DMSO-d6 (100 ml) was refluxed for 60 h. The solution was subjected to evaporation and a residue was partitioned between dichloromethane and water. An organic phase was isolated therefrom, dried on sodium sulfate and was subjected to evaporation. After evaporation of the solvent, a residue was purified using column chromatography on silica gel using 40 to 50% hexane in dichloromethane to obtain 7.38 g (77%) of target Compound A-3.

Step 2) Preparation of Ligand A-2

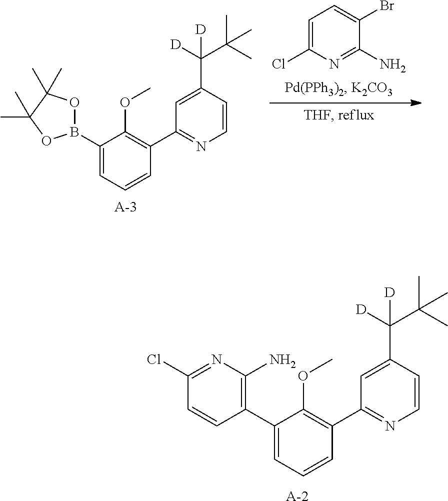

A-3 (7.30 g, 19 mmol), 3-bromo-6-chloropyridin-2-amine (3.94 g, 19 mmol), sodium carbonate (4.03 g, 38 mmol) and Pd(PPh₃)₄ (0.46 g, 0.4 mmol) were dissolved in tetrahydrofuran (100 ml) and a mixed solution was refluxed, and was stirred for 6 hours. A crude mixture was filtered through celite and silica gel, and a solid was dissolved in dichloromethane. While methanol was added thereto in a dropwise manner, the solid was precipitated to obtain 5.98 g (82%) of target Compound A-2.

Step 3) Preparation of Ligand A-1

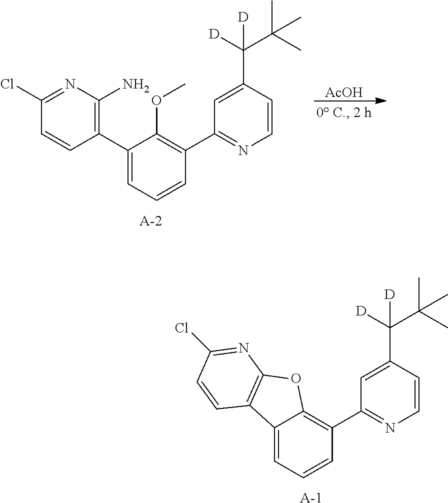

A-2 (5.95 g, 15.5 mmol) was added to acetic acid (100 ml) and tetrahydrofuran (50 ml) and a mixture was stirred at 0° C. for 2 hours, and then a reaction product was heated to room temperature. A residue was partitioned between ethyl acetate and water and an organic phase was isolated therefrom, washed with aqueous sodium bicarbonate and brine and dried under sodium sulfate. When the solvent was evaporated, the residue was subjected to column chromatography on silica gel with 30% dichloromethane in hexane to obtain 3.88 g (71%) of target Compound A-1.

Step 4) Preparation of Ligand A

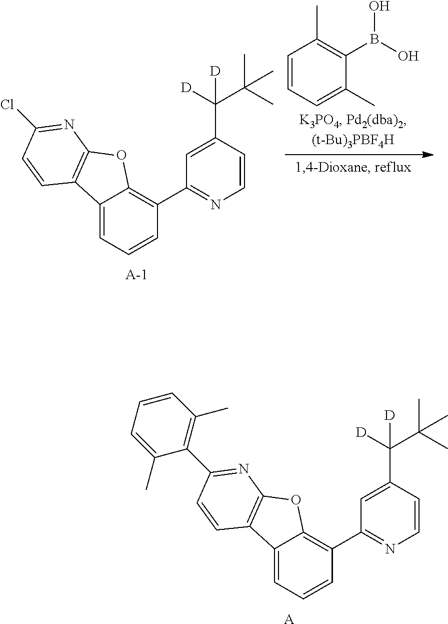

A mixed solution in which A-1 (3.88 g, 11 mmol), Pd₂(dba)₃ (0.20 g, 0.22 mmol), K₃PO₄ (4.67 g, 22 mmol) and (t-bu)₃PBF₄H were dissolved in 1,4-dioxane (100 ml) (0.13 g, 0.44 mmol) was refluxed overnight. The solution was subjected to evaporation and a residue was partitioned between dichloromethane and water. An organic phase was isolated therefrom, dried on sodium sulfate and was subjected to evaporation. Then, a crude mixture was subjected to column chromatography on silica gel with 30 to 40% dichloromethane in hexane to obtain 3.39 g (73%) of target Compound A.

(2) Preparation of Ligand B

Step 1) Preparation of Ligand B-3

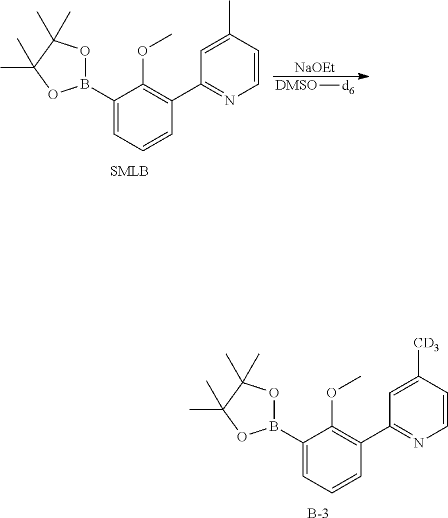

A solution in which SM_B (8.13 g, 25 mmol) and sodium ethoxide (3.39 g, 50 mmol) were dissolved in DMSO-d6 (100 ml) was refluxed for 60 h. The solution was subjected to evaporation and a residue was partitioned between dichloromethane and water. An organic phase was isolated therefrom, dried on sodium sulfate and was subjected to evaporation. After evaporation of the solvent, the residue was purified using column chromatography on silica gel using 40 to 50% hexane in dichloromethane to obtain 5.91 g (72%) of target Compound B-3.

Step 2) Preparation of Ligand B-2

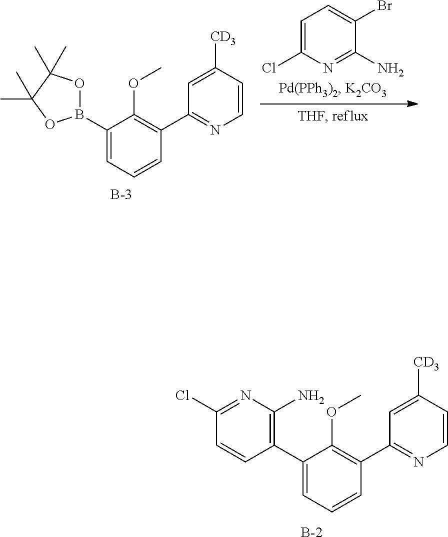

A mixed solution in which B-3 (5.91 g, 18 mmol), 3-bromo-6-chloropyridin-2-amine (3.73 g, 18 mmol), sodium carbonate (3.82 g, 36 mmol) and Pd(PPh₃)₄ (0.46 g, 0.4 mmol) were dissolved in tetrahydrofuran (100 ml) was refluxed, and was stirred for 6 hours. A crude mixture was filtered through celite and silica gel, and a solid was dissolved in dichloromethane. While methanol was added thereto in a dropwise manner, the solid was precipitated to obtain 4.91 g (83%) of target Compound B-2.

Step 3) Preparation of Ligand B-1

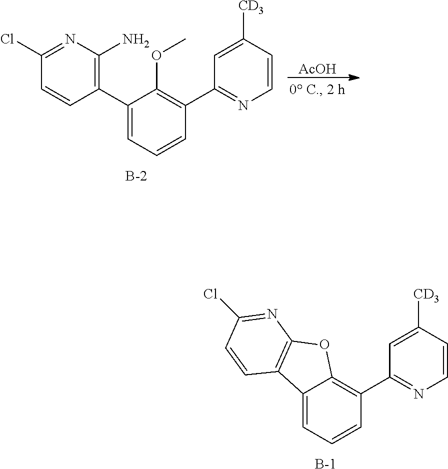

B-2 (4.91 g, 15 mmol) was added to acetic acid (100 ml) and tetrahydrofuran (40 ml) and a mixed solution was stirred at 0° C. for 2 hours, and then a reaction product was heated to room temperature. A residue was partitioned between ethyl acetate and water and an organic phase was isolated therefrom, washed with aqueous sodium bicarbonate and brine and dried on sodium sulfate. When the solvent was evaporated, the residue was subjected to column chromatography on silica gel with 30% dichloromethane in hexane to obtain 3.57 g (80%) of target Compound B-1.

Step 4) Preparation of Ligand B

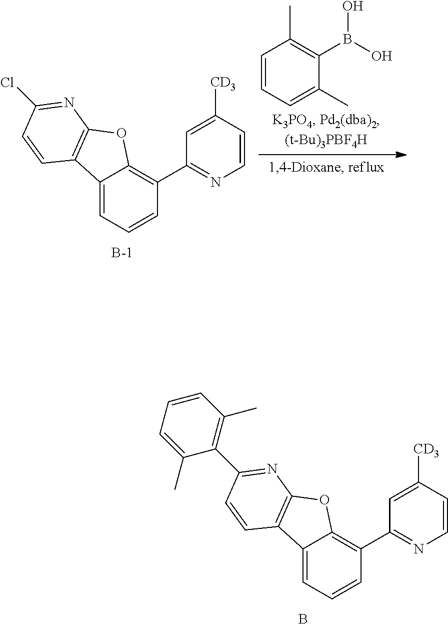

A mixed solution in which B-1 (3.57 g, 12 mmol), Pd₂(dba)₃ (0.22 g, 0.24 mmol), K₃PO₄ (5.09 g, 24 mmol) and (t-bu)₃PBF₄H (0.14 g, 0.48 mmol) were dissolved in 1,4-dioxane (120 ml) was refluxed overnight. The solution was subjected to evaporation and a residue was partitioned between dichloromethane and water. An organic phase was isolated therefrom, dried on sodium sulfate and was subjected to evaporation. Then, a crude mixture was subjected to column chromatography on silica gel with 30 to 40% dichloromethane in hexane to obtain 3.31 g (75%) of target Compound B.

(3) Preparation of Ligand C

Step 1) Preparation of Ligand C-3

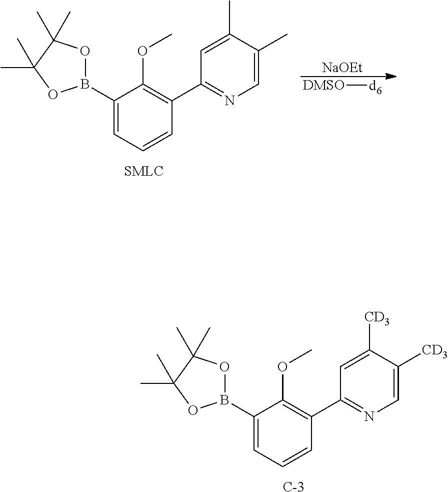

A solution in which SM_C (8.48 g, 25 mmol) and sodium ethoxide (3.39 g, 50 mmol) were dissolved in DMSO-d6 (100 ml) was refluxed for 60 h. The solution was subjected to evaporation and a residue was partitioned between dichloromethane and water. An organic phase was isolated therefrom, dried on sodium sulfate and was subjected to evaporation. After evaporation of the solvent, a residue was purified using column chromatography on silica gel using 40 to 50% hexane in dichloromethane to obtain 6.39 g (74%) of target Compound C-3.

Step 2) Preparation of Ligand C-2

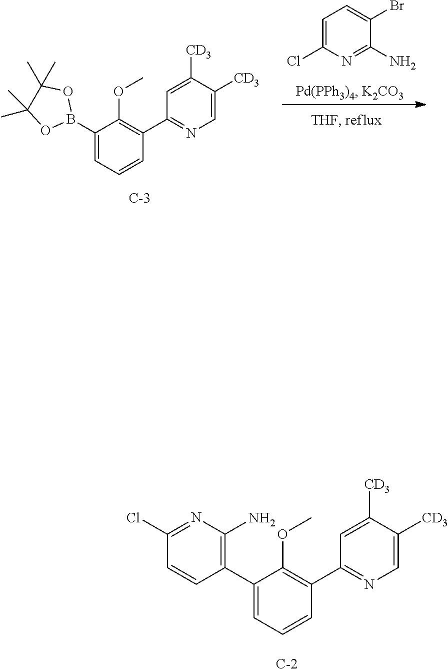

A mixed solution in which C-3 (6.39 g, 18.5 mmol), 3-bromo-6-chloropyridin-2-amine (3.83 g, 18.5 mmol), sodium carbonate (3.32 g, 37 mmol) and Pd(PPh₃)₄ (0.46 g, 0.4 mmol) were dissolved in tetrahydrofuran (100 ml) was refluxed, and was stirred for 6 hours. A crude mixture was filtered through celite and silica gel, and a solid was dissolved in dichloromethane. While methanol was added thereto in a dropwise manner, the solid was precipitated to obtain 5.05 g (79%) of target Compound C-2.

Step 3) Preparation of Ligand C-1

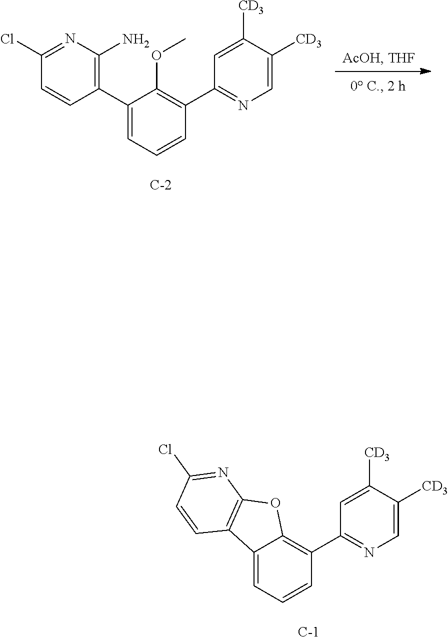

C-2 (5.05 g, 14.6 mmol) was added to acetic acid (100 ml) and tetrahydrofuran (40 ml) and a mixture was stirred at 0° C. for 2 hours, and then a reaction product was heated to room temperature. A residue was partitioned between ethyl acetate and water and an organic phase was isolated therefrom, washed with aqueous sodium bicarbonate and brine and dried on sodium sulfate. Upon evaporation of the solvent, a residue was subjected to column chromatography on silica gel with 30% dichloromethane in hexane to obtain 3.81 g (83%) of target Compound C-1.

Step 4) Preparation of Ligand C

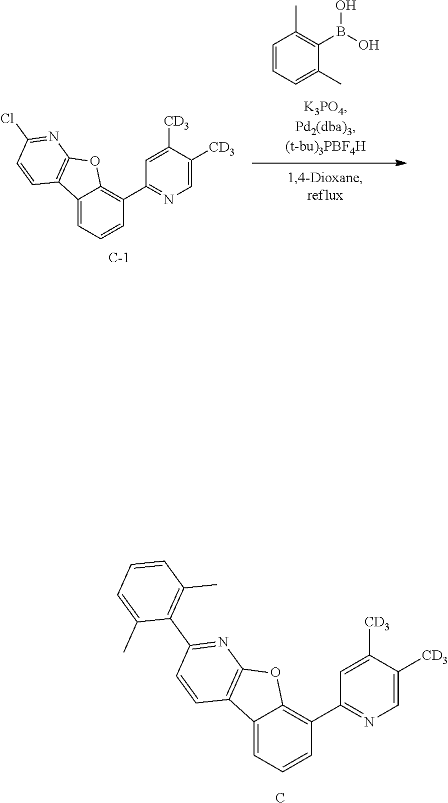

A mixed solution in which C-1 (3.81 g, 12.1 mmol), Pd₂(dba)₃ (0.22 g, 0.24 mmol), K₃PO₄ (5.09 g, 24 mmol) and (t-bu)₃PBF₄H were dissolved in 1,4-dioxane (120 ml) (0.14 g, 0.48 mmol) was refluxed overnight. The solution was subjected to evaporation and a residue was partitioned between dichloromethane and water. An organic phase was isolated therefrom, dried on sodium sulfate and was subjected to evaporation. Then, a crude mixture was subjected to column chromatography on silica gel with 30 to 40% dichloromethane in hexane to obtain 3.16 g (68%) of target Compound C

(4) Preparation of Ligand D

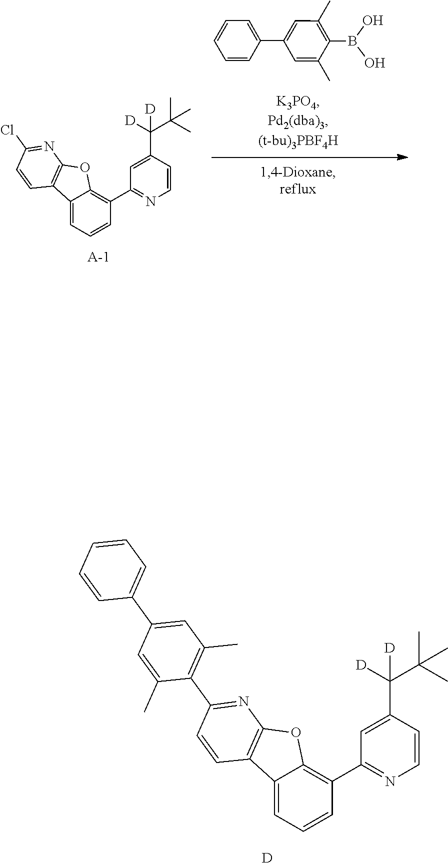

A mixed solution in which A-1 (5.79 g, 16.4 mmol), Pd₂(dba)₃ (0.30 g, 0.33 mmol), K₃PO₄ (7.01 g, 33 mmol) and (t-bu)₃PBF₄H (0.20 g, 0.67 mmol) were dissolved in 1,4-dioxane (100 ml) was refluxed overnight. The solution was subjected to evaporation and a residue was partitioned between dichloromethane and water. An organic phase was isolated therefrom, dried on sodium sulfate and was subjected to evaporation. Then, a crude mixture was subjected to column chromatography on silica gel with 20 to 30% dichloromethane in hexane to obtain 5.40 g (66%) of target Compound D.

(5) Preparation of Ligand E

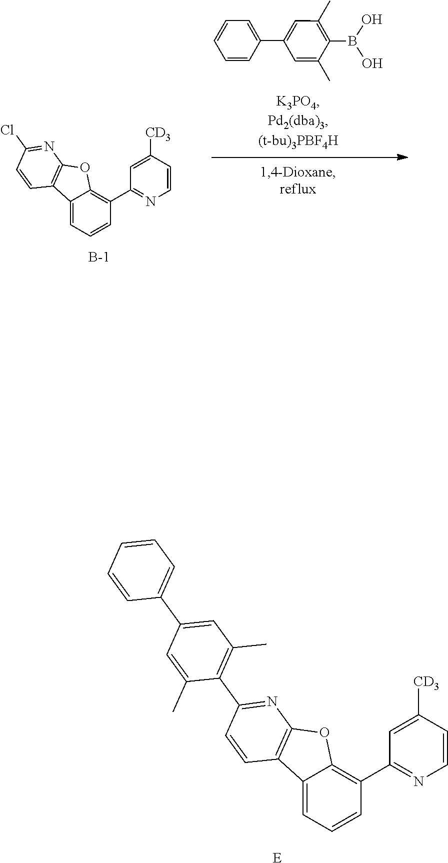

A mixed solution in which B-1 (5.48 g, 18.4 mmol), Pd₂(dba)₃ (0.34 g, 0.37 mmol), K₃PO₄ (7.85 g, 37 mmol) and (t-bu)₃PBF₄H (0.22 g, 0.75 mmol) were dissolved in 1,4-dioxane (150 ml) was refluxed overnight. The solution was subjected to evaporation and a residue was partitioned between dichloromethane and water. An organic phase was isolated therefrom, dried on sodium sulfate and was subjected to evaporation. Then, a crude mixture was subjected to column chromatography on silica gel with 25 to 30% dichloromethane in hexane to obtain 6.28 g (77%) of target Compound E.

(6) Preparation of Ligand F

Step 1) Preparation of Ligand F-3

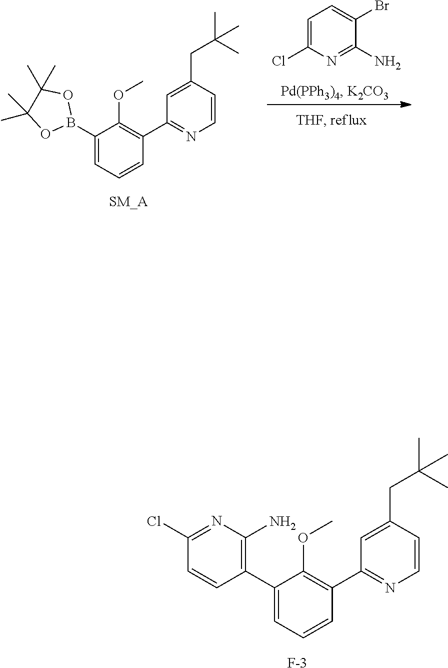

SM_A (11.44 g, 30 mmol), 3-bromo-6-chloropyridin-2-amine (6.22 g, 30 mmol), sodium carbonate (6.36 g, 60 mmol) and Pd(PPh₃)₄ (0.69 g, 0.6 mmol) were dissolved in tetrahydrofuran (150 ml), and a mixed solution was refluxed, and was stirred for 6 hours. A crude mixture was filtered through celite and silica gel, and a solid was dissolved in dichloromethane. While methanol was added thereto in a dropwise manner, the solid was precipitated to obtain 9.74 g (85%) of target Compound F-3.

Step 2) Preparation of Ligand F-2

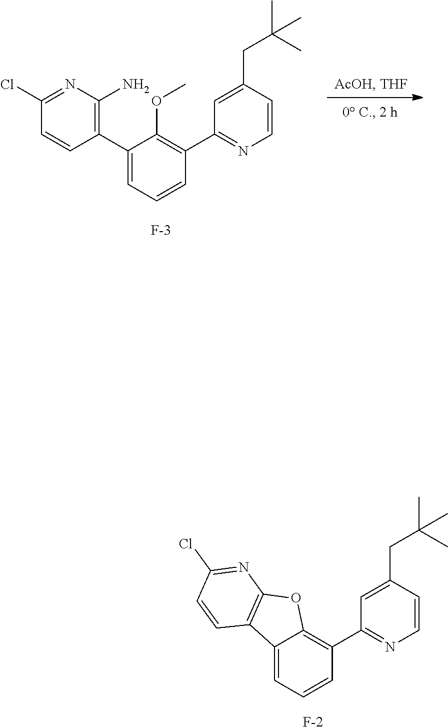

F-3 (9.74 g, 25.5 mmol) was added to acetic acid (120 ml) and tetrahydrofuran (60 ml) and a mixed solution was stirred at 0° C. for 2 hours, and a reaction product was heated to room temperature. A residue was partitioned between ethyl acetate and water and an organic phase was isolated therefrom, washed with aqueous sodium bicarbonate and brine and dried on sodium sulfate. Upon evaporation of the solvent, a residue was subjected to column chromatography on silica gel with 30% dichloromethane in hexane to obtain 6.26 g (70%) of target Compound F-2.

Step 3) Preparation of Ligand F-1

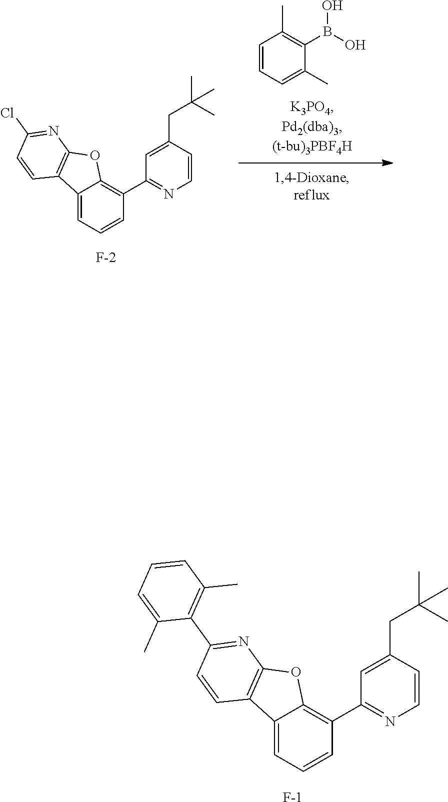

A mixed solution in which A-1 (6.26 g, 17.8 mmol), Pd₂(dba)₃ (0.33 g, 0.36 mmol), K₃PO₄ (7.64 g, 36 mmol) and (t-bu)₃PBF₄H (0.21 g, 0.72 mmol) were dissolved in 1,4-dioxane (120 ml) was refluxed overnight. The solution was subjected to evaporation and a residue was partitioned between dichloromethane and water. An organic phase was isolated therefrom, dried on sodium sulfate and was subjected to evaporation. Then, a crude mixture was subjected to column chromatography on silica gel with 30 to 40% dichloromethane in hexane to obtain 5.17 g (69%) of target Compound F-1.

Step 4) Preparation of Ligand F

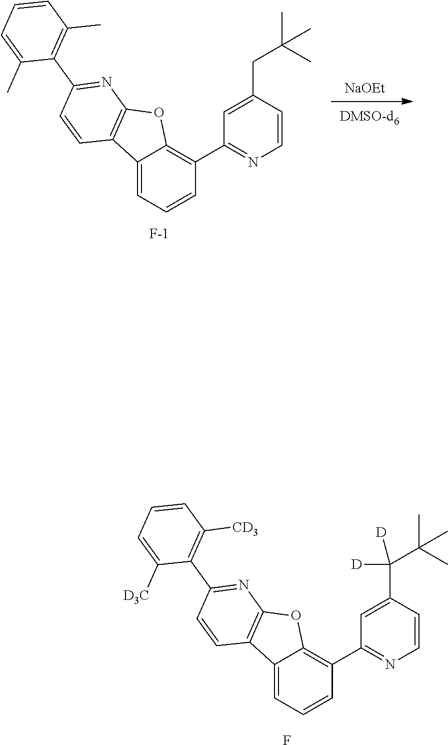

A solution in which F-1 (5.05 g, 12 mmol) and sodium ethoxide (4.07 g, 60 mmol) were dissolved in DMSO-d6 (120 ml) was refluxed for 60 h. The solution was subjected to evaporation and a residue was partitioned between dichloromethane and water. An organic phase was isolated therefrom, dried on sodium sulfate and was subjected to evaporation. After evaporation of the solvent, a residue was purified using column chromatography on silica gel using 40 to 50% hexane in dichloromethane to obtain 3.65 g (71%) of target Compound F.

(7) Preparation of Ligand G

Step 1) Preparation of Ligand G-3

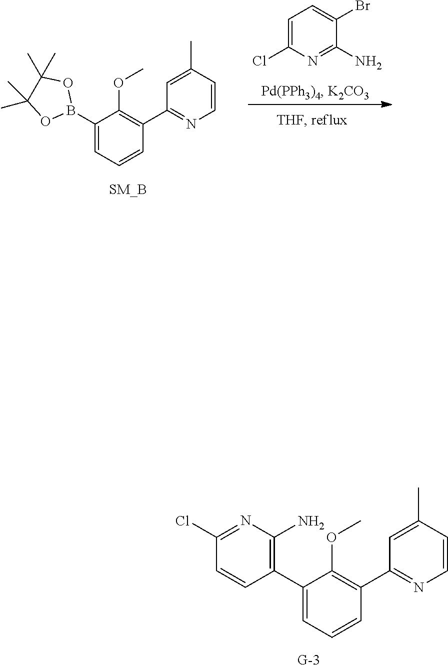

A mixed solution in which SM_B (9.76 g, 30 mmol), 3-bromo-6-chloropyridin-2-amine (6.22 g, 30 mmol), sodium carbonate (6.36 g, 60 mmol) and Pd(PPh₃)₄ (0.69 g, 0.6 mmol) were dissolved in tetrahydrofuran (150 ml) was refluxed, and was stirred for 6 hours. A crude mixture was filtered through celite and silica gel, and a solid was dissolved in dichloromethane. While methanol was added thereto in a dropwise manner, the solid was precipitated to obtain 7.82 g (80%) of target Compound F-3.

Step 2) Preparation of Ligand G-2

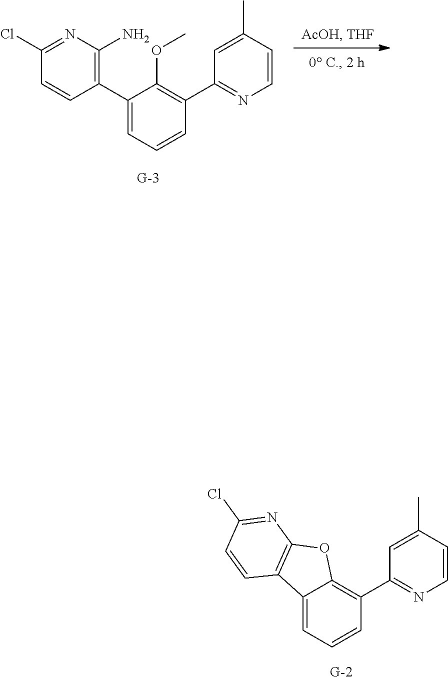

G-3 (7.82 g, 24 mmol) was added to acetic acid (120 ml) and tetrahydrofuran (60 ml) and a mixed solution was stirred at 0° C. for 2 hours, and then a reaction mixture was heated to room temperature. A residue was partitioned between ethyl acetate and water and an organic phase was isolated therefrom, washed with aqueous sodium bicarbonate and brine and dried on sodium sulfate. Upon evaporation of the solvent, the residue was subjected to column chromatography on silica gel with 30% dichloromethane in hexane to obtain 5.23 g (74%) of target Compound G-2.

Step 3) Preparation of Ligand G-1

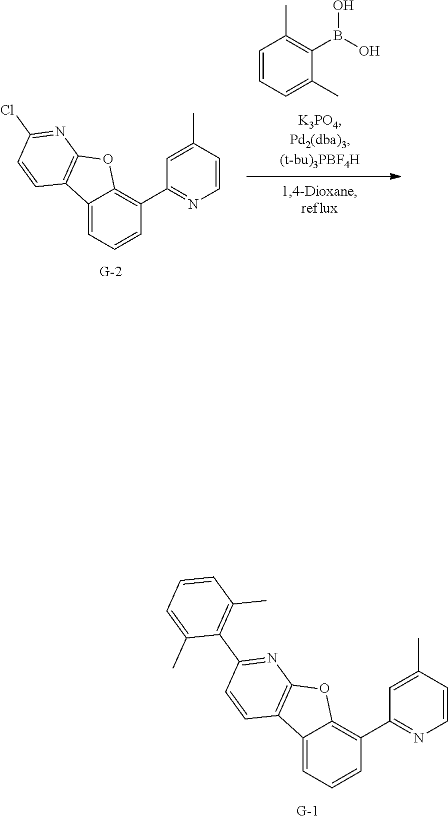

A mixed solution in which A-1 (5.01 g, 17 mmol), Pd₂(dba)₃ (0.31 g, 0.34 mmol), K₃PO₄ (7.22 g, 34 mmol) and (t-bu)₃PBF₄H (0.20 g, 0.69 mmol) were dissolved in 1,4-dioxane (120 ml) was refluxed overnight. The solution was subjected to evaporation and a residue was partitioned between dichloromethane and water. An organic phase was isolated therefrom, dried on sodium sulfate and was subjected to evaporation. Then, a crude mixture was subjected to column chromatography on silica gel with 30 to 40% dichloromethane in hexane to obtain 4.46 g (72%) of target Compound G-1.

Step 4) Preparation of Ligand G

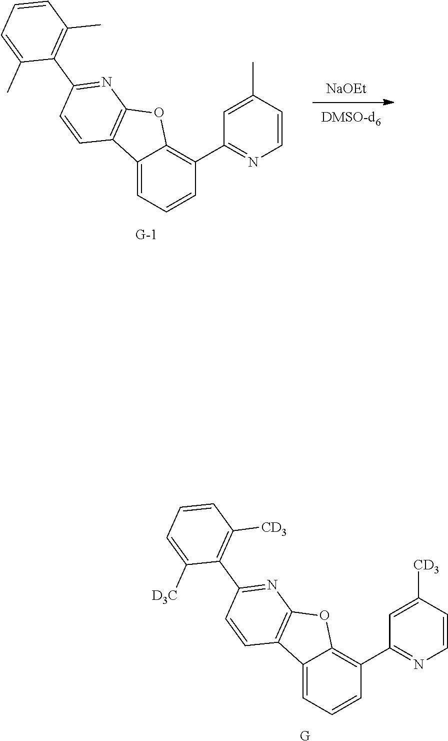

A solution in which G-1 (4.37 g, 12 mmol) and sodium ethoxide (4.07 g, 60 mmol) were dissolved in DMSO-d6 (120 ml) was refluxed for 60 h. The solution was subjected to evaporation and a residue was partitioned between dichloromethane and water. An organic phase was isolated therefrom, dried on sodium sulfate and was subjected to evaporation. After evaporation of the solvent, a residue was purified using column chromatography on silica gel using 40 to 50% hexane in dichloromethane to obtain 3.27 g (73%) of target Compound G.

(8) Preparation of Ligand H′

Step 1) Preparation of Ligand HH

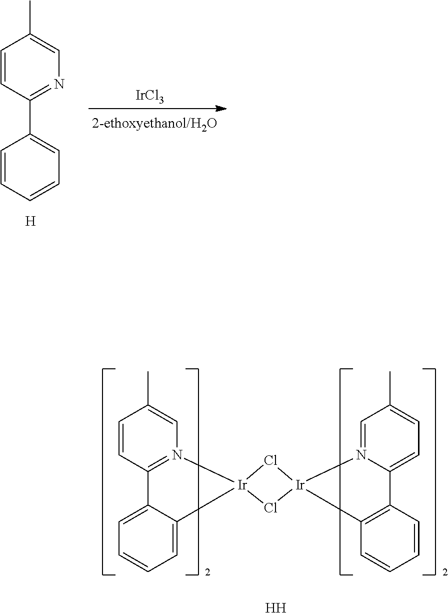

A solution in which H (6.77 g, 40 mmol) and IrCl₃ (4.78 g, 16 mmol) were dissolved in ethoxyethanol (100 ml) and distilled water (30 ml) was refluxed and stirred for 24 h. Thereafter, a temperature is lowered to room temperature and a resulting solid is separated therefrom via filtration under reduced pressure. After the solid was filtered through a filter and was sufficiently washed with water and cold methanol, and filtration under reduced pressure was repeated several times thereon to obtain 8.39 g (93%) of target Compound HH.

Step 2) Preparation of Ligand H′

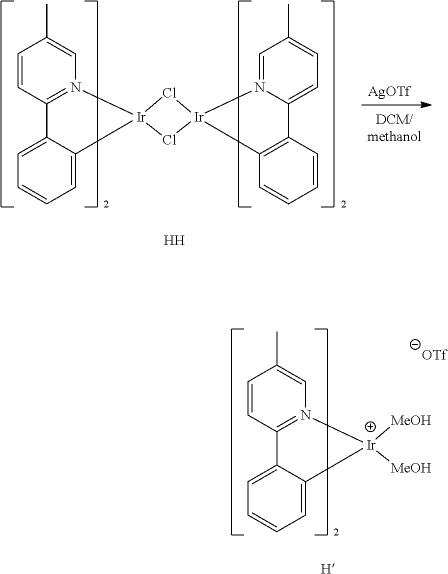

A solution in which HH (6.77 g, 6 mmol) and silver trifluoromethanesulfonate (4.54 g, 18 mmol) were dissolved in dichloromethane (100 ml) and methanol (100 ml) was stirred at room temperature overnight. After completion of a reaction, a solid precipitate is removed therefrom via filtration through celite. Filtrate obtained through the filter was subjected to repeated filtrations under reduced pressure to obtain 8.46 g (95%) of target Compound H′.

(9) Preparation of Ligand I′

Step 1) Preparation of Ligand II

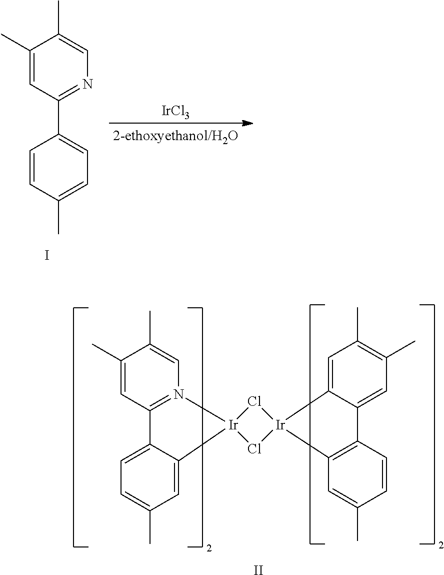

A solution in which I (7.89 g, 40 mmol) and IrCl₃ (4.78 g, 16 mmol) were dissolved in ethoxyethanol (100 ml) and distilled water (30 ml) was refluxed and stirred for 24 h. Thereafter, a temperature is lowered to room temperature and a resulting solid is separated therefrom via filtration under reduced pressure. The solid was filtered through a filter and was thoroughly washed with water and cold methanol, and then filtration under reduced pressure was repeated several times thereon to obtain 8.93 g (90%) of target Compound II.

Step 2) Preparation of Ligand I′

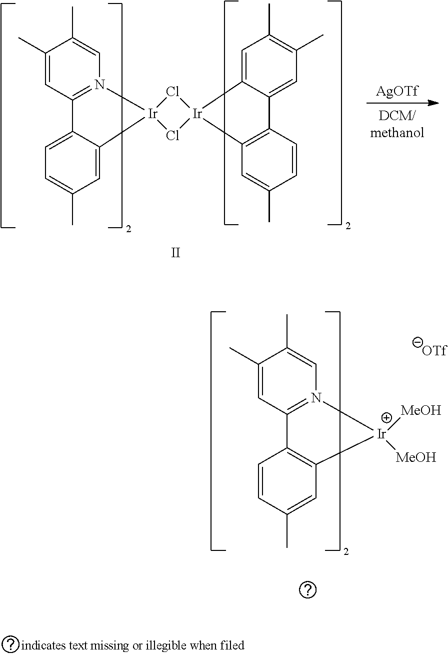

A solution in which II (7.44 g, 6 mmol) and silver trifluoromethanesulfonate (4.54 g, 18 mmol) were dissolved in dichloromethane (100 ml) and methanol (100 ml) was stirred at room temperature overnight. After completion of a reaction, a solid precipitate is removed therefrom via filtration through celite. The filtrate obtained through the filter was subjected to filtration under reduced pressure repeatedly several times to obtain 8.81 g (92%) of target Compound I′.

(10) Preparation of Ligand J′

Step 1) Preparation of Ligand JJ

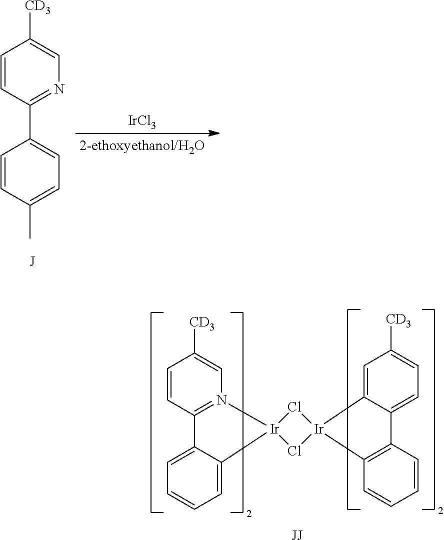

A solution in which J (6.89 g, 40 mmol) and IrCl₃ (4.78 g, 16 mmol) were dissolved in ethoxyethanol (100 ml) and distilled water (30 ml) was refluxed and stirred for 24 h. Thereafter, a temperature is lowered to room temperature and a resulting solid is separated therefrom via filtration under reduced pressure. The solid was filtered through a filter and was thoroughly washed with water and cold methanol, and then a process of filtration under reduced pressure was repeated several times thereon to obtain 8.48 g (93%) of target Compound JJ.

Step 2) Preparation of Ligand J′

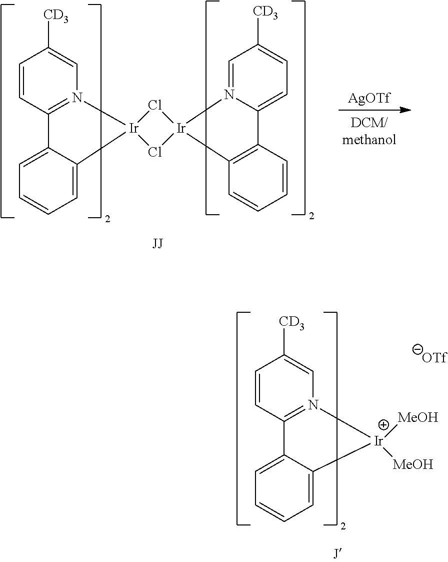

A solution in which JJ (6.84 g, 6 mmol) and silver trifluoromethanesulfonate (4.54 g, 18 mmol) were dissolved in dichloromethane (100 ml) and methanol (100 ml) was stirred at room temperature overnight. After completion of a reaction, the solid precipitate is removed therefrom via filtration through celite. The filtrate obtained through the filter was subjected to filtration under reduced pressure repeatedly several times to obtain 8.53 g (95%) of target Compound J′.

(11) Preparation of Ligand K′

Step 1) Preparation of Ligand KK

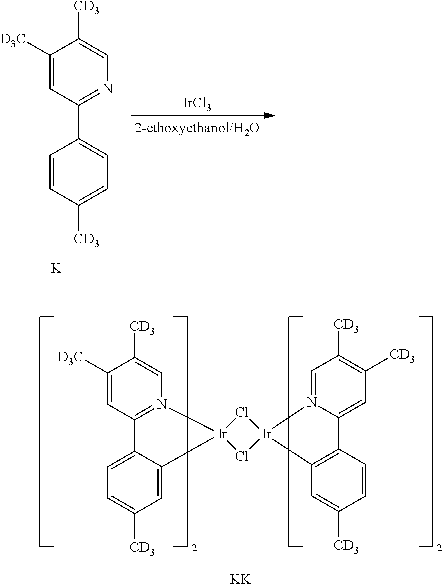

A solution in which K (8.25 g, 40 mmol) and IrCl₃ (4.78 g, 16 mmol) were dissolved in ethoxyethanol (100 ml) and distilled water (30 ml) was refluxed and stirred for 24 h. Thereafter, a temperature is lowered to room temperature and a resulting solid is separated therefrom via filtration under reduced pressure. The solid was filtered through a filter and was thoroughly washed with water and cold methanol, and then a process of filtration under reduced pressure was repeated several times thereon to obtain 9.29 g (91%) of target Compound KK.

Step 2) Preparation of Ligand K′

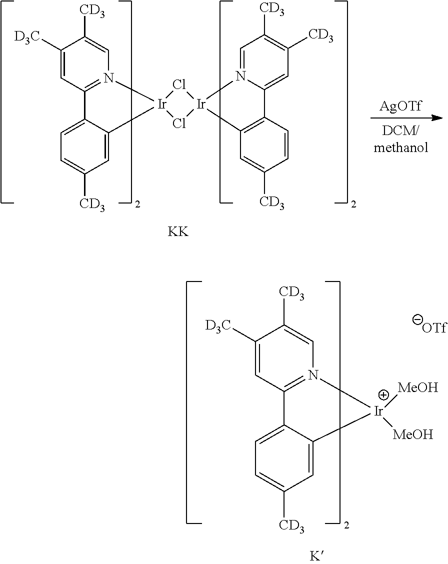

A solution in which KK (7.66 g, 6 mmol) and silver trifluoromethanesulfonate (4.54 g, 18 mmol) were dissolved in dichloromethane (100 ml) and methanol (100 ml) was stirred at room temperature overnight. After completion of a reaction, a solid precipitate is removed therefrom via filtration through celite. The filtrate obtained through the filter was subjected to filtration under reduced pressure repeatedly several times to obtain 9.20 g (94%) of target Compound K′.

### Preparation Example—Preparation of Iridium Compound

<Preparation of Iridium Compound 13>

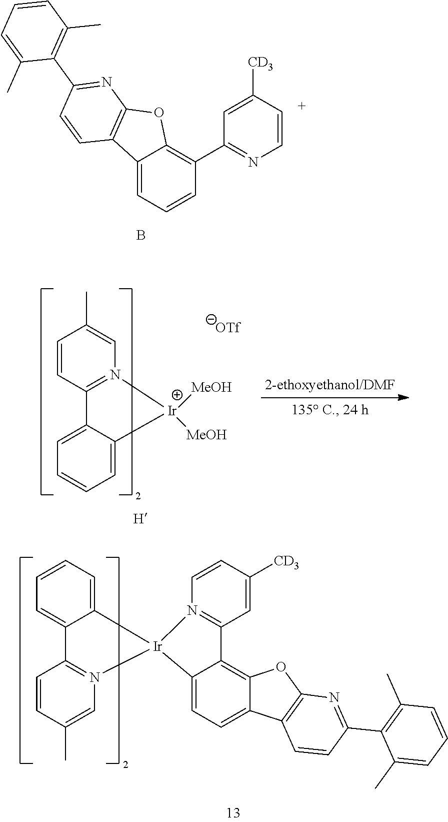

A solution in which B (1.84 g, 5 mmol) and H′ (4.45 g, 6 mmol) were dissolved in 2-ethoxyethanol (100 ml) and DMF (100 ml) was stirred at 135° C. for 24 hours. After completion of a reaction, a temperature was lowered to room temperature, an organic phase was isolated therefrom using dichloromethane and distilled water, and moisture was removed therefrom via adding anhydrous magnesium sulfate thereto. A solution obtained through filtration was depressurized to obtain a residue. Then, the residue was purified using column chromatography on silica gel using 25% ethyl acetate in hexane to obtain 3.89 g (87%) of target iridium compound 13.

<Preparation of Iridium Compound 14>

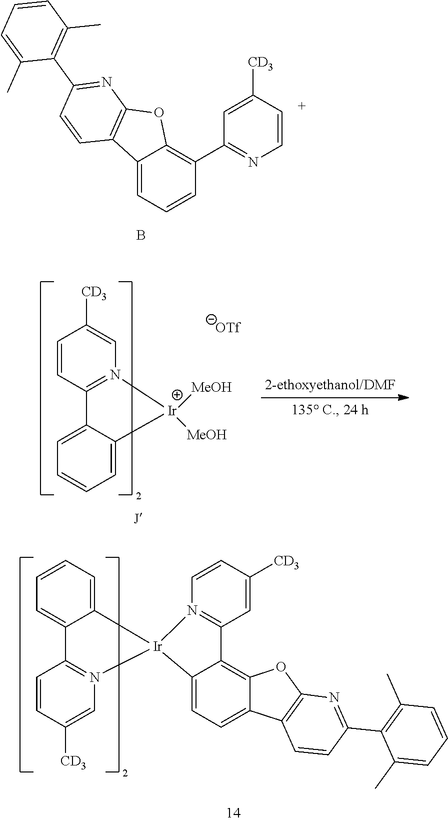

A solution in which B (1.84 g, 5 mmol) and J′ (4.49 g, 6 mmol) were dissolved in 2-ethoxyethanol (100 ml) and DMF (100 ml) was stirred at 135° C. for 24 hours. After completion of a reaction, a temperature was lowered to room temperature, an organic phase was isolated therefrom using dichloromethane and distilled water, and moisture was removed therefrom via adding anhydrous magnesium sulfate thereto. A solution obtained through filtration was depressurized to obtain a residue. Then, the residue was purified using column chromatography on silica gel using 25% ethyl acetate in hexane to obtain 3.69 g (82%) of target iridium compound 14.

<Preparation of Iridium Compound 15>

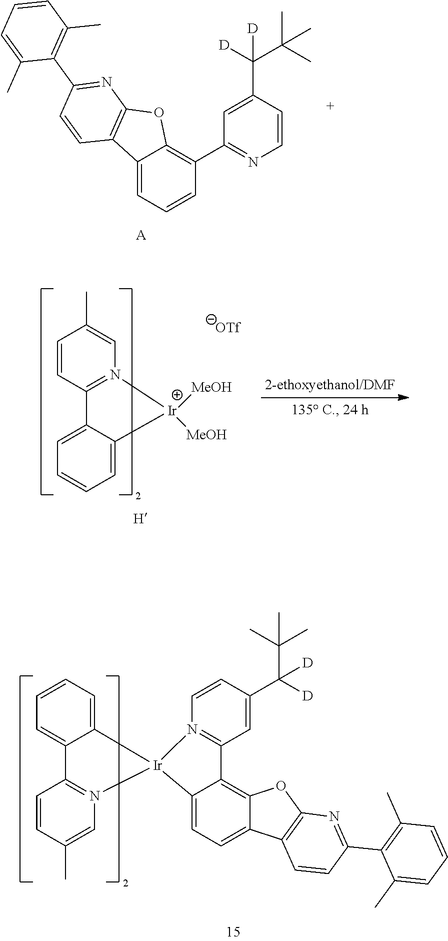

A solution in which A (2.11 g, 5 mmol) and H′ (4.45 g, 6 mmol) were dissolved in 2-ethoxyethanol (100 ml) and DMF (100 ml) was stirred at 135° C. for 24 hours. After completion of a reaction, a temperature was lowered to room temperature, an organic phase was isolated therefrom using dichloromethane and distilled water, and moisture was removed therefrom via adding anhydrous magnesium sulfate thereto. A solution obtained through filtration was depressurized to obtain a residue. Then, the residue was purified using column chromatography on silica gel using 25% ethyl acetate in hexane to obtain 3.99 g (84%) of target iridium compound 15.

<Preparation of Iridium Compound 16>

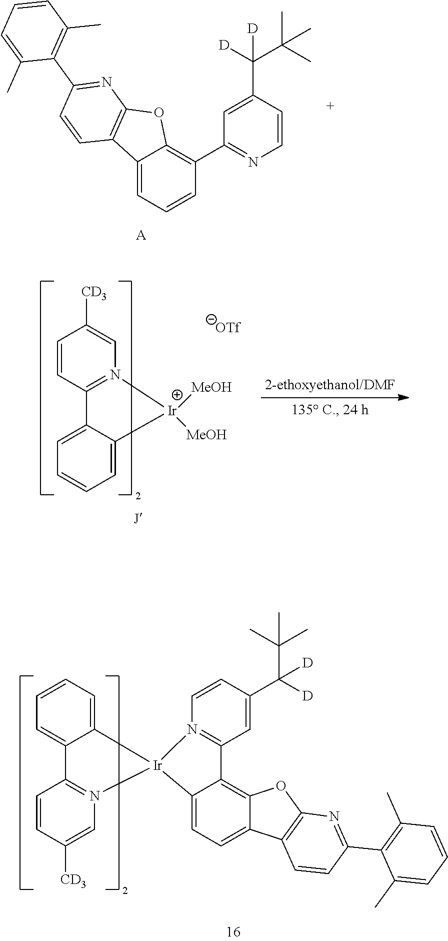

A solution in which A (2.11 g, 5 mmol) and J′ (4.49 g, 6 mmol) were dissolved in 2-ethoxyethanol (100 ml) and DMF (100 ml) was stirred at 135° C. for 24 hours. After completion of a reaction, a temperature was lowered to room temperature, an organic phase was isolated therefrom using dichloromethane and distilled water, and moisture was removed therefrom via adding anhydrous magnesium sulfate thereto. A solution obtained through filtration was depressurized to obtain a residue. Then, the residue was purified using column chromatography on silica gel using 25% ethyl acetate in hexane to obtain 4.06 g (85%) of target iridium compound 16.

<Preparation of Iridium Compound 17>

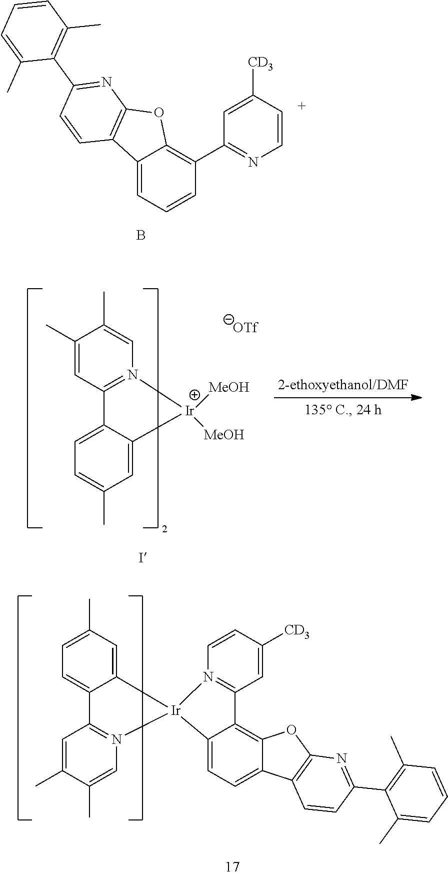

A solution in which B (1.84 g, 5 mmol) and I′ (4.79 g, 6 mmol) were dissolved in 2-ethoxyethanol (100 ml) and DMF (100 ml) was stirred at 135° C. for 24 hours. After completion of a reaction, a temperature was lowered to room temperature, an organic phase was isolated therefrom using dichloromethane and distilled water, and moisture was removed therefrom via adding anhydrous magnesium sulfate thereto. A solution obtained through filtration was depressurized to obtain a residue. Then, the residue was purified using column chromatography on silica gel using 25% ethyl acetate in hexane to obtain 4.00 g (84%) of target iridium compound 17.

<Preparation of Iridium Compound 18>

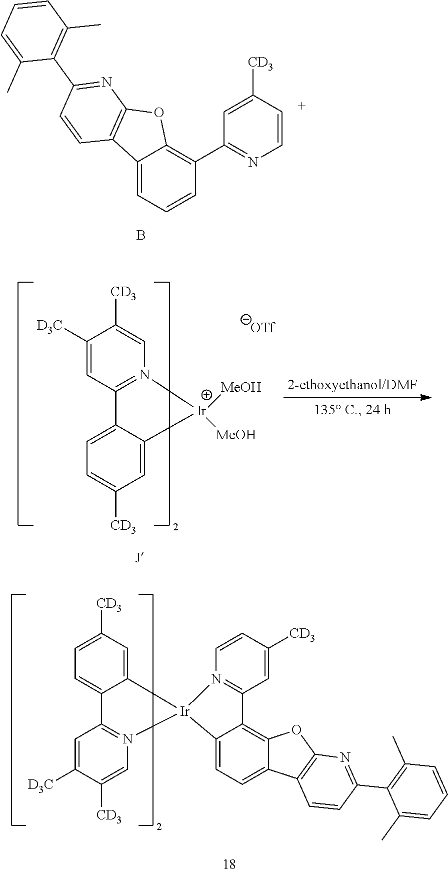

A solution in which B (1.84 g, 5 mmol) and K′ (4.90 g, 6 mmol) were dissolved in 2-ethoxyethanol (100 ml) and DMF (100 ml) was stirred at 135° C. for 24 hours. After completion of a reaction, a temperature was lowered to room temperature, an organic phase was isolated therefrom using dichloromethane and distilled water, and moisture was removed therefrom via adding anhydrous magnesium sulfate thereto. A solution obtained through filtration was depressurized to obtain a residue. Then, the residue was purified using column chromatography on silica gel using 25% ethyl acetate in hexane to obtain 3.93 g (81%) of target iridium compound 18.

<Preparation of Iridium Compound 19>

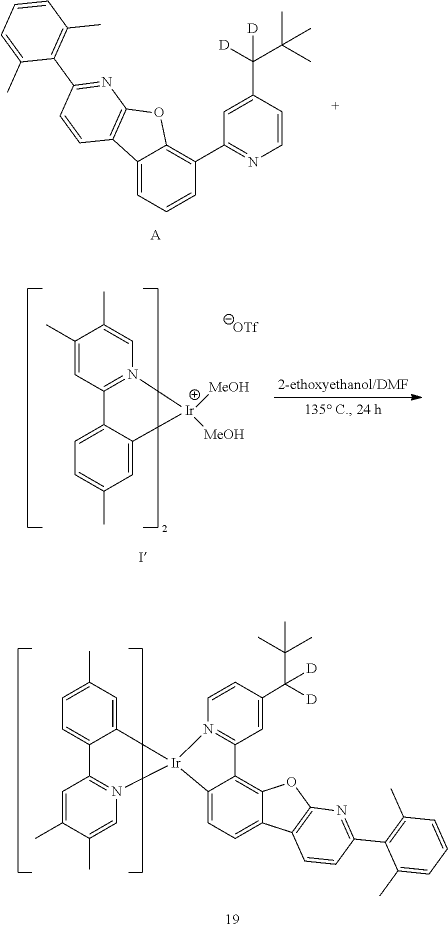

A solution in which A (2.11 g, 5 mmol) and I′ (4.79 g, 6 mmol) were dissolved in 2-ethoxyethanol (100 ml) and DMF (100 ml) was stirred at 135° C. for 24 hours. After completion of a reaction, a temperature was lowered to room temperature, an organic phase was isolated therefrom using dichloromethane and distilled water, and moisture was removed therefrom via adding anhydrous magnesium sulfate thereto. A solution obtained through filtration was depressurized to obtain a residue. Then, the residue was purified using column chromatography on silica gel using 25% ethyl acetate in hexane to obtain 4.03 g (80%) of target iridium compound 19.

<Preparation of Iridium Compound 20>

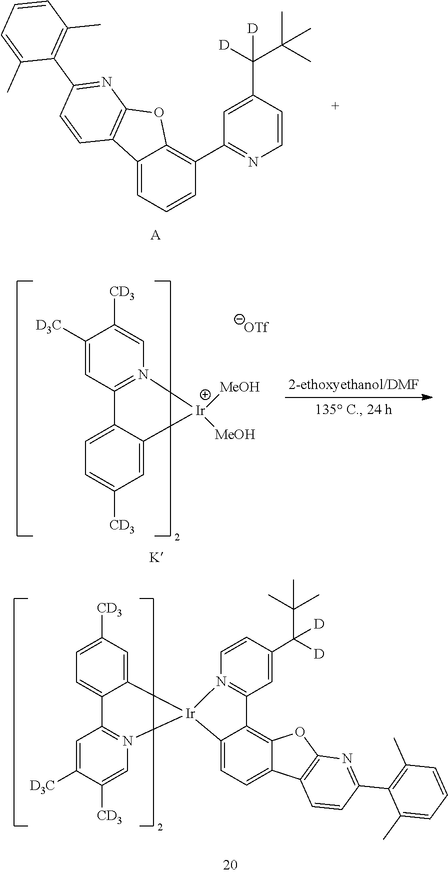

A solution in which A (2.11 g, 5 mmol) and K′ (4.90 g, 6 mmol) were dissolved in 2-ethoxyethanol (100 ml) and DMF (100 ml) was stirred at 135° C. for 24 hours. After completion of a reaction, a temperature was lowered to room temperature, an organic phase was isolated therefrom using dichloromethane and distilled water, and moisture was removed therefrom via adding anhydrous magnesium sulfate thereto. A solution obtained through filtration was depressurized to obtain a residue. Then, the residue was purified using column chromatography on silica gel using 25% ethyl acetate in hexane to obtain 4.20 g (82%) of target iridium compound 20.

<Preparation of Iridium Compound 21>

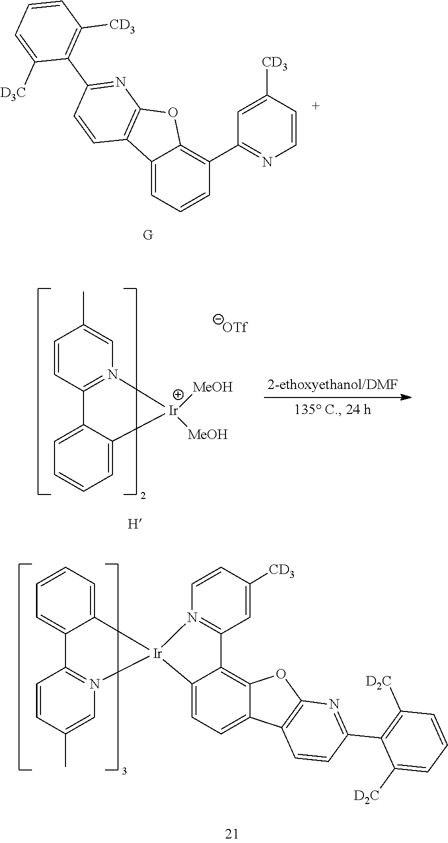

A solution in which G (1.87 g, 5 mmol) and H′ (4.45 g 6 mmol) were dissolved in 2-ethoxyethanol (100 ml) and DMF (100 ml) was stirred at 135° C. for 24 hours. After completion of a reaction, a temperature was lowered to room temperature, an organic phase was isolated therefrom using dichloromethane and distilled water, and moisture was removed therefrom via adding anhydrous magnesium sulfate thereto. A solution obtained through filtration was depressurized to obtain a residue. Then, the residue was purified using column chromatography on silica gel using 25% ethyl acetate in hexane to obtain 3.69 g (82%) of target iridium compound 21.

<Preparation of Iridium Compound 22>

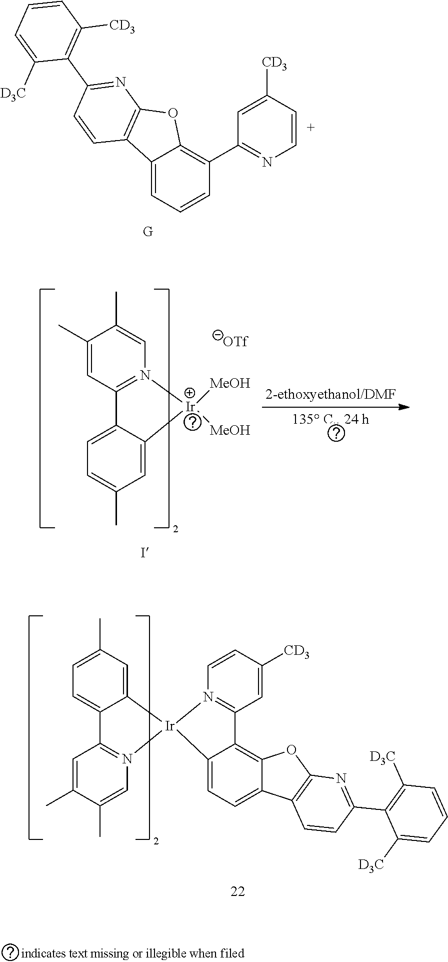

A solution in which G (1.87 g, 5 mmol) and I′ (4.79 g, 6 mmol) were dissolved in 2-ethoxyethanol (100 ml) and DMF (100 ml) was stirred at 135° C. for 24 hours. After completion of a reaction, a temperature was lowered to room temperature, an organic phase was isolated therefrom using dichloromethane and distilled water, and moisture was removed therefrom via adding anhydrous magnesium sulfate thereto. A solution obtained through filtration was depressurized to obtain a residue. Then, the residue was purified using column chromatography on silica gel using 25% ethyl acetate in hexane to obtain 3.97 g (83%) of target iridium compound 22.

<Preparation of Iridium Compound 23>

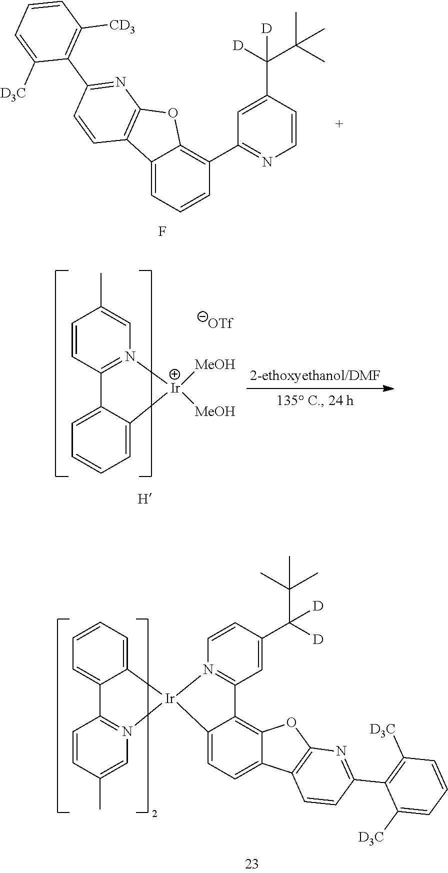

A solution in which F (2.14 g, 5 mmol) and H′ (4.45 g, 6 mmol) were dissolved in 2-ethoxyethanol (100 ml) and DMF (100 ml) was stirred at 135° C. for 24 hours. After completion of a reaction, a temperature was lowered to room temperature, an organic phase was isolated therefrom using dichloromethane and distilled water, and moisture was removed therefrom via adding anhydrous magnesium sulfate thereto. A solution obtained through filtration was depressurized to obtain a residue. Then, the residue was purified using column chromatography on silica gel using 25% ethyl acetate in hexane to obtain 4.11 g (86%) of target iridium compound 23.

<Preparation of Iridium Compound 24>

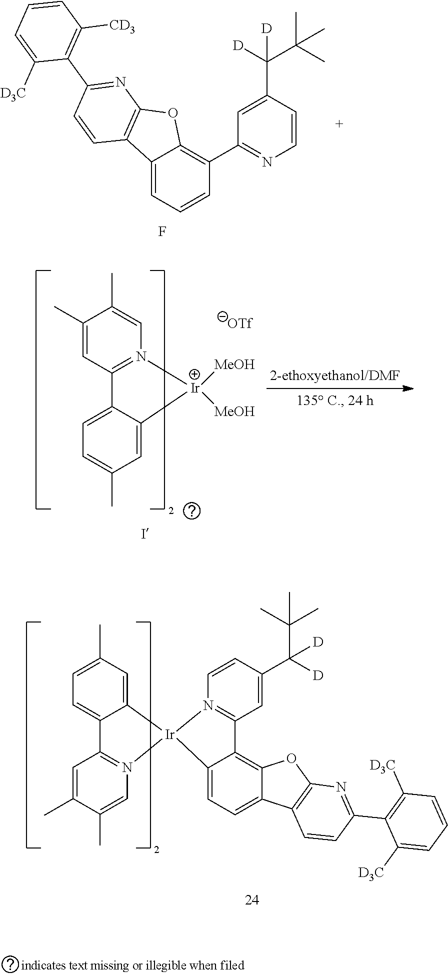

A solution in which F (2.14 g, 5 mmol) and I′ (4.79 g, 6 mmol) were dissolved in 2-ethoxyethanol (100 ml) and DMF (100 ml) was stirred at 135° C. for 24 hours. After completion of a reaction, a temperature was lowered to room temperature, an organic phase was isolated therefrom using dichloromethane and distilled water, and moisture was removed therefrom via adding anhydrous magnesium sulfate thereto. A solution obtained through filtration was depressurized to obtain a residue. Then, the residue was purified using column chromatography on silica gel using 25% ethyl acetate in hexane to obtain 3.80 g (75%) of target iridium compound 24.

<Preparation of Iridium Compound 25>

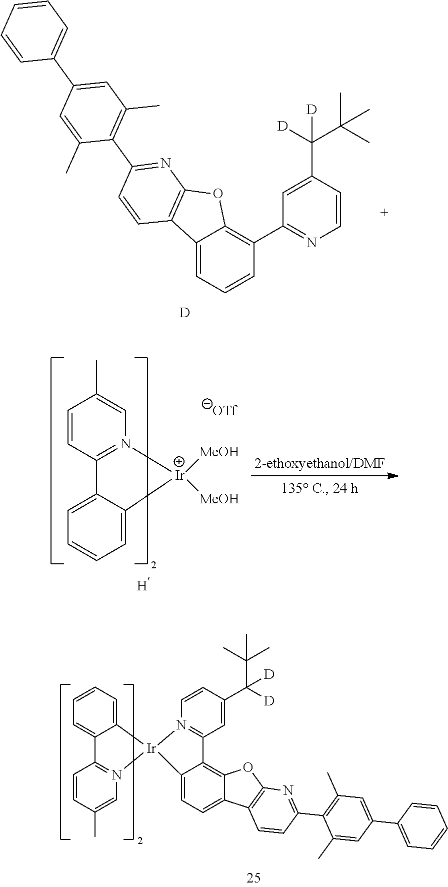

A solution in which D (2.49 g, 5 mmol) and H′ (4.45 g, 6 mmol) were dissolved in 2-ethoxyethanol (100 ml) and DMF (100 ml) was stirred at 135° C. for 24 hours. After completion of a reaction, a temperature was lowered to room temperature, an organic phase was isolated therefrom using dichloromethane and distilled water, and moisture was removed therefrom via adding anhydrous magnesium sulfate thereto. A solution obtained through filtration was depressurized to obtain a residue. Then, the residue was purified using column chromatography on silica gel using 25% ethyl acetate in hexane to obtain 4.10 g (80%) of target iridium compound 25.

<Preparation of Iridium Compound 26>

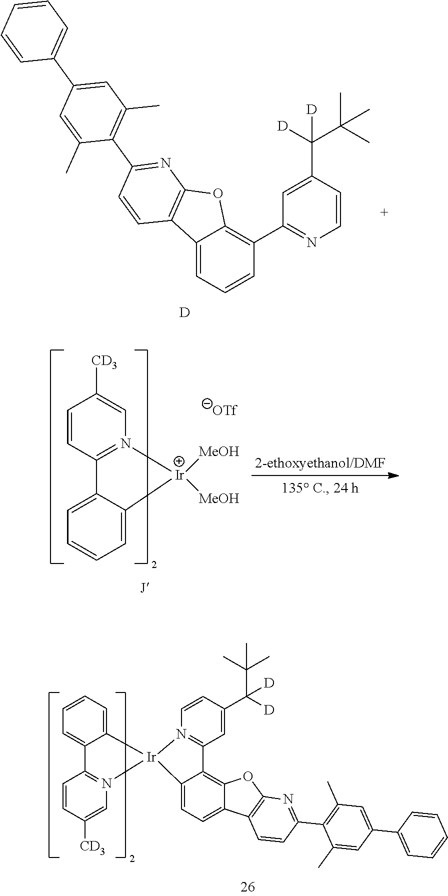

A solution in which D (2.49 g, 5 mmol) and J′ (4.49 g, 6 mmol) were dissolved in 2-ethoxyethanol (100 ml) and DMF (100 ml) was stirred at 135° C. for 24 hours. After completion of a reaction, a temperature was lowered to room temperature, an organic phase was isolated therefrom using dichloromethane and distilled water, and moisture was removed therefrom via adding anhydrous magnesium sulfate thereto. A solution obtained through filtration was depressurized to obtain a residue. Then, the residue was purified using column chromatography on silica gel using 25% ethyl acetate in hexane to obtain 4.34 g (84%) of target iridium compound 26.

<Preparation of Iridium Compound 27>

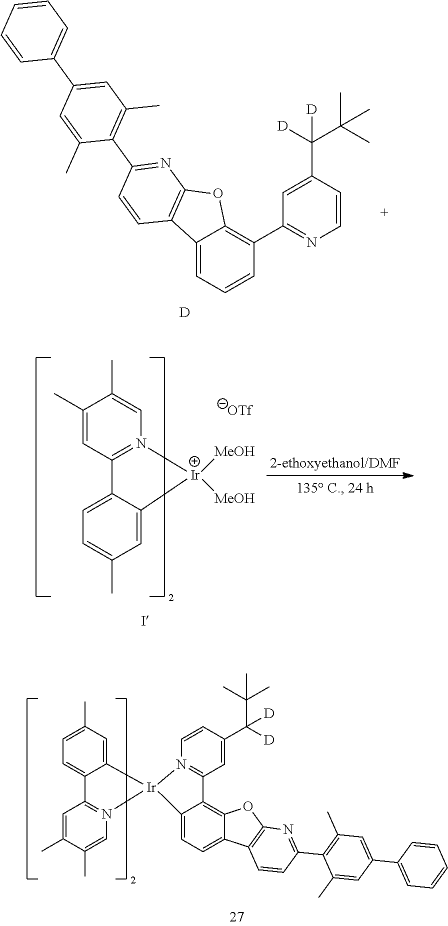

A solution in which D (2.49 g, 5 mmol) and I′ (4.79 g, 6 mmol) were dissolved in 2-ethoxyethanol (100 ml) and DMF (100 ml) was stirred at 135° C. for 24 hours. After completion of a reaction, a temperature was lowered to room temperature, an organic phase was isolated therefrom using dichloromethane and distilled water, and moisture was removed therefrom via adding anhydrous magnesium sulfate thereto. A solution obtained through filtration was depressurized to obtain a residue. Then, the residue was purified using column chromatography on silica gel using 25% ethyl acetate in hexane to obtain 4.22 g (78%) of target iridium compound 27.

<Preparation of Iridium Compound 28>

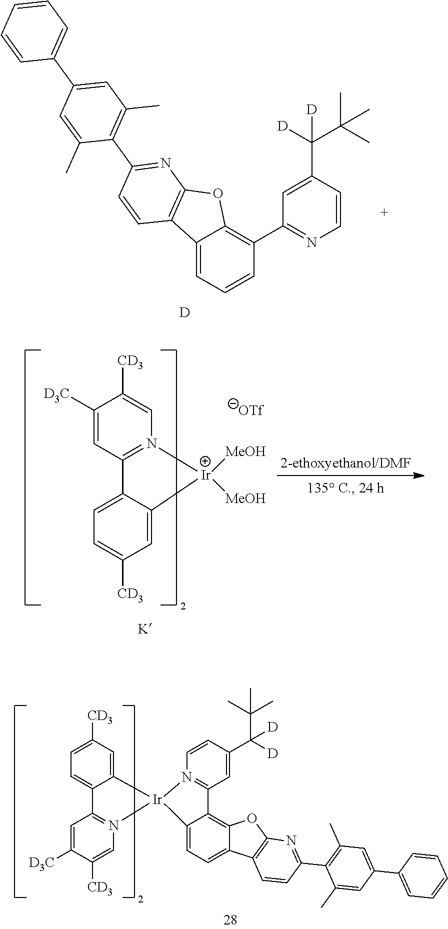

A solution in which D (2.49 g, 5 mmol) and K′ (4.90 g, 6 mmol) were dissolved in 2-ethoxyethanol (100 ml) and DMF (100 ml) was stirred at 135° C. for 24 hours. After completion of a reaction, a temperature was lowered to room temperature, an organic phase was isolated therefrom using dichloromethane and distilled water, and moisture was removed therefrom via adding anhydrous magnesium sulfate thereto. A solution obtained through filtration was depressurized to obtain a residue. Then, the residue was purified using column chromatography on silica gel using 25% ethyl acetate in hexane to obtain 4.46 g (81%) of target iridium compound 28.

<Preparation of Iridium Compound 29>

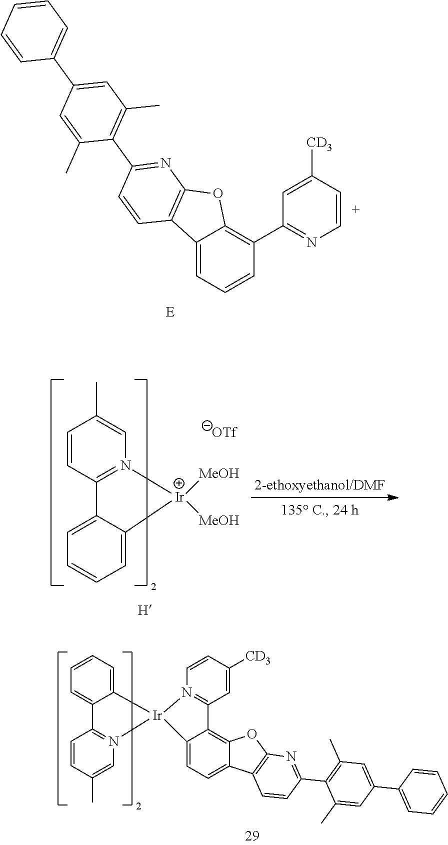

A solution in which E (2.22 g, 5 mmol) and H′ (4.45 g, 6 mmol) were dissolved in 2-ethoxyethanol (100 ml) and DMF (100 ml) was stirred at 135° C. for 24 hours. After completion of a reaction, a temperature was lowered to room temperature, an organic phase was isolated therefrom using dichloromethane and distilled water, and moisture was removed therefrom via adding anhydrous magnesium sulfate thereto. A solution obtained through filtration was depressurized to obtain a residue. Then, the residue was purified using column chromatography on silica gel using 25% ethyl acetate in hexane to obtain 4.22 g (87%) of target iridium compound 29.

<Preparation of Iridium Compound 30>

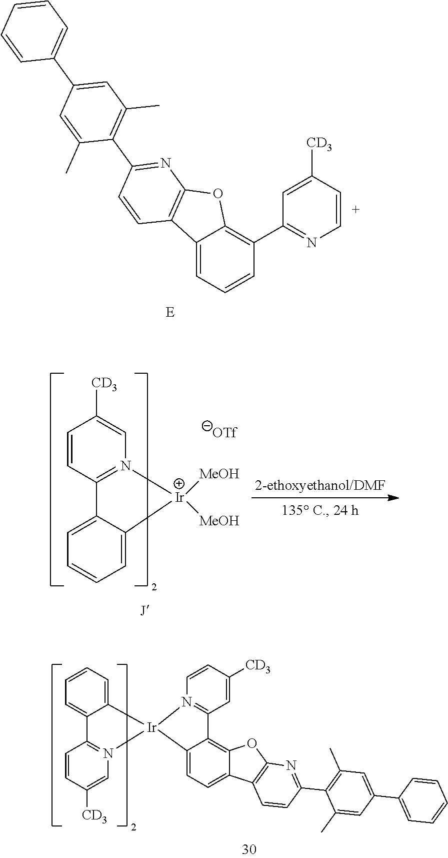

A solution in which E (2.22 g, 5 mmol) and J′ (4.49 g, 6 mmol) were dissolved in 2-ethoxyethanol (100 ml) and DMF (100 ml) was stirred at 135° C. for 24 hours. After completion of a reaction, a temperature was lowered to room temperature, an organic phase was isolated therefrom using dichloromethane and distilled water, and moisture was removed therefrom via adding anhydrous magnesium sulfate thereto. A solution obtained through filtration was depressurized to obtain a residue. Then, the residue was purified using column chromatography on silica gel using 25% ethyl acetate in hexane to obtain 4.20 g (86%) of target iridium compound 30.

<Preparation of Iridium Compound 31>

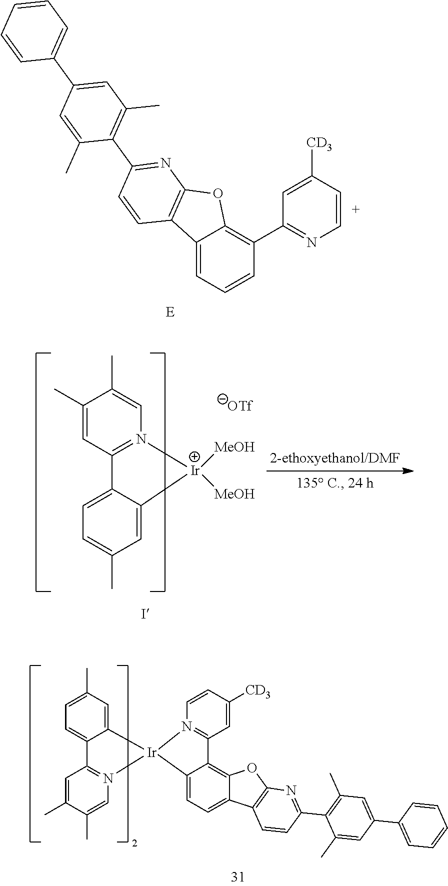

A solution in which E (2.22 g, 5 mmol) and I′ (4.79 g, 6 mmol) were dissolved in 2-ethoxyethanol (100 ml) and DMF (100 ml) was stirred at 135° C. for 24 hours. After completion of a reaction, a temperature was lowered to room temperature, an organic phase was isolated therefrom using dichloromethane and distilled water, and moisture was removed therefrom via adding anhydrous magnesium sulfate thereto. A solution obtained through filtration was depressurized to obtain a residue. Then, the residue was purified using column chromatography on silica gel using 25% ethyl acetate in hexane to obtain 4.11 g (80%) of target iridium compound 31.

<Preparation of Iridium Compound 32>

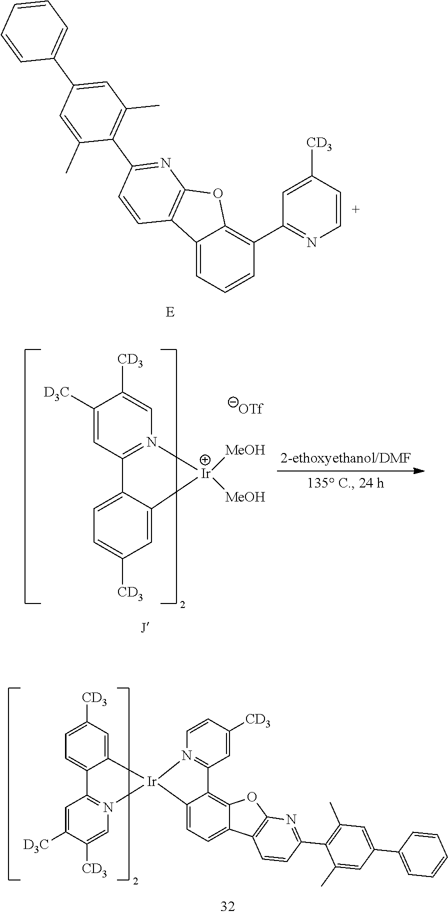

A solution in which E (2.22 g, 5 mmol) and K′ (4.90 g, 6 mmol) were dissolved in 2-ethoxyethanol (100 ml) and DMF (100 ml) was stirred at 135° C. for 24 hours. After completion of a reaction, a temperature was lowered to room temperature, an organic phase was isolated therefrom using dichloromethane and distilled water, and moisture was removed therefrom via adding anhydrous magnesium sulfate thereto. A solution obtained through filtration was depressurized to obtain a residue. Then, the residue was purified using column chromatography on silica gel using 25% ethyl acetate in hexane to obtain 4.44 g (85%) of target iridium compound 32.

<Preparation of Iridium Compound 33>

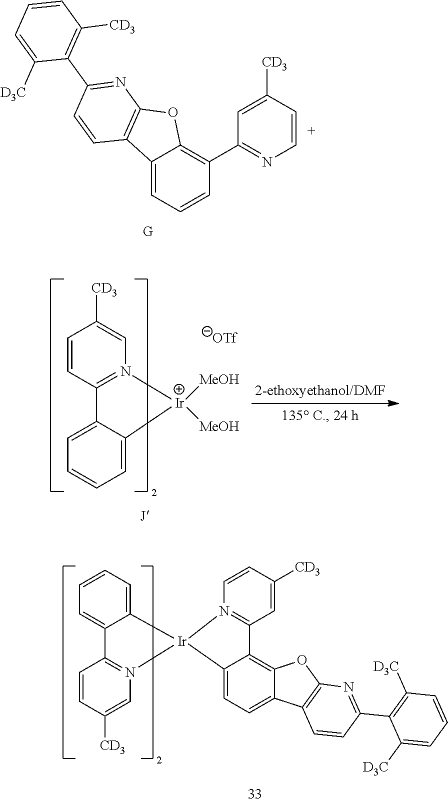

A solution in which G (1.87 g, 5 mmol) and J′(4.49 g, 6 mmol) were dissolved in 2-ethoxyethanol (100 ml) and DMF (100 ml) was stirred at 135° C. for 24 hours. After completion of a reaction, a temperature was lowered to room temperature, an organic phase was isolated therefrom using dichloromethane and distilled water, and moisture was removed therefrom via adding anhydrous magnesium sulfate thereto. A solution obtained through filtration was depressurized to obtain a residue. Then, the residue was purified using column chromatography on silica gel using 25% ethyl acetate in hexane to obtain 3.63 g (80%) of target iridium compound 33.

<Preparation of Iridium Compound 34>

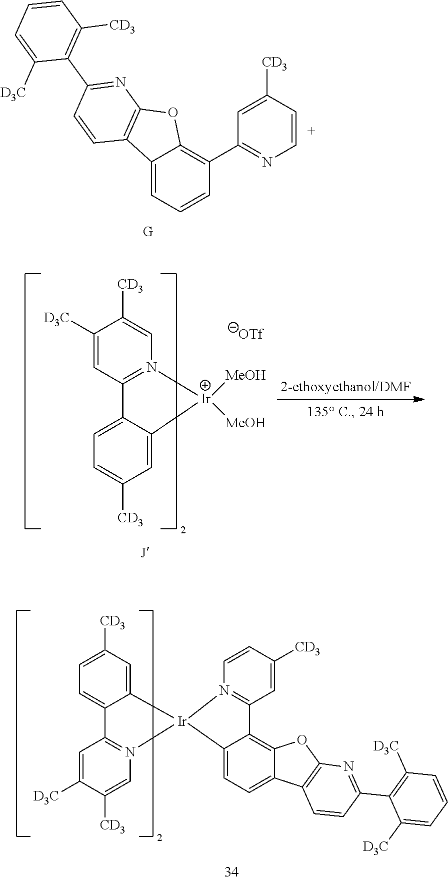

A solution in which G (1.87 g, 5 mmol) and K′ (4.90 g, 6 mmol) were dissolved in 2-ethoxyethanol (100 ml) and DMF (100 ml) was stirred at 135° C. for 24 hours. After completion of a reaction, a temperature was lowered to room temperature, an organic phase was isolated therefrom using dichloromethane and distilled water, and moisture was removed therefrom via adding anhydrous magnesium sulfate thereto. A solution obtained through filtration was depressurized to obtain a residue. Then, the residue was purified using column chromatography on silica gel using 25% ethyl acetate in hexane to obtain 4.00 g (82%) of target iridium compound 34.

<Preparation of Iridium Compound 35>

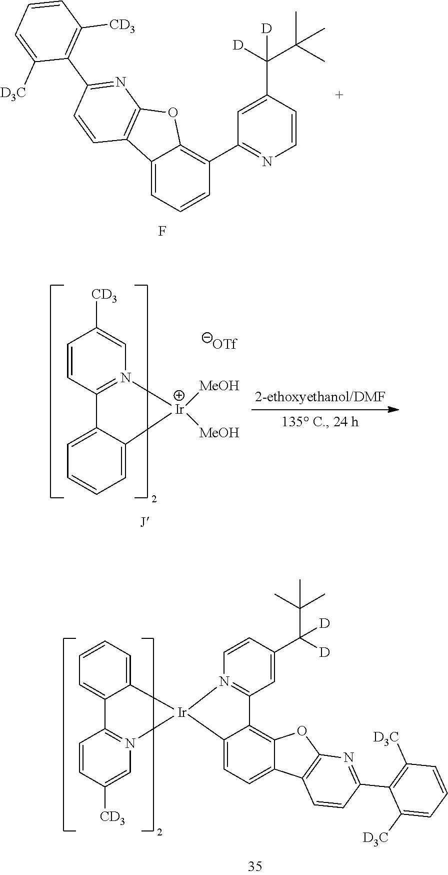

A solution in which F (2.14 g, 5 mmol) and J′ (4.49 g, 6 mmol) were dissolved in 2-ethoxyethanol (100 ml) and DMF (100 ml) was stirred at 135° C. for 24 hours. After completion of a reaction, a temperature was lowered to room temperature, an organic phase was isolated therefrom using dichloromethane and distilled water, and moisture was removed therefrom via adding anhydrous magnesium sulfate thereto. A solution obtained through filtration was depressurized to obtain a residue. Then, the residue was purified using column chromatography on silica gel using 25% ethyl acetate in hexane to obtain 3.90 g (81%) of target iridium compound 35.

<Preparation of Iridium Compound 36>

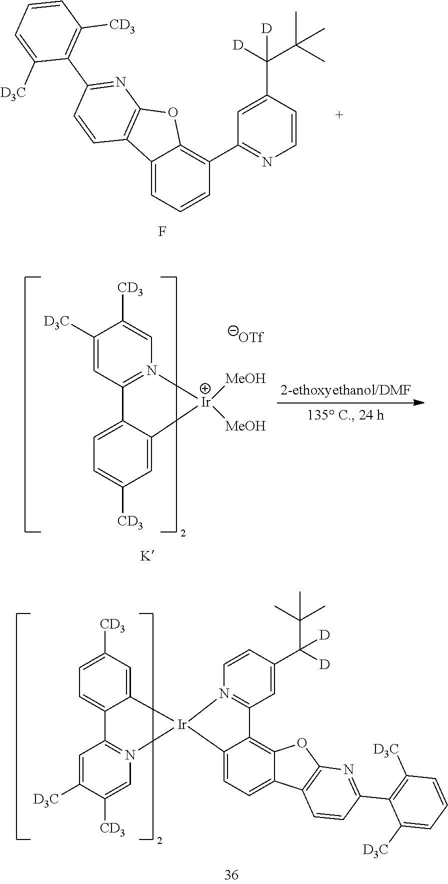

A solution in which F (2.14 g, 5 mmol) and K′ (4.90 g, 6 mmol) were dissolved in 2-ethoxyethanol (100 ml) and DMF (100 ml) was stirred at 135° C. for 24 hours. After completion of a reaction, a temperature was lowered to room temperature, an organic phase was isolated therefrom using dichloromethane and distilled water, and moisture was removed therefrom via adding anhydrous magnesium sulfate thereto. A solution obtained through filtration was depressurized to obtain a residue. Then, the residue was purified using column chromatography on silica gel using 25% ethyl acetate in hexane to obtain 4.07 g (79%) of target iridium compound 36.

### Present Example 1

A glass substrate having a thin film of ITO (indium tin oxide) having a thickness of 1,000 Å coated thereon was washed, followed by ultrasonic cleaning with a solvent such as isopropyl alcohol, acetone or methanol. Then, the glass substrate was dried. Thus, an ITO transparent electrode was formed. HI-1 as a hole injection material was deposited on the ITO transparent electrode in a thermal vacuum deposition manner. Thus, a hole injection layer having a thickness of 60 nm was formed. then, NPB as a hole transport material was deposited on the hole injection layer in a thermal vacuum deposition manner. Thus, a hole transport layer having a thickness of 80 nm was formed. Then, CBP as a host material of a light-emitting layer was deposited on the hole transport layer in a thermal vacuum deposition manner. The Compound 1 as a dopant was doped into the host material at a doping concentration of 5%. Thus, the light-emitting layer of a thickness of 30 nm was formed. ET-1: Liq (1:1) (30 nm) as a material for an electron transport layer and an electron injection layer was deposited on the light-emitting layer. Then, 100 nm thick aluminum was deposited thereon to form a negative electrode. In this way, an organic light-emitting diode was manufactured.

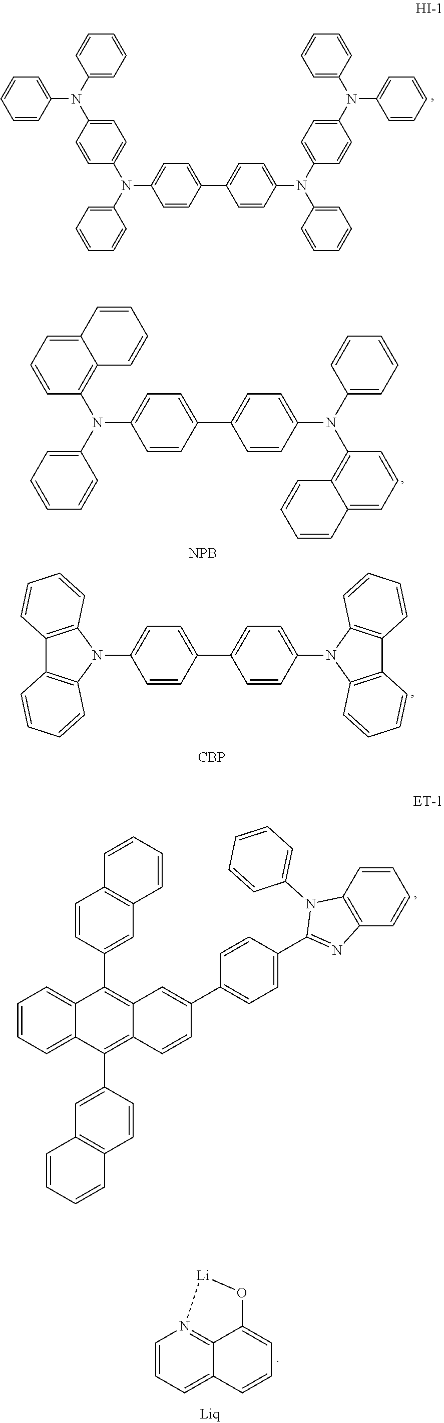

The HI-1 means N1,N1′-([1,1′-biphenyl]-4,4′-diyl)bis(N1,N4,N4-triphenylbenzene-1,4-diamine).

The ET-1 means 2-(4-(9,10-di(naphthalen-2-yl)anthracen-2-yl)phenyl)-1-phenyl-1H-benzo[d]imidazole. [00266]<Present Examples 2 to 25 and Comparative Examples 1 to 3>

Organic light-emitting diodes of Present Examples 2 to 25 and Comparative Examples 1 to 3 were manufactured in the same method as in Present Example 1, except that Compounds indicated in following Tables 2 and 3 were used instead of the Compound 1 as the dopant in the Present Example 1.

<Evaluation of Performances of Organic Light-Emitting Diodes>

Regarding the organic light-emitting diodes prepared according to Present Examples 1 to 25 and Comparative Examples 1 to 3, operation voltages and efficiency characteristics at 10 mA/cm² current, and lifetime characteristics when being accelerated at 40 mA/cm² and 40° C. were measured. Thus, operation voltage (V), EQE (0%), and LT95 (0%) were measured, and were converted to values relative to values of Comparative Example 1. Results are shown in Tables 2 to 3 below. LT95 refers to a lifetime evaluation scheme and means a time it takes for an organic light-emitting diode to lose 500 of initial brightness thereof.

TABLE 2

| | | | Maximum | | |
|---|---|---|---|---|---|
| | | Operation | luminous | EQE | LT95 |
| | | voltage | efficiency (%, | (%, | (%, relative |
| Examples | Dopant | (V) | relative value) | relative value) | value) |
| Comparative | Ref 1 | 4.36 | 100 | 100 | 100 |
| Example 1 | | | | | |
| Comparative | Ref 2 | 4.35 | 104 | 108 | 111 |
| Example 2 | | | | | |
| Comparative | Ref 3 | 4.36 | 108 | 110 | 127 |
| Example 3 | | | | | |
| Present | Compound 1 | 4.32 | 111 | 125 | 153 |
| Example 1 | | | | | |
| Present | Compound 13 | 4.35 | 114 | 130 | 179 |
| Example 2 | | | | | |
| Present | Compound 14 | 4.34 | 115 | 132 | 185 |
| Example 3 | | | | | |
| Present | Compound 15 | 4.36 | 116 | 133 | 183 |
| Example 4 | | | | | |
| Present | Compound 16 | 4.33 | 117 | 134 | 189 |
| Example 5 | | | | | |
| Present | Compound 17 | 4.34 | 116 | 134 | 183 |
| Example 6 | | | | | |
| Present | Compound 18 | 4.32 | 117 | 135 | 186 |
| Example 7 | | | | | |
| Present | Compound 19 | 4.36 | 118 | 137 | 188 |
| Example 8 | | | | | |
| Present | Compound 20 | 4.33 | 119 | 138 | 191 |
| Example 9 | | | | | |
| Present | Compound 21 | 4.32 | 114 | 132 | 184 |
| Example 10 | | | | | |
| Present | Compound 22 | 4.35 | 116 | 135 | 189 |
| Example 11 | | | | | |
| Present | Compound 23 | 4.35 | 116 | 134 | 189 |
| Example 12 | | | | | |
| Present | Compound 24 | 4.34 | 118 | 138 | 194 |
| Example 13 | | | | | |

TABLE 3

| | | | Maximum | | |
|---|---|---|---|---|---|
| | | Operation | luminous | EQE | LT95 |
| | | voltage | efficiency | (%, | (%, relative |
| Examples | Dopant | (V) | (%, relative value) | relative value) | value) |
| Present | Compound 25 | 4.33 | 115 | 138 | 177 |
| Example 14 | | | | | |
| Present | Compound 26 | 4.32 | 116 | 139 | 183 |
| Example 15 | | | | | |
| Present | Compound 27 | 4.32 | 117 | 141 | 181 |
| Example 16 | | | | | |
| Present | Compound 28 | 4.34 | 118 | 143 | 184 |
| Example 17 | | | | | |
| Present | Compound 29 | 4.32 | 112 | 135 | 173 |
| Example 18 | | | | | |
| Present | Compound 30 | 4.34 | 114 | 136 | 179 |
| Example 19 | | | | | |
| Present | Compound 31 | 4.35 | 115 | 139 | 177 |
| Example 20 | | | | | |
| Present | Compound 32 | 4.32 | 116 | 140 | 180 |
| Example 21 | | | | | |
| Present | Compound 33 | 4.34 | 115 | 133 | 191 |
| Example 22 | | | | | |
| Present | Compound 34 | 4.35 | 117 | 137 | 192 |
| Example 23 | | | | | |
| Present | Compound 35 | 4.32 | 117 | 135 | 195 |
| Example 24 | | | | | |
| Present | Compound 36 | 4.34 | 119 | 139 | 197 |
| Example 25 | | | | | |

Structures of Ref 1 to Ref 3 as dopant materials respectively in Comparative Examples 1 to 3 in Table 2 are as follows:

Ref 1:

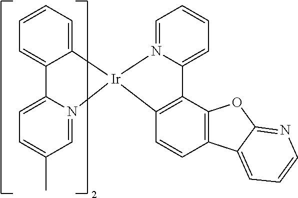

Ref 2:

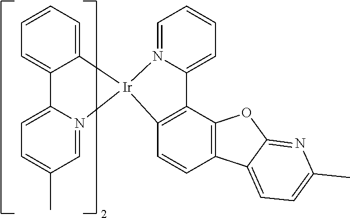

Ref 3:

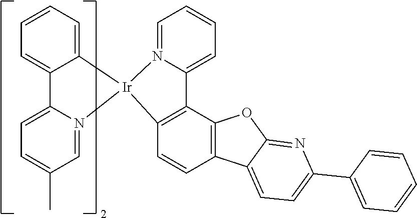

It may be identified from the results of the above Table 2 to Table 3 that in the organic light-emitting diode in which the organometallic compound of each of Present Examples 1 to 25 according to the present disclosure is used as the dopant of the light-emitting layer of the diode, the operation voltage of the diode is lowered, and maximum luminous efficiency, external quantum efficiency (EQE) and lifetime (LT95) of the diode are improved, compared to those in Comparative Examples 1 to 3.

A scope of protection of the present disclosure should be construed by the scope of the claims, and all technical ideas within the scope equivalent thereto should be construed as being included in the scope of the present disclosure. Although the embodiments of the present disclosure have been described in more detail with reference to the accompanying drawings, the present disclosure is not necessarily limited to these embodiments. The present disclosure may be implemented in various modified manners within the scope not departing from the technical idea of the present disclosure. Accordingly, the embodiments disclosed in the present disclosure are not intended to limit the technical idea of the present disclosure, but to describe the present disclosure. the scope of the technical idea of the present disclosure is not limited by the embodiments. Therefore, it should be understood that the embodiments as described above are illustrative and non-limiting in all respects. The scope of protection of the present disclosure should be interpreted by the claims, and all technical ideas within the scope of the present disclosure should be interpreted as being included in the scope of the present disclosure.

What is claimed is:

1. An organometallic compound represented by Chemical Formula 1: 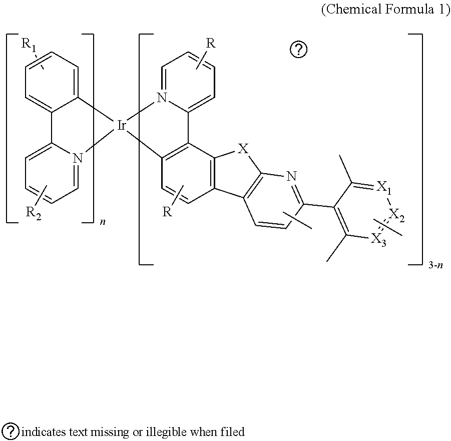
wherein in Chemical Formula 1,
X represents one selected from a group consisting of O, S and Se;
each of X₁, X₂ and X₃ independently represents N or CRₐ;
each of R₁, R₂ and R₃ independently represents mono-substitution, di-substitution, tri-substitution, tetra-substitution or no-substitution;
each of R₅, R₆, R₇, and Rₐ independently represents mono-substitution, di-substitution, tri-substitution, or no-substitution;
each of R₄ and R₈ independently represents mono-substitution, di-substitution, or no-substitution;
each of R₁, R₂, R₃, R₄, R₇, R₈ and Rₐ independently represents one selected from a group consisting of hydrogen, deuterium, halide, deuterated or undeuterated alkyl, cycloalkyl, heteroalkyl, arylalkyl, alkoxy, aryloxy, amino, silyl, alkenyl, cycloalkenyl, heteroalkenyl, alkynyl, aryl, heteroaryl, acyl, carbonyl, carboxylic acid, ester, nitrile, isonitrile, sulfanyl, sulfinyl, sulfonyl, phosphino, and combinations thereof,
each of R₅ and R₆ independently represents one selected from a group consisting of halide, deuterated or undeuterated alkyl, cycloalkyl, heteroalkyl, arylalkyl, alkoxy, aryloxy, amino, silyl, alkenyl, cycloalkenyl, heteroalkenyl, alkynyl, aryl, heteroaryl, acyl, carbonyl, carboxylic acid, ester, nitrile, isonitrile, sulfanyl, sulfinyl, sulfonyl, phosphino, and combinations thereof, and
n is 0, 1 or 2.

2. The organometallic compound of claim 1, wherein n is 0.

3. The organometallic compound of claim 1, wherein n is 1.

4. The organometallic compound of claim 1, wherein n is 2.

5. The organometallic compound of claim 1, where X is oxygen (O).

6. The organometallic compound of claim 1, wherein X is sulfur (S).

7. The organometallic compound of claim 1, wherein the organometallic compound represented by Chemical Formula 1 includes one selected from a group consisting of following compounds 1 to 564:

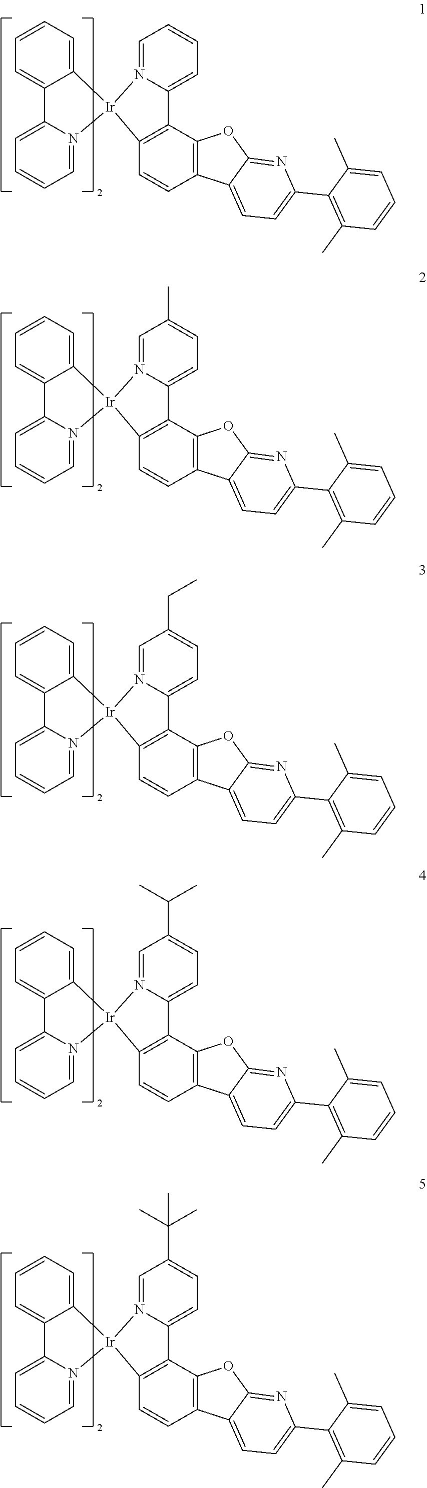

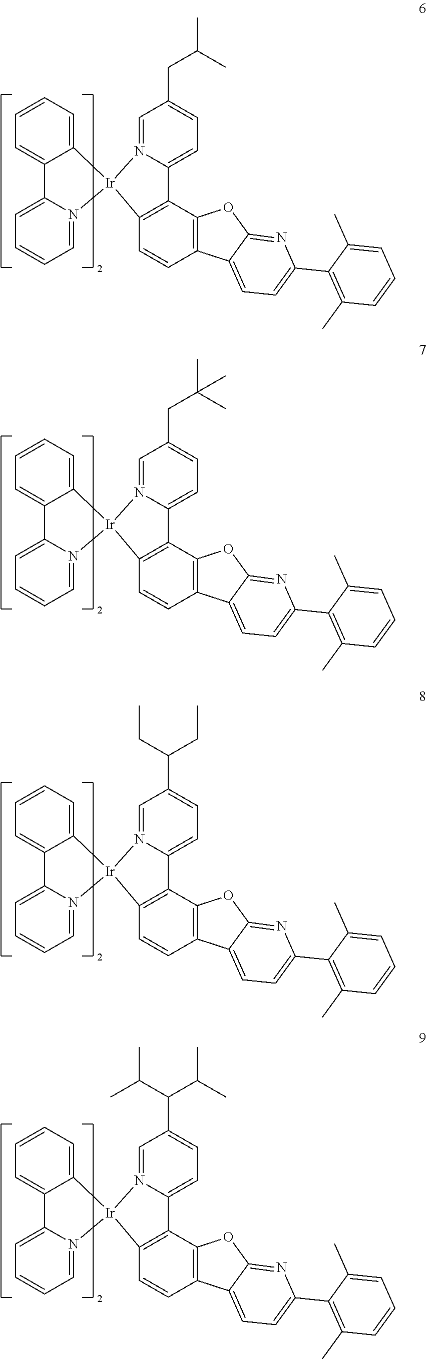

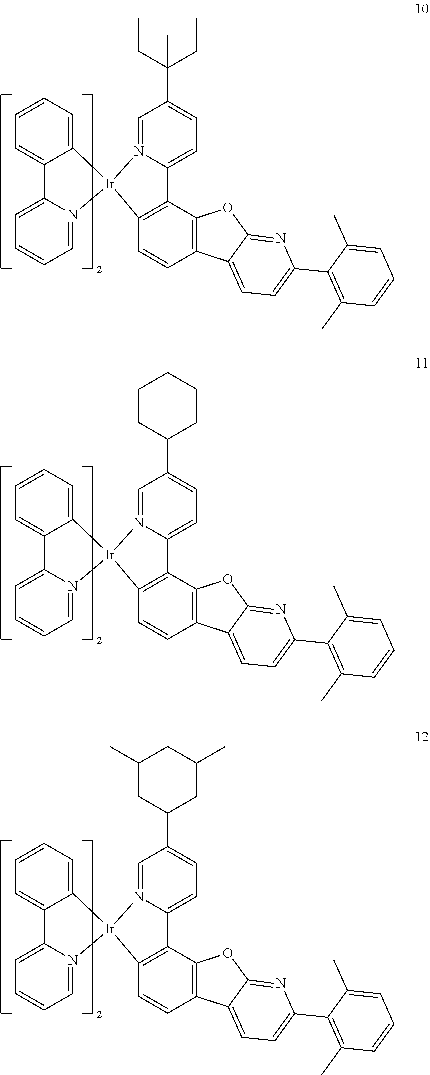

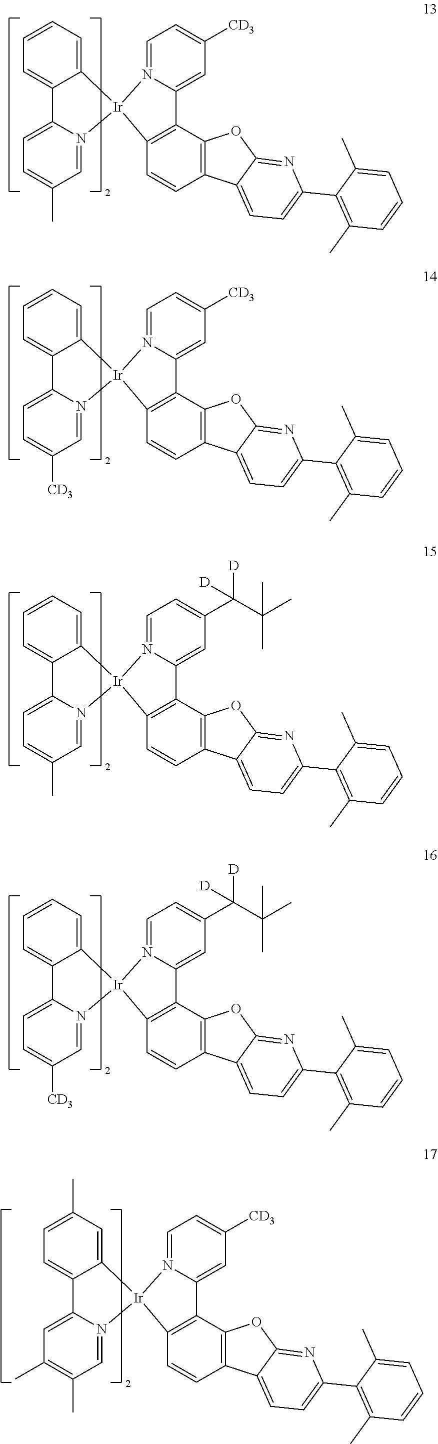

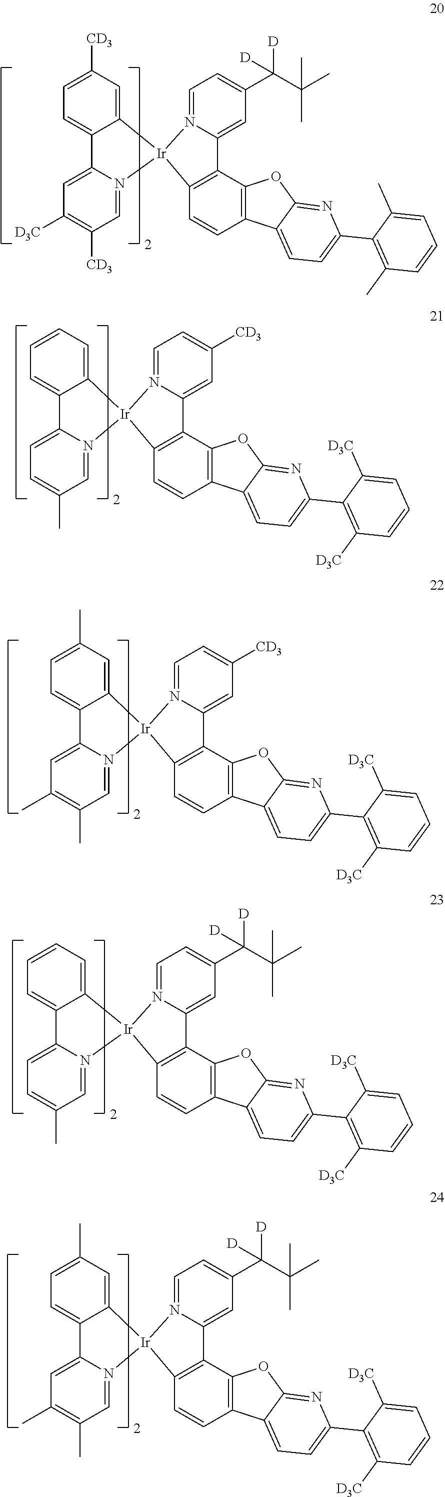

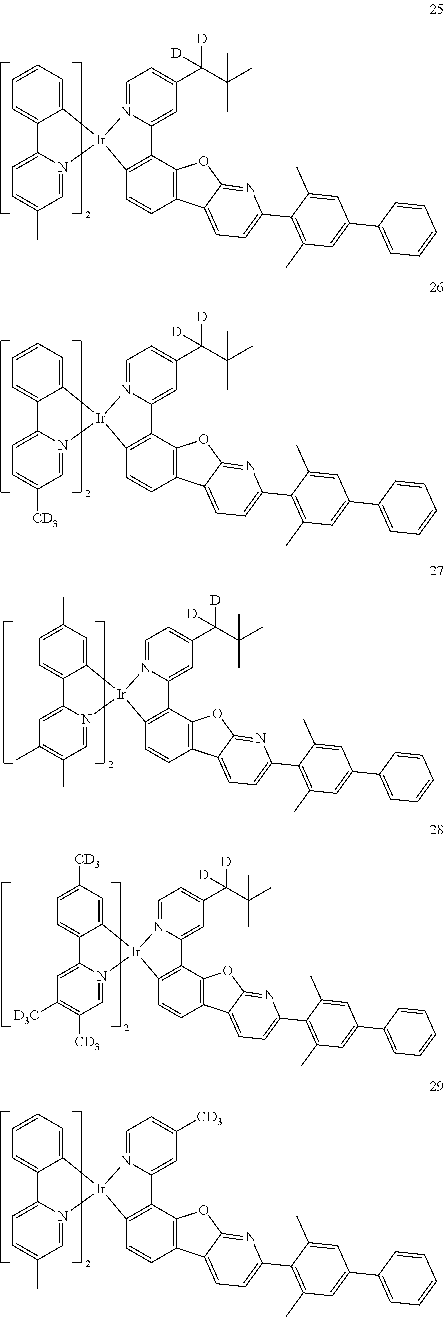

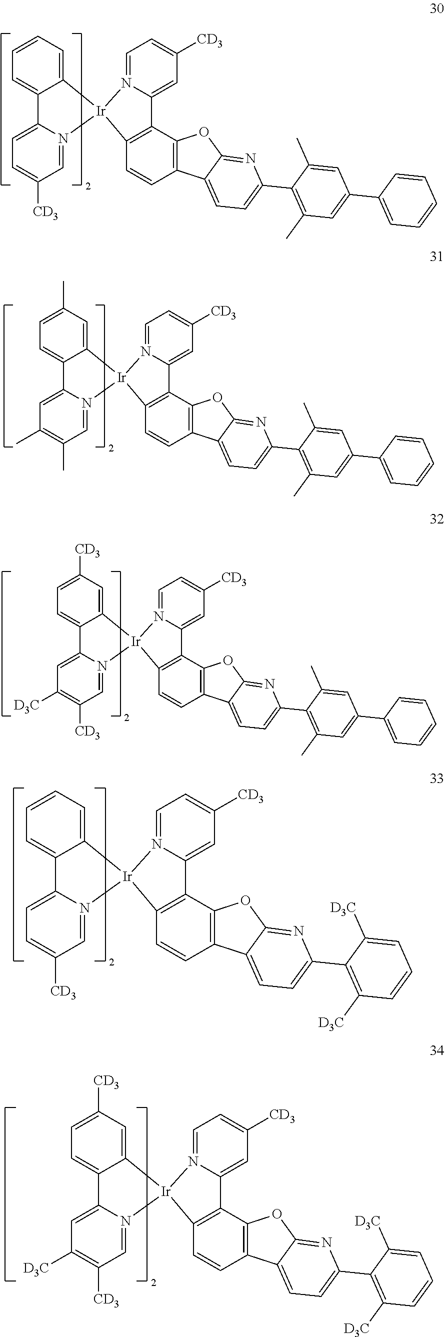

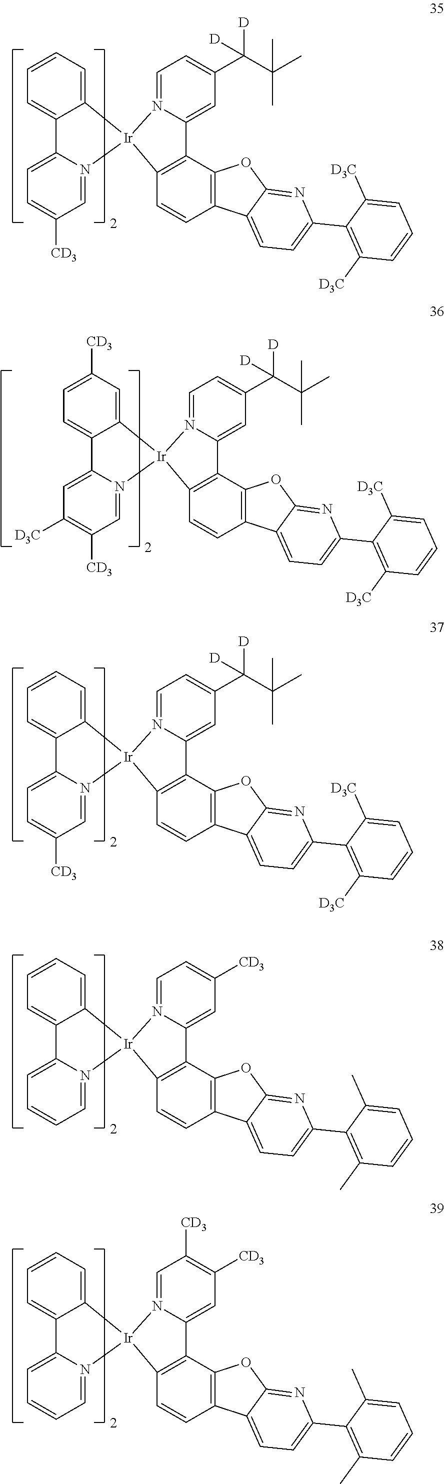

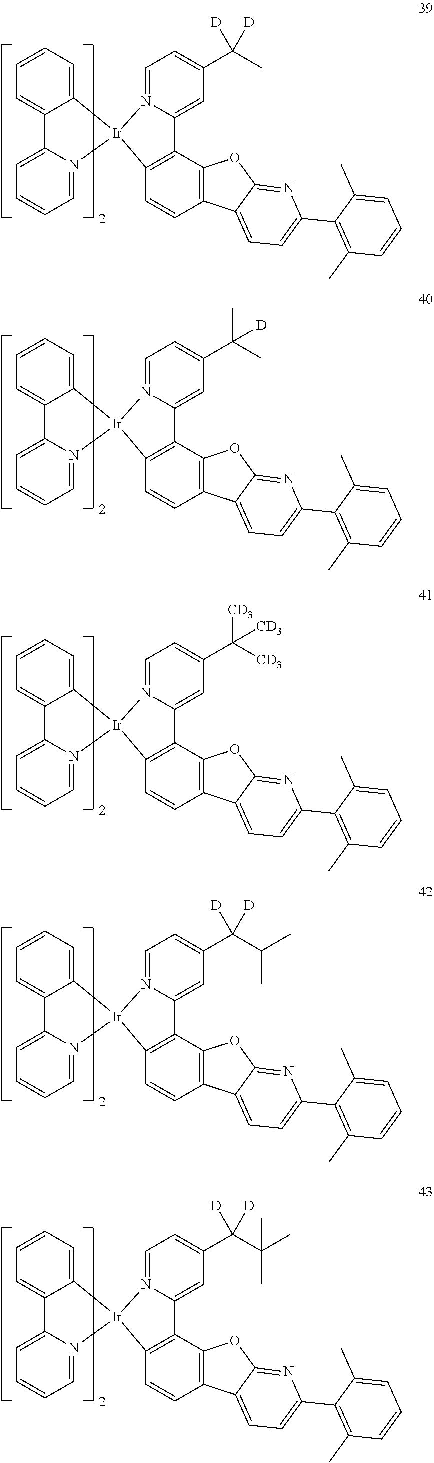

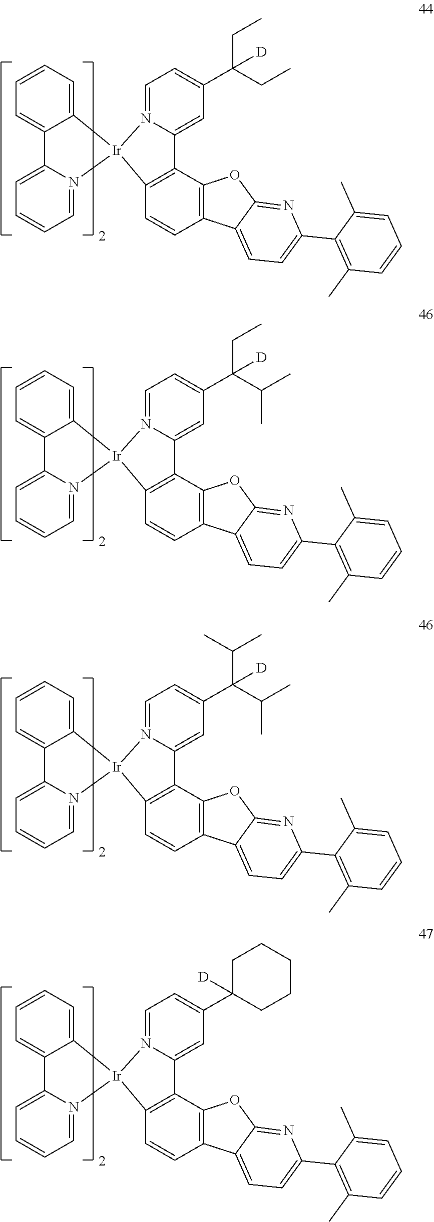

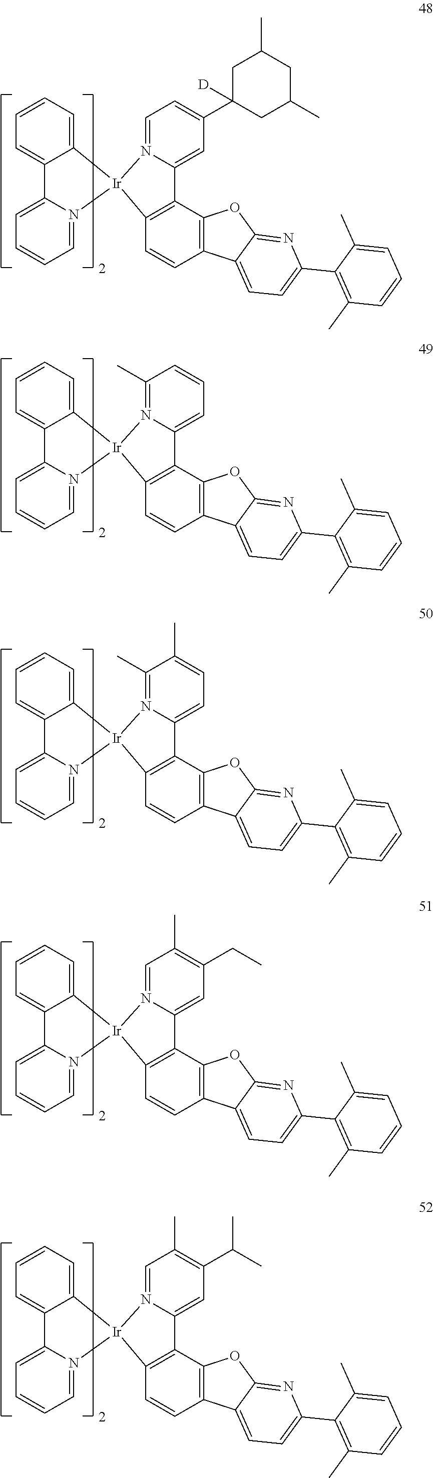

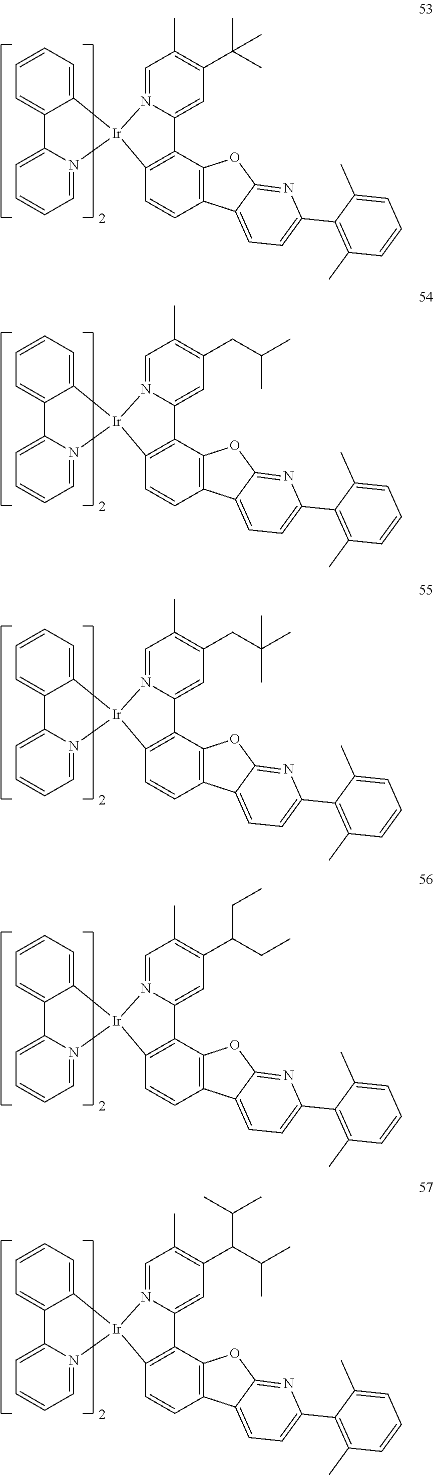

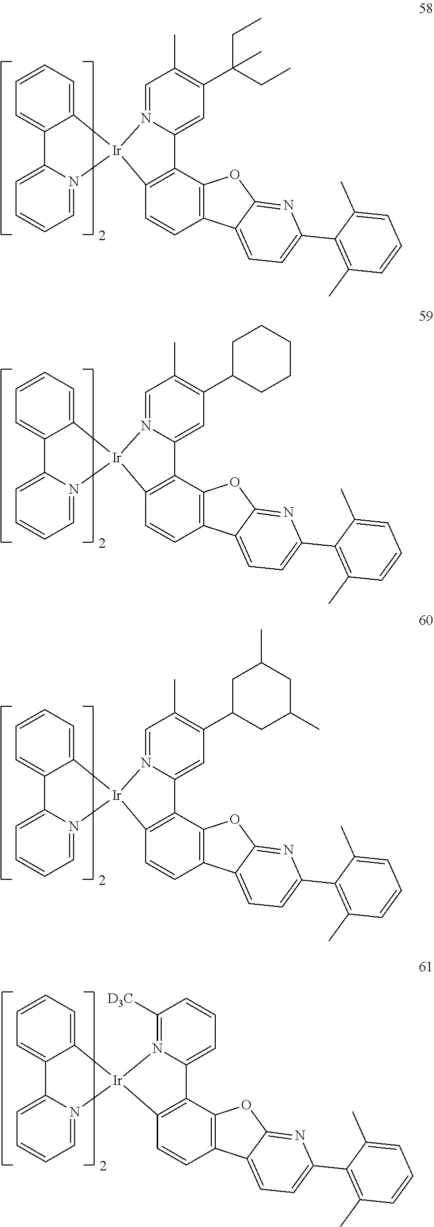

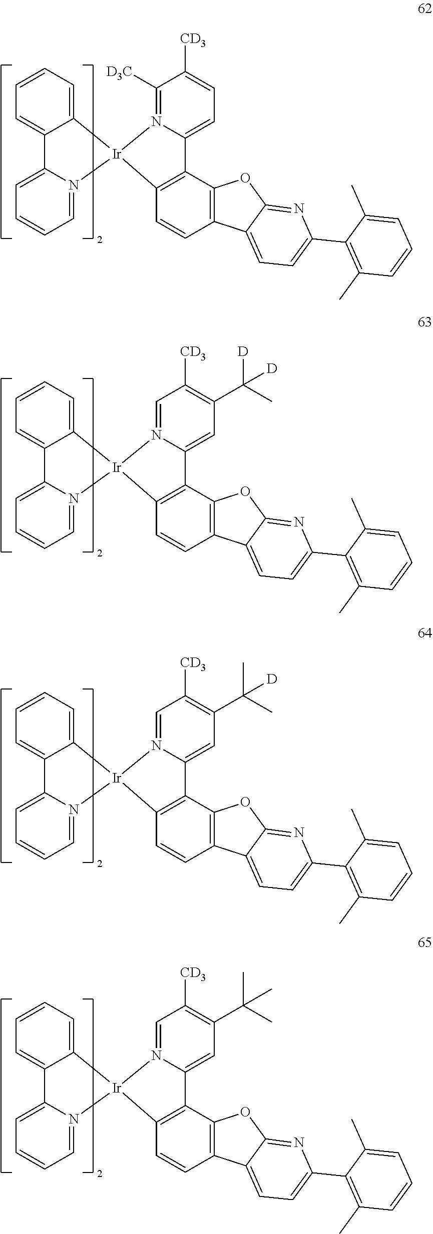

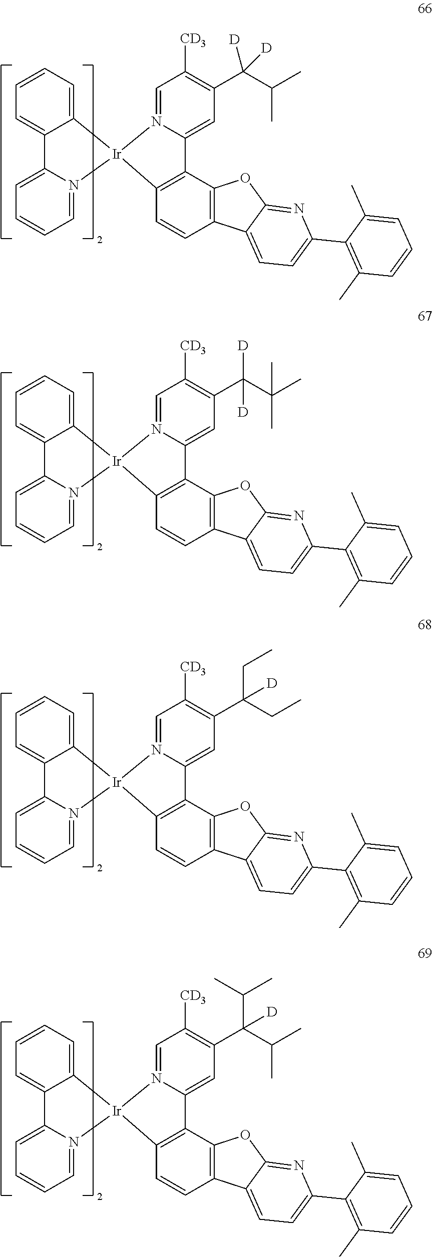

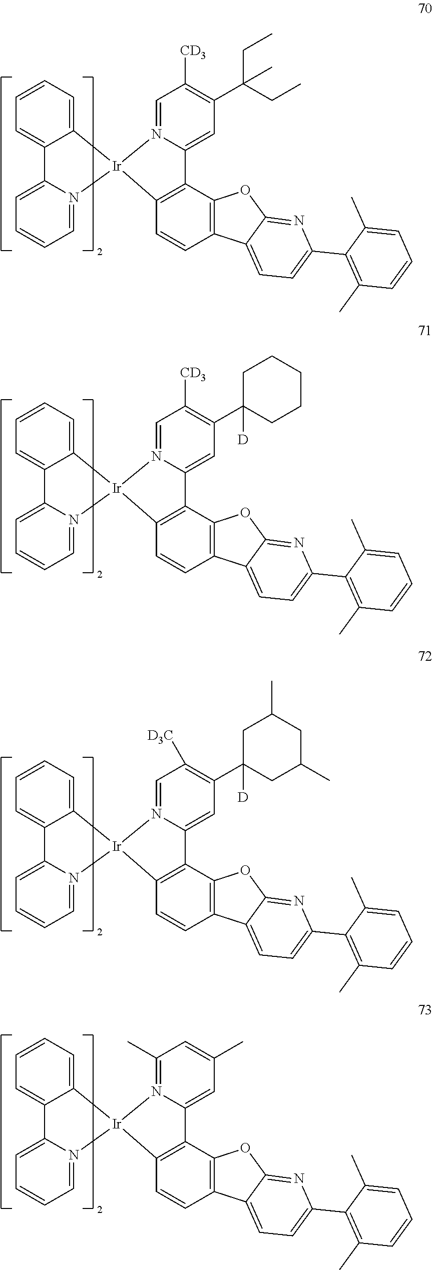

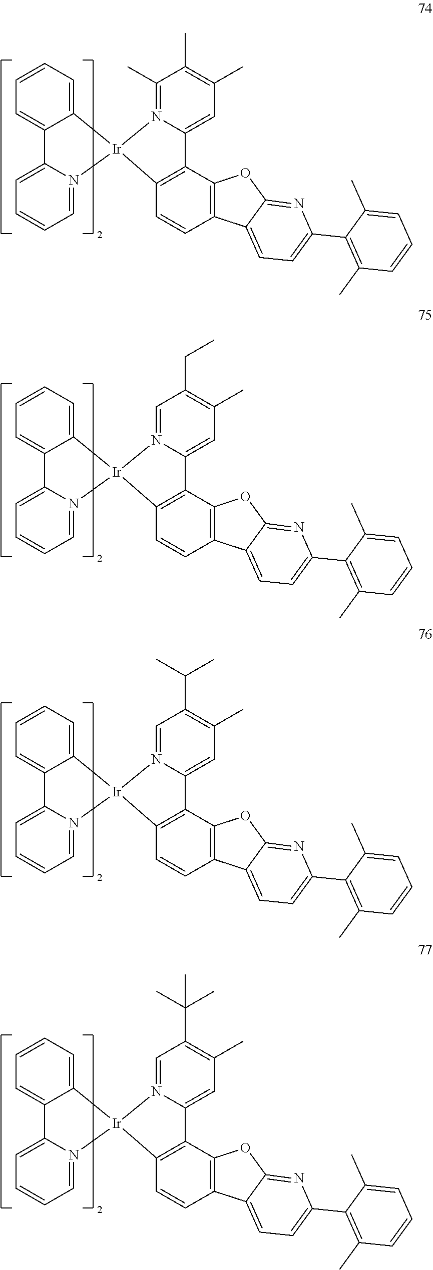

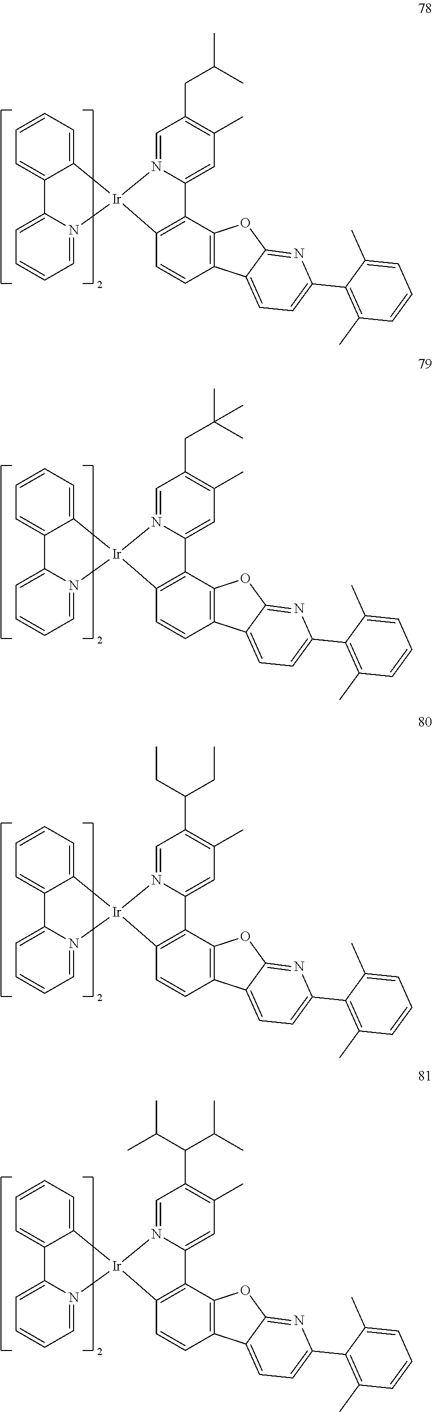

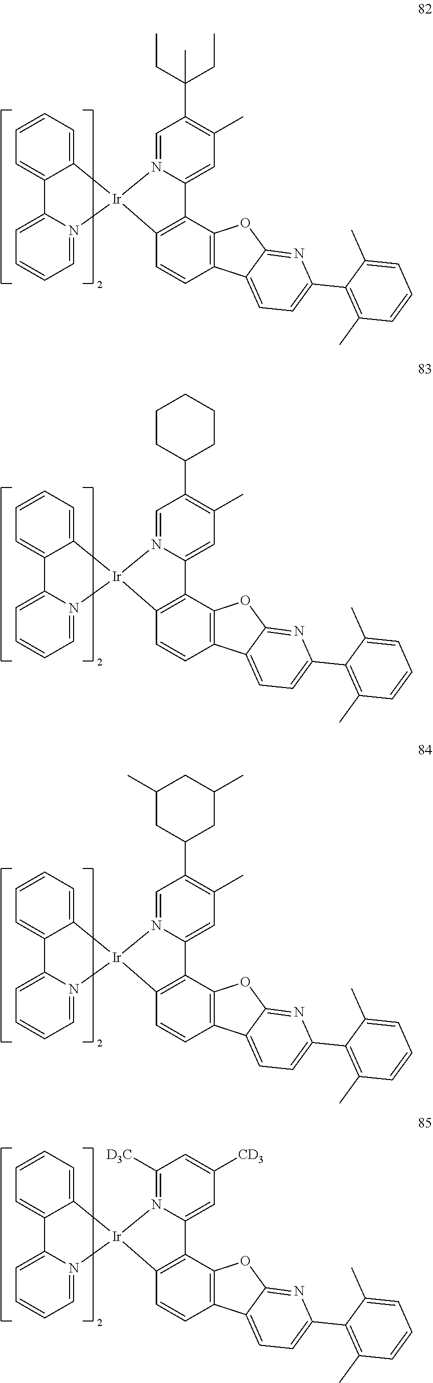

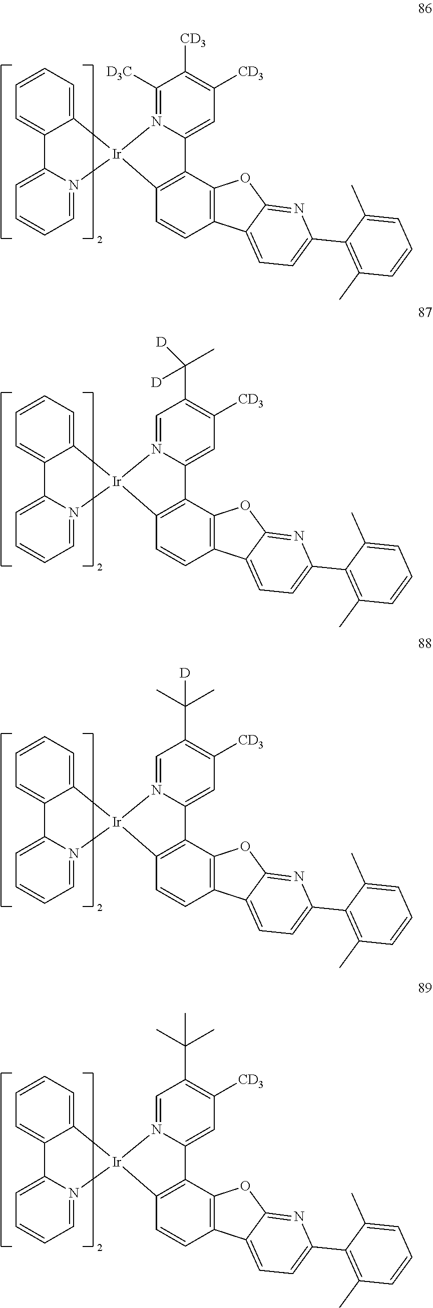

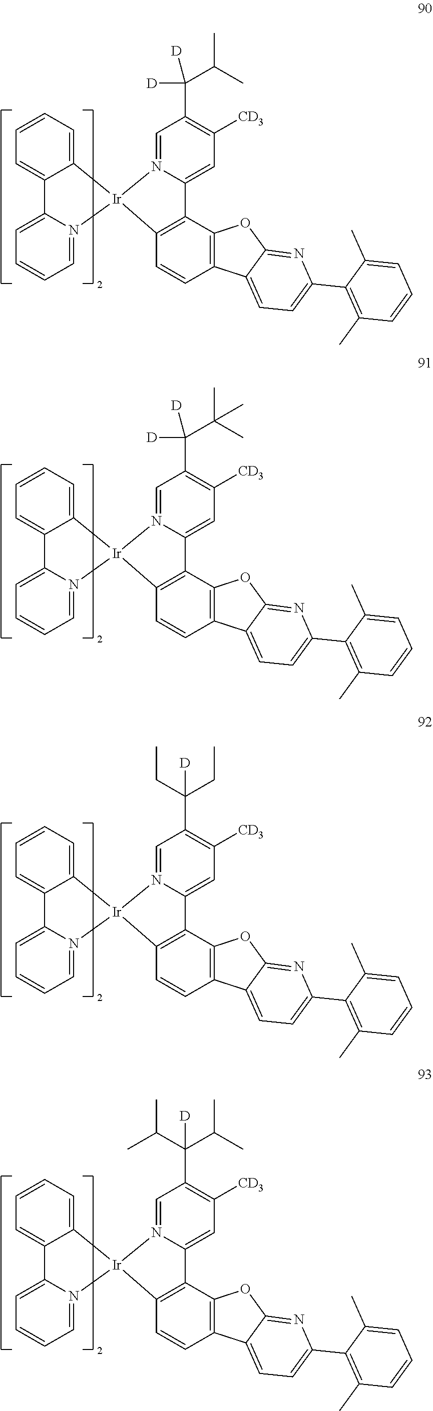

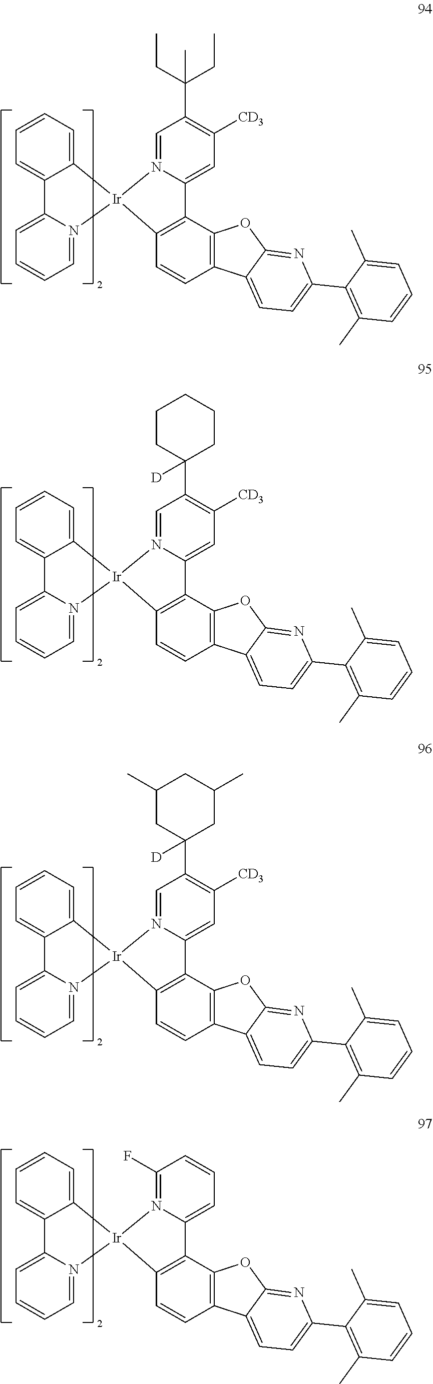

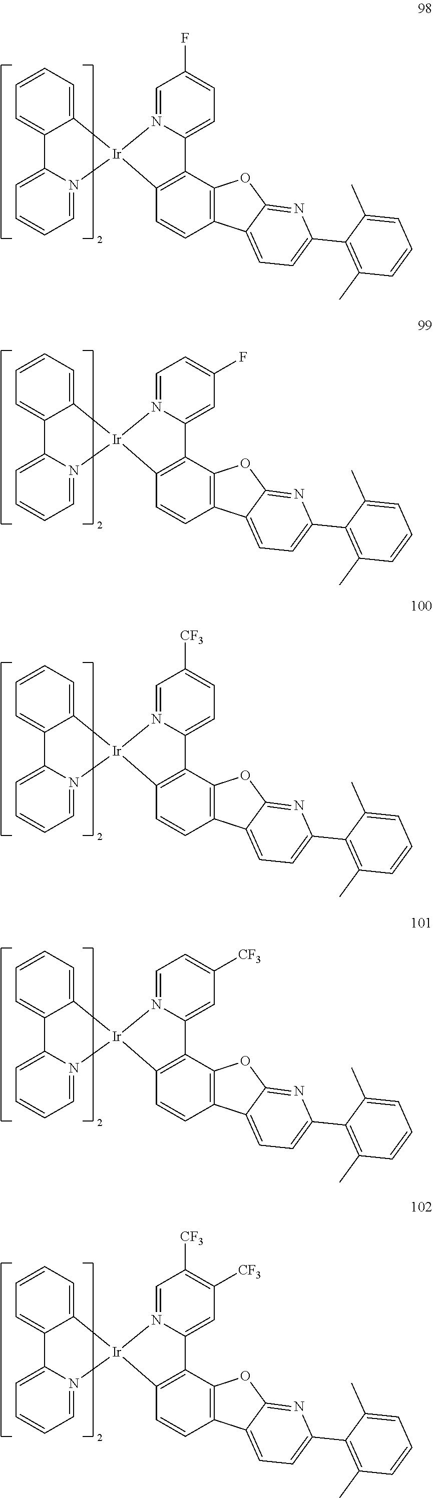

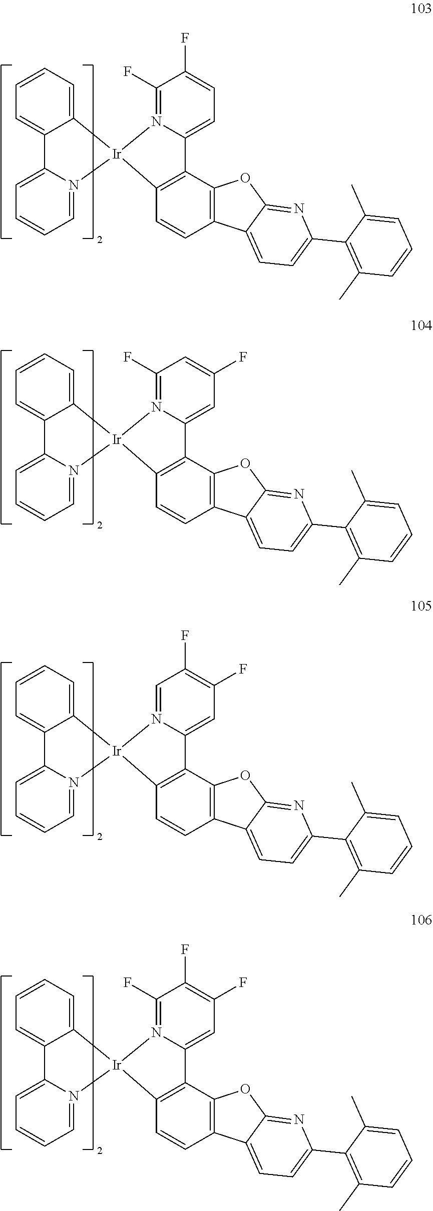

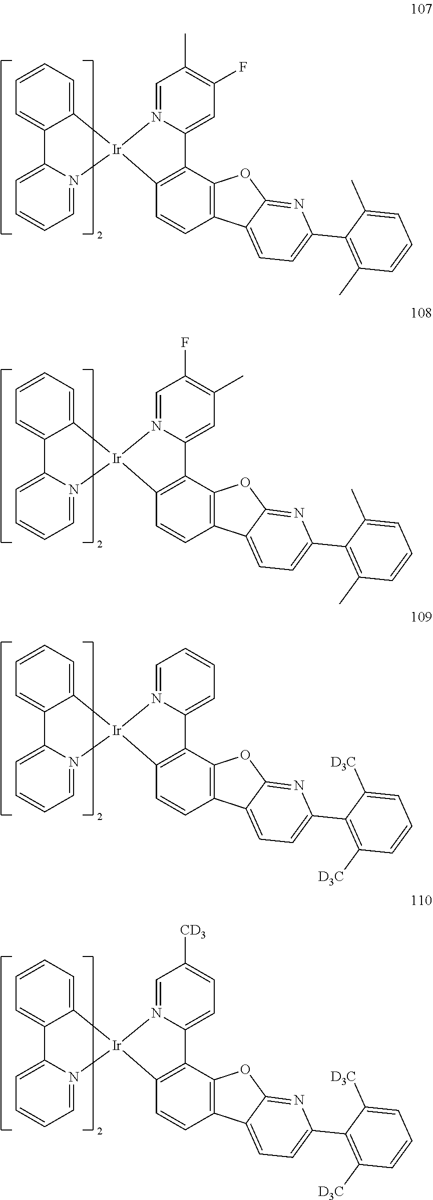

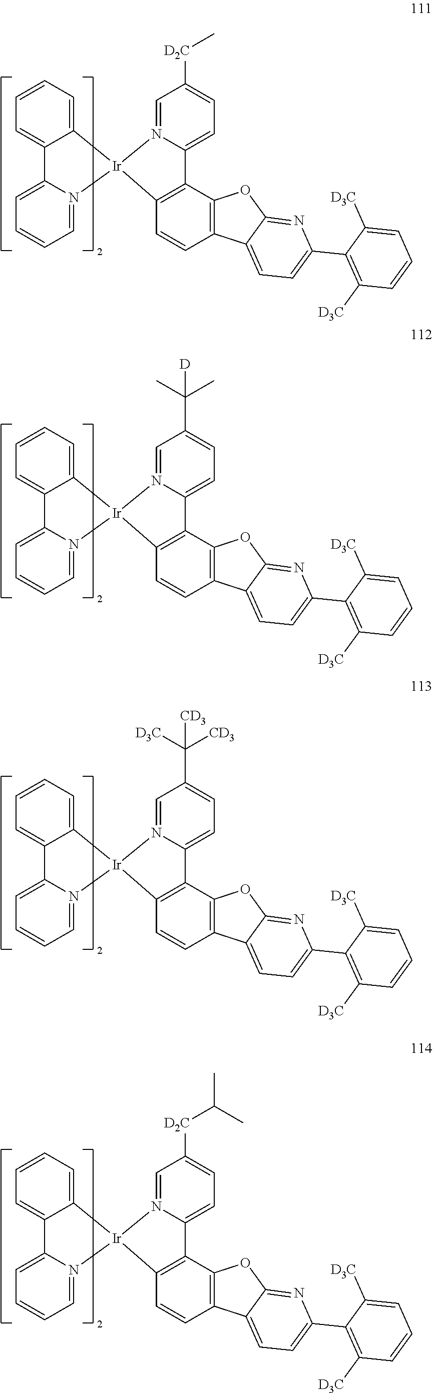

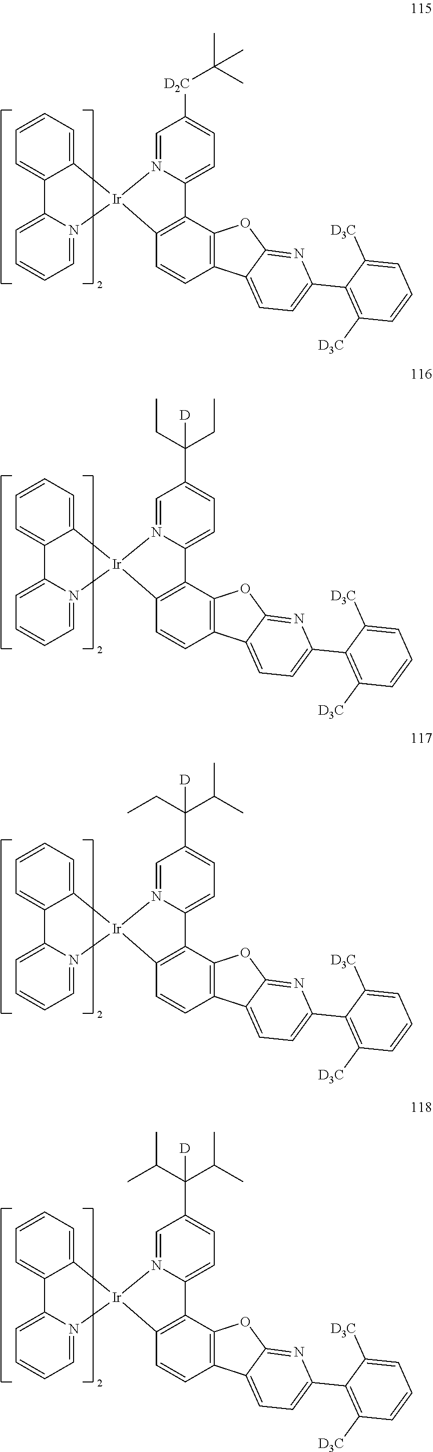

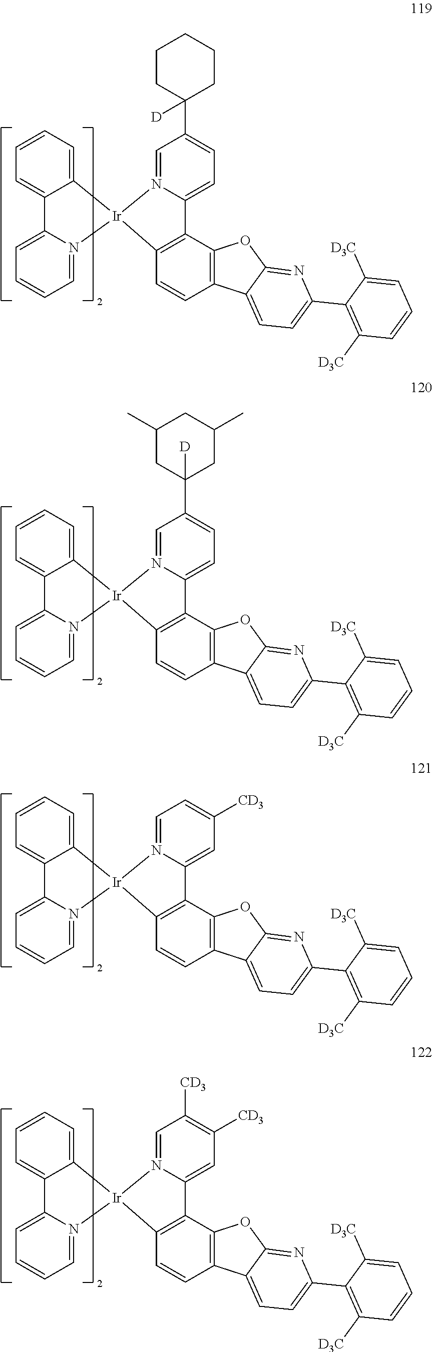

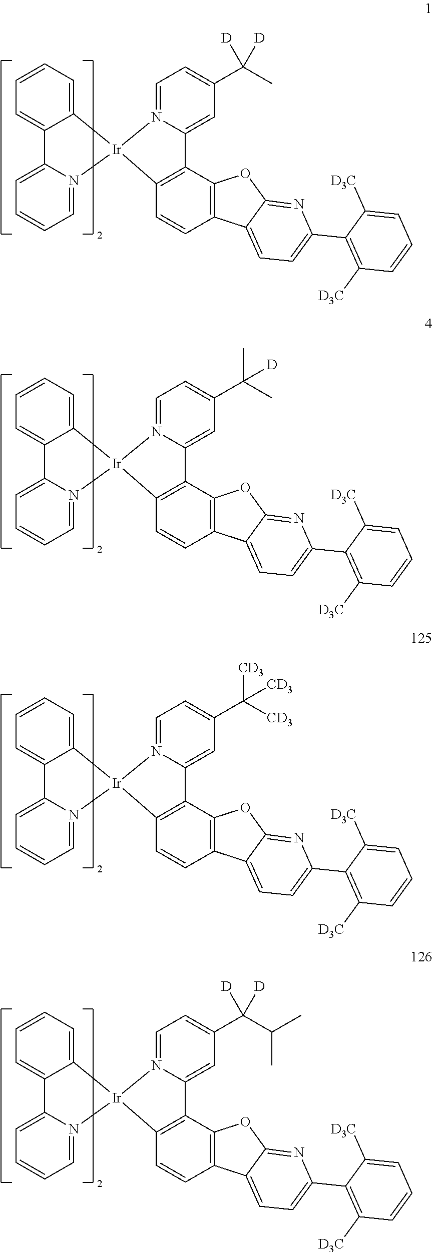

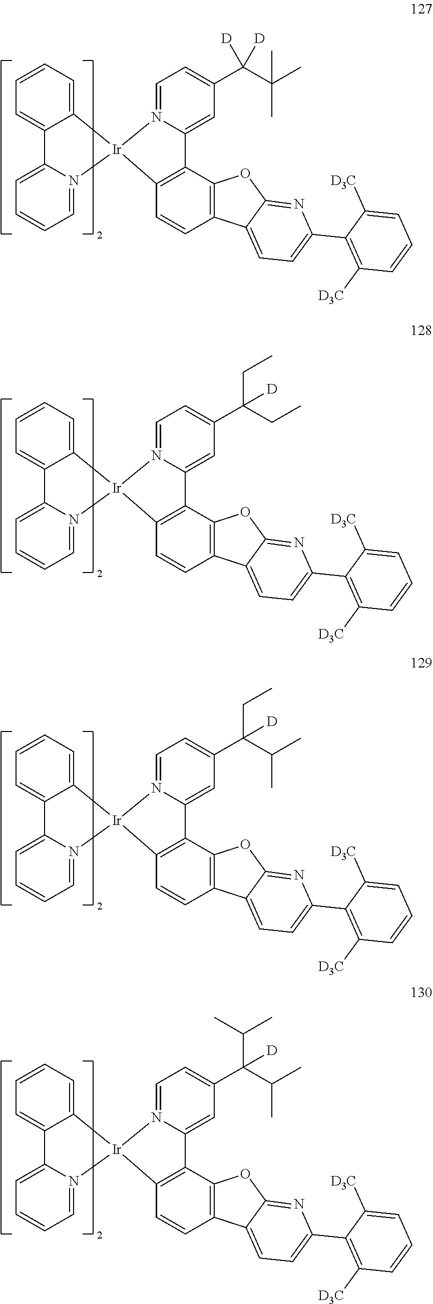

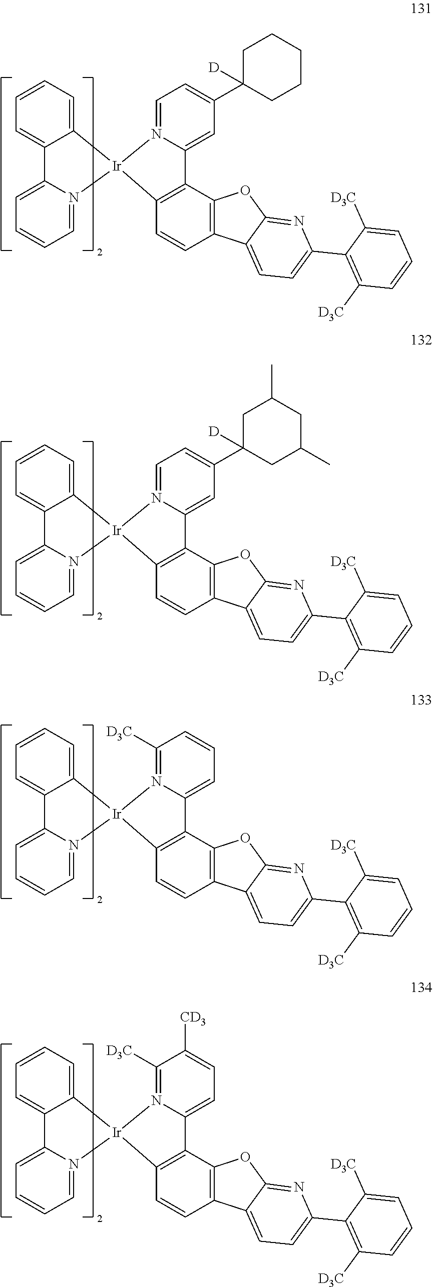

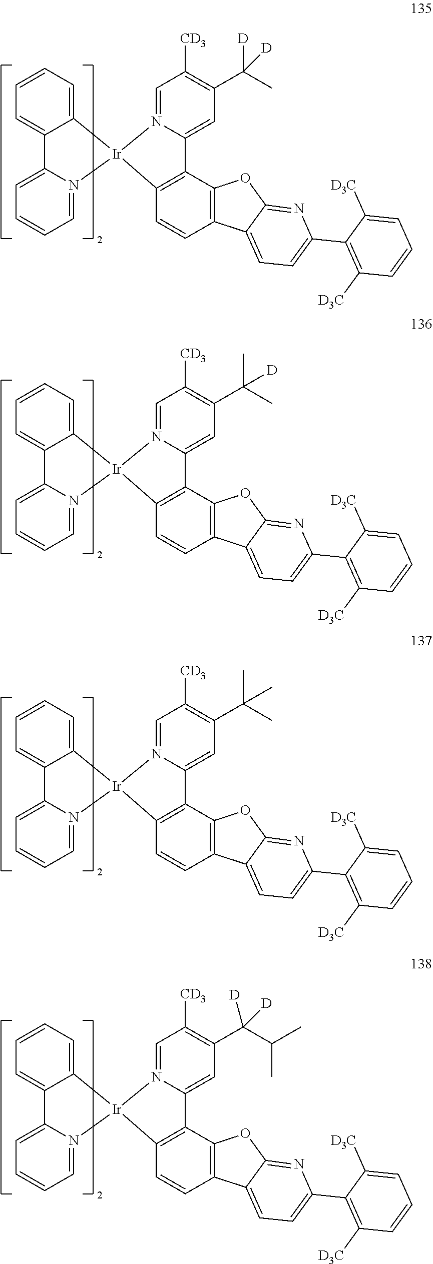

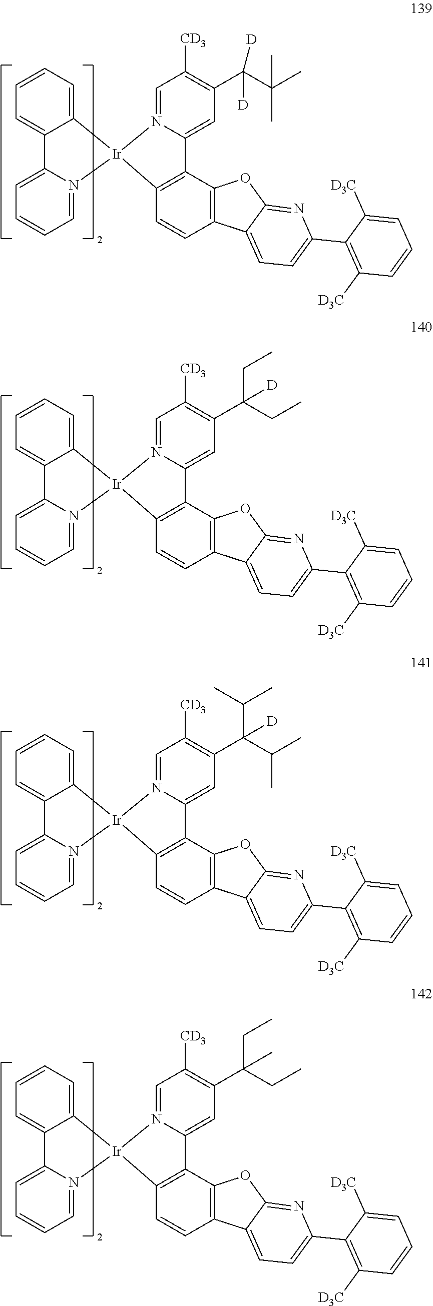

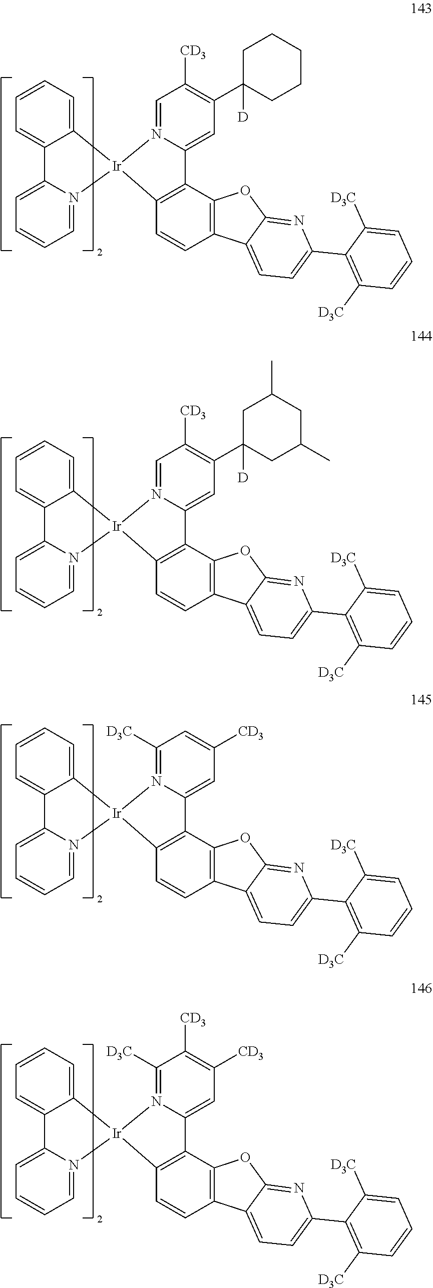

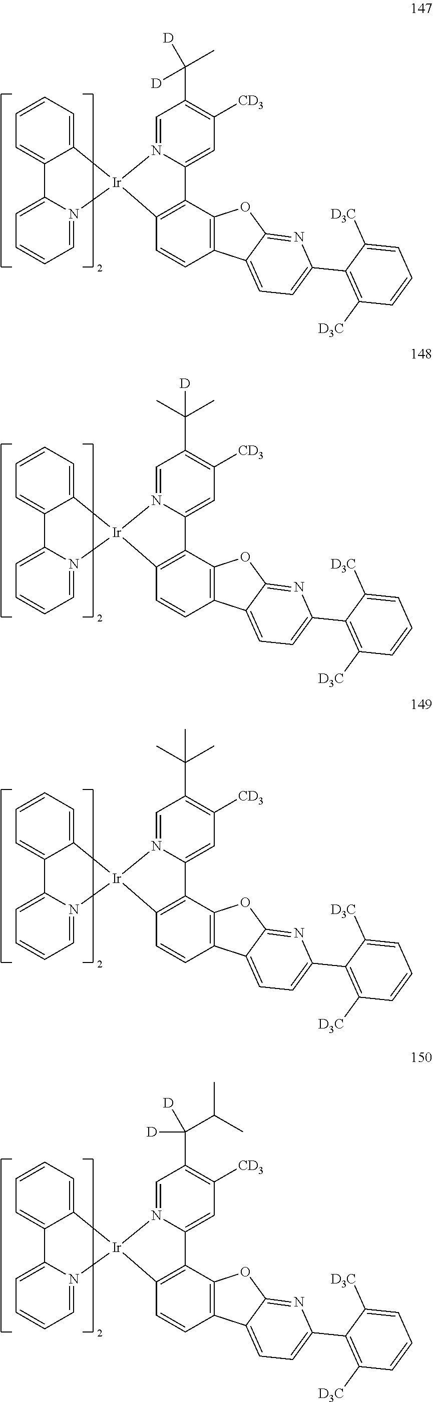

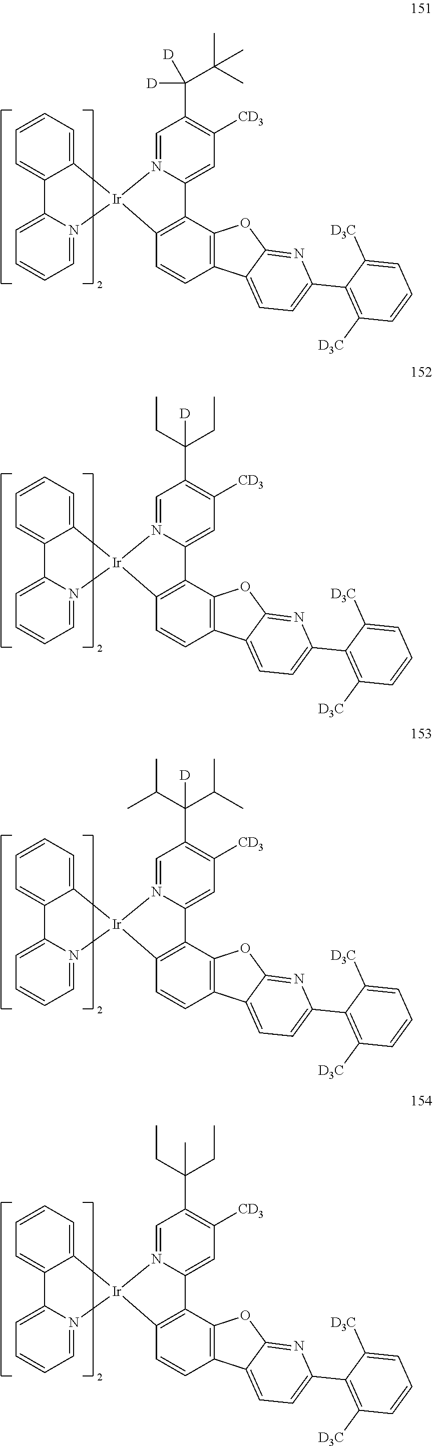

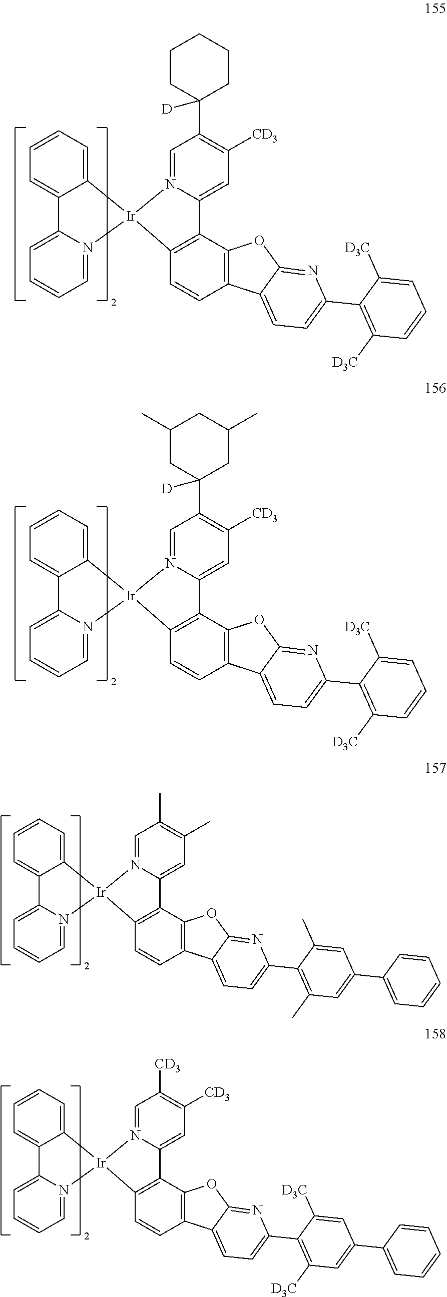

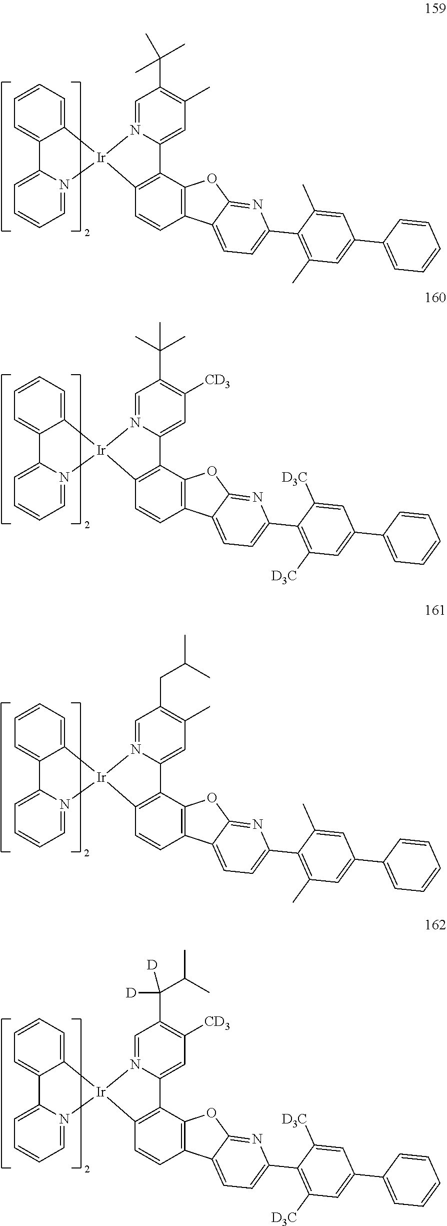

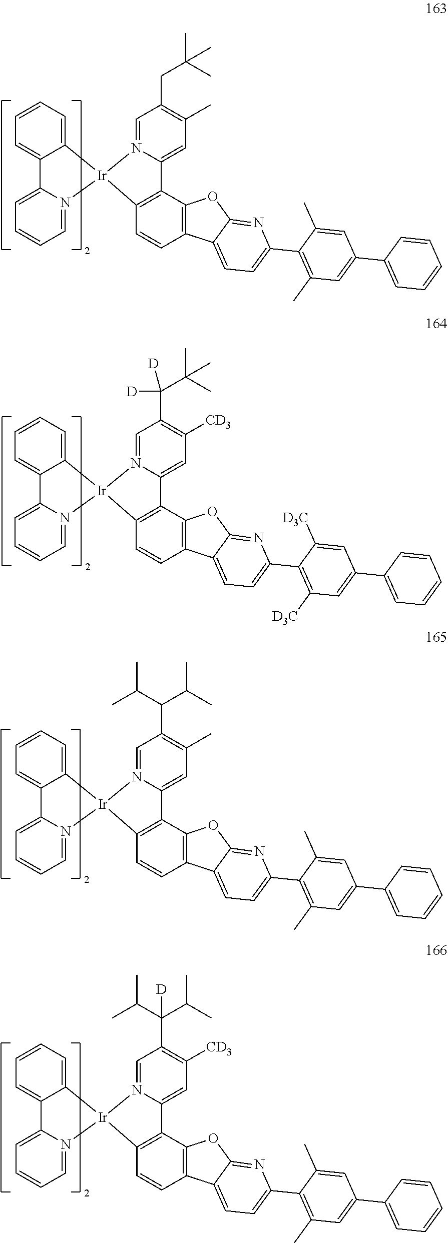

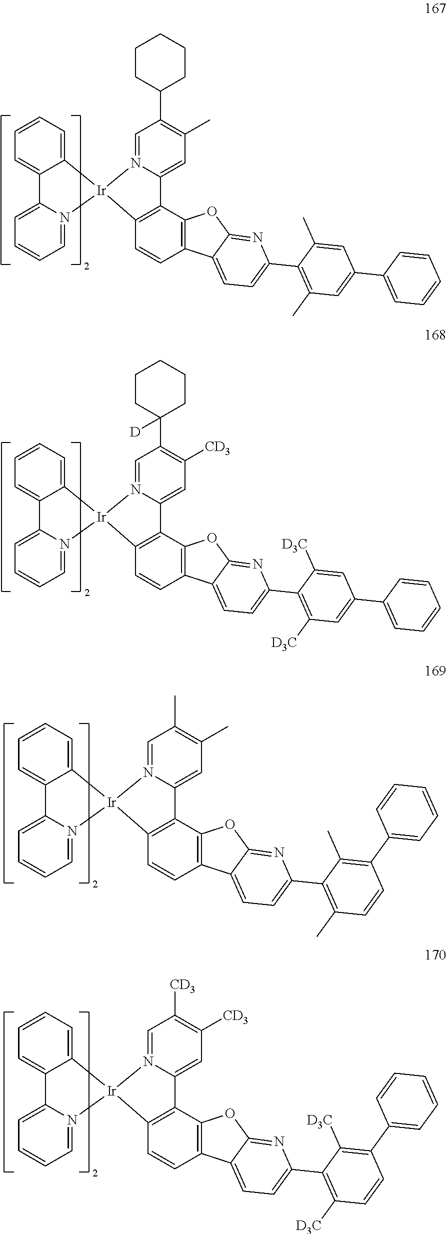

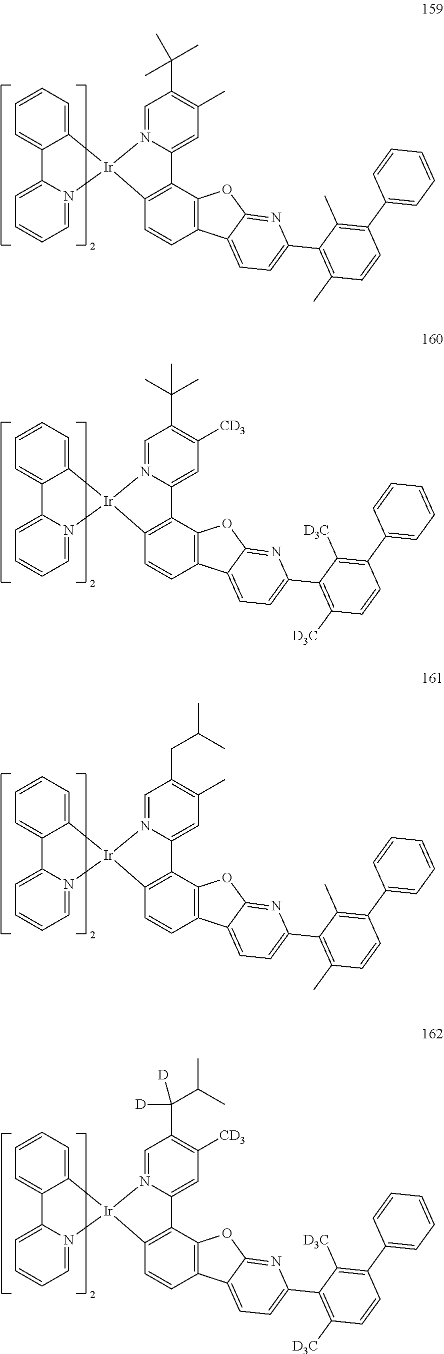

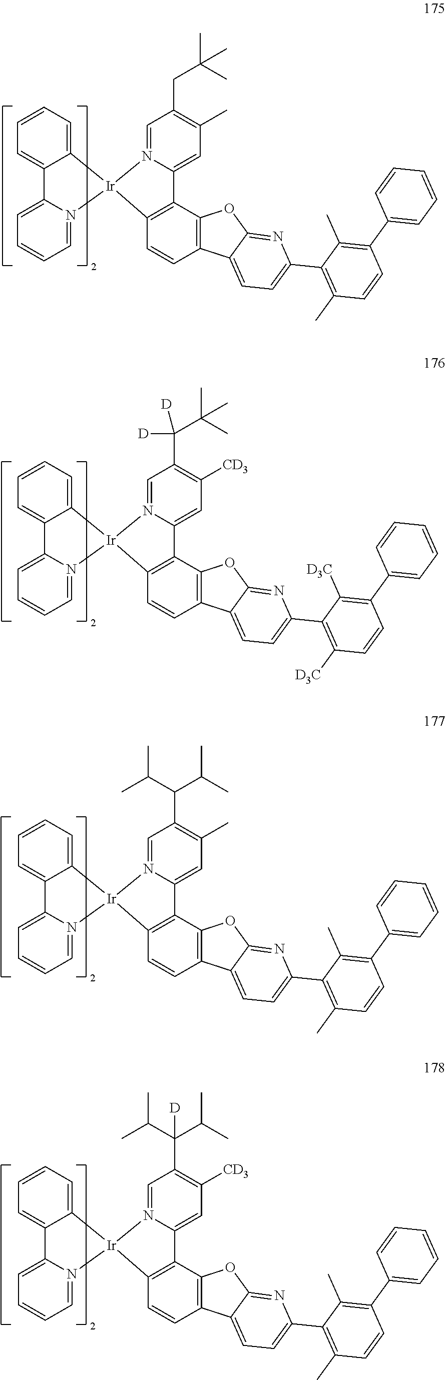

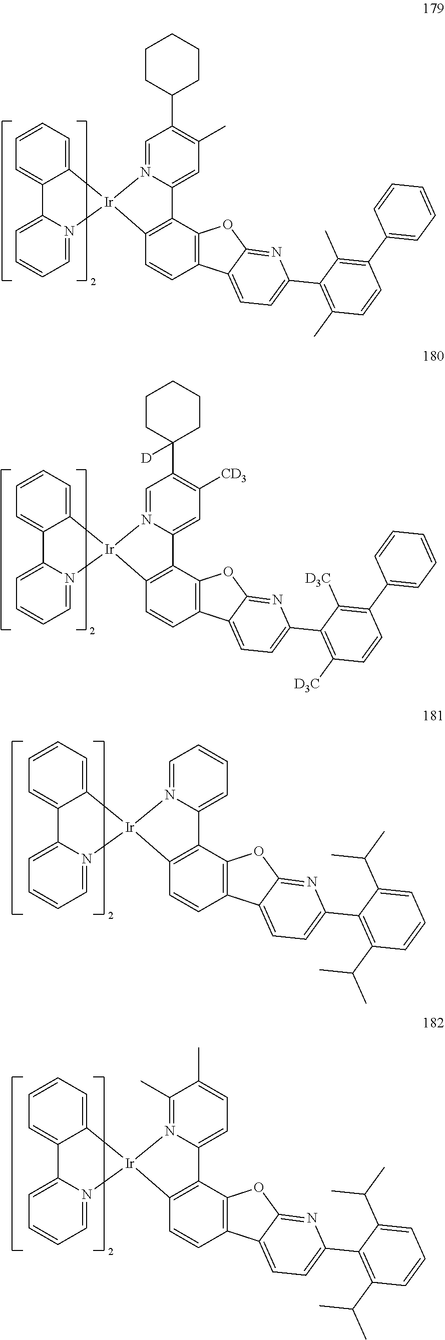

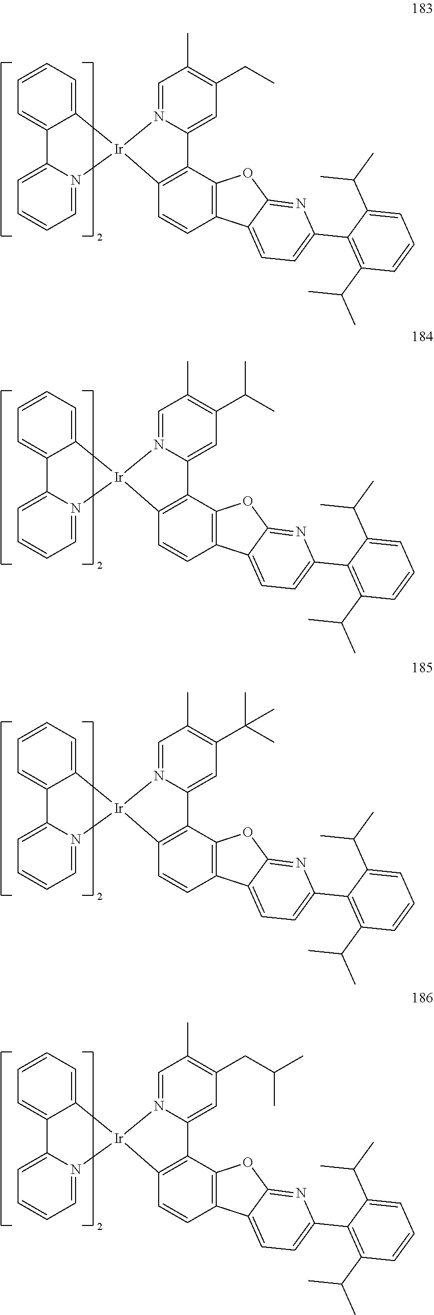

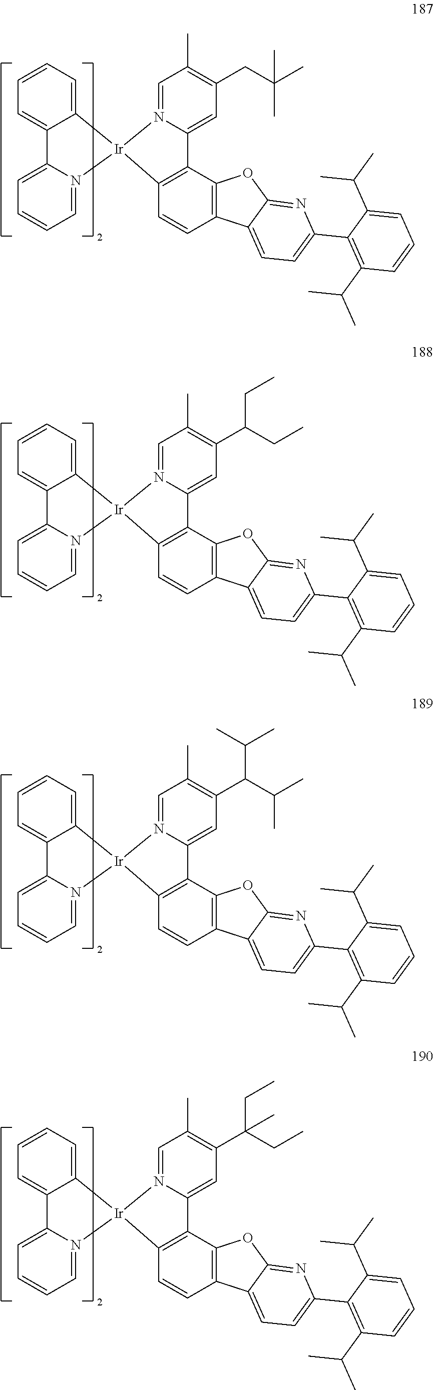

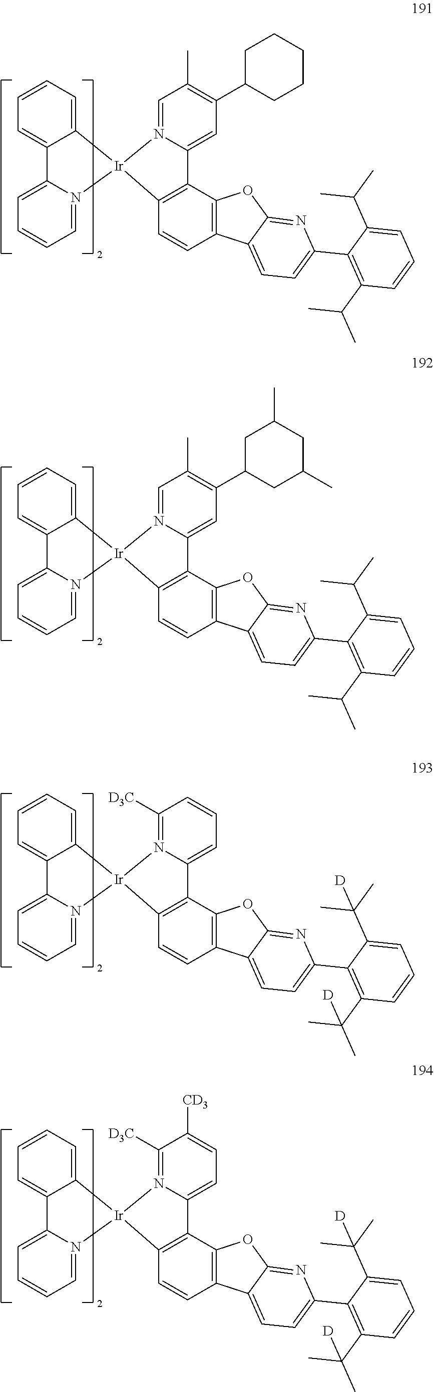

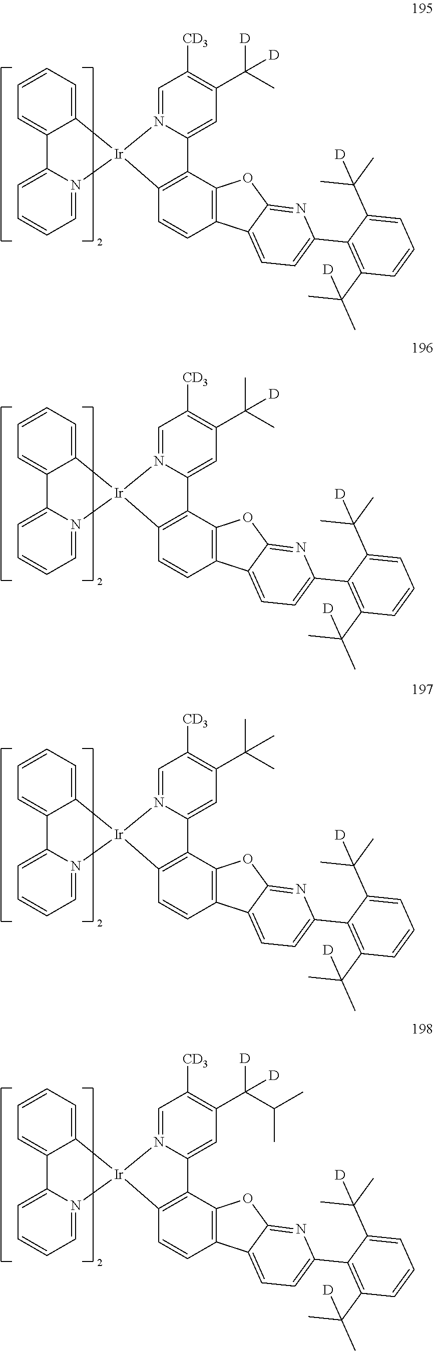

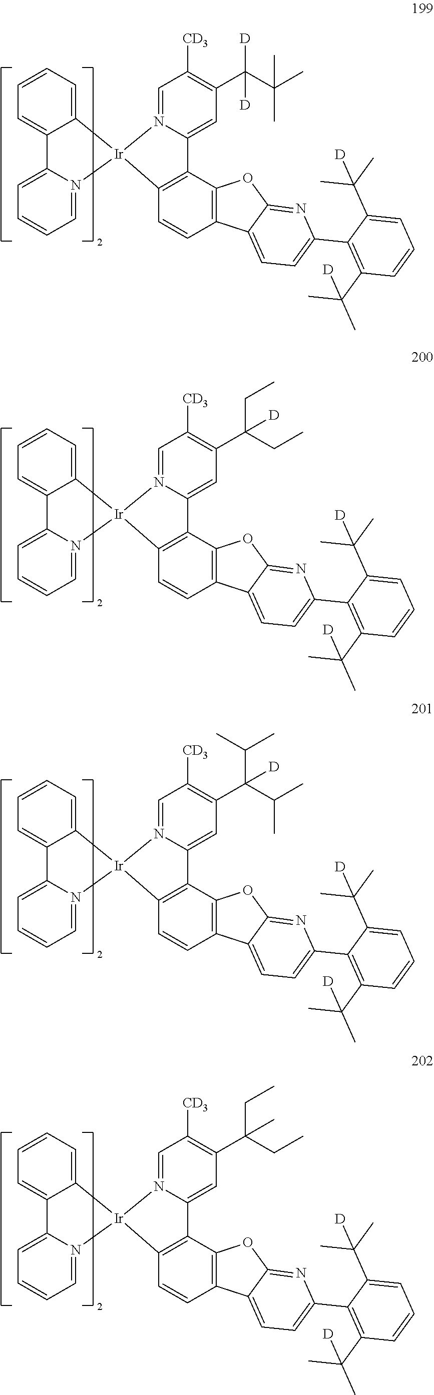

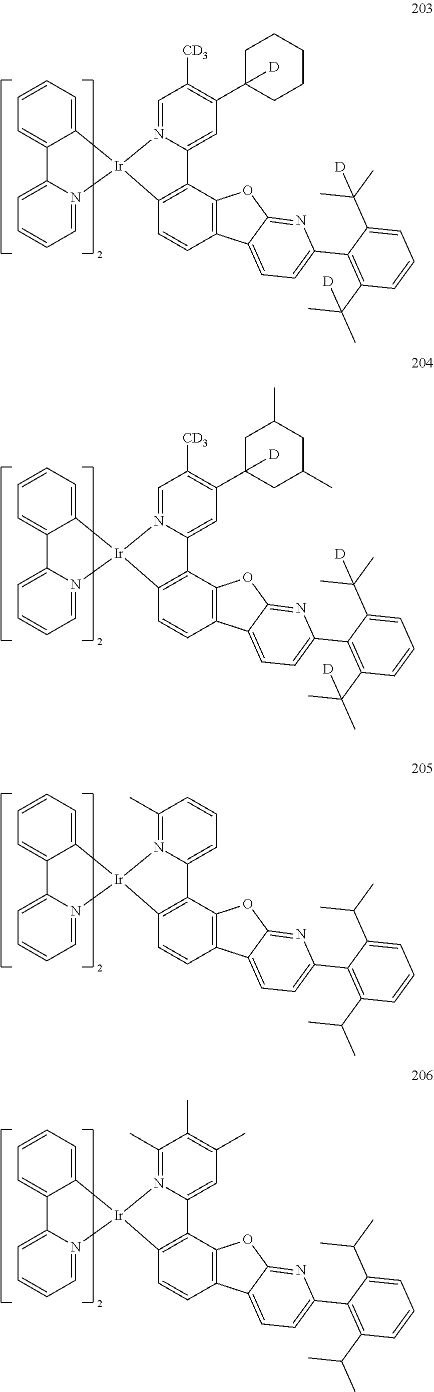

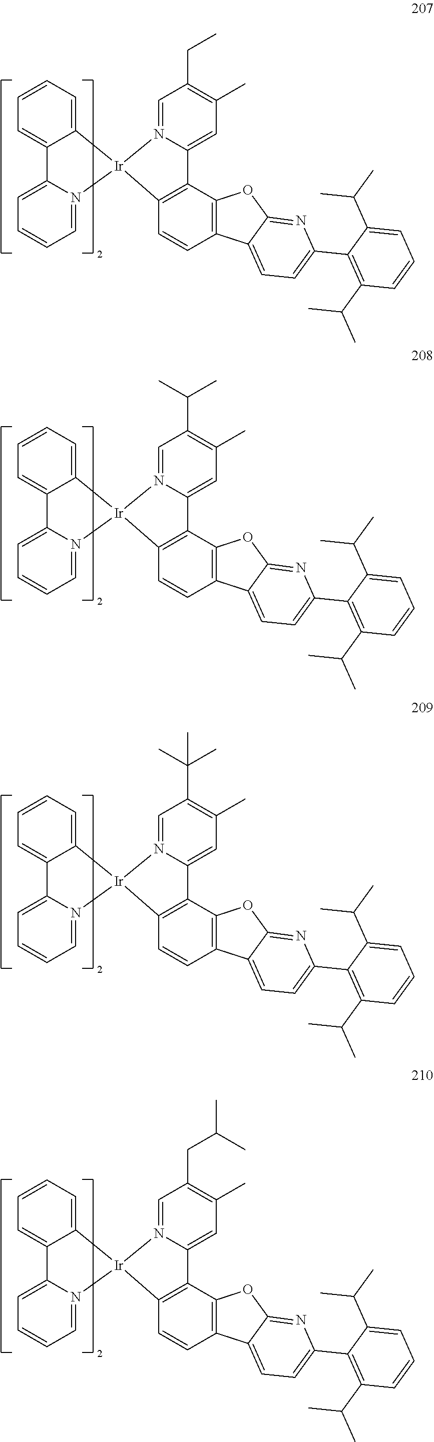

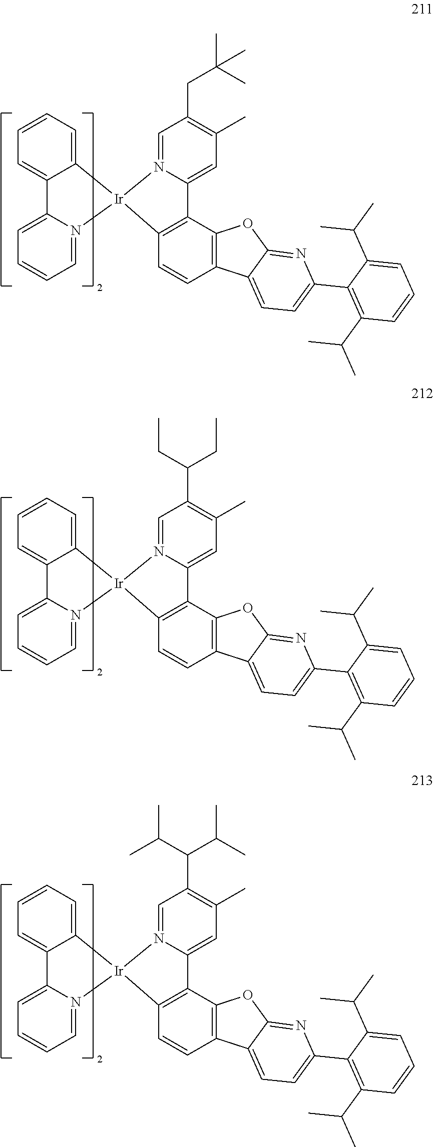

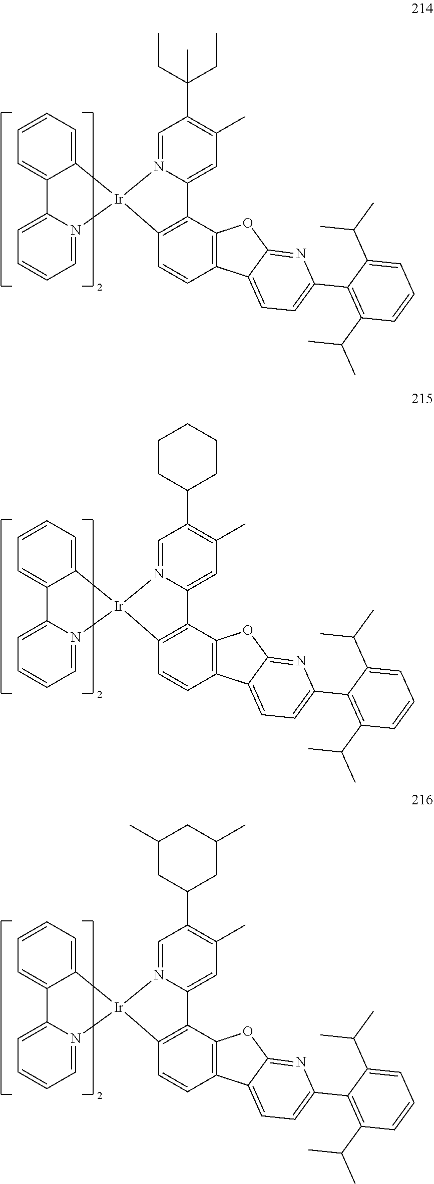

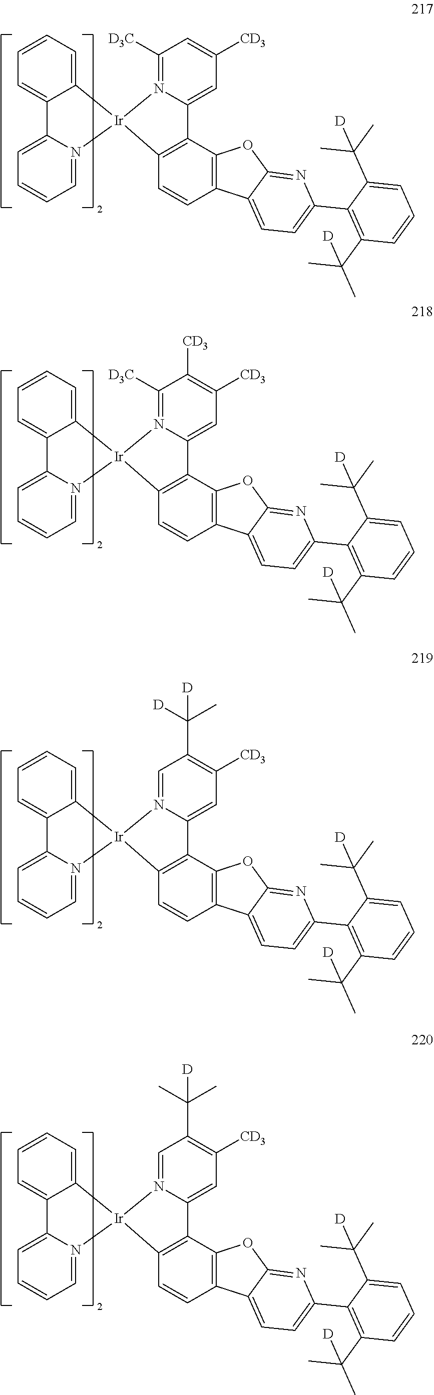

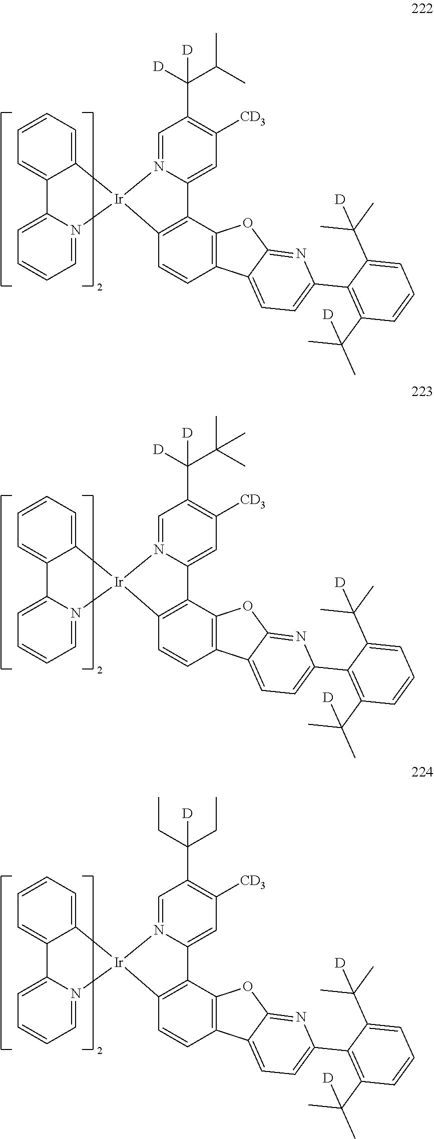

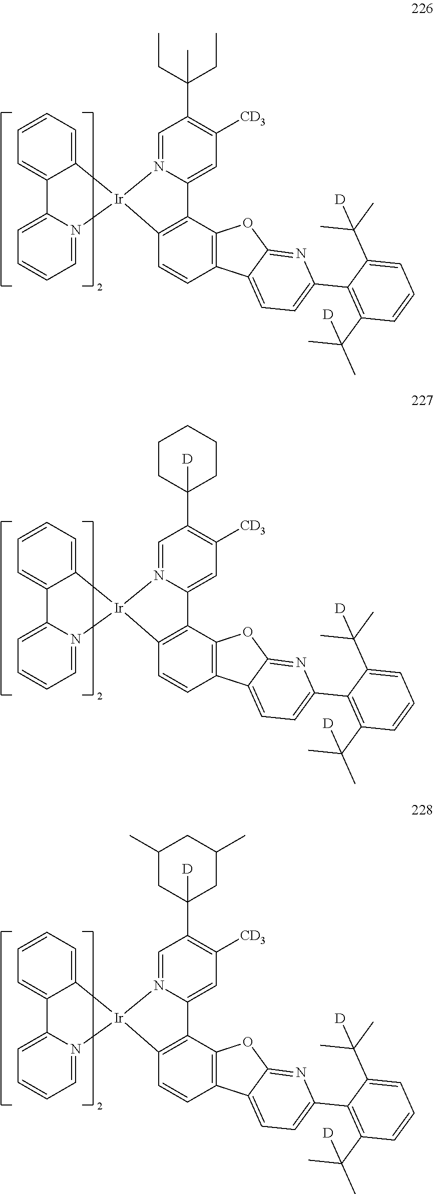

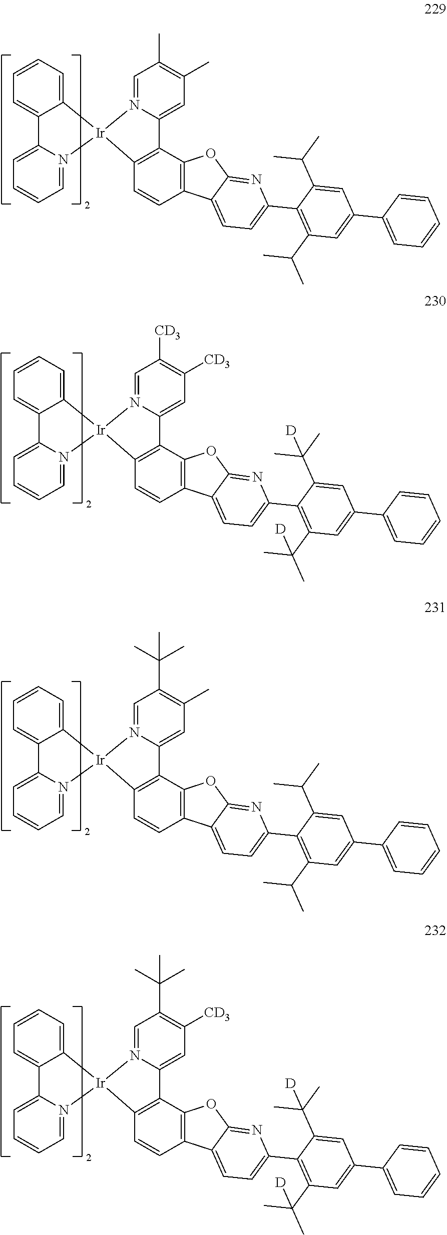

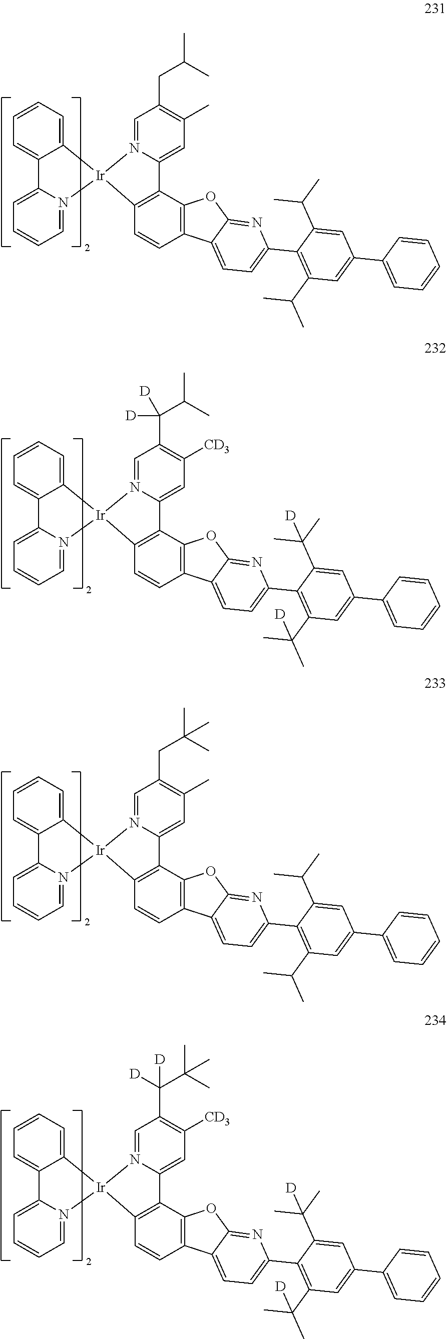

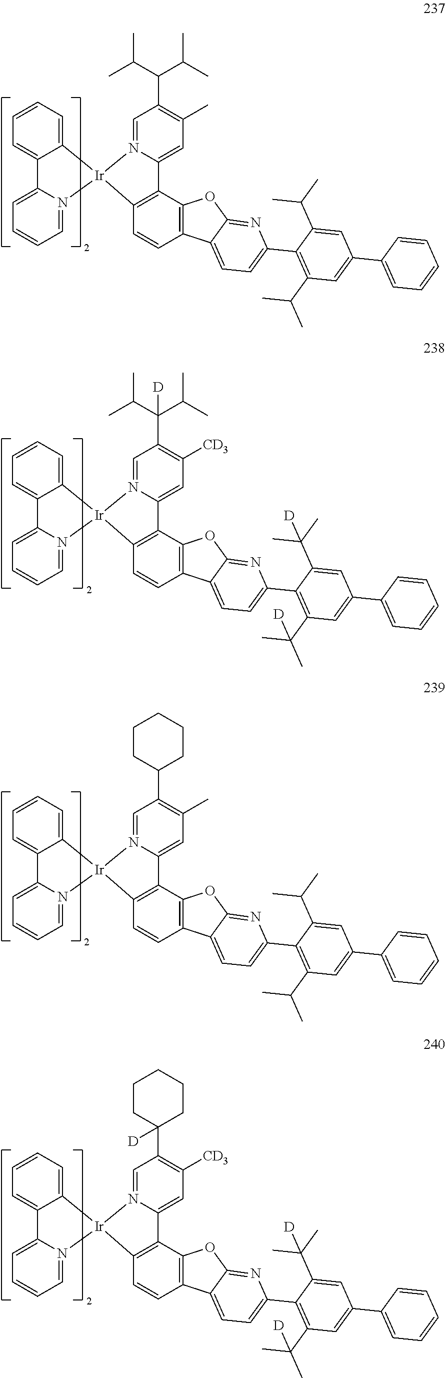

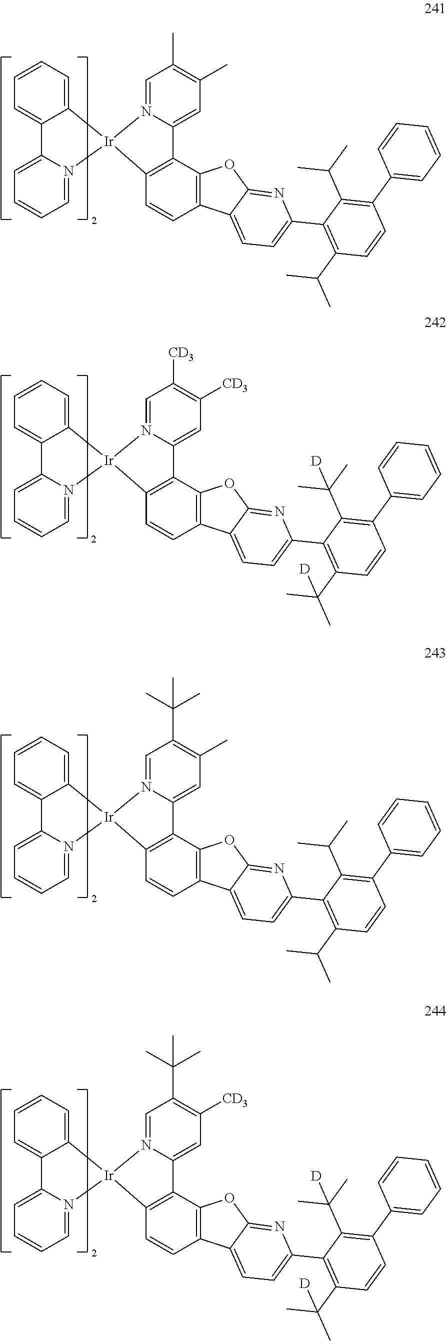

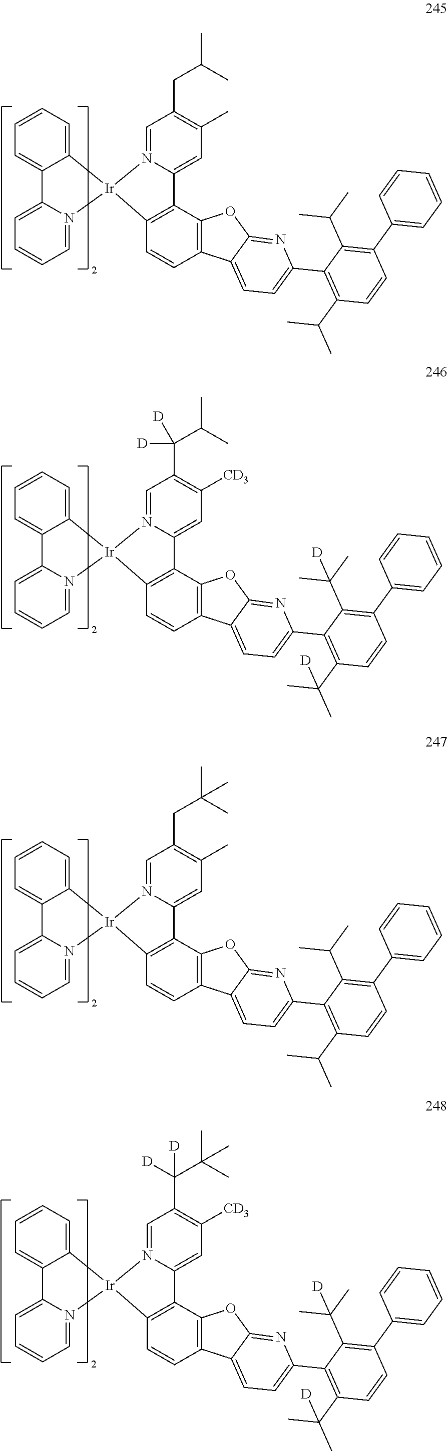

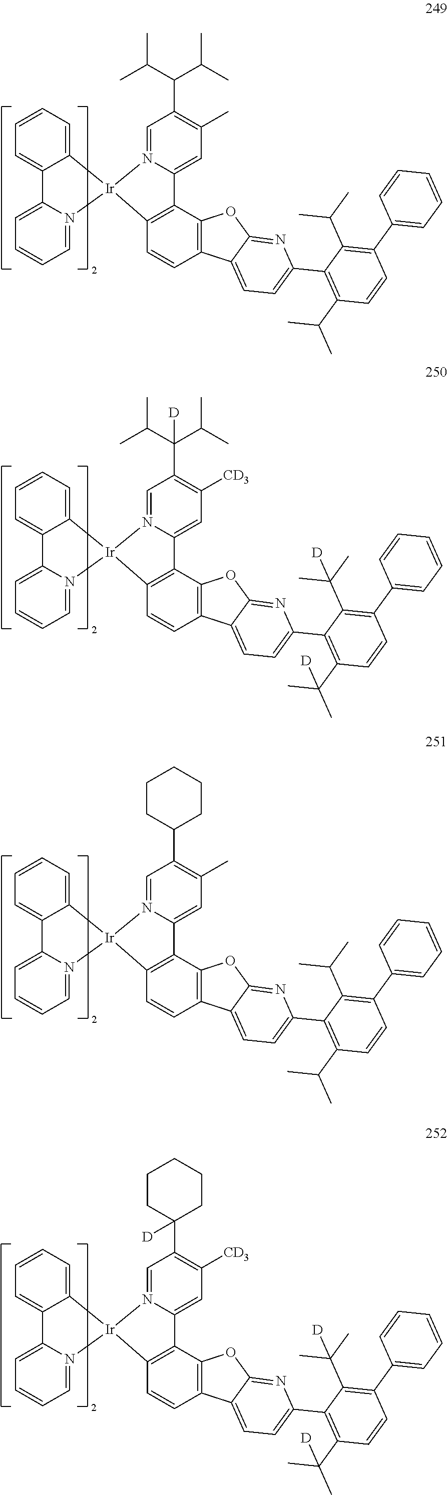

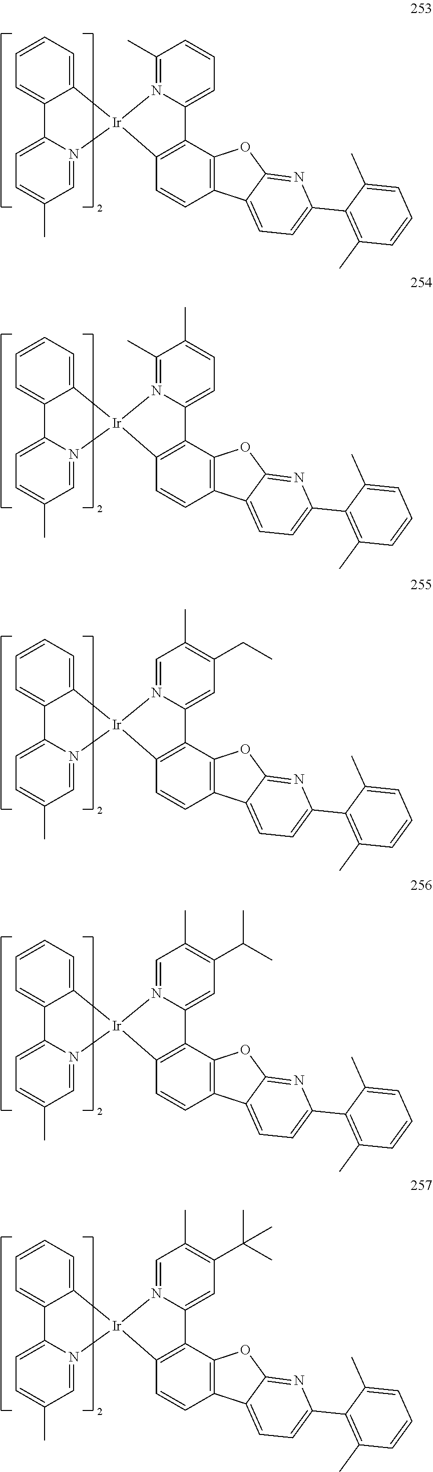

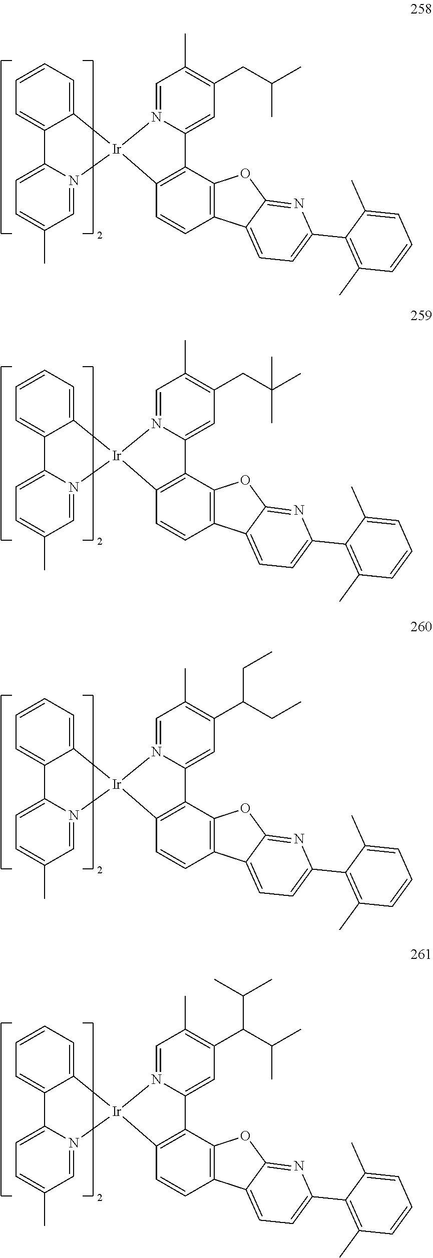

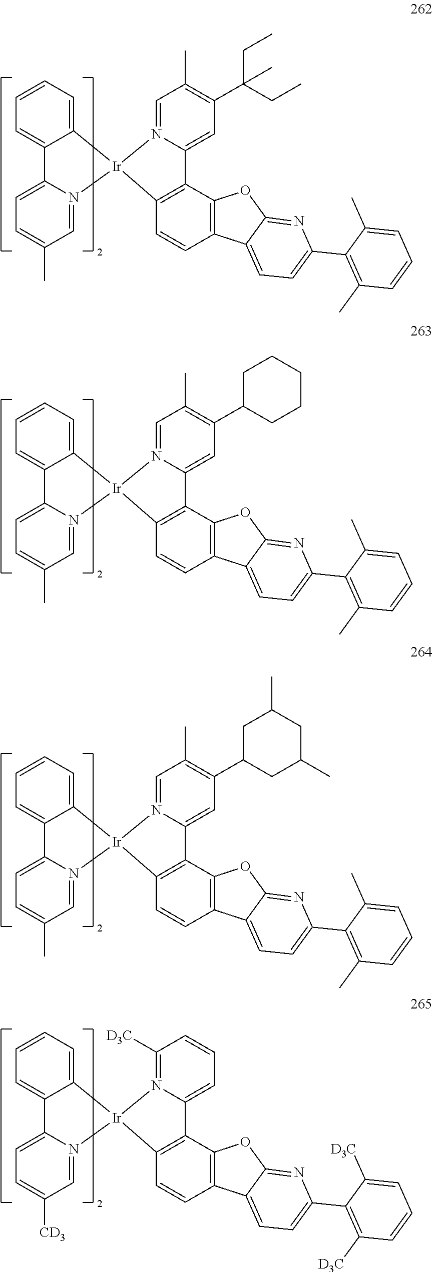

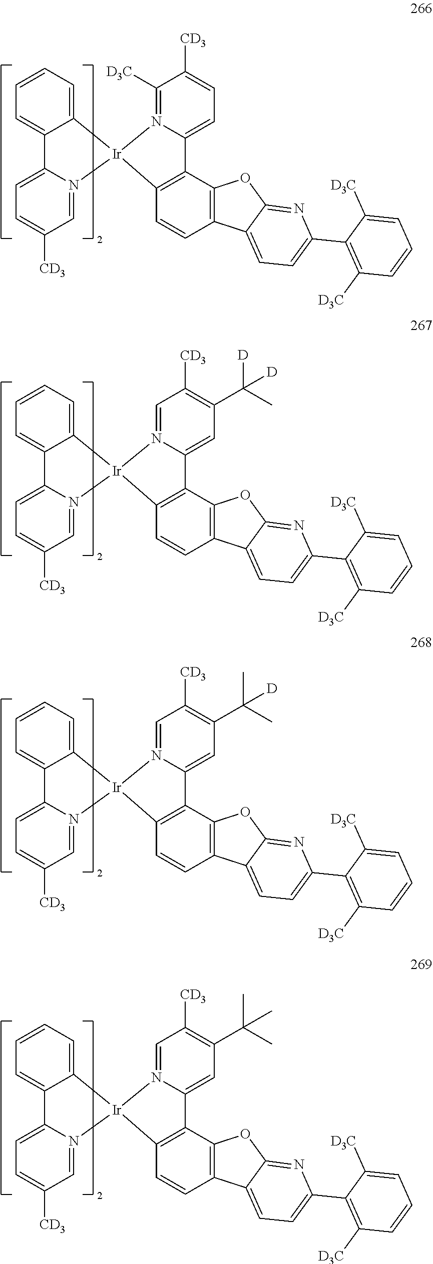

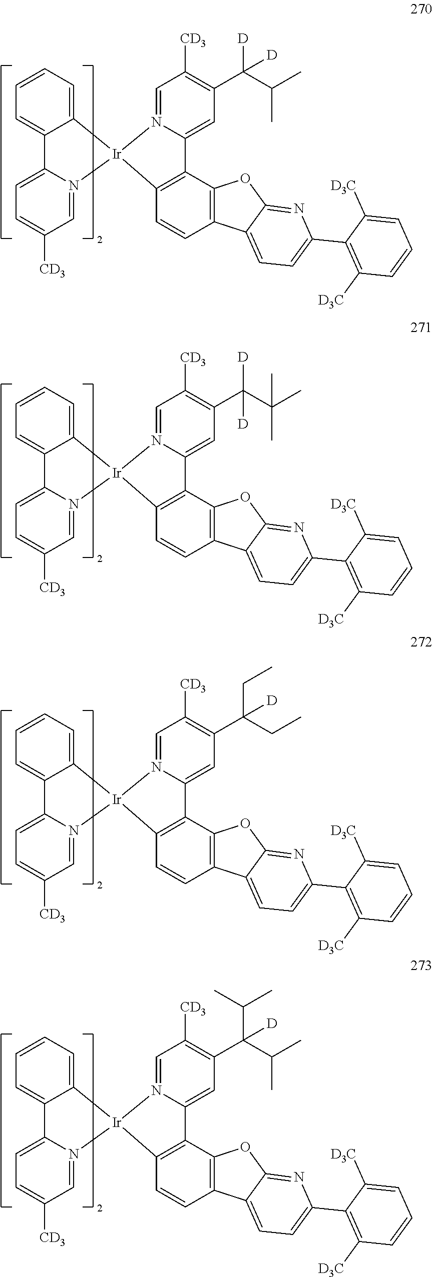

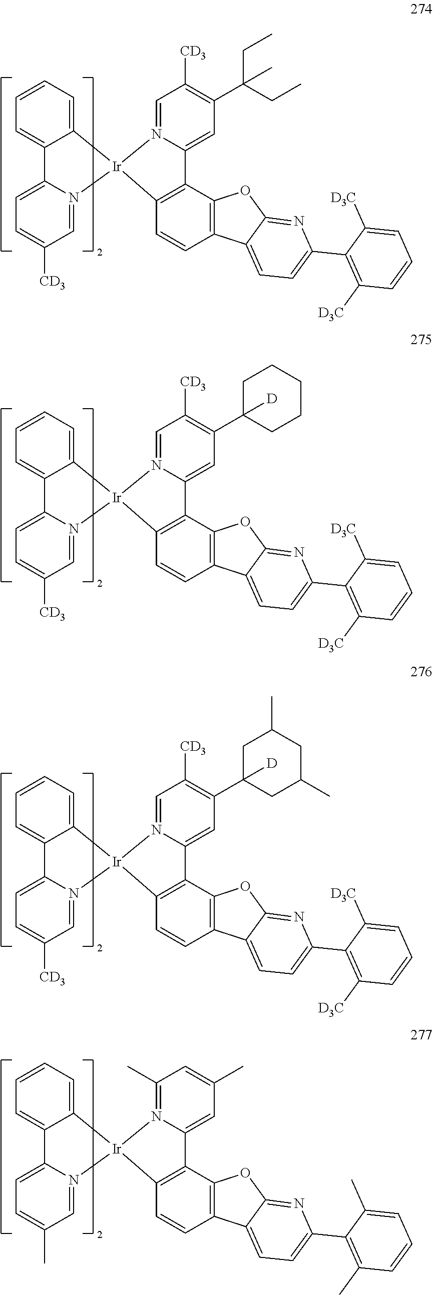

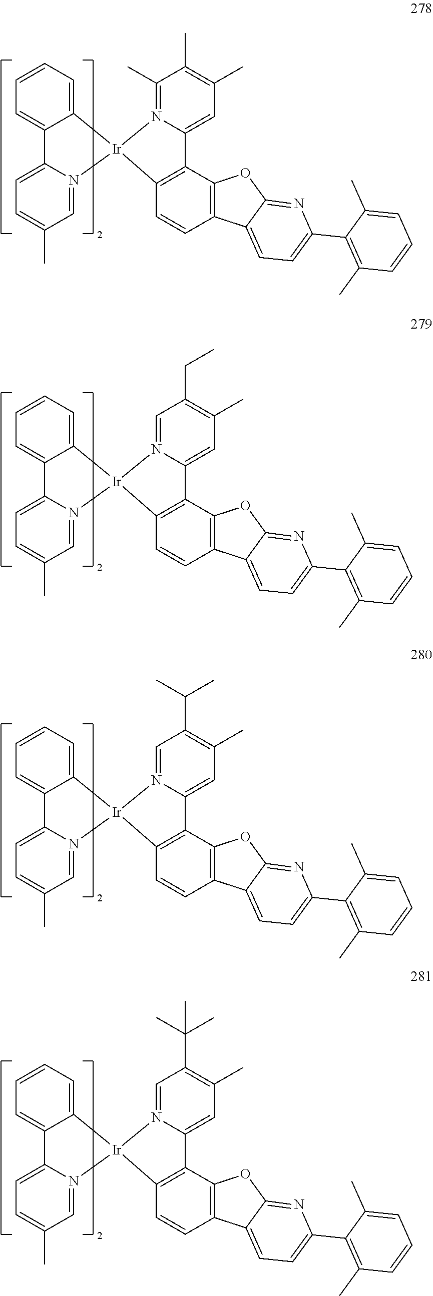

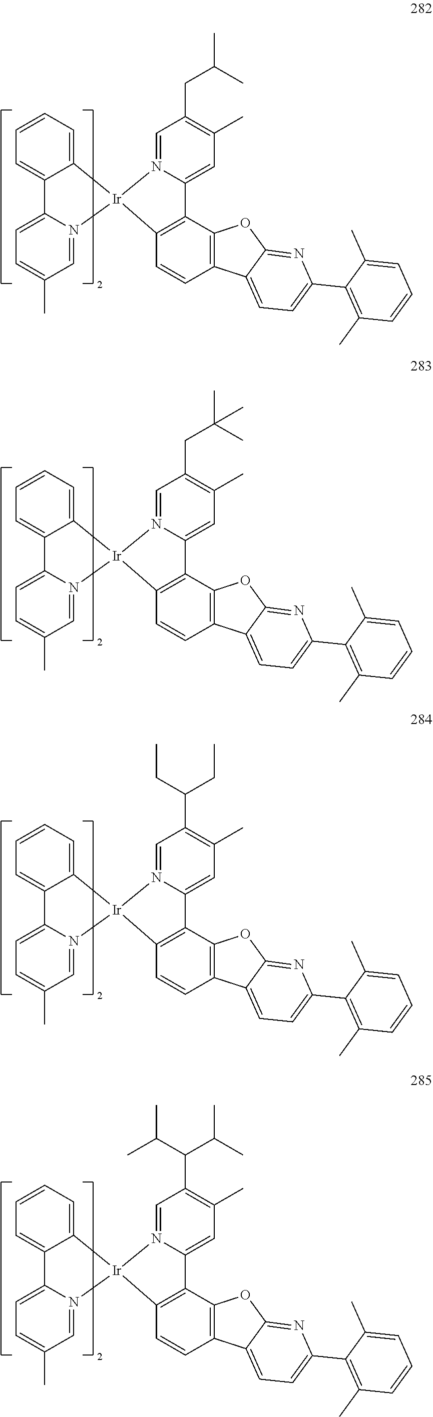

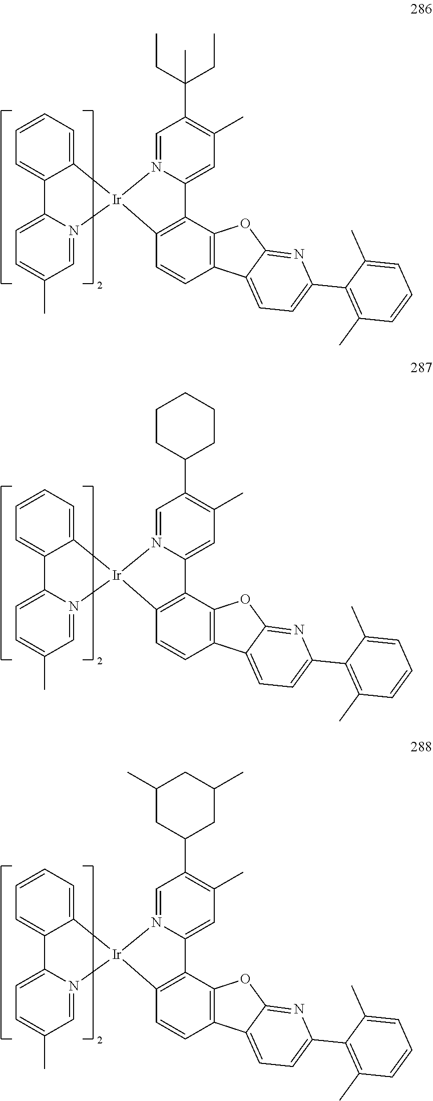

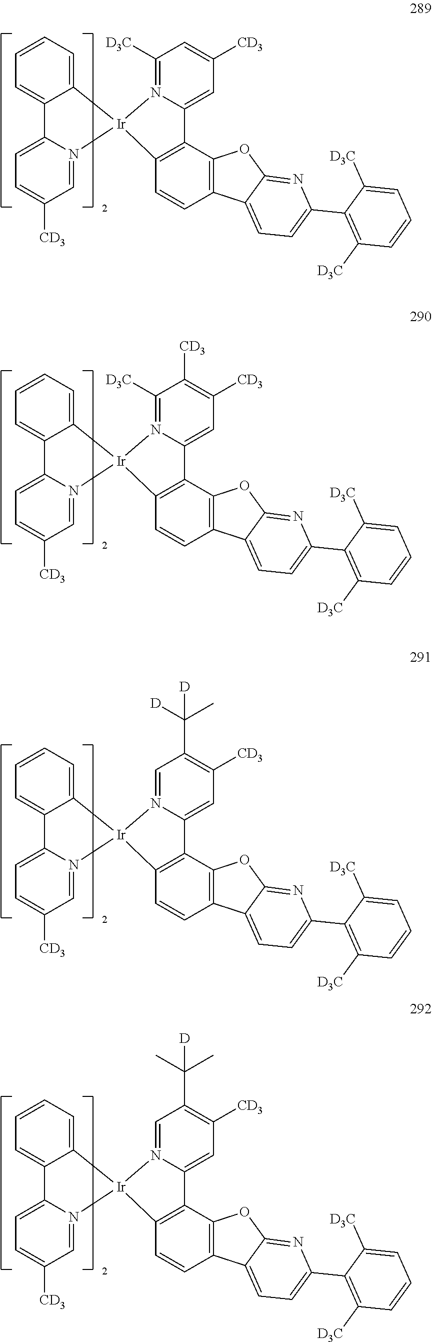

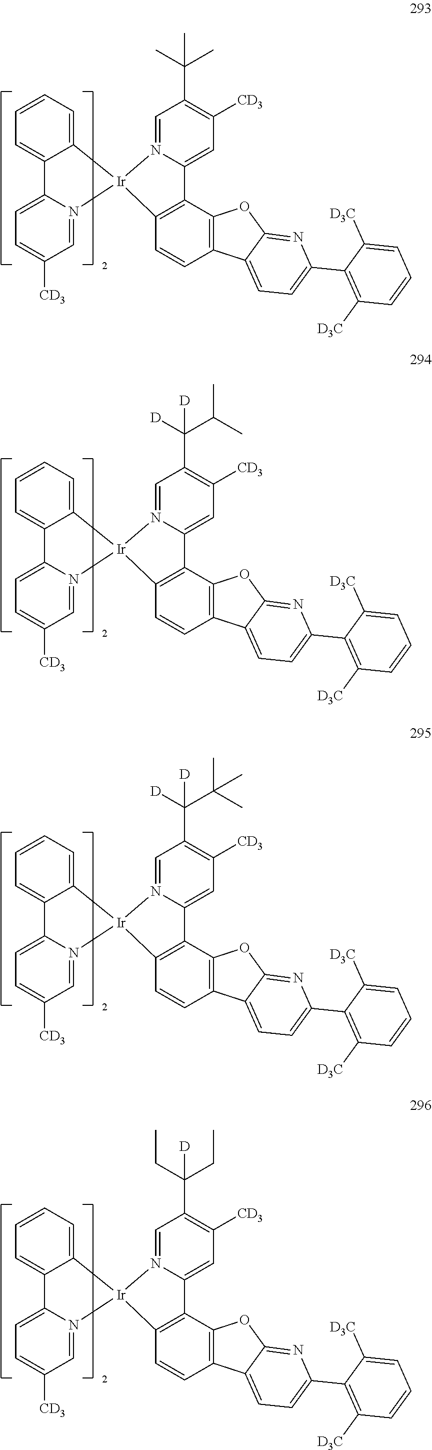

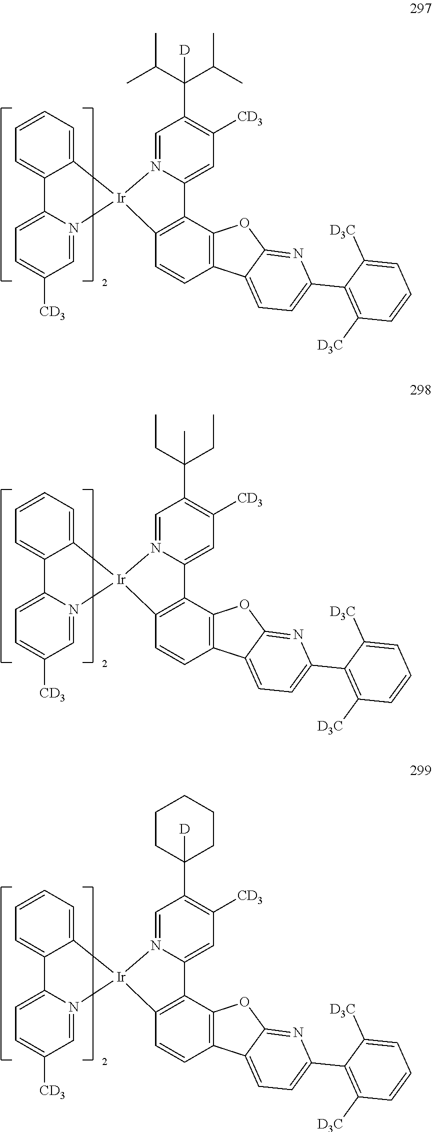

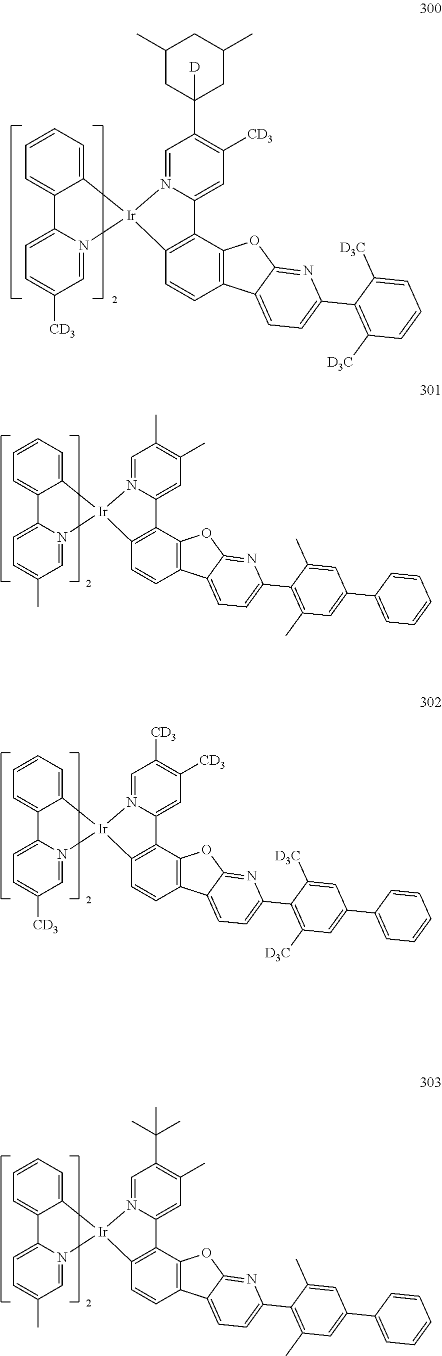

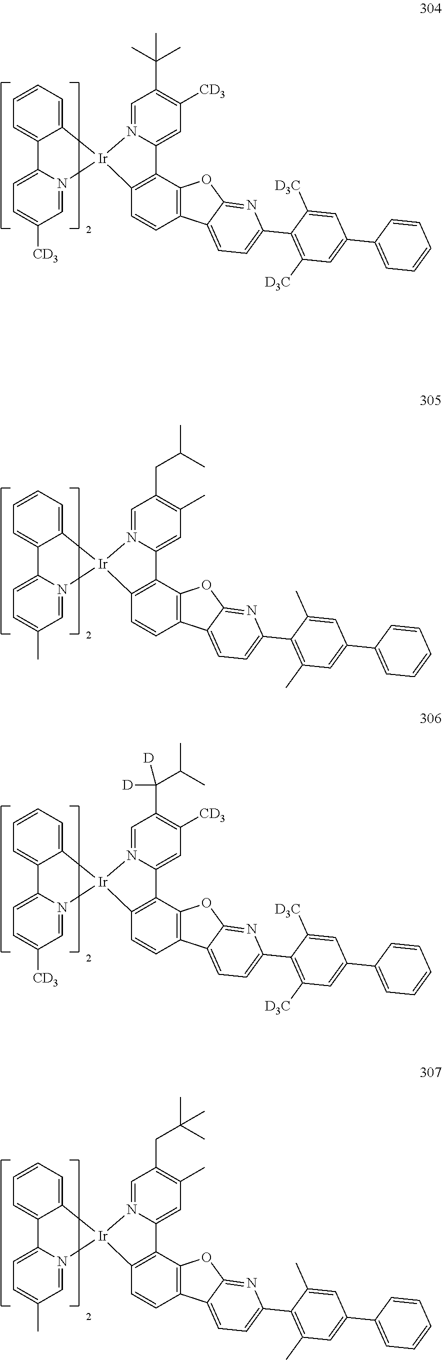

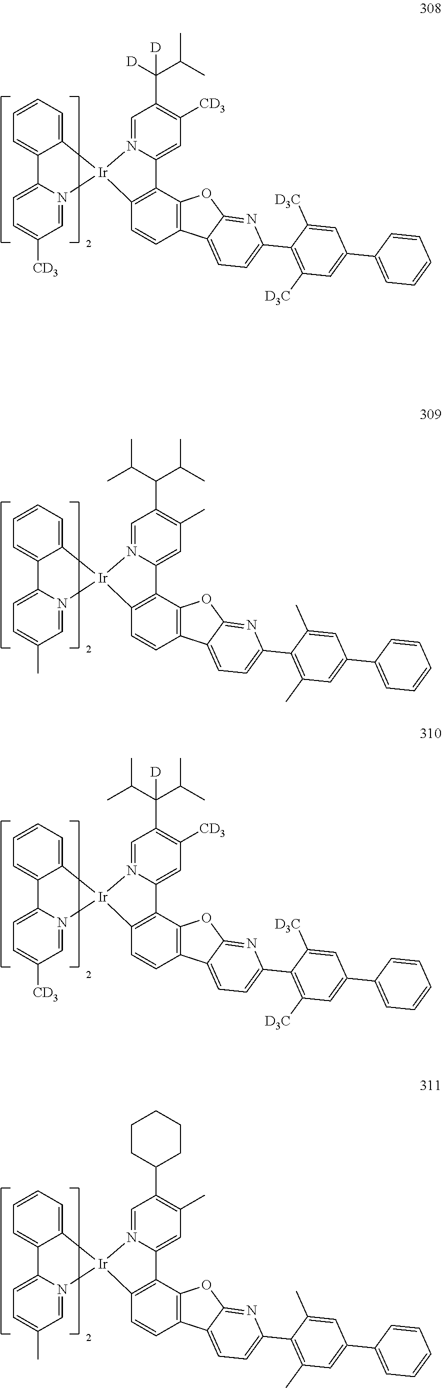

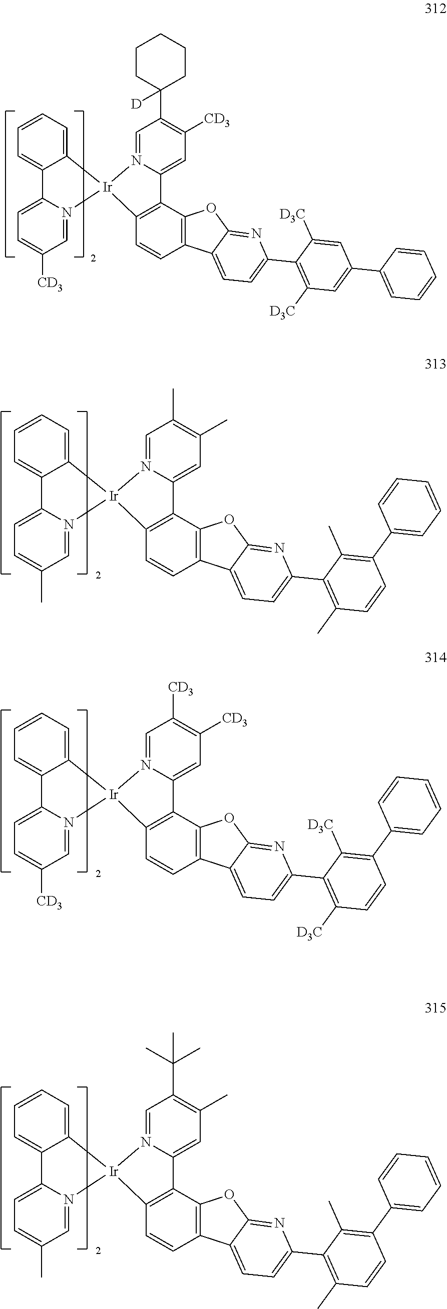

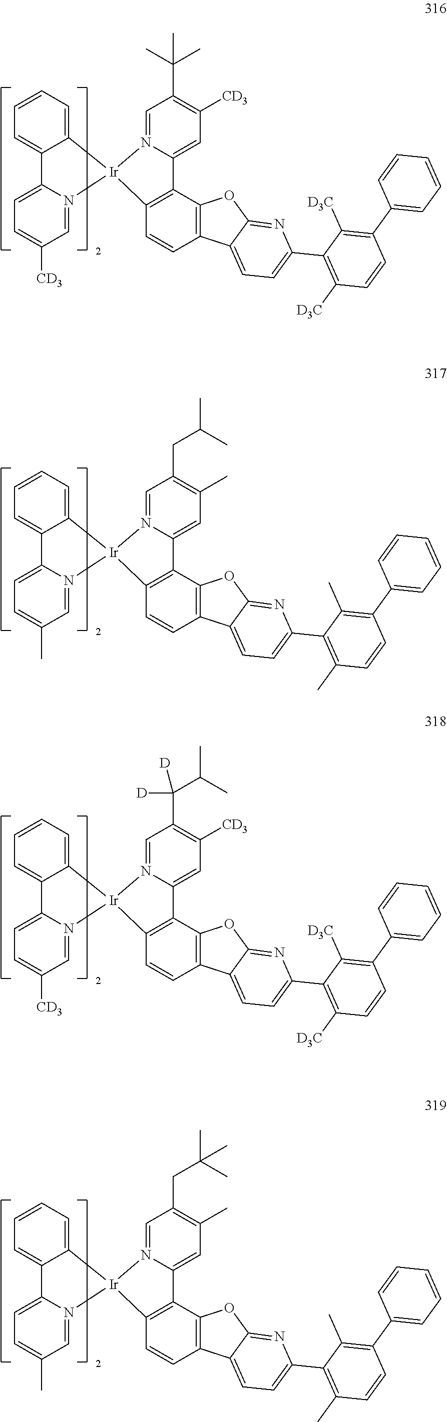

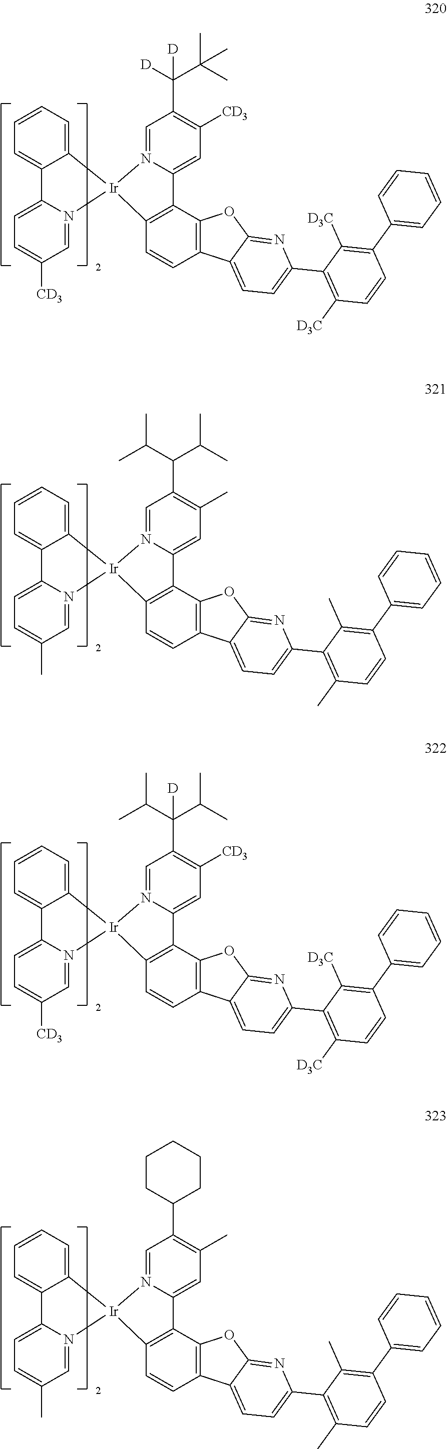

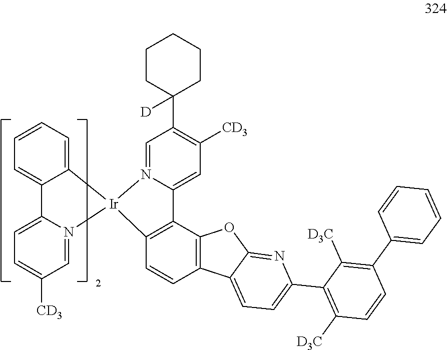

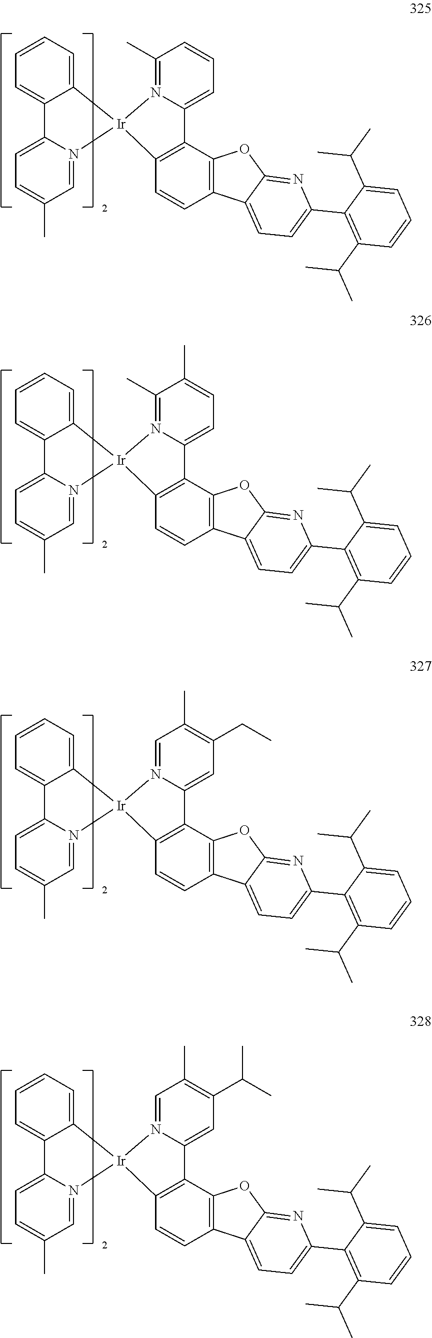

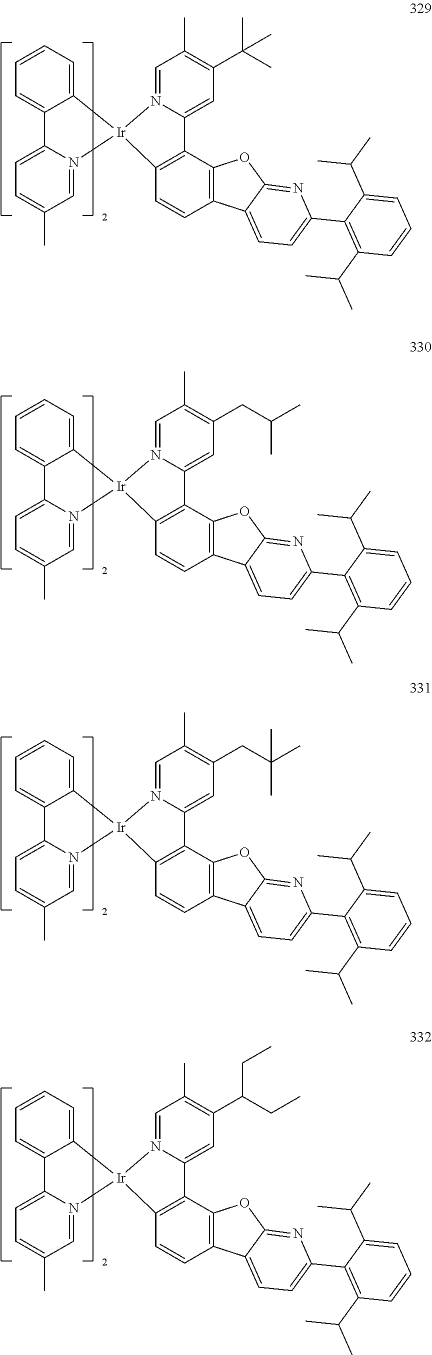

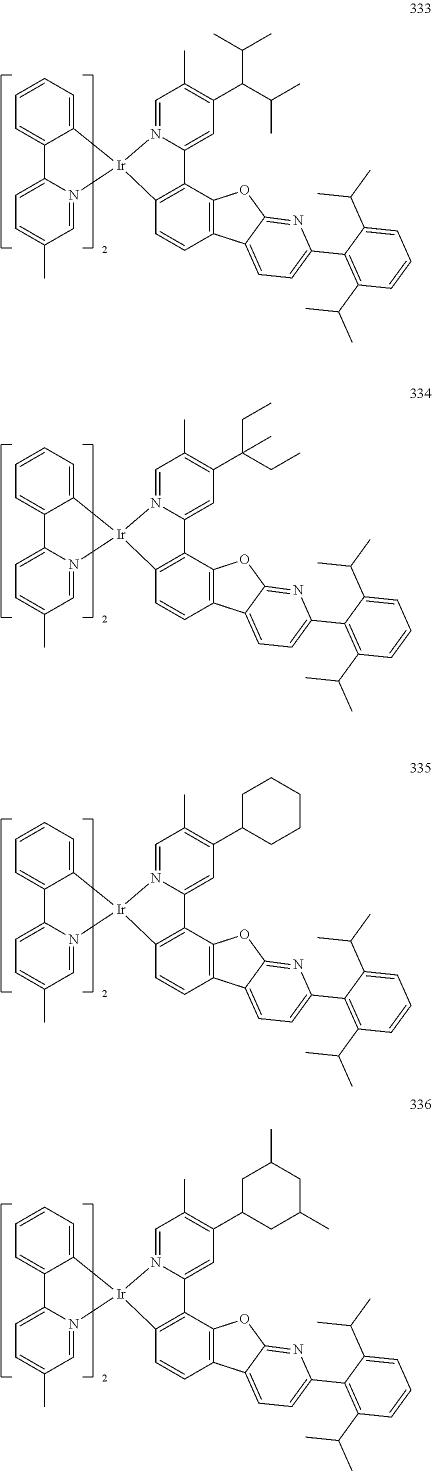

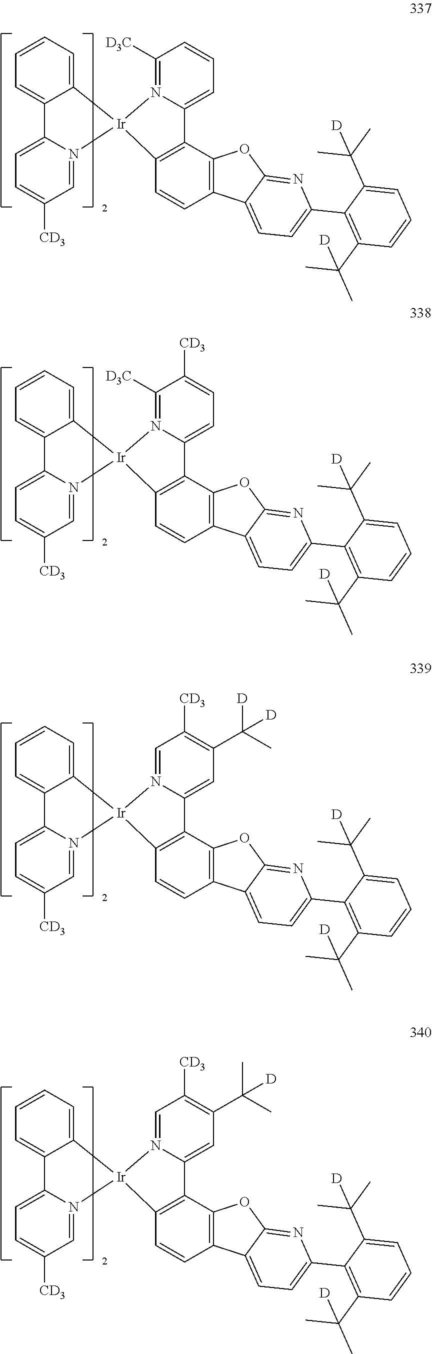

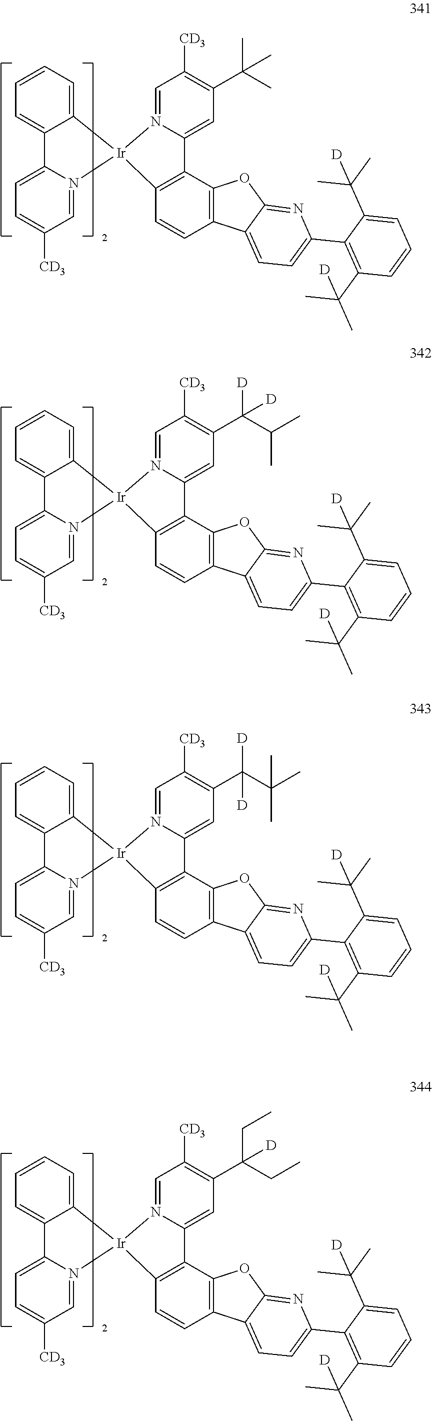

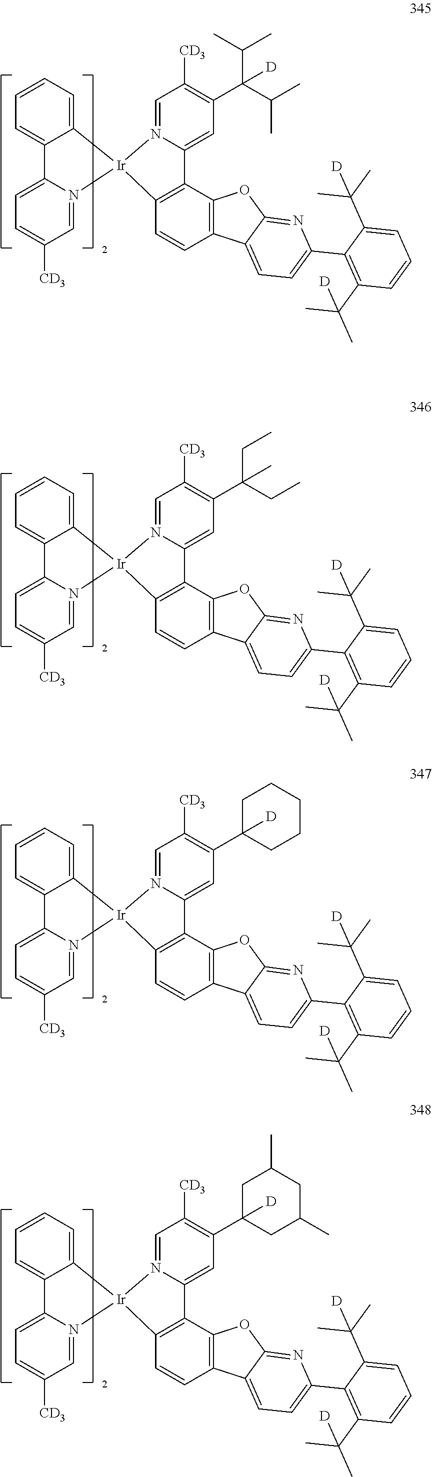

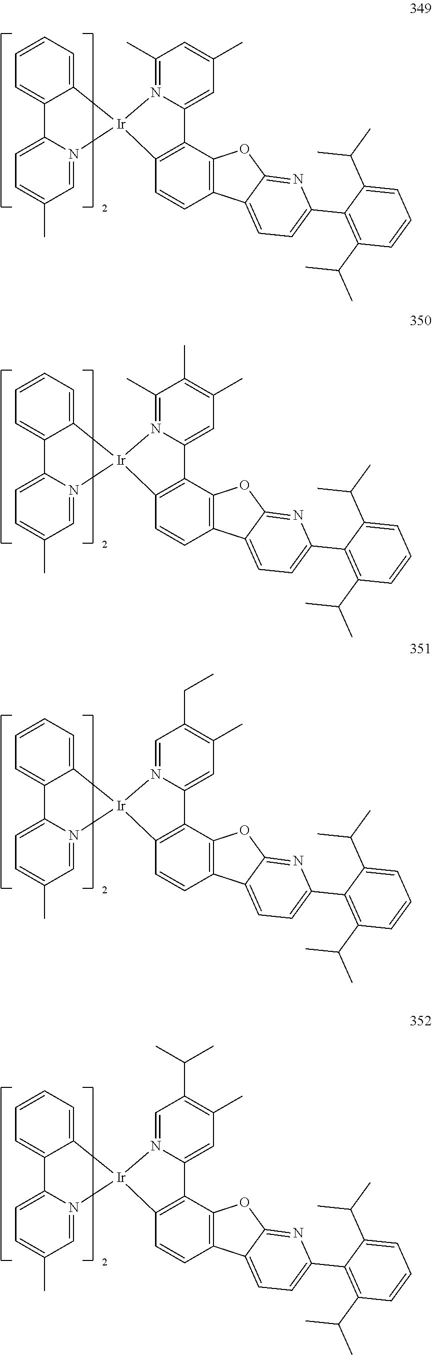

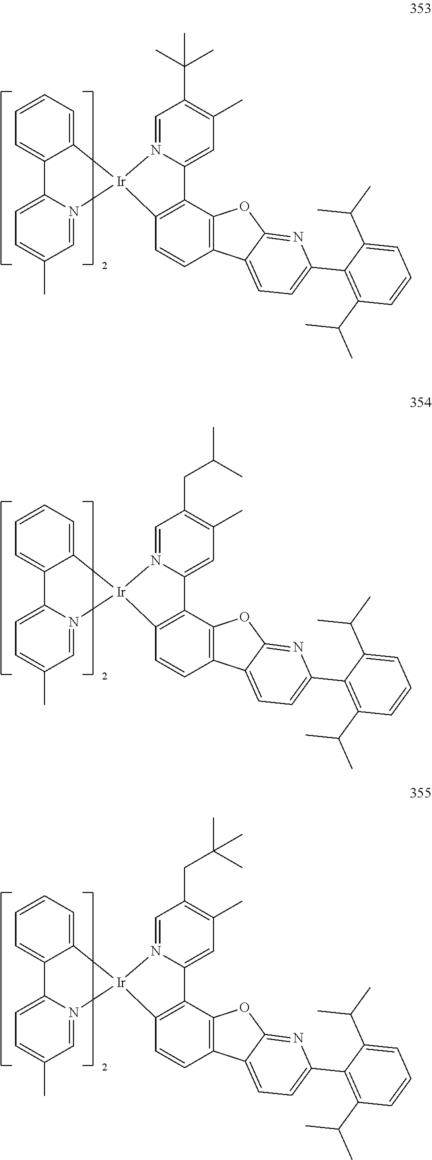

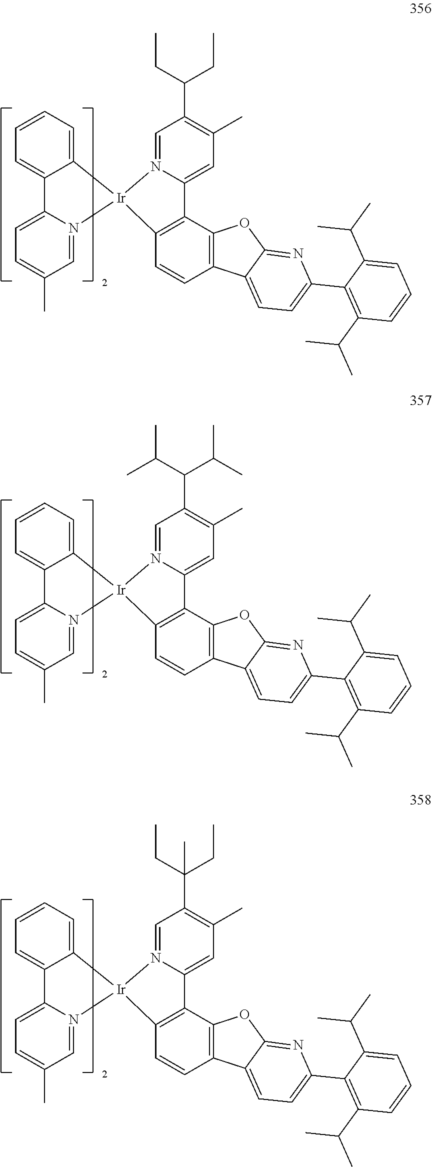

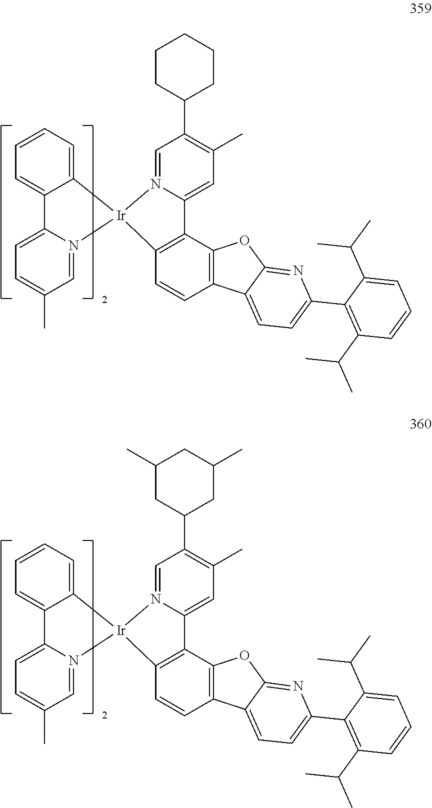

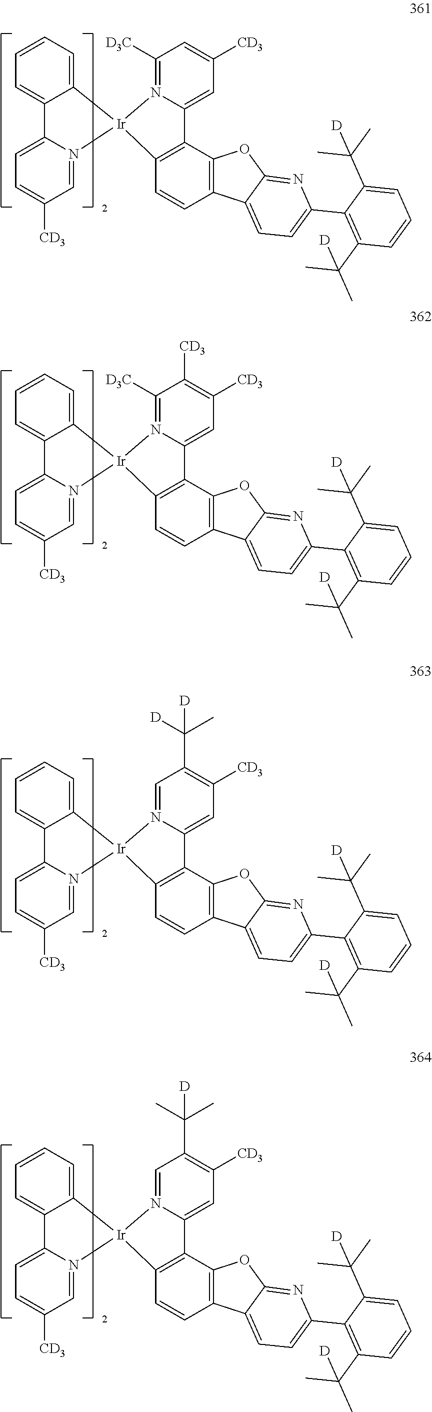

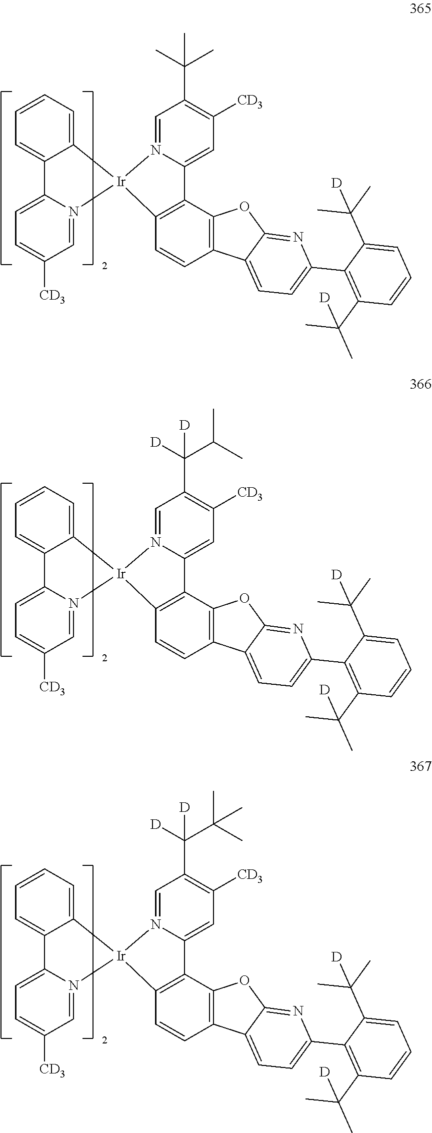

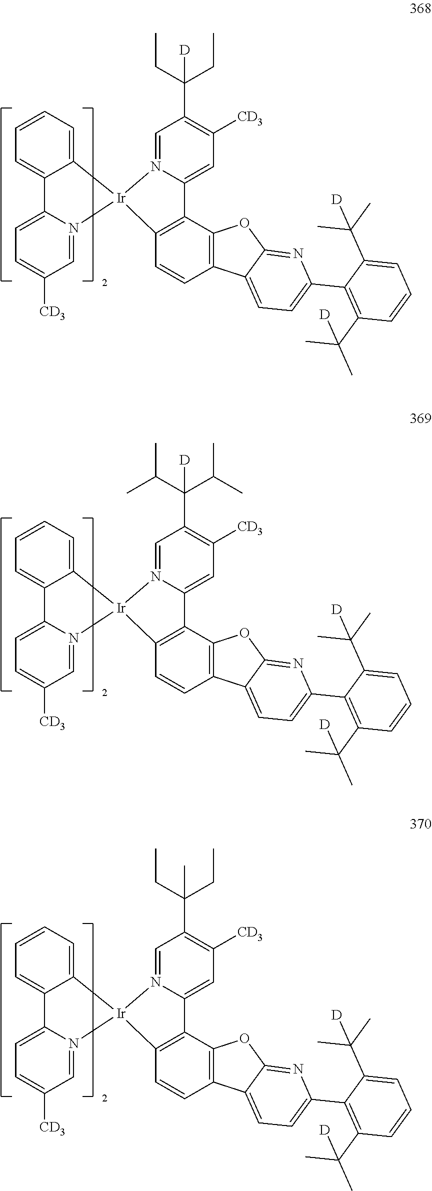

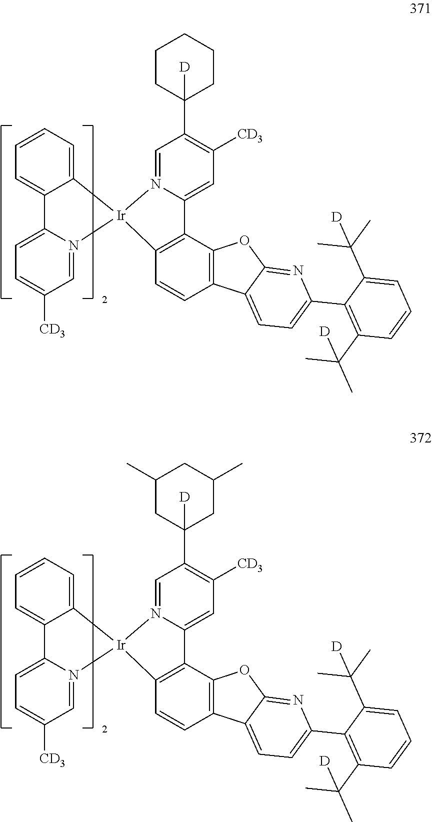

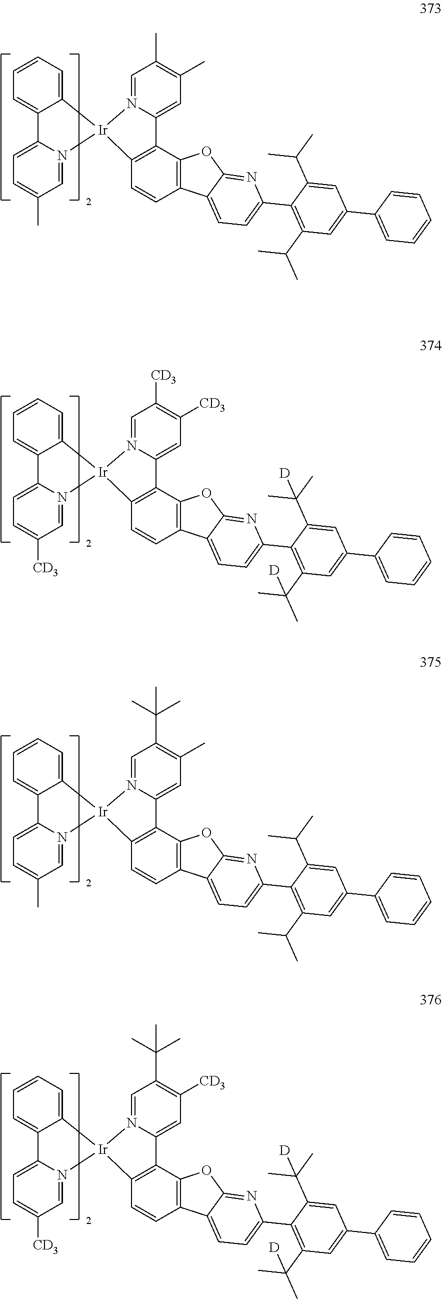

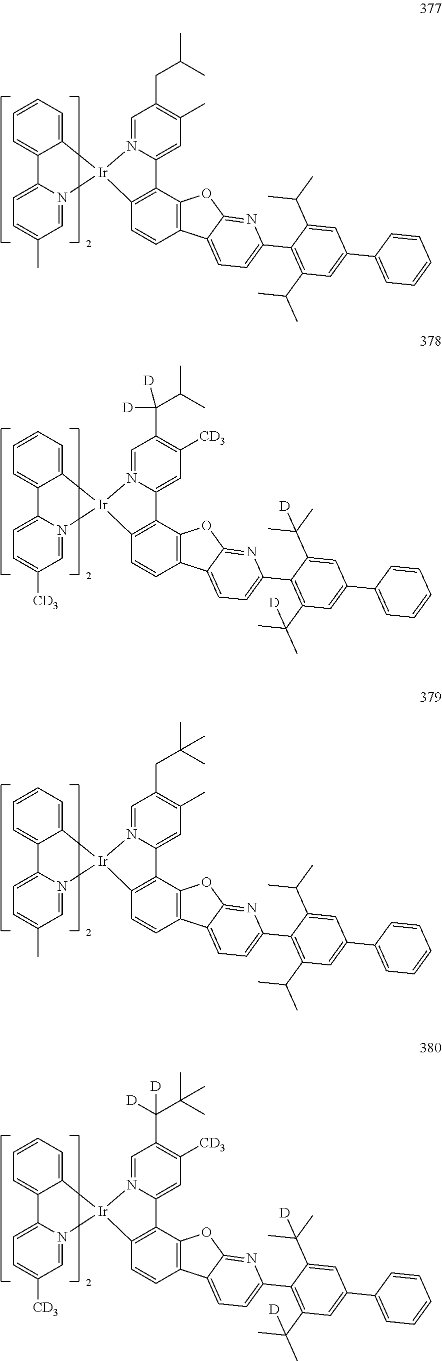

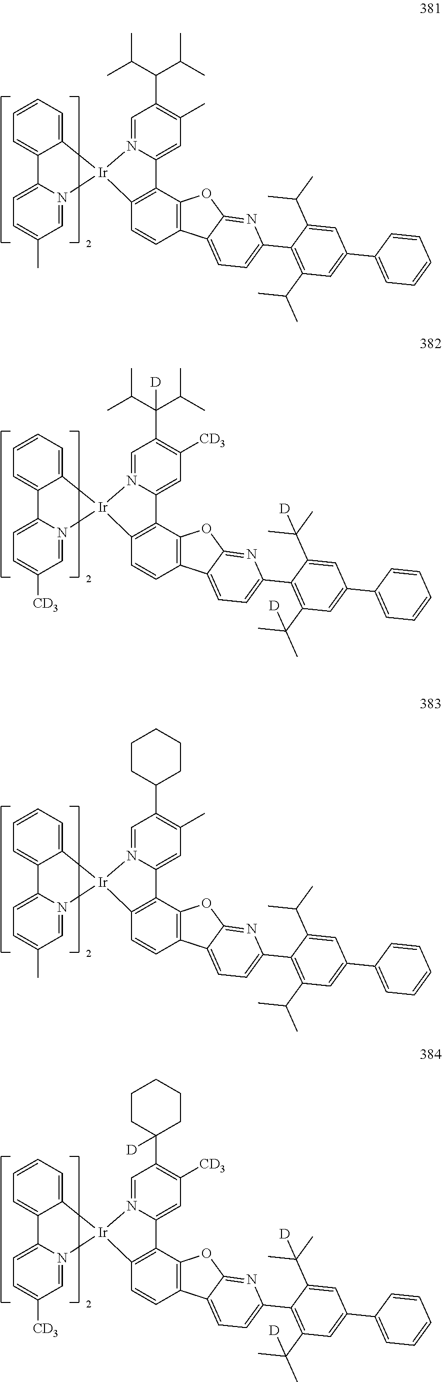

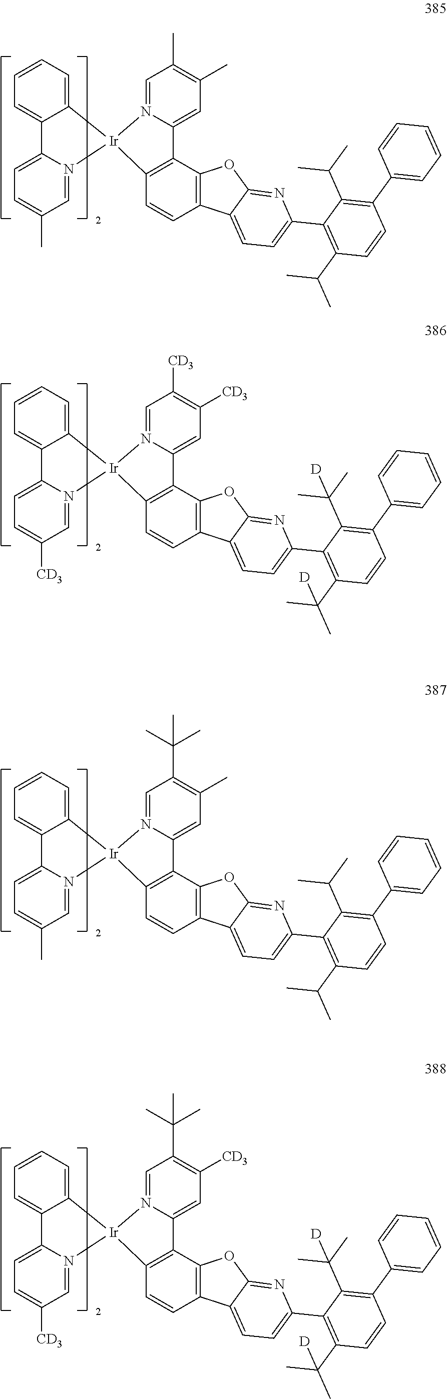

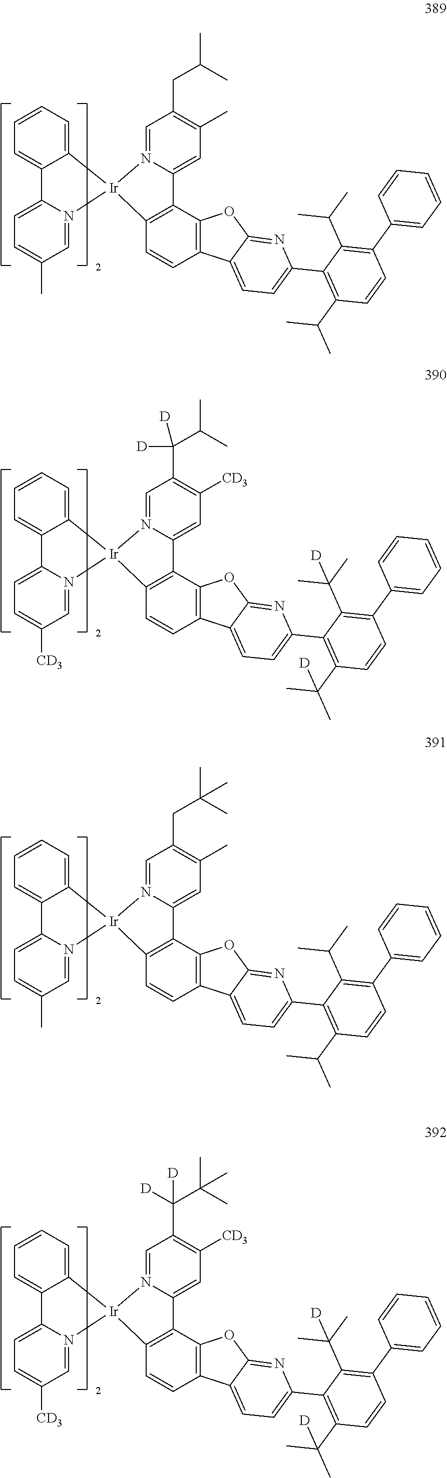

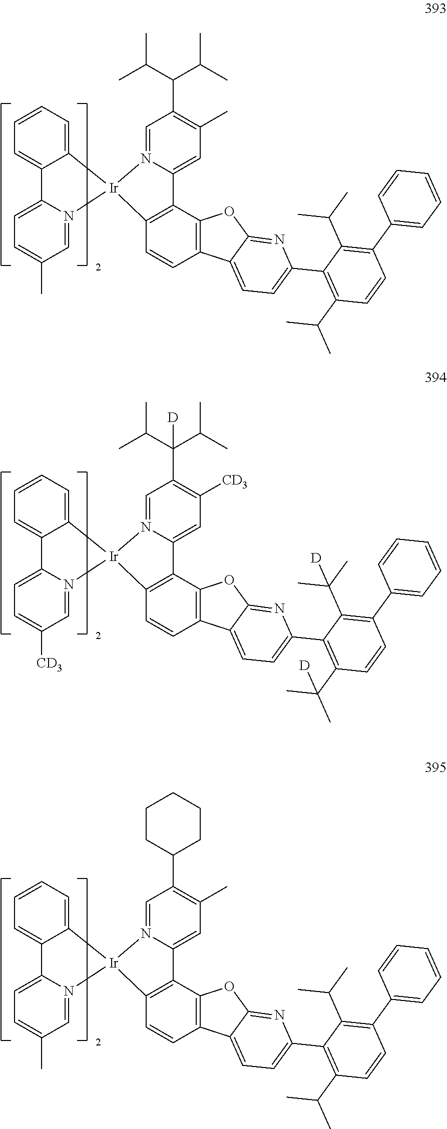

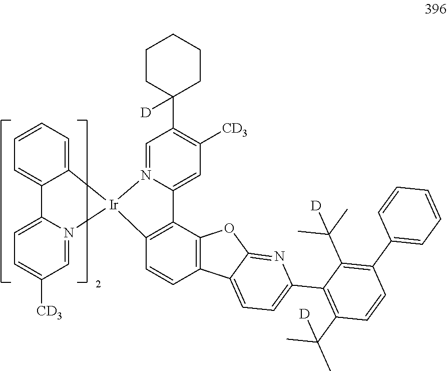

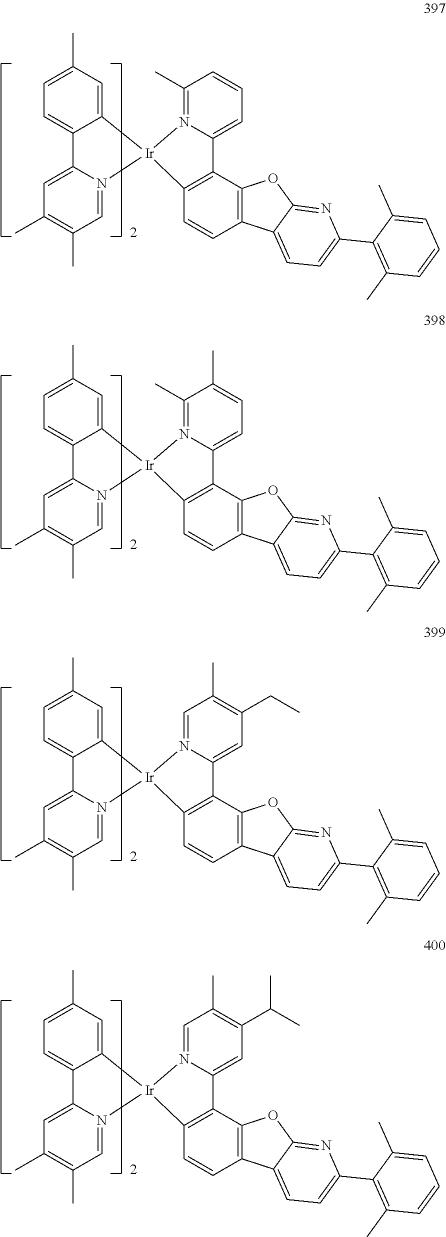

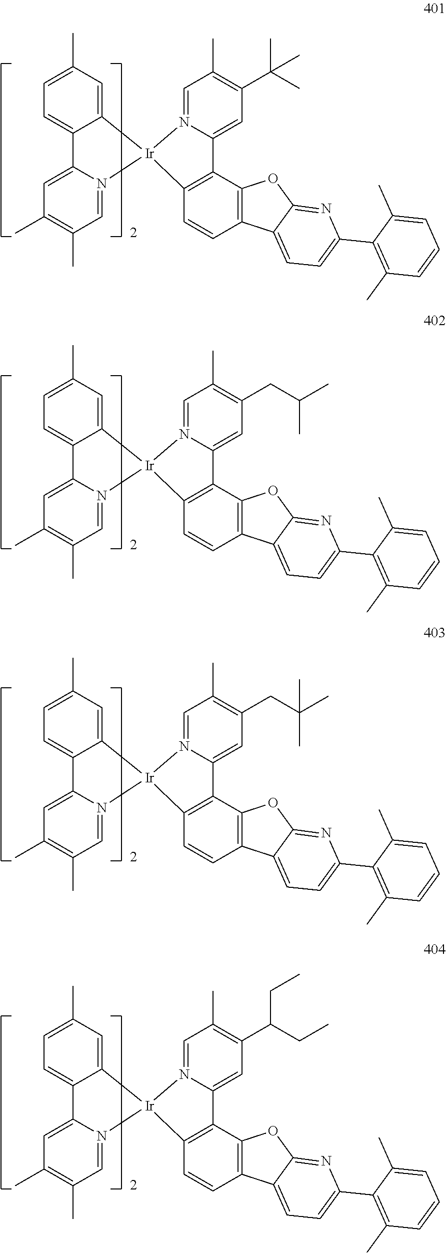

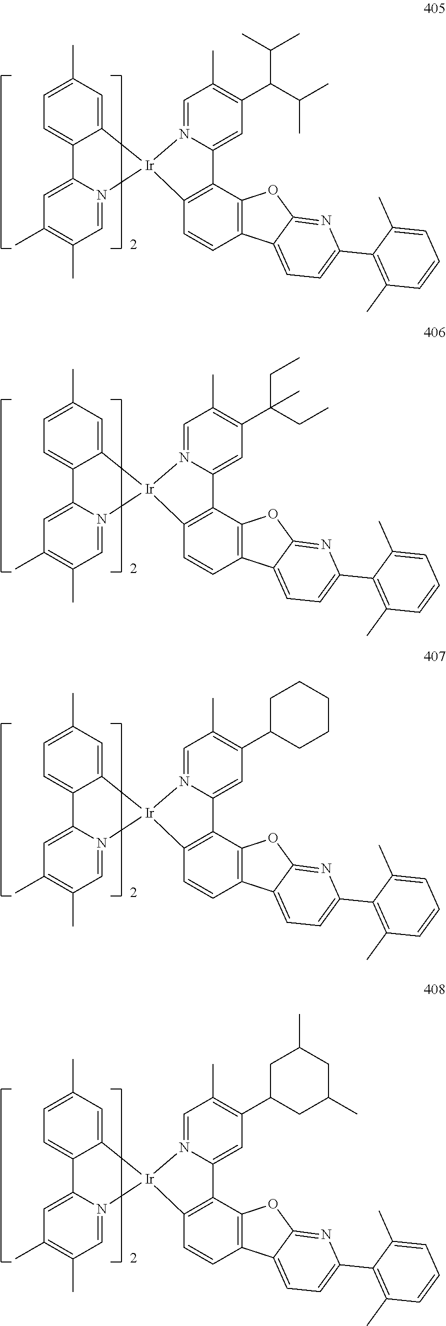

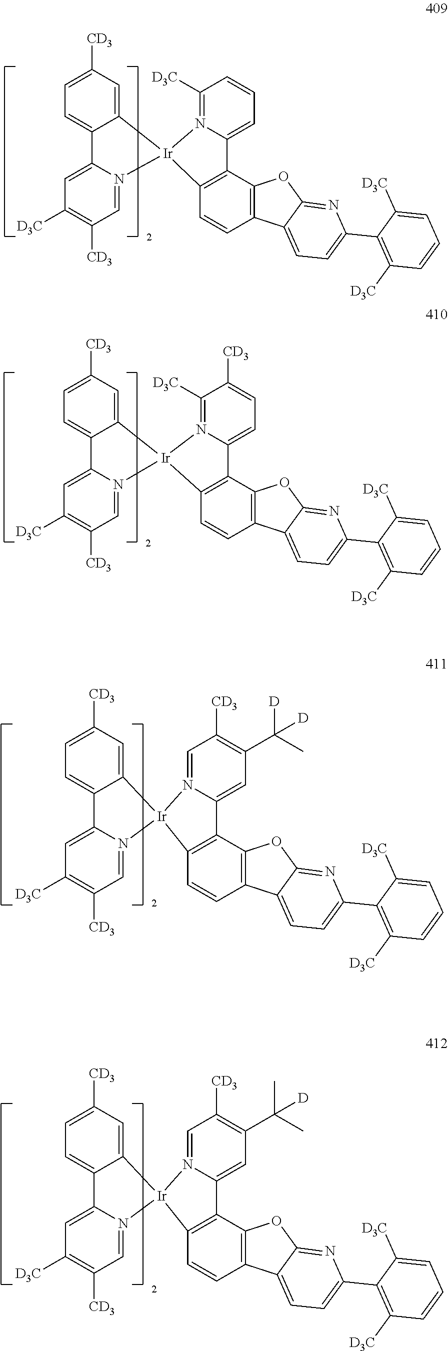

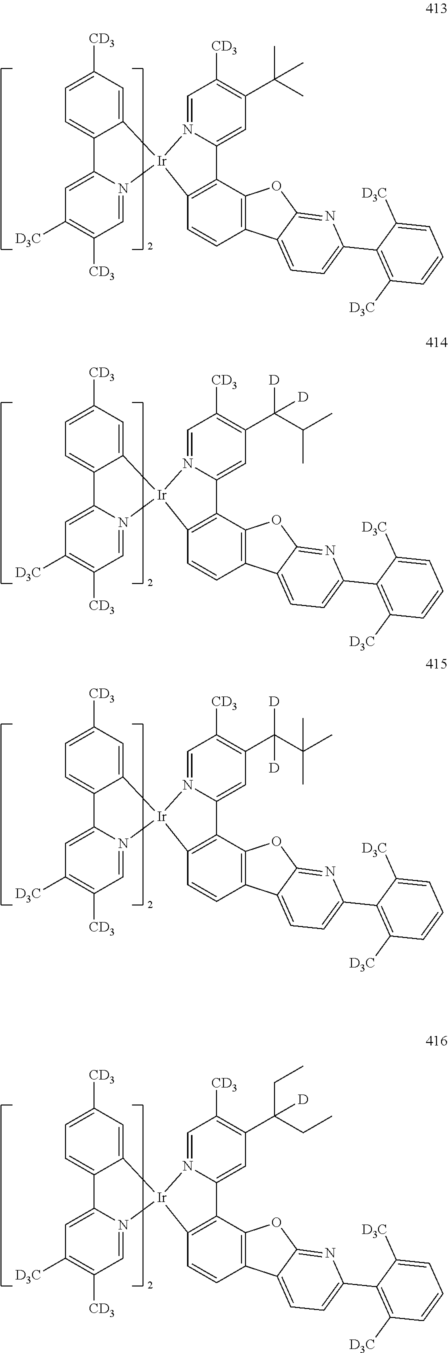

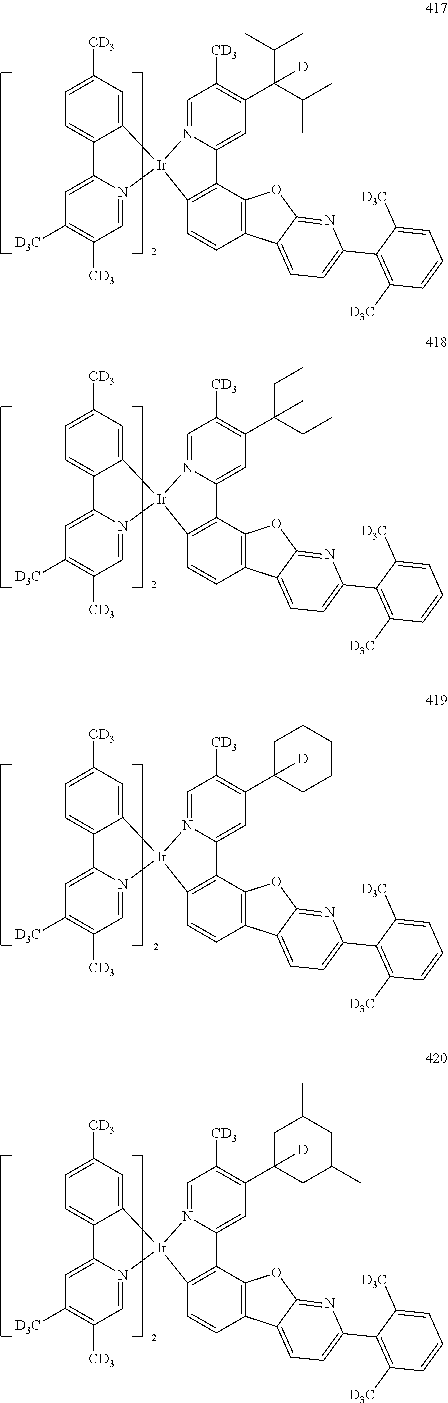

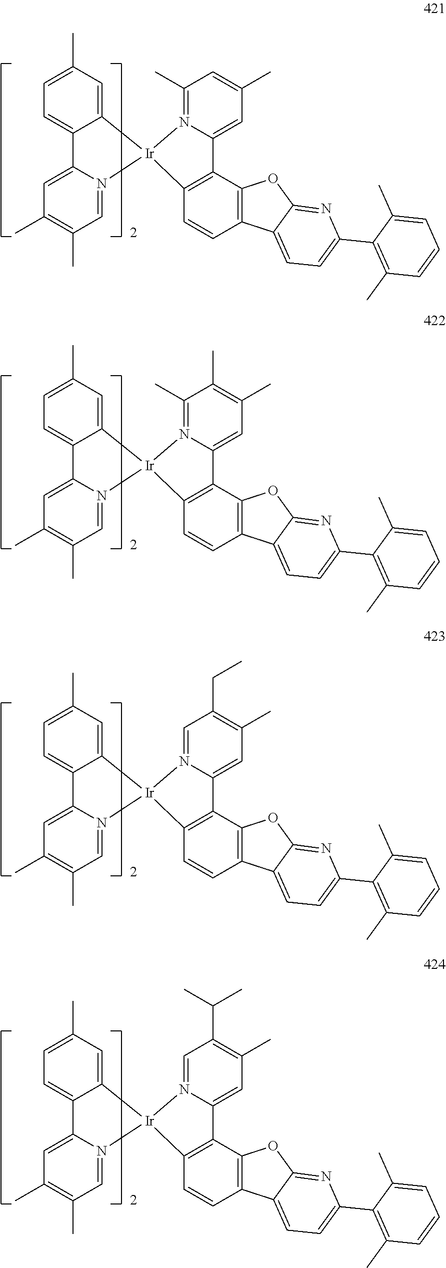

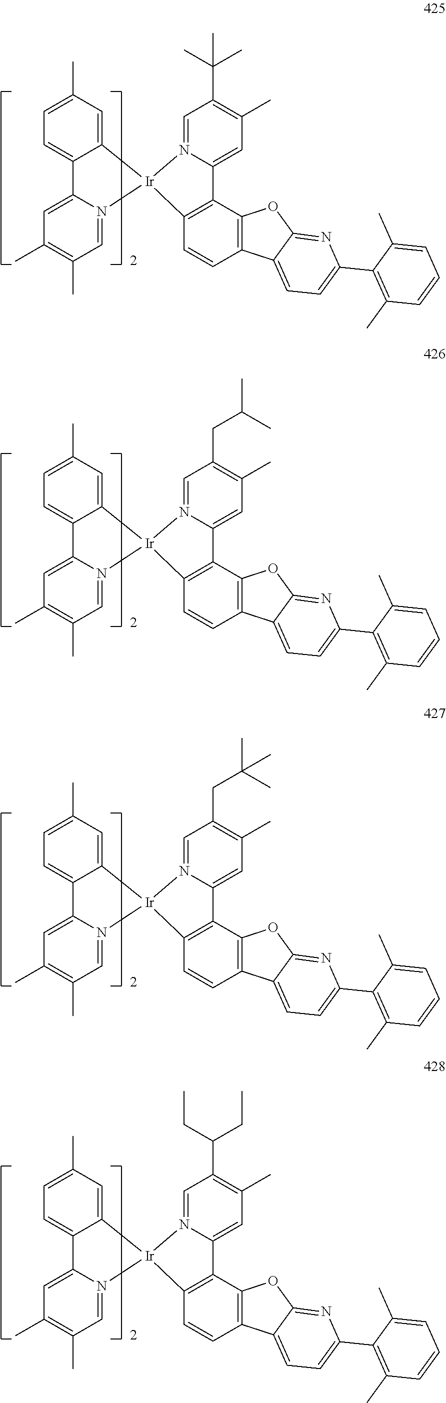

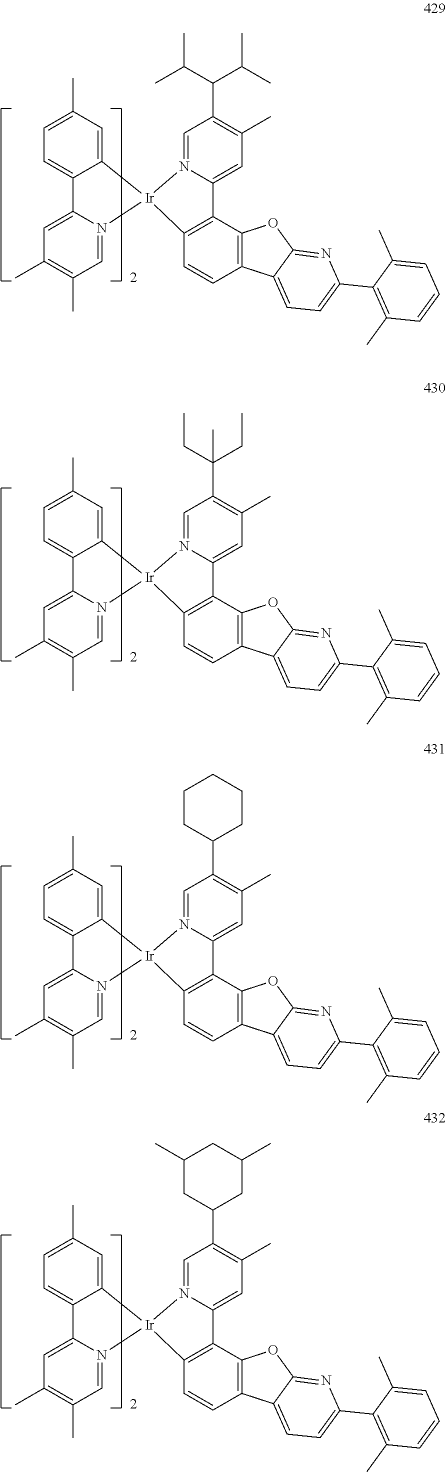

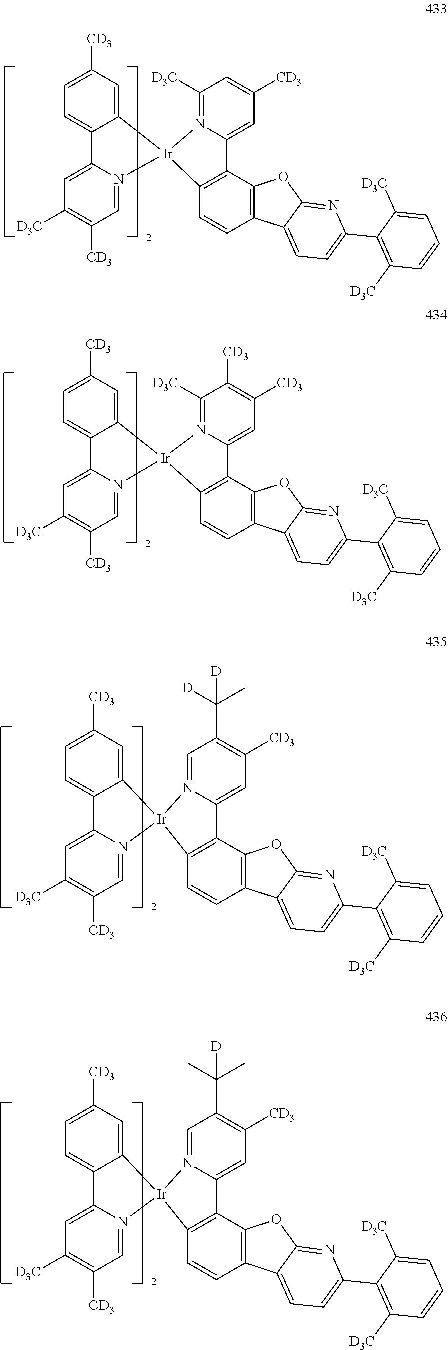

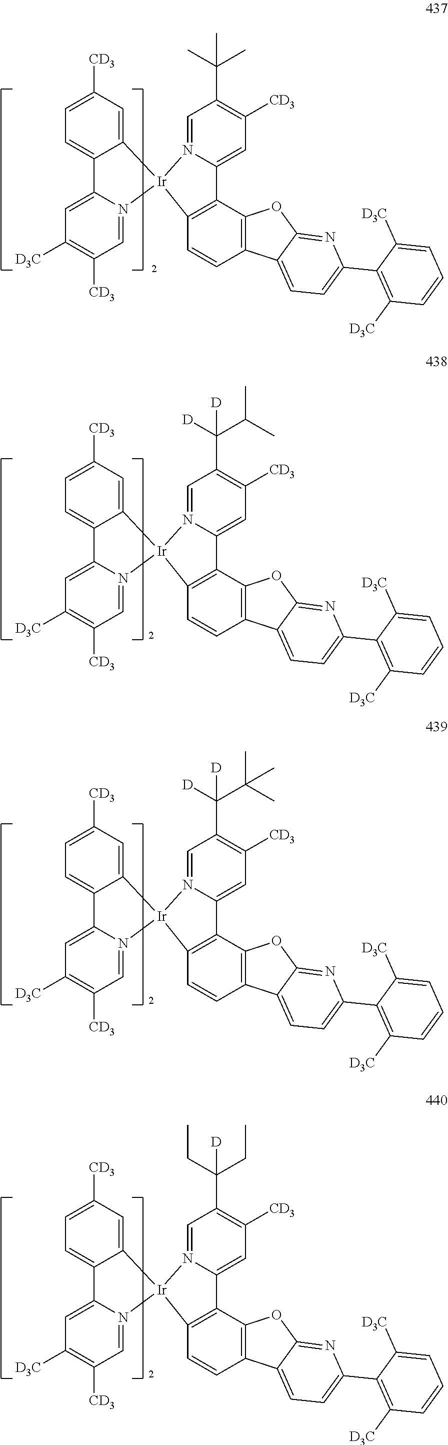

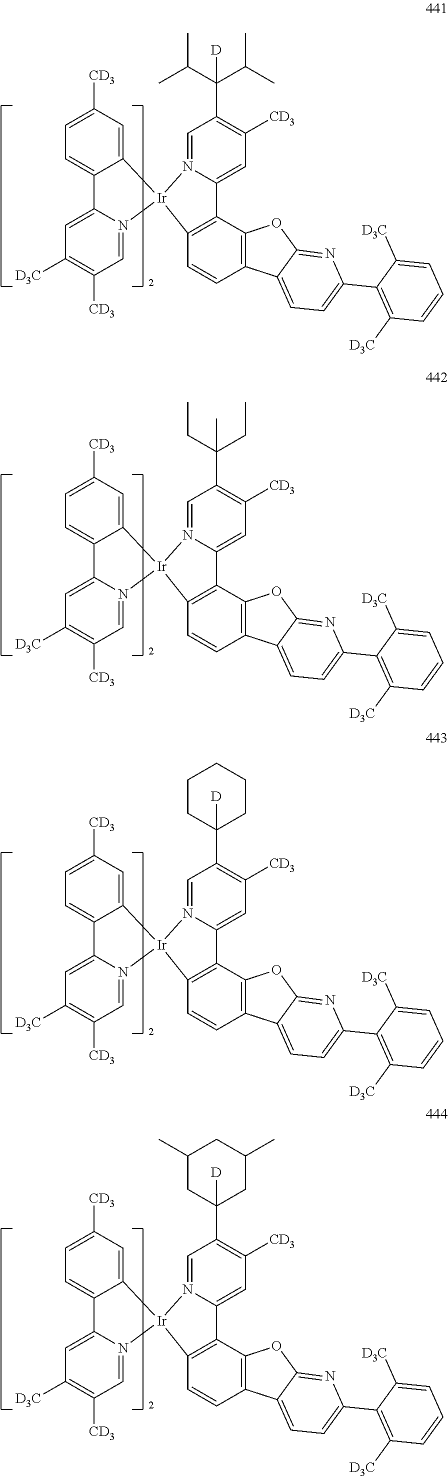

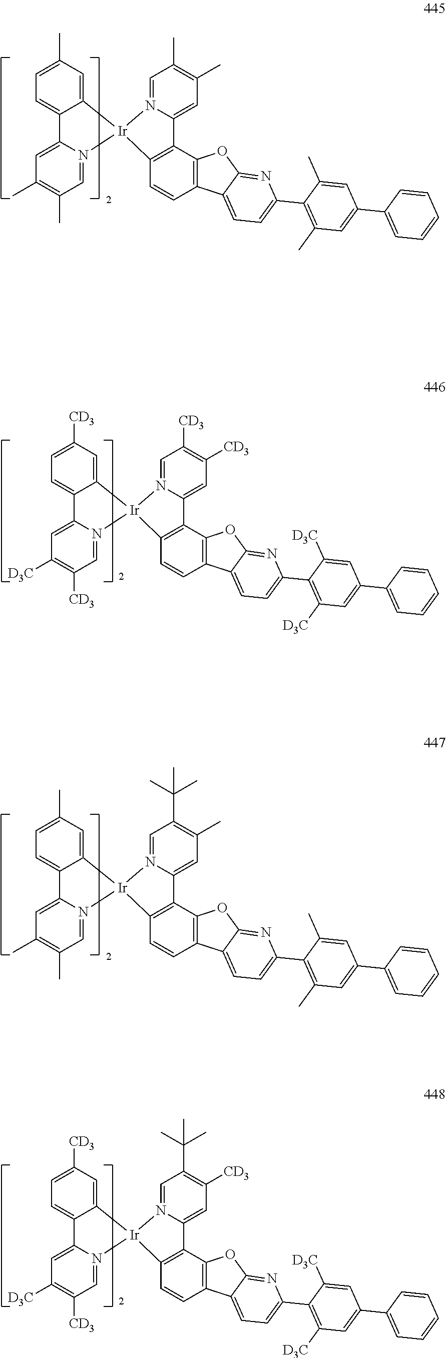

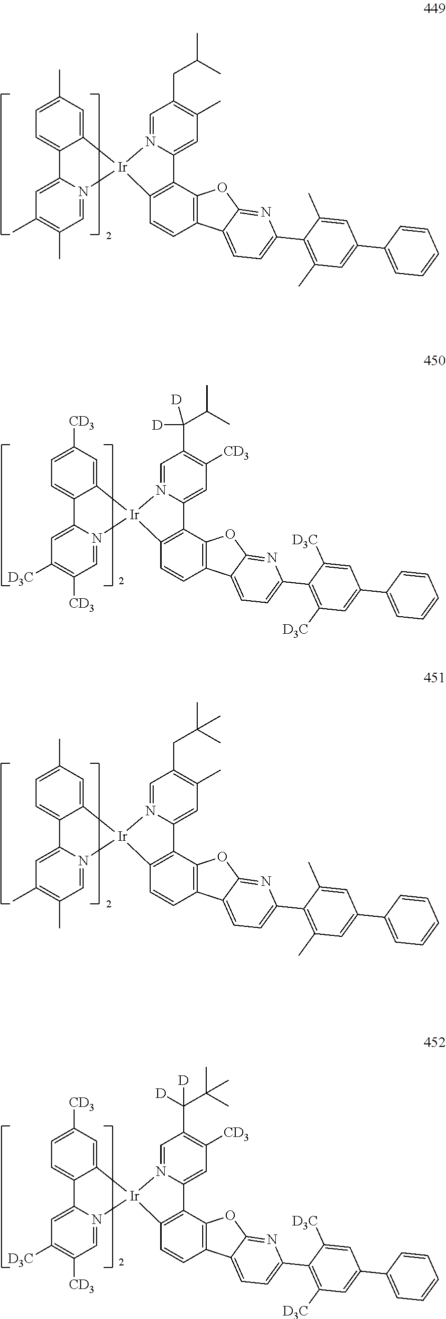

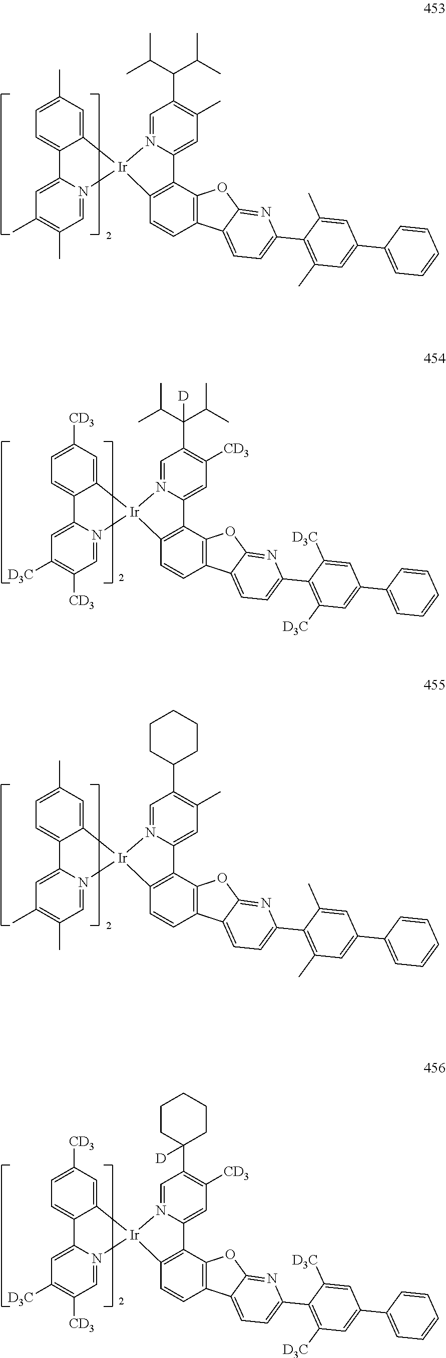

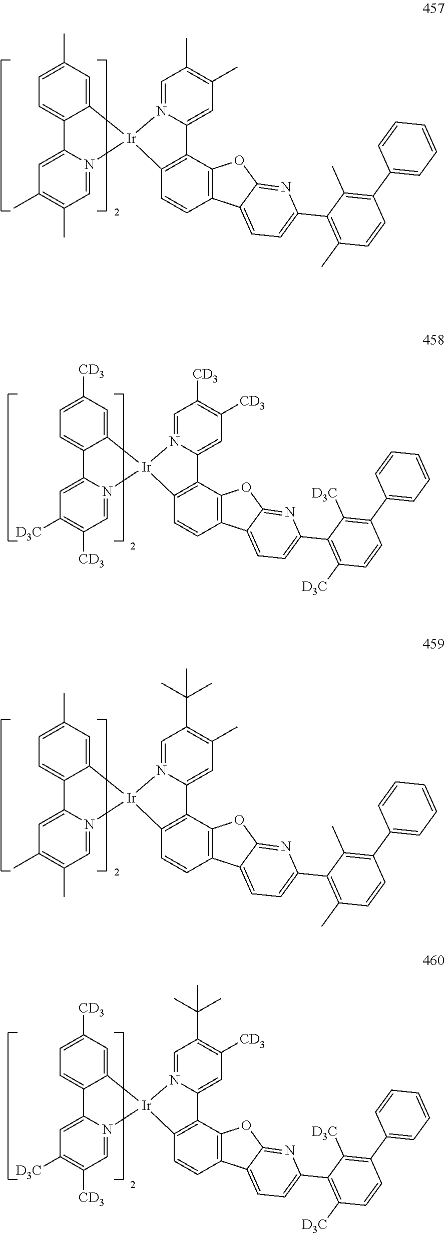

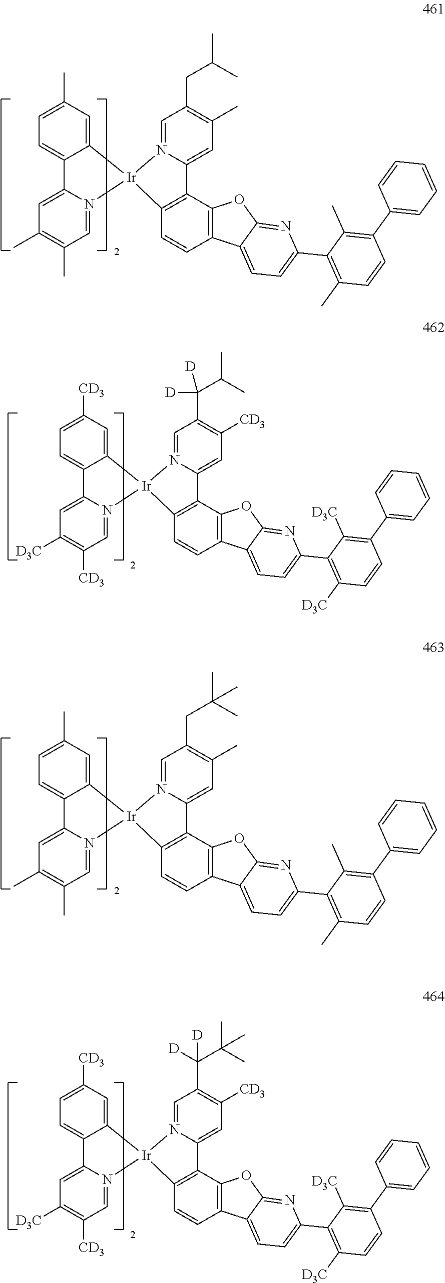

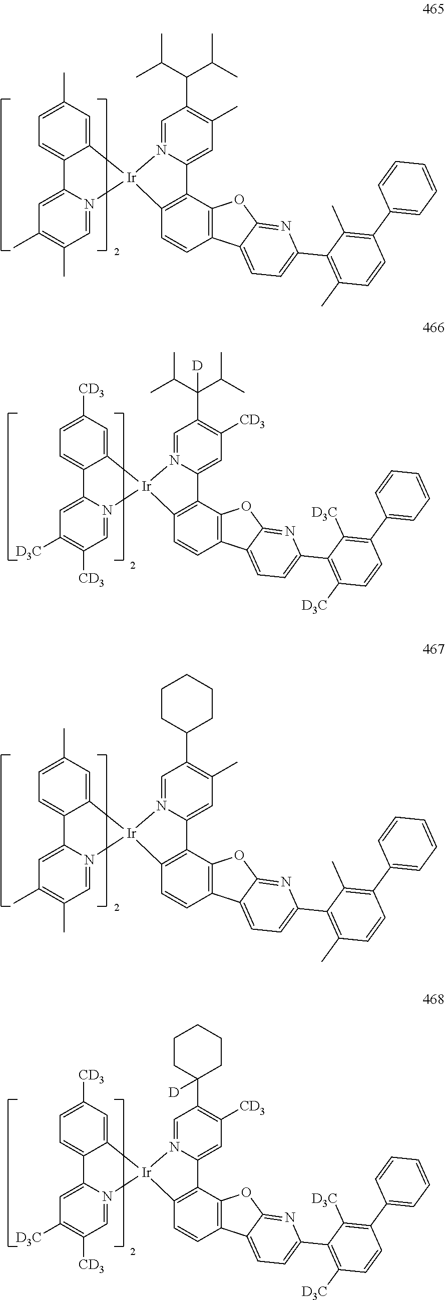

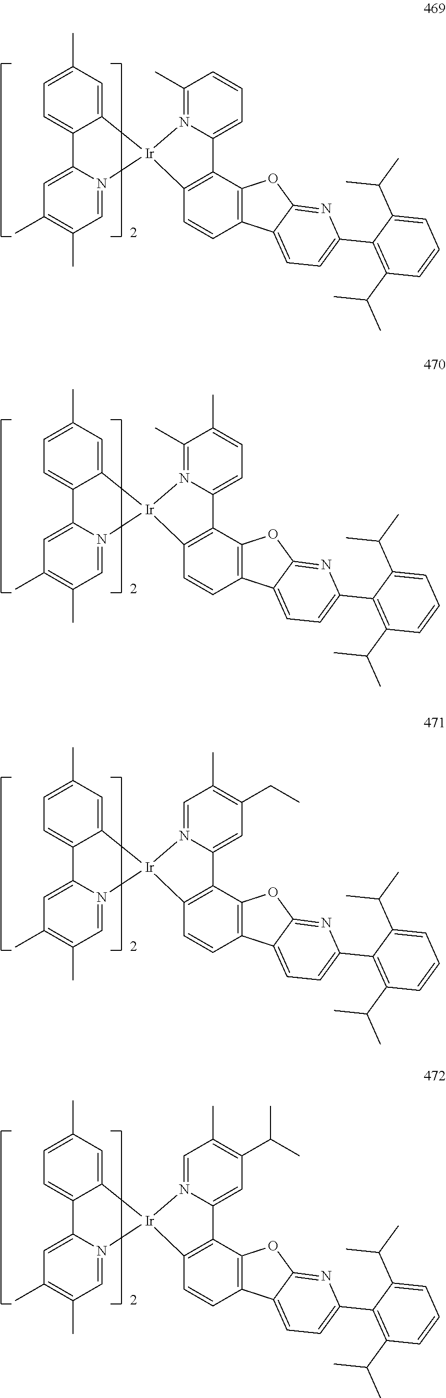

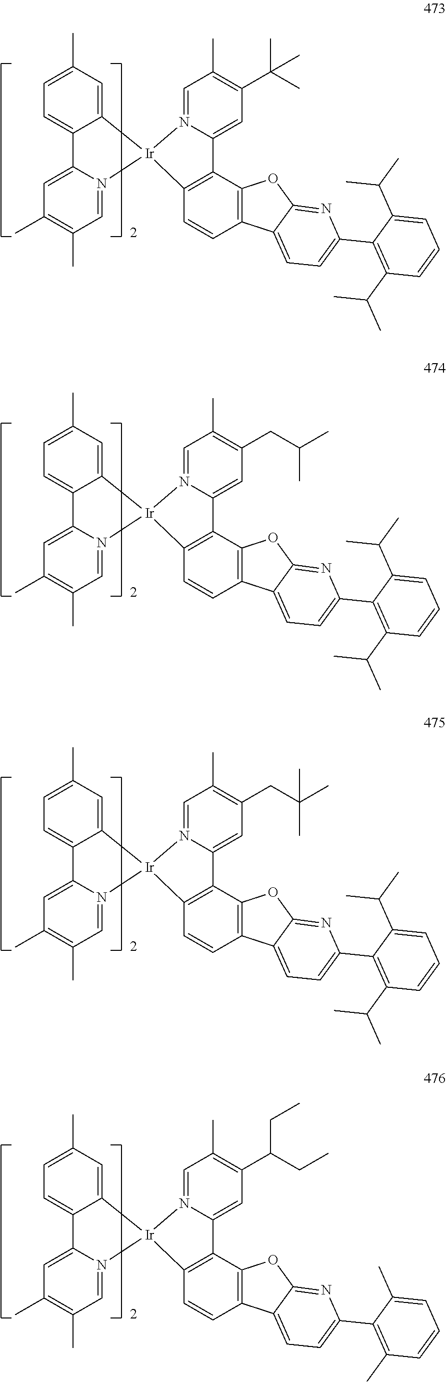

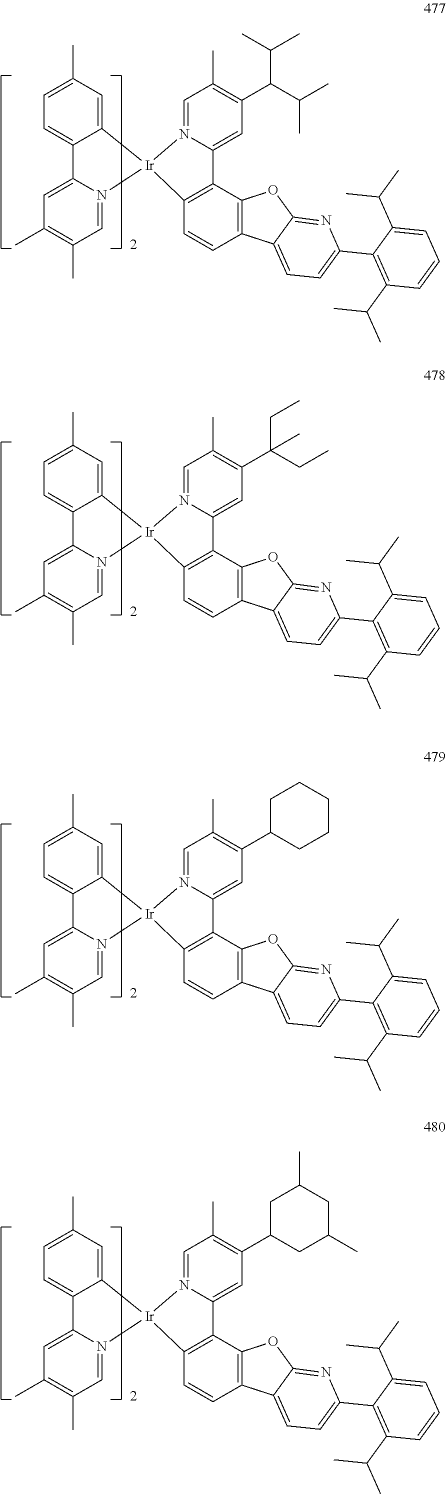

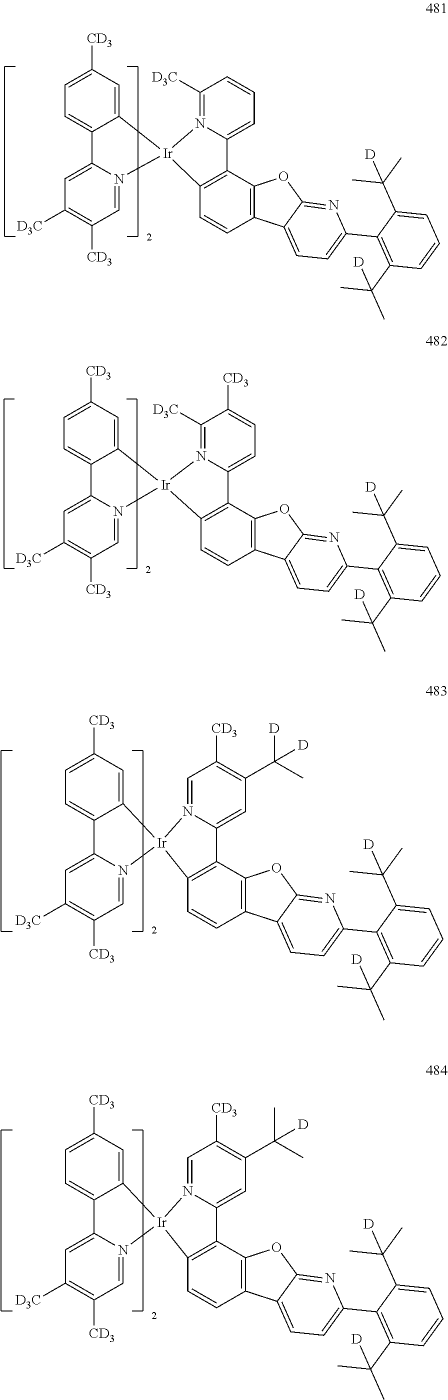

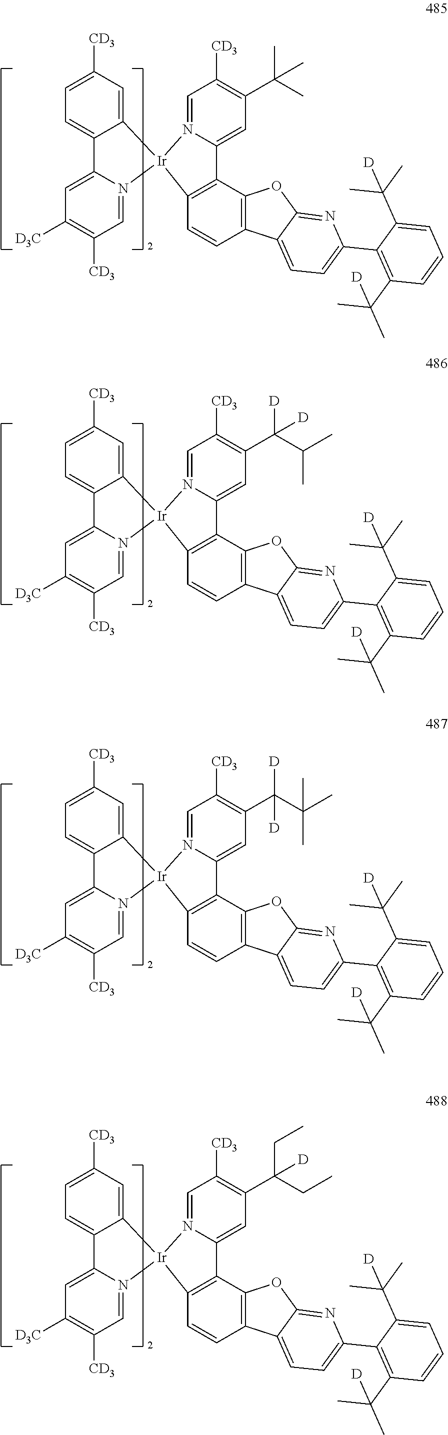

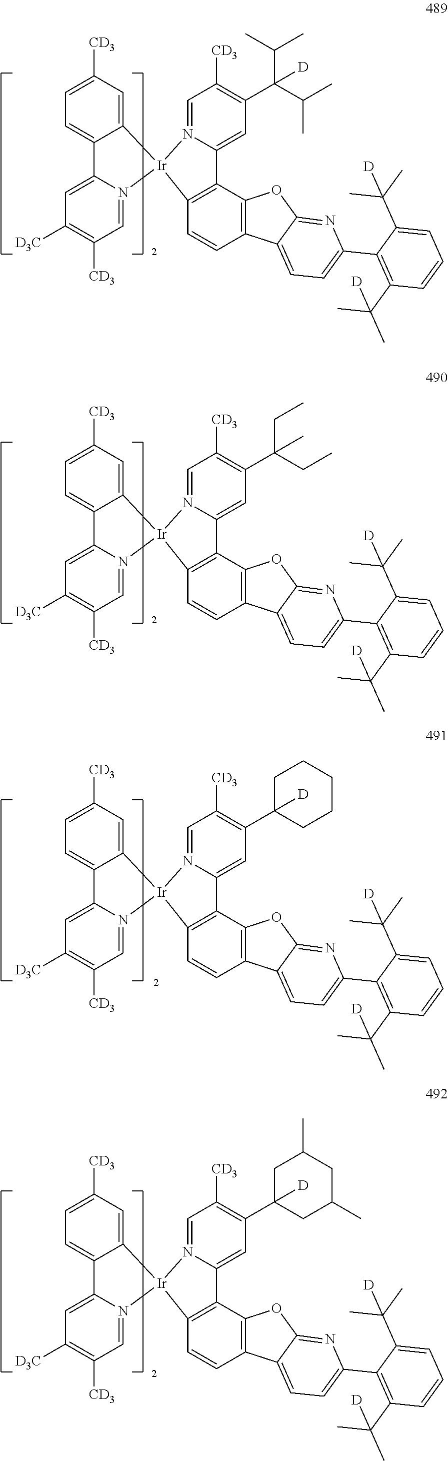

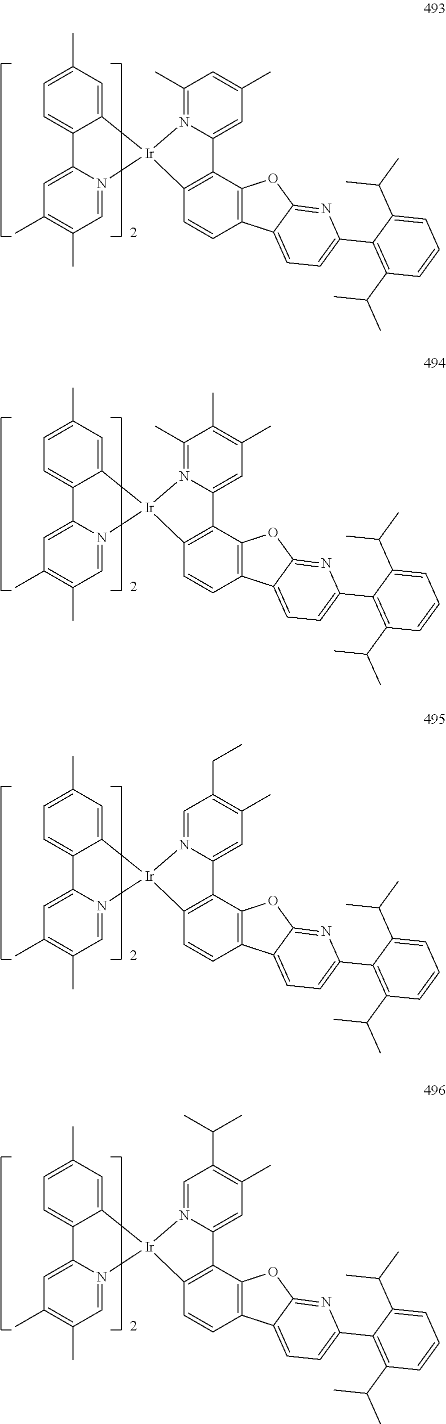

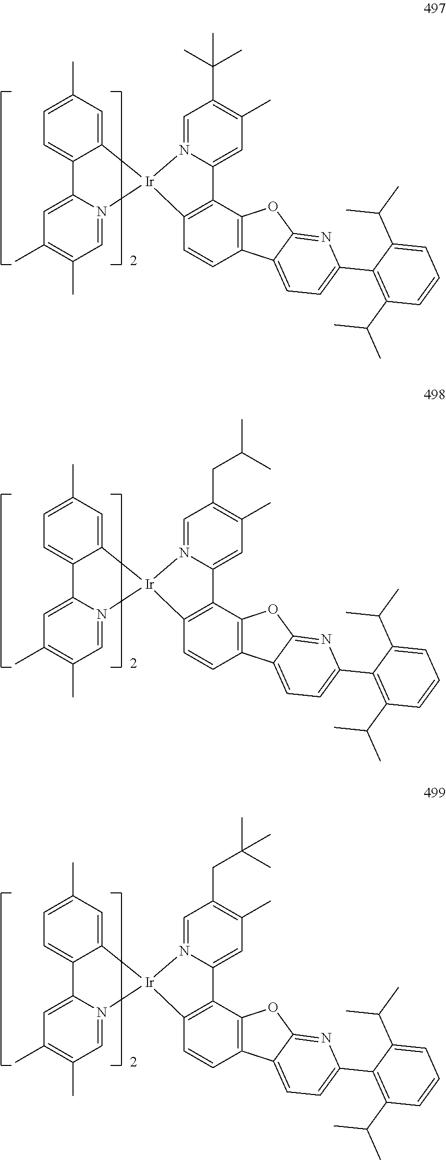

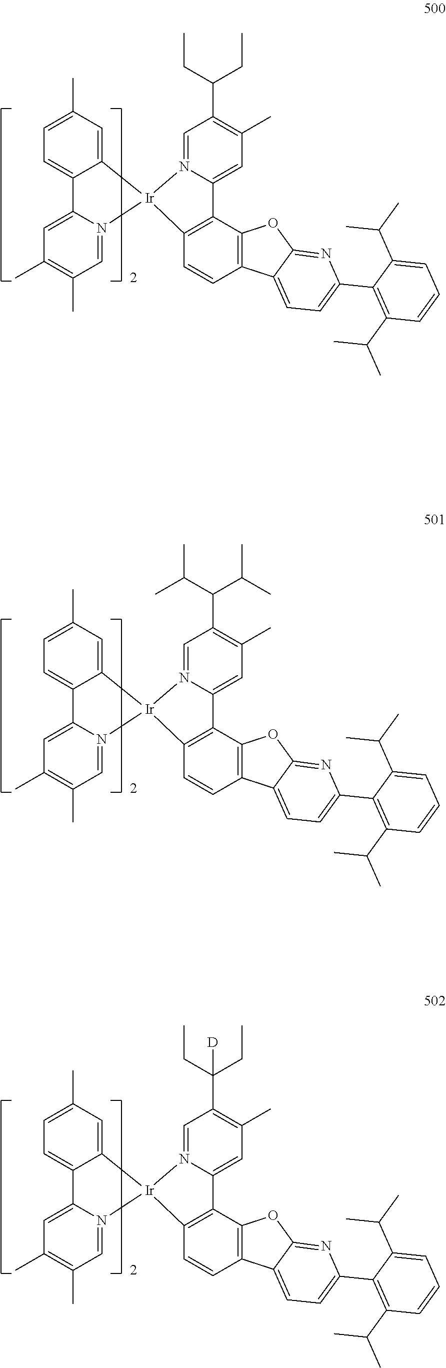

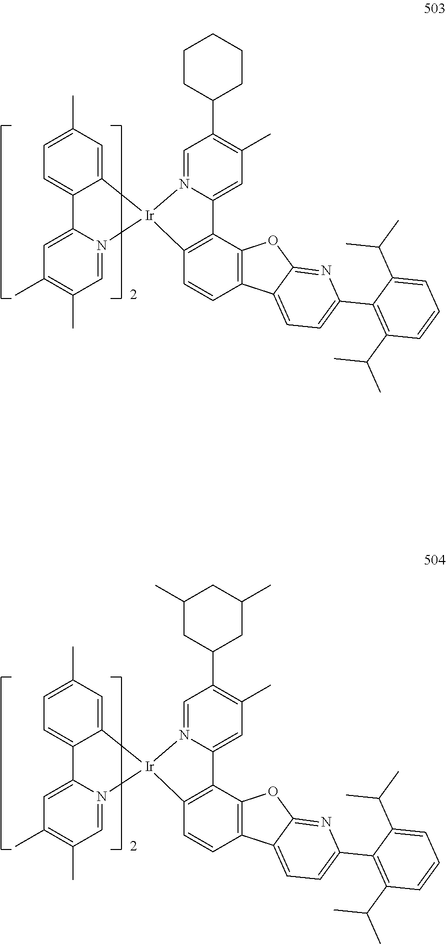

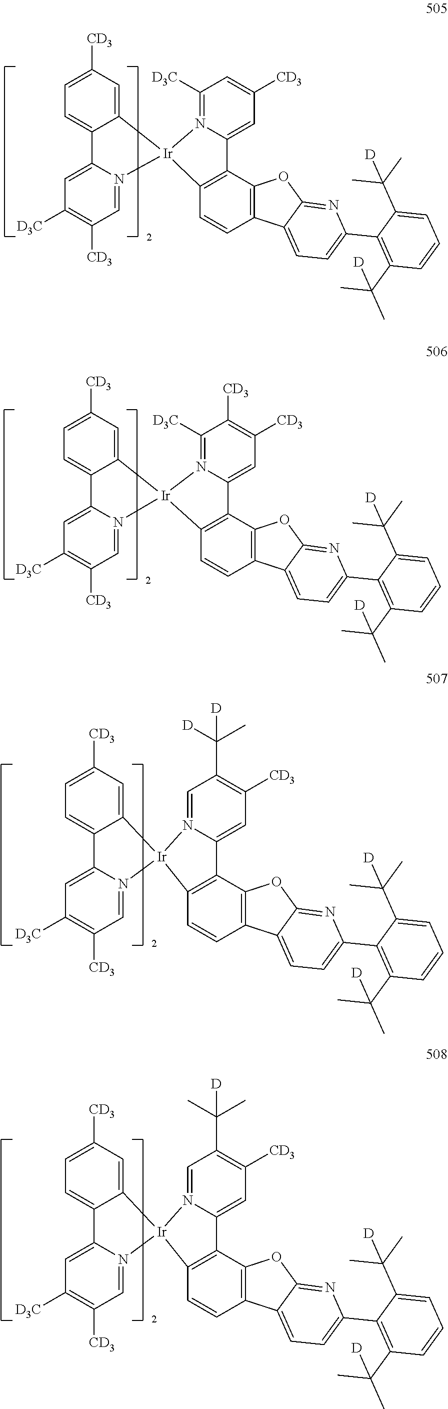

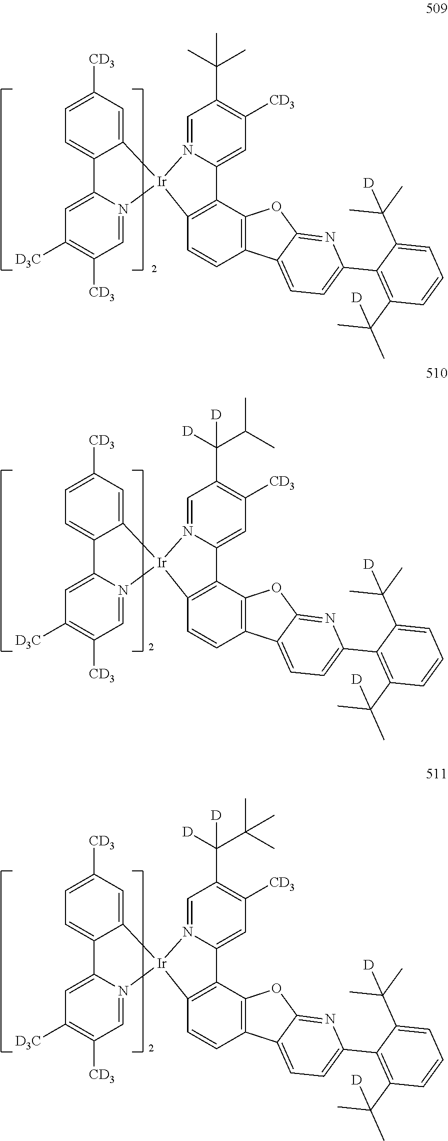

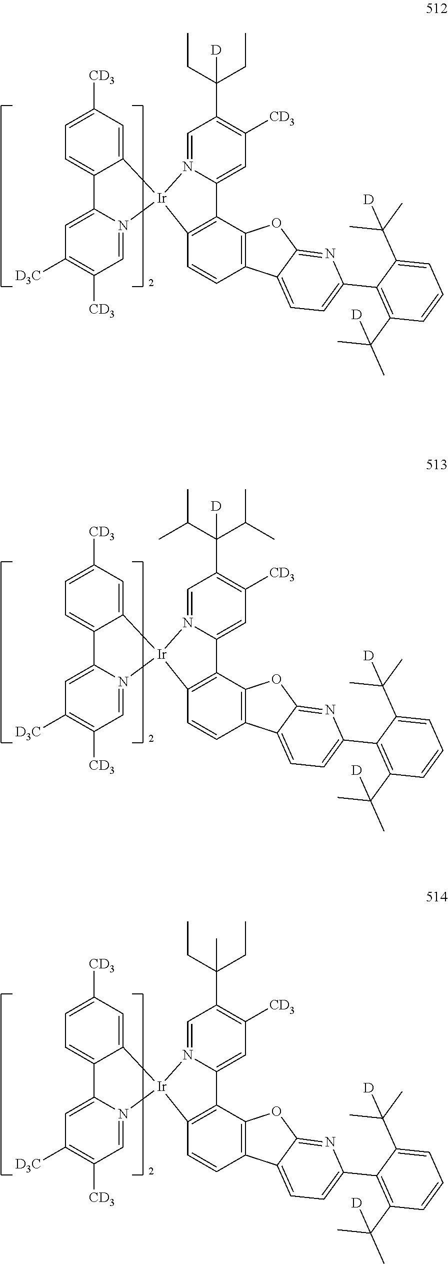

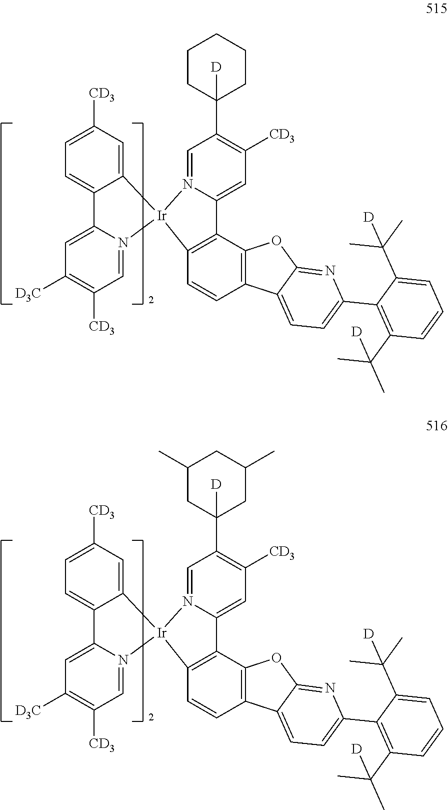

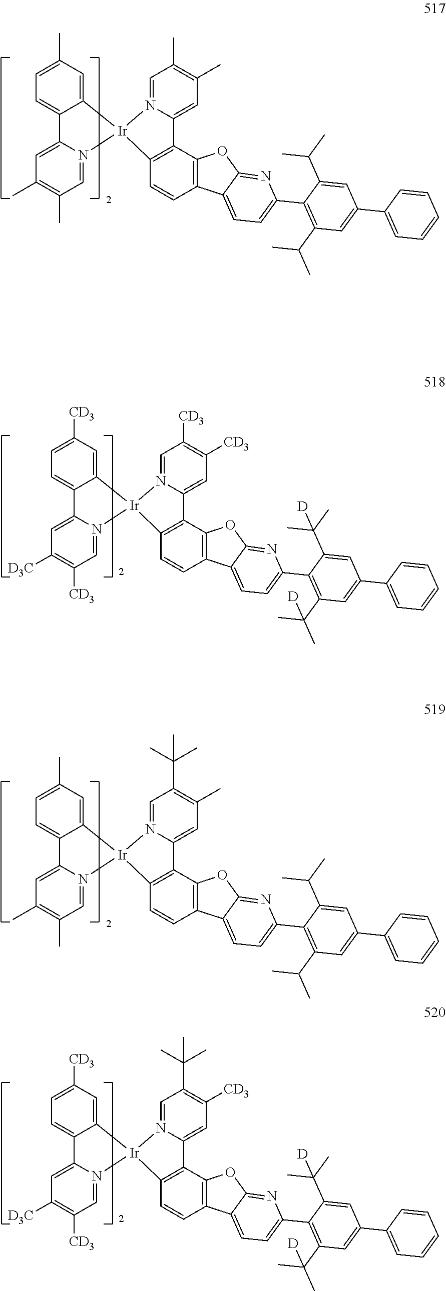

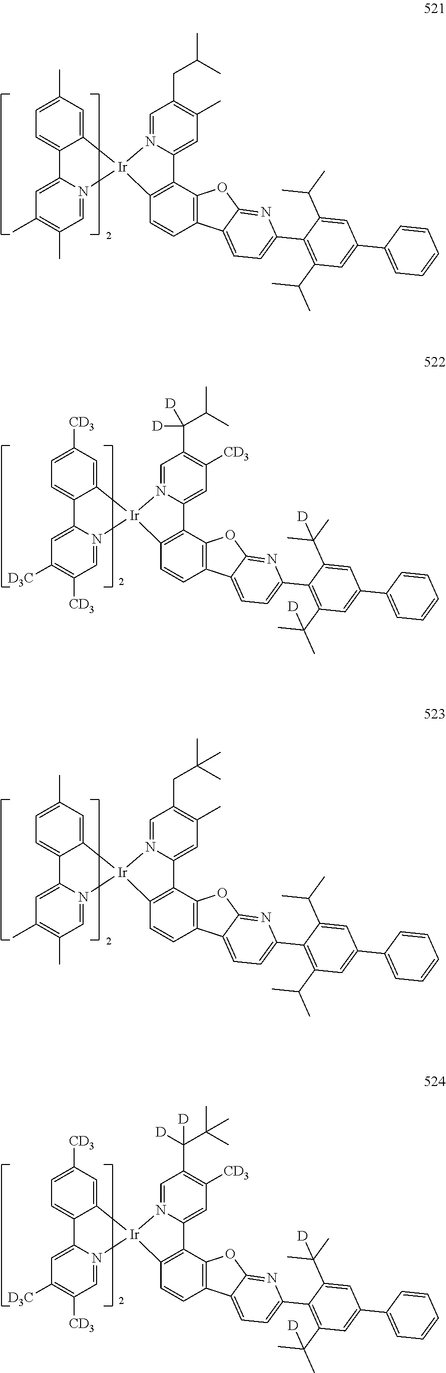

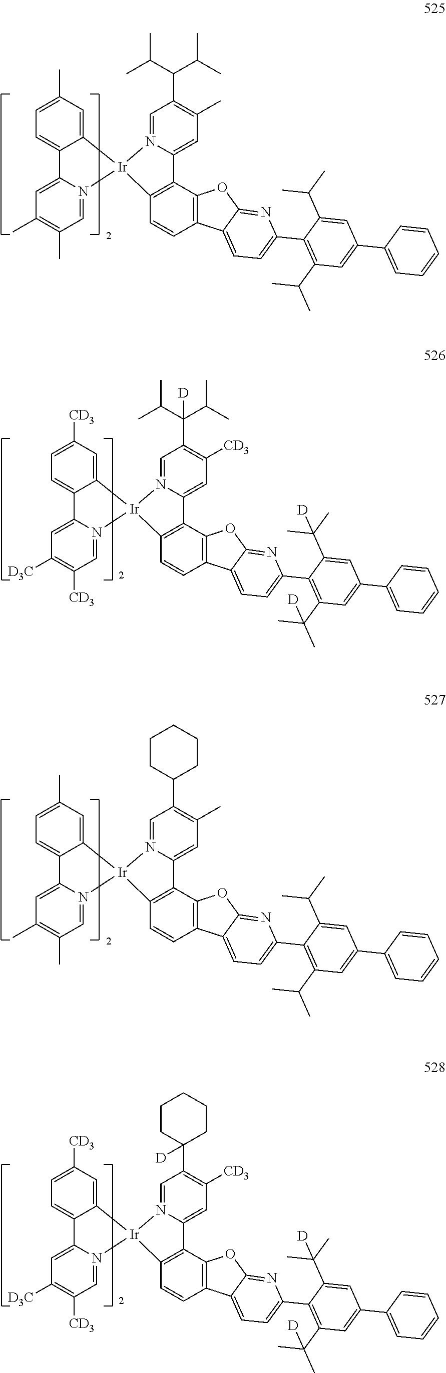

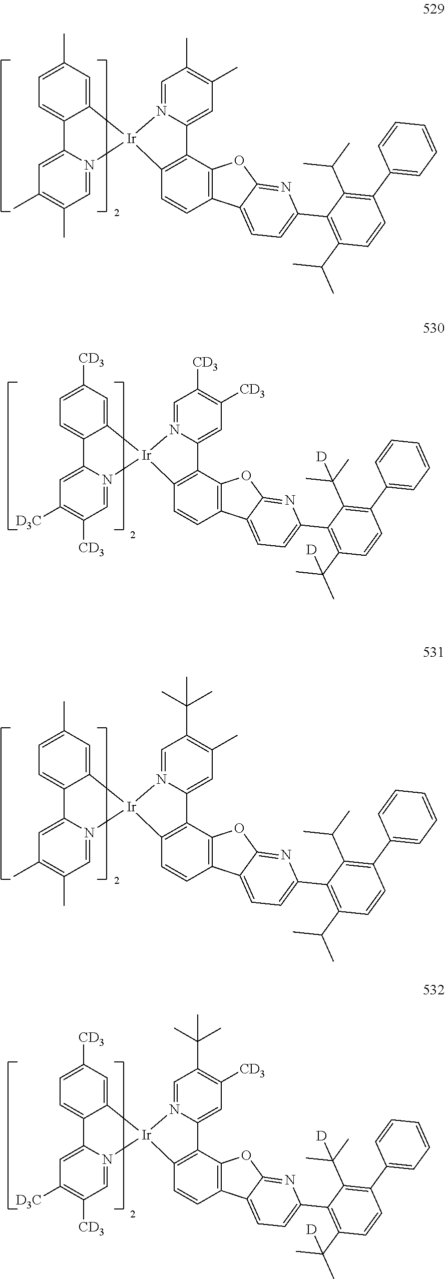

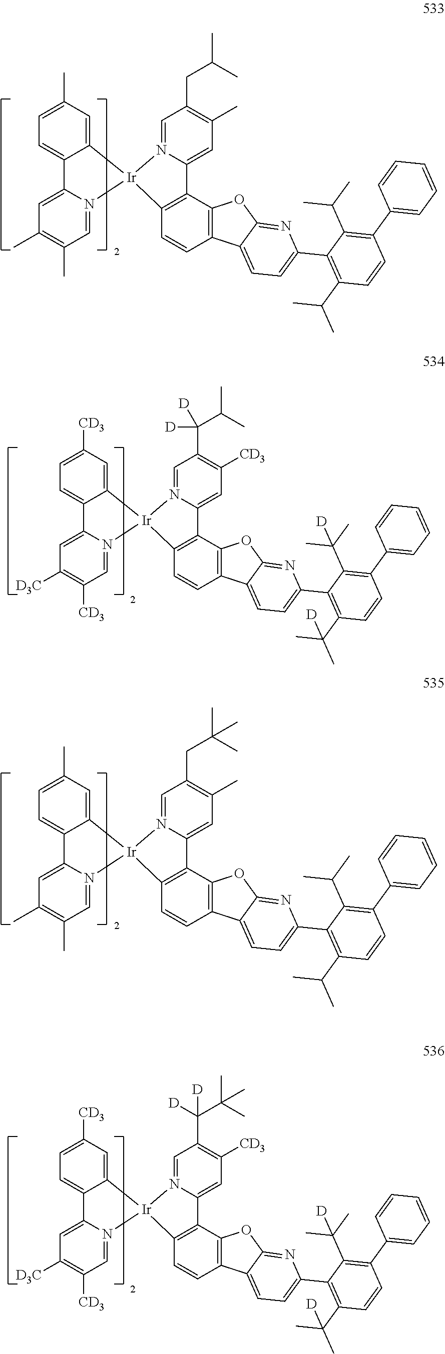

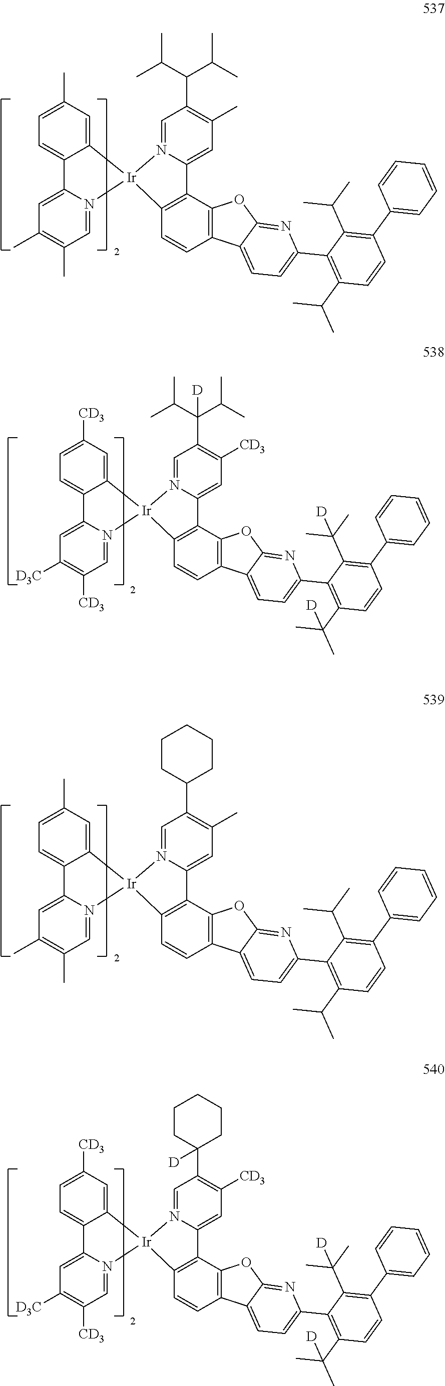

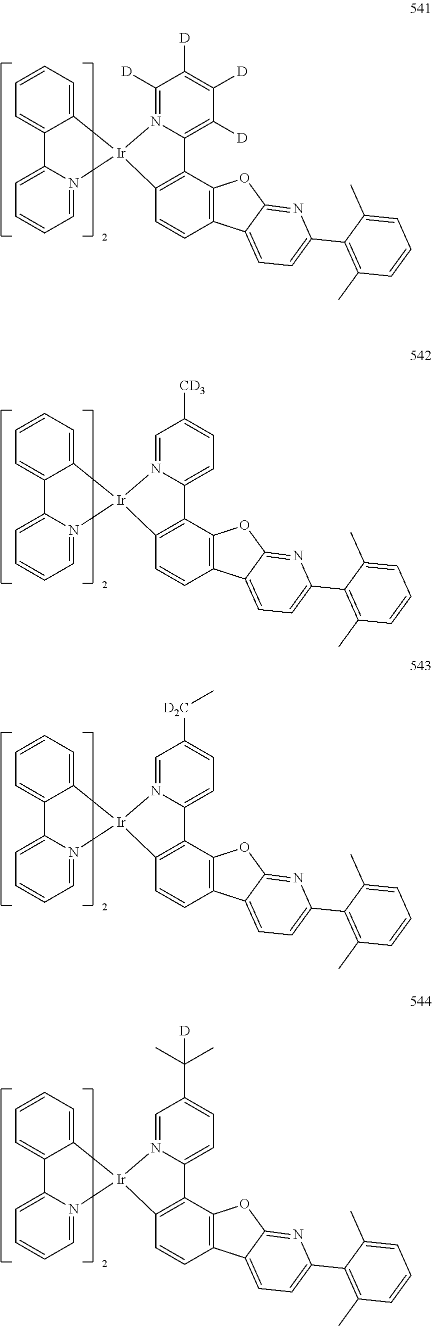

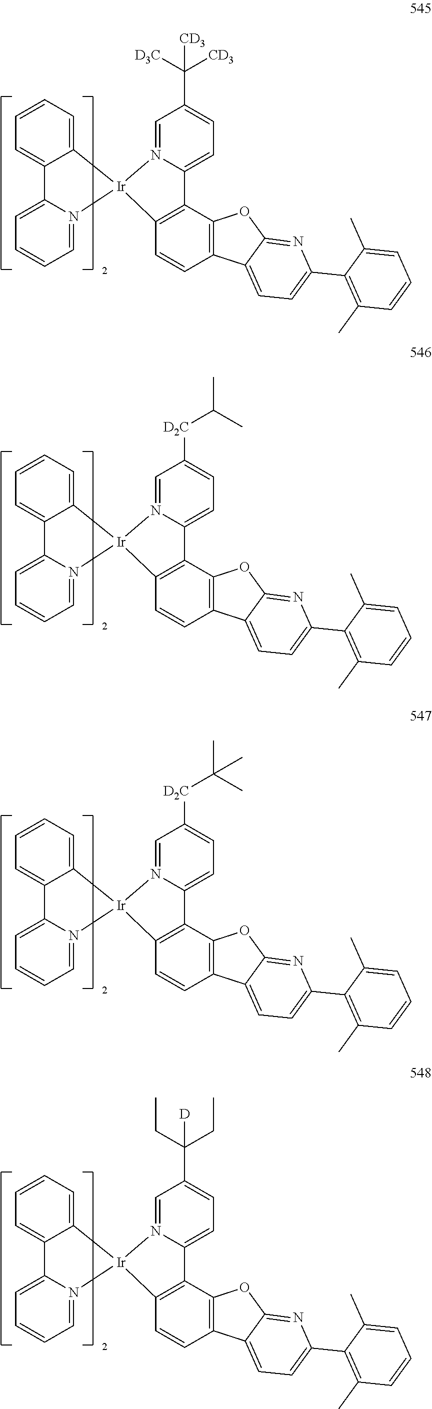

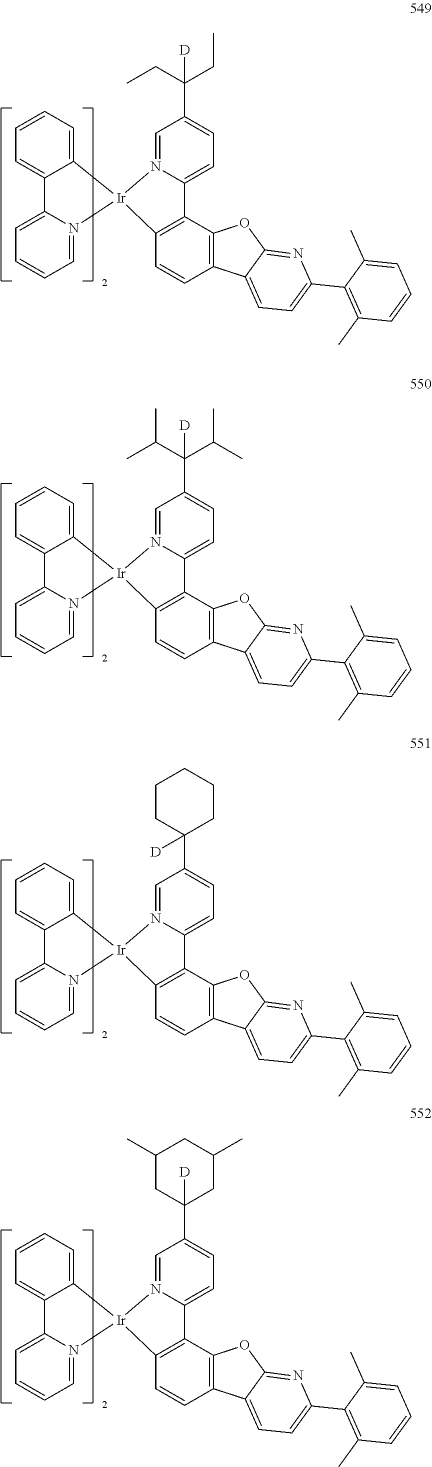

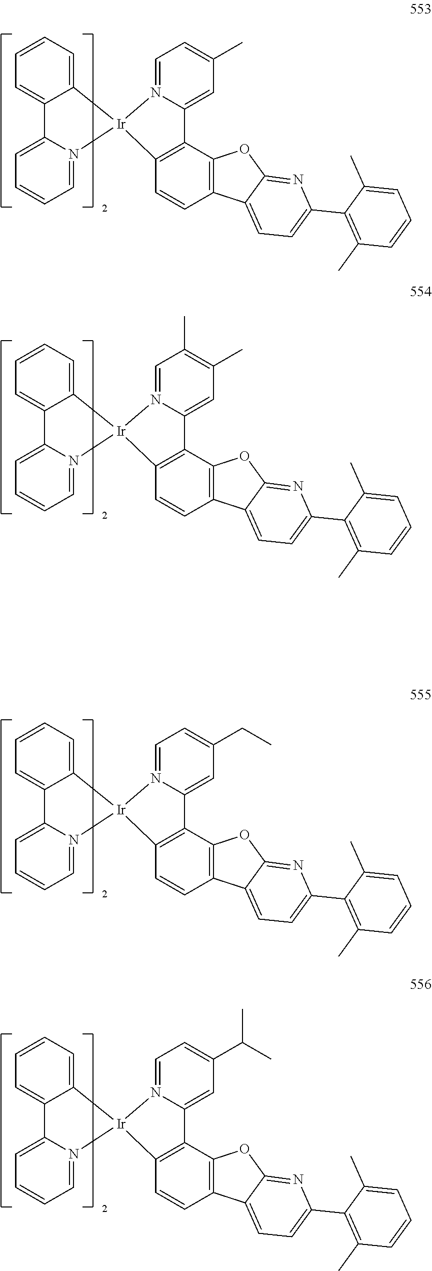

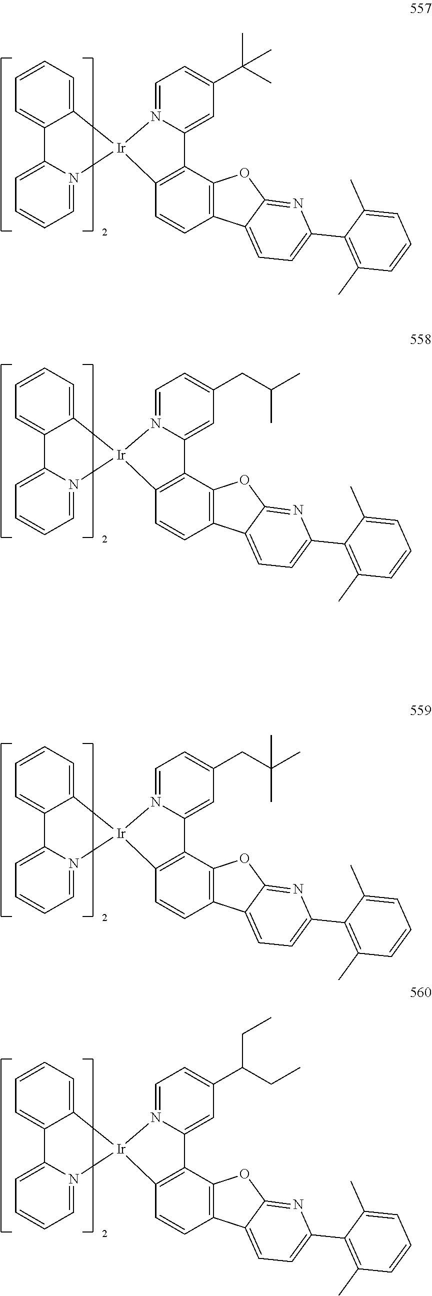

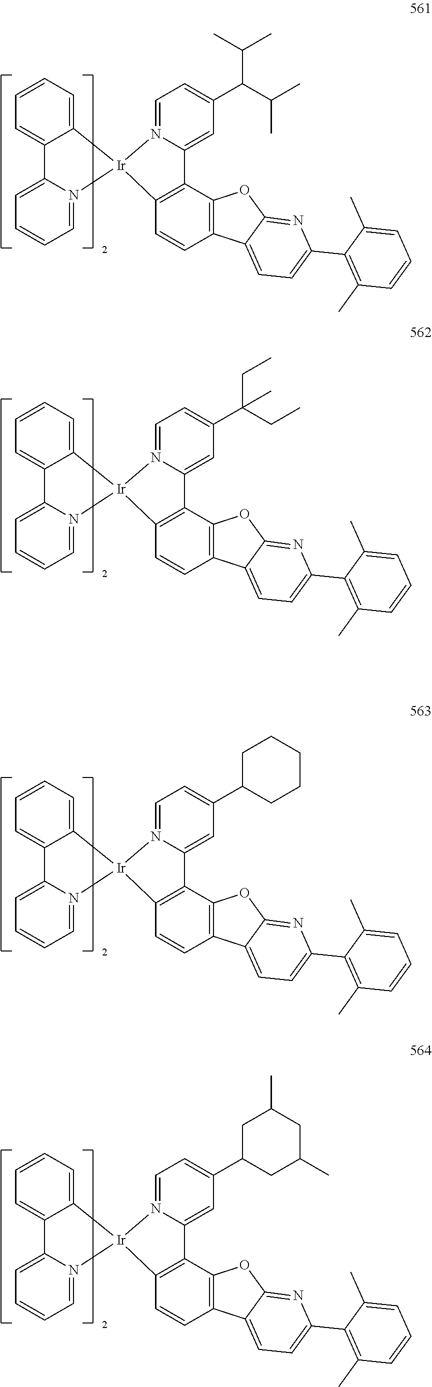

8. An organic light-emitting device, comprising:
a first electrode;
a second electrode facing the first electrode; and
an organic layer disposed between the first electrode and the second electrode,
wherein the organic layer includes a light-emitting layer,
wherein the light-emitting layer contains a dopant material, and
wherein the dopant material includes the organometallic compound according to claim 1.

9. The device of claim 8, wherein the light-emitting layer comprises a green phosphorescent light-emitting layer.

10. The device of claim 8, wherein the organic layer further includes at least one selected from a group consisting of a hole injection layer, a hole transport layer, an electron transport layer and an electron injection layer.

11. An organic light-emitting device, comprising:
a first electrode and a second electrode facing each other; and
a first light-emitting stack and a second light-emitting stack positioned between the first electrode and the second electrode,
wherein each of the first light-emitting stack and the second light-emitting stack includes at least one light-emitting layer,
wherein at least one of the light-emitting layers is a green phosphorescent light-emitting layer,
wherein the green phosphorescent light-emitting layer contains a dopant material, and
wherein the dopant material includes the organometallic compound according to claim 1.

12. An organic light-emitting device, comprising:
a first electrode and a second electrode facing each other; and
a first light-emitting stack, a second light-emitting stack, and a third light-emitting stack positioned between the first electrode and the second electrode,
wherein each of the first light-emitting stack, the second light-emitting stack and the third light-emitting stack includes at least one light-emitting layer,
wherein at least one of the light-emitting layers is a green phosphorescent light-emitting layer,
wherein the green phosphorescent light-emitting layer contains a dopant material, and
wherein the dopant material includes the organometallic compound according to claim 1.

13. An organic light-emitting display device, comprising:
a substrate;
a driving element positioned on the substrate; and
an organic light-emitting element disposed on the substrate and connected to the driving element, wherein the organic light-emitting element includes the organic light-emitting device according to claim 8.
